(19) United States
(12) Patent Application Publication
(10) Pub. No.: US 2026/0247861 A1
(43) Pub. Date: Aug. 20, 2026

(54) COMPOUND, LUMINESCENT ELEMENT MATERIAL, LUMINESCENT ELEMENT, DISPLAY DEVICE, AND ILLUMINATOR

(71) Applicant: TORAY Industries, Inc., Tokyo (JP)

(72) Inventors: Hiroki NODA, Otsu-shi, Shiga (JP); Hidetaka HOSHINO, Otsu-shi, Shiga (JP); Kazumasa NAGAO, Otsu-shi, Shiga (JP)

(73) Assignee: TORAY Industries, Inc., Tokyo (JP)

(21) Appl. No.: 19/119,266

(22) PCT Filed: Oct. 20, 2023
(86) PCT No.: PCT/JP2023/038013

§ 371 Date: Apr. 8, 2025

(30) Foreign Application Priority Data
Oct. 27, 2022 (JP) 2022-172173
Dec. 23, 2022 (JP) 2022-206396

(51) Int. Cl. H10K 85/60; C07F 5/02; C09K 11/06; H10K 50/12; H10K 101/20

(52) U.S. Cl. CPC H10K 85/658; C07F 5/027; C09K 11/06; H10K 85/6572; C09K 2211/1018; H10K 50/12; H10K 2101/20

(57) ABSTRACT

A compound having a structure represented by the following general formula (1) or (2). Provided is a compound which has high luminance efficiency and excellent durability, and has green emission characteristics.

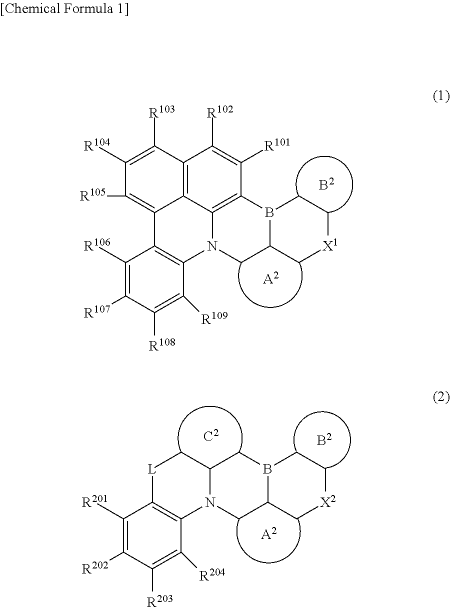

### TECHNICAL FIELD

The present invention relates to a compound, a light emitting element material, a light emitting element, a display device, and an illumination device.

### BACKGROUND ART

The organic thin-film light emitting element emits light by recombination of electrons injected from a cathode and holes injected from an anode in a light emitting layer sandwiched between the two electrodes. The organic thin-film light emitting element has a feature of being capable of achieving thinning, low driving voltage and high luminance, and is also capable of emitting multicolor light.

Toward further increasing the color gamut of display devices and illumination devices using organic thin-film light emitting devices, materials with narrower half widths of emission peaks have been actively developed. There have been proposed, as such technologies, for example, polycyclic aromatic compounds in which a plurality of aromatic rings are linked through boron and nitrogen atoms (see, for example, Patent Literatures 1 to 3).

### CITATION LIST

### Patent Literature

### [Patent Literature 1]

WO 2021/122538 A

### [Patent Literature 2]

JP 7026405 B2

### [Patent Literature 3]

JP 5935199 B2

### [Patent Literature 4]

Chinese Patent Publication No. 107417715

### SUMMARY OF INVENTION

### Technical Problem

The polycyclic aromatic compounds mentioned in Patent Literatures 1 to 4 have high luminance as blue light emitting materials, but cannot be used as green light emitting materials due to their short emission wavelengths. Therefore, an object of the present invention is to provide a compound having green emission characteristics.

### Solution to Problem

In order to solve the above problems, the present invention has the following configuration.
[1] A compound having a structure represented by the following general formula (1) or (2):

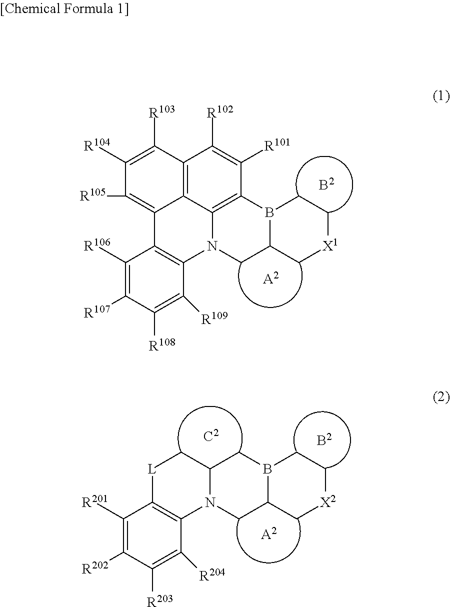

wherein, in the above general formula (1), R¹⁰¹ to R¹⁰⁹ are each independently selected from the group consisting of a hydrogen atom, a halogen atom, a cyano group, an alkyl group, a cycloalkyl group, an alkenyl group, a cycloalkenyl group, an alkynyl group, an alkoxy group, an alkylthio group, an aryl ether group, an arylthio ether group, an aryl group, a heteroaryl group, a carboxyl group, an oxycarbonyl group, a carbamoyl group, an amino group, a nitro group and a silyl group; and these groups may further have a substituent; in which R¹⁰⁸ is selected from substituents other than a hydrogen atom;
ring A¹ and ring B¹ are each independently a substituted or unsubstituted aryl ring having 6 to 30 ring-forming carbon atoms, or a substituted or unsubstituted heteroaryl ring having 5 to 30 ring-forming atoms;
X¹ is O, N—R¹¹⁰ or S, R¹¹⁰ is an alkyl group, a cycloalkyl group, an alkenyl group, an imino group, an aryl group or a heteroaryl group; these groups may further have a substituent; and R¹¹⁰ may further form a ring structure between ring A¹ or ring B¹ via a linking group; in this case, the linking group is a single bond, —O—, —S—, >CR¹¹¹R¹¹² or >SiR¹¹³R¹¹⁴; R¹¹¹ to R¹¹⁴ are each independently selected from the group consisting of a hydrogen atom, a halogen atom, an alkyl group, a cycloalkyl group, an aryl group and a heteroaryl group, these groups may further have a substituent; and R¹¹¹ and R¹¹², and R¹¹³ and R¹¹⁴ may be further bonded via a linking group; and
wherein, in the above general formula (2), R²⁰¹ to R²⁰⁴ are each independently selected from the group consisting of a hydrogen atom, a halogen atom, a cyano group, an alkyl group, a cycloalkyl group, an alkenyl group, a cycloalkenyl group, an alkynyl group, an alkoxy group, an alkylthio group, an aryl ether group, an arylthio ether group, an aryl group, a heteroaryl group, a carboxyl group, an oxycarbonyl group, a carbamoyl group, an amino group, a nitro group and a silyl group; and these groups may further have a substituent; in which R²⁰³ is selected from substituents other than a hydrogen atom;
ring A² and ring B² are each independently a substituted or unsubstituted aryl ring having 6 to 30 ring-forming carbon atoms, or a substituted or unsubstituted heteroaryl ring having 5 to 30 ring-forming atoms;
ring C² is a substituted or unsubstituted polycyclic aromatic hydrocarbon having 11 or more and 20 or less ring-forming atoms;
L is a single bond, O, S, >CR²⁰⁵R²⁰⁶ or >SiR²⁰⁷R²⁰⁸; R²⁰⁵ to R²⁰⁸ are each independently selected from the group consisting of a hydrogen atom, a halogen atom, an alkyl group, a cycloalkyl group, an aryl group and a heteroaryl group, these groups may further have a substituent; and R²⁰⁵ and R²⁰⁶, and R²⁰⁷ and R²⁰⁸ may be further bonded via a linking group;
X² is O, N—R²⁰⁹ or S, R²⁰⁹ is an alkyl group, a cycloalkyl group, an alkenyl group, an imino group, an aryl group or a heteroaryl group; these groups may further have a substituent; and R²⁰⁹ may further form a ring structure between ring A² or ring B² via a linking group; in this case, the linking group is a single bond, —O—, —S—, >CR²¹⁰R²¹¹ or >SiR²¹²R²¹³; R²¹⁰ to R²¹³ are each independently selected from the group consisting of a hydrogen atom, a halogen atom, an alkyl group, a cycloalkyl group, an aryl group and a heteroaryl group, these groups may further have a substituent; and R²¹⁰ and R²¹¹, and R²¹² and R²¹³ may be further bonded via a linking group.
[2] The compound according to [1], wherein R¹⁰⁸ and R²⁰³ are selected from an alkyl group, an aryl group and a heteroaryl group.
[3] The compound according to [1] or [2], wherein, in the general formula (2), L is a single bond.
[4] The compound according to any one of [1] to [3], wherein, in the general formula (2), X² is N—R²⁰⁹, and R²⁰⁹ is a substituted or unsubstituted aryl group, a substituted or unsubstituted heteroaryl group, a substituted or unsubstituted alkenyl group, or a substituted or unsubstituted imino group.
[5] A light emitting element material comprising the compound according to any one of [1] to [4].
[6] A light emitting element material comprising a cathode, an anode, and one or more organic layers disposed between the cathode and the anode, wherein at least one layer of the organic layers contains the compound according to any one of [1] to [4].
[7] The light emitting element according to [6], wherein at least one layer of the one or more organic layers is a light emitting layer, and the light emitting layer contains the compound according to any one of [1] to [4].
[8] The light emitting element according to [7], wherein the light emitting layer further contains a matrix material.
[9] The light emitting element according to [7] or [8], wherein the light emitting layer further contains a compound which exhibits delayed fluorescence.
[10] The light emitting element according to [7], wherein the light emitting layer further contains a matrix material and a compound which exhibits delayed fluorescence, and when excited singlet energy of the matrix material is S₁ (1), excited singlet energy of a compound which exhibits delayed fluorescence is S₁ (2), and excited singlet energy of a compound having one or more structures represented by the general formula (1) or (2) is S₁ (3), they satisfy the relationship of the formula 1:

$${S}_{1} ( 1 ) > {S}_{1} ( 2 ) > {S}_{1} ( 3 ) . \qquad ( Formula 1 )$$

[11] The light emitting element according to any one of [7] to [10], further comprising a charge generation layer.
[12] The light emitting element according to any one of [7] to [11], which is a top-emission type organic electroluminescence element.
[13] A photoelectric conversion material comprising the compound according to any one of [1] to [4].
[14] A color conversion composition which converts incident light into light having a wavelength different from that of the incident light, comprising the compound according to any one of [1] to [4] and a binder resin.
[15] A color conversion sheet comprising the color conversion composition according to [14], or a cured product thereof.
[16] A light source unit comprising a light source and the color conversion sheet according to [15].
[17] A display device comprising the light emitting element according to any one of [6] to [12].
[18] A display device comprising the light source unit according to [16].
[19] An illumination device comprising the light emitting element according to any one of [6] to [12].
[20] An illumination device comprising the light source unit according to [16].

### Advantageous Effects of Invention

The compound of the present invention has a longer emission wavelength as compared with the conventionally known polycyclic aromatic compounds, and has green emission characteristics. The compound of the present invention can provide a light emitting device which is excellent in color purity of green emission.

### DESCRIPTION OF EMBODIMENTS

The present invention will be described in detail below. However, the present invention is not limited to the embodiments and specific examples mentioned below.

### <Compound Having Structure Represented by General Formula (1) or (2)>

The compound according to the embodiments of the present invention has a structure represented by the following general formula (1) or (2).

The polycyclic aromatic compounds mentioned in Patent Literatures 1 to 4 have a strong and highly planar skeleton and therefore exhibit high luminous efficiency as blue light emitting materials. Because of small peak half width in the emission wavelength, the color purity can be improved. However, they cannot be used as a green light emitting material.

In the compound according to the embodiments of the present invention, a 7H-benzo[kl]acridine skeleton in the general formula (1) or a polycyclic aromatic hydrocarbon having 11 or more and 20 or less ring-forming atoms in the general formula (2) is introduced to extend the conjugation length due to the fused ring structure, thus making it possible to lengthen the emission wavelength of a polycyclic aromatic compound which emits blue light to obtain green emission. In the compound according to the embodiments of the present invention, the entire molecule is made rigid by introducing a fused ring structure. This limits the vibration of the compound according to the embodiments of the present invention and suppresses deactivation in the excited state. Therefore, when the compound according to the embodiments of the present invention is used as a light emitting element material, the efficiency and durability of the light emitting device can be improved.

In the present invention, the term “number of ring-forming atoms” refers to the number of atoms that form the skeleton of a monocyclic ring or a fused ring, and does not include the number of atoms in the substituents substituted on the ring. For example, when the ring is an anthracene ring, the number of ring-forming atoms is 14, regardless of the presence or absence of substituents.

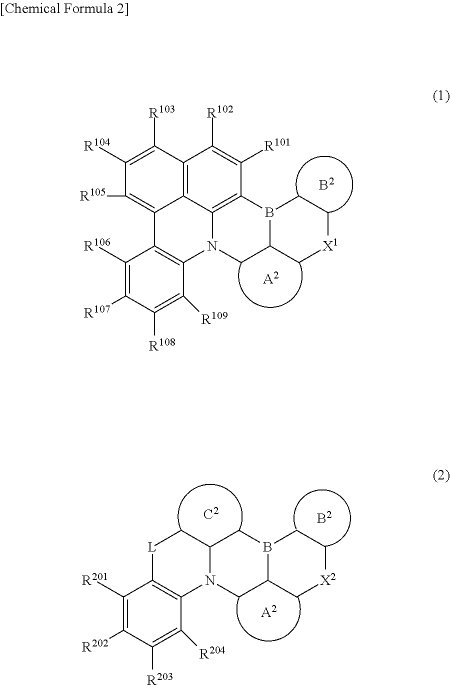

In the above general formula (1), R¹⁰¹ to R¹⁰⁹ are each independently selected from the group consisting of a hydrogen atom, a halogen atom, a cyano group, an alkyl group, a cycloalkyl group, an alkenyl group, a cycloalkenyl group, an alkynyl group, an alkoxy group, an alkylthio group, an aryl ether group, an arylthio ether group, an aryl group, a heteroaryl group, a carboxyl group, an oxycarbonyl group, a carbamoyl group, an amino group, a nitro group and a silyl group. These groups may further have a substituent.

From the viewpoints of the electrical stability or thermal stability, it is preferable that R¹⁰¹ to R¹⁰⁹ are each independently selected from the group consisting of a hydrogen atom, a substituted or unsubstituted alkyl group, a substituted or unsubstituted cycloalkyl group, a substituted or unsubstituted aryl group, and a substituted or unsubstituted heteroaryl group.

However, in order to suppress the formation of an isomer of a compound having a structure represented by the general formula (1) as R¹⁰⁹ becomes a reaction point in the process of synthesizing a compound having a structure represented by the general formula (1), R¹⁰⁸ is selected from the above groups other than a hydrogen atom. R¹⁰⁸ is preferably a substituted or unsubstituted alkyl group, a substituted or unsubstituted aryl group, or a substituted or unsubstituted heteroaryl group, more preferably a secondary alkyl group, a tertiary alkyl group, or a substituted or unsubstituted aryl group, and particularly preferably a tertiary alkyl group.

Ring A¹ and ring B¹ are each independently a substituted or unsubstituted aryl ring having 6 to 30 ring-forming carbon atoms, or a substituted or unsubstituted heteroaryl ring having 5 to 30 ring-forming atoms. Specific examples of the ring include, but are not limited to, a substituted or unsubstituted phenyl ring, a substituted or unsubstituted naphthyl ring, a substituted or unsubstituted phenanthryl ring, a substituted or unsubstituted anthryl ring, a substituted or unsubstituted dibenzofuranyl ring, a substituted or unsubstituted dibenzothiophenyl ring, and a substituted or unsubstituted carbazolyl ring. From the viewpoint of the electrical stability or thermal stability, ring B¹ is more preferably a substituted or unsubstituted phenyl ring, or a substituted or unsubstituted naphthyl ring.

X¹ is O, N—R¹¹⁰ or S, and R¹¹⁰ is an alkyl group, a cycloalkyl group, an alkenyl group, an imino group, an aryl group or a heteroaryl group. These groups may further have a substituent. R¹⁰⁰ may further form a ring structure between ring A¹ or ring B¹ via a linking group. In this case, the linking group is a single bond, —O—, —S—, >CR¹¹¹R¹¹² or >SiR¹¹³R¹¹⁴. R¹¹¹ to R¹¹⁴ are each independently selected from the group consisting of a hydrogen atom, a halogen atom, an alkyl group, a cycloalkyl group, an aryl group and a heteroaryl group, and these groups may further have a substituent. R¹¹¹ and R¹¹², and R¹¹³ and R¹¹⁴ may be further bonded via a linking group.

From the viewpoint of the electrical stability or thermal stability, it is preferable that X¹ is N—R¹¹⁰, and R¹¹⁰ is a substituted or unsubstituted aryl group, a substituted or unsubstituted heteroaryl group, a substituted or unsubstituted alkenyl group, or a substituted or unsubstituted imino group.

In the above general formula (2), R²⁰¹ to R²⁰⁴ are each independently selected from the group consisting of a hydrogen atom, a halogen atom, a cyano group, an alkyl group, a cycloalkyl group, an alkenyl group, a cycloalkenyl group, an alkynyl group, an alkoxy group, an alkylthio group, an aryl ether group, an arylthio ether group, an aryl group, a heteroaryl group, a carboxyl group, an oxycarbonyl group, a carbamoyl group, an amino group, a nitro group and a silyl group These groups may further have a substituent.

From the viewpoint of the electrical stability or thermal stability, it is preferable that R²⁰¹ to R²⁰⁴ are each independently selected from the group consisting of a hydrogen atom, a substituted or unsubstituted alkyl group, a substituted or unsubstituted cycloalkyl group, a substituted or unsubstituted aryl group, and a substituted or unsubstituted heteroaryl group.

However, in order to suppress the formation of an isomer of a compound having a structure represented by the general formula (2) as R²⁰⁴ becomes a reaction point in the process of synthesizing a compound having a structure represented by the general formula (2), R²⁰³ is selected from the above groups other than a hydrogen atom. R²⁰³ is preferably a substituted or unsubstituted alkyl group, a substituted or unsubstituted aryl group, or a substituted or unsubstituted heteroaryl group, more preferably a secondary alkyl group, a tertiary alkyl group, or a substituted or unsubstituted aryl group, and particularly preferably a tertiary alkyl group.

Ring A² and ring B² are each independently a substituted or unsubstituted aryl ring having 6 to 30 ring-forming carbon atoms, or a substituted or unsubstituted heteroaryl ring having 5 to 30 ring-forming atoms. Specific examples of the ring include, but are not limited to, a substituted or unsubstituted phenyl ring, a substituted or unsubstituted naphthyl ring, a substituted or unsubstituted phenanthryl ring, a substituted or unsubstituted anthryl ring, a substituted or unsubstituted dibenzofuranyl ring, a substituted or unsubstituted dibenzothiophenyl ring, and a substituted or unsubstituted carbazolyl ring.

From the viewpoint of the electrical stability or thermal stability, ring A² is preferably a substituted or unsubstituted phenyl ring. Ring B² is more preferably a substituted or unsubstituted phenyl ring, a substituted or unsubstituted naphthyl ring, a substituted or unsubstituted dibenzofuranyl ring, or a substituted or unsubstituted acenaphthyl ring.

Ring C² is a substituted or unsubstituted polycyclic aromatic hydrocarbon having 11 or more and 20 or less ring-forming atoms. Specific examples of the ring are shown in the following (3), but are not limited thereto.

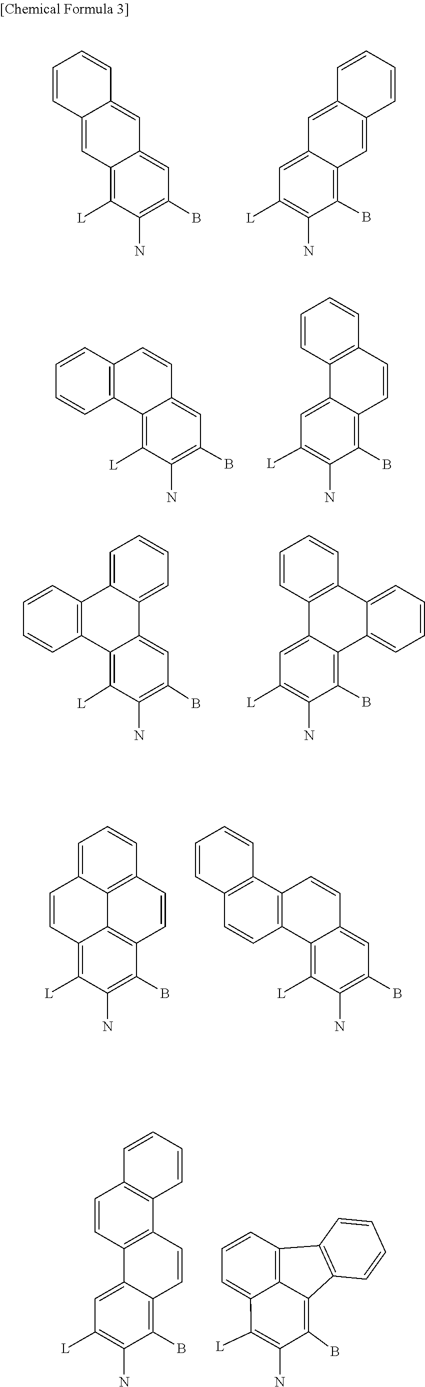

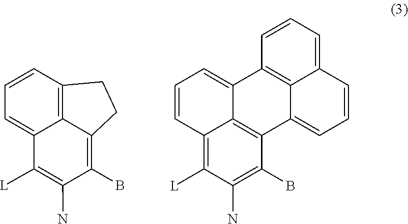

In the above formula (3), B, N and L each represent a bonding site to B, N and L in the general formula (2). The polycyclic aromatic hydrocarbon represented by the formula (3) may further have a substituent.

In the general formula (2), L is a single bond, O, S, >CR²⁰⁵R²⁰⁶ or >SiR²⁰⁷R²⁰⁸. R²⁰⁵ to R²⁰⁸ are each independently selected from the group consisting of a hydrogen atom, a halogen atom, an alkyl group, a cycloalkyl group, an aryl group and a heteroaryl group, and these groups may further have a substituent. R²⁰⁵ and R²⁰⁶, and R²⁰⁷ and R²⁰⁸ may be further bonded via a linking group. From the viewpoints of the light emitting element efficiency and element life, L is preferably a single bond.

X² is O, N—R²⁰⁹ or S, and R²⁰⁹ is an alkyl group, a cycloalkyl group, an alkenyl group, an imino group, an aryl group or a heteroaryl group. These groups may further have a substituent. R²⁰⁹ may further form a ring structure between ring A² or ring B² via a linking group. In this case, the linking group is a single bond, —O—, —S—, >CR²¹⁰R²¹¹ or >SiR²¹²R²¹³. R²¹⁰ to R²¹³ are each independently selected from the group consisting of a hydrogen atom, a halogen atom, an alkyl group, a cycloalkyl group, an aryl group and a heteroaryl group, and these groups may further have a substituent. R²¹⁰ and R²¹¹, and R²¹² and R²¹³ may be further bonded via a linking group.

From the viewpoint of the electrical stability or thermal stability, it is preferable that X² is N—R²⁰⁹, and R²⁰⁹ is a substituted or unsubstituted aryl group, a substituted or unsubstituted heteroaryl group, a substituted or unsubstituted alkenyl group, or a substituted or unsubstituted imino group.

The compound having a structure represented by the general formula (2) is preferably a compound represented by any one of the following general formulas (4) to (8).

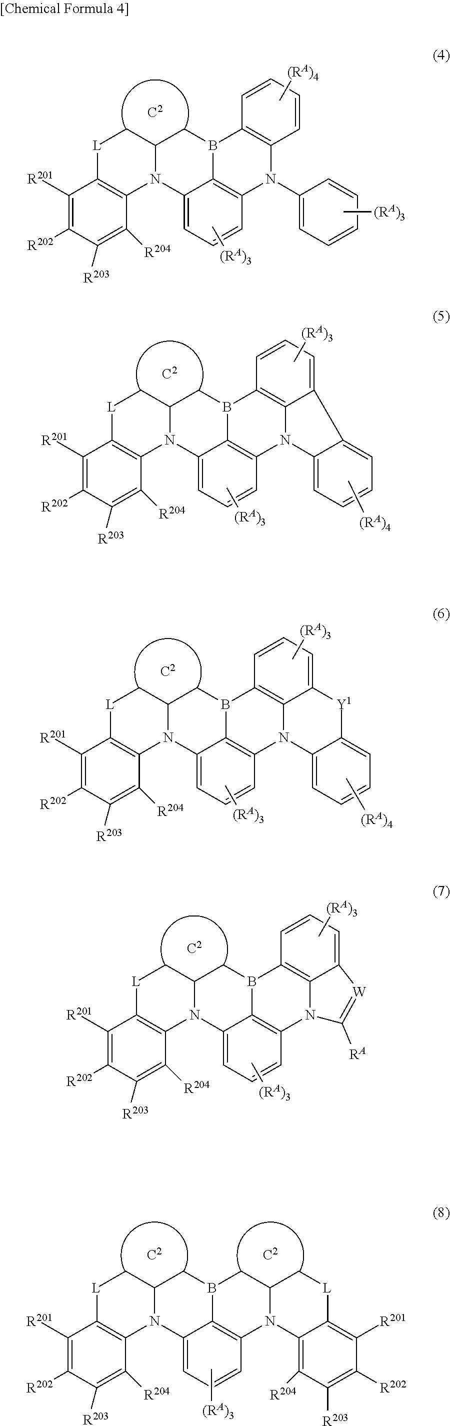

In the above general formula (4) to (8), R²⁰¹ to R²⁰⁴, L and C² have the same meanings as R²⁰¹ to R²⁰⁴, L and C² in the general formula (2). R^{A} each independently represent a hydrogen atom, a substituted or unsubstituted alkyl group, a substituted or unsubstituted cycloalkyl group, a substituted or unsubstituted aryl group, or a substituted or unsubstituted heteroaryl group. However, one or more pairs of adjacent two or more R^{A} may be bonded to each other to form a substituted or unsubstituted monocyclic ring, or a substituted or unsubstituted fused ring. Y¹ is —O—, —S—, >CR²¹⁰R²¹¹ or >SiR²¹²R²¹³. R²¹⁰ to R²¹³ have the same meanings as R²¹⁰ to R²¹³ in the general formula (2). W is N or C—R^{A}.

At least one of R^{A} is preferably an alkyl group, a substituted or unsubstituted aryl group, or a substituted or unsubstituted heteroaryl group. It is preferable that one pair of adjacent two or more R^{A} are bonded to each other to form a substituted or unsubstituted monocyclic ring, or a substituted or unsubstituted fused ring. Such a monocyclic or fused ring include is not particularly limited and is preferably a benzofuran ring, a benzene ring, an indane ring, a phenanthrene ring and a fluoranthene ring.

The compound having a structure represented by the general formula (2) is more preferably a compound represented by any one of the following general formulas (9-1) to (9-48).

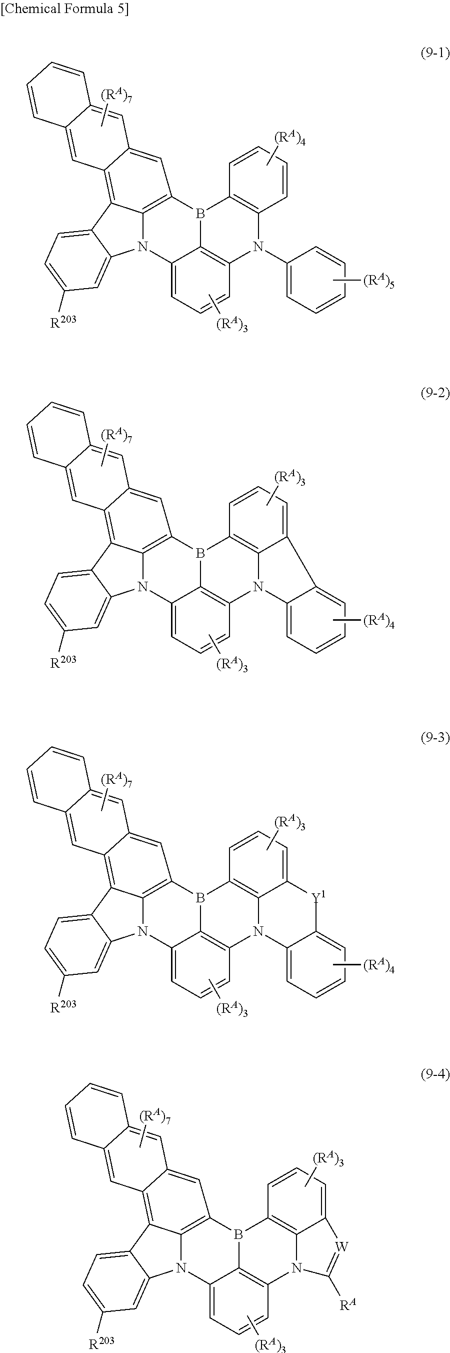

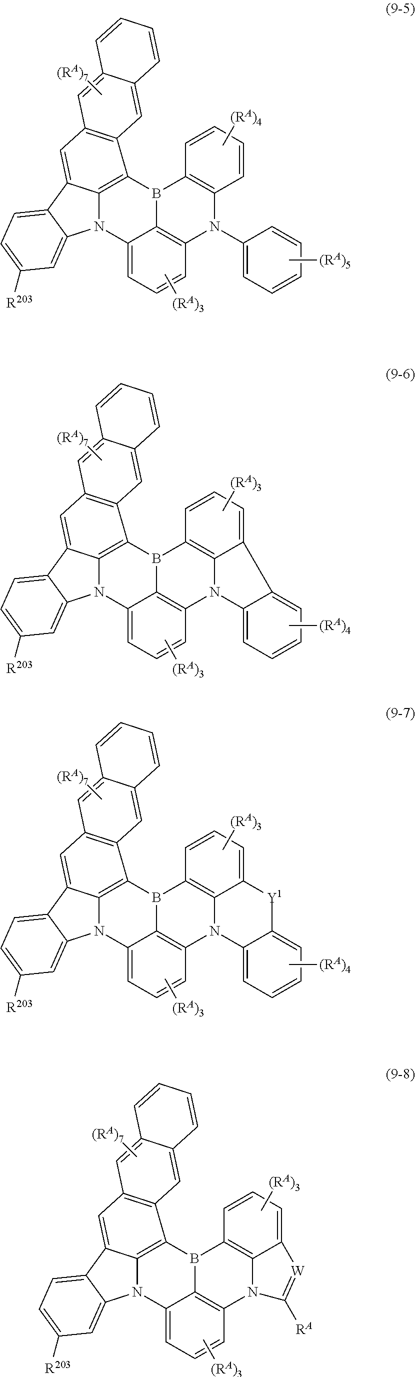

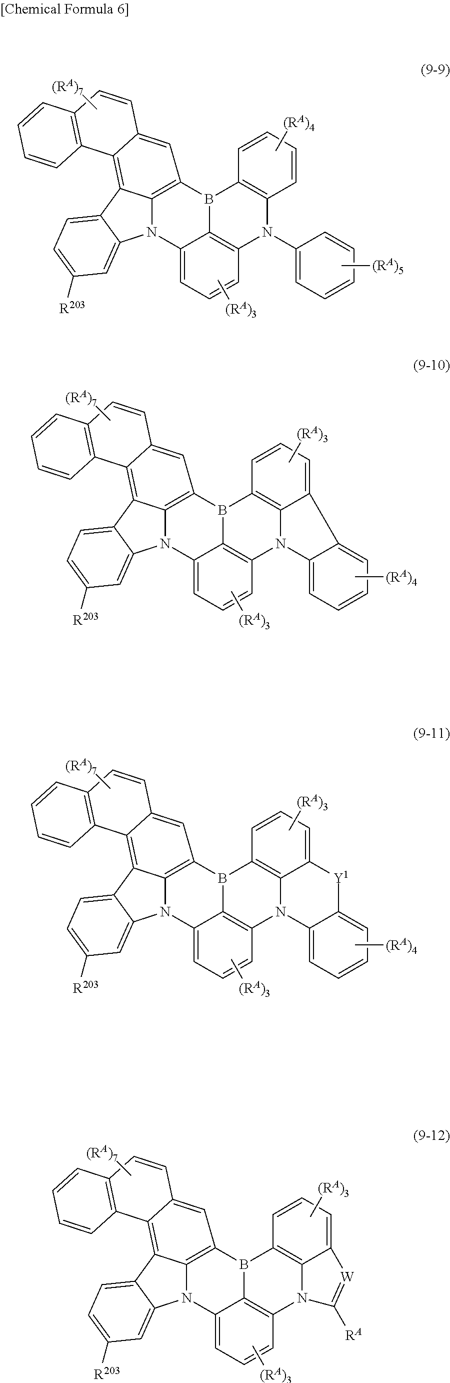

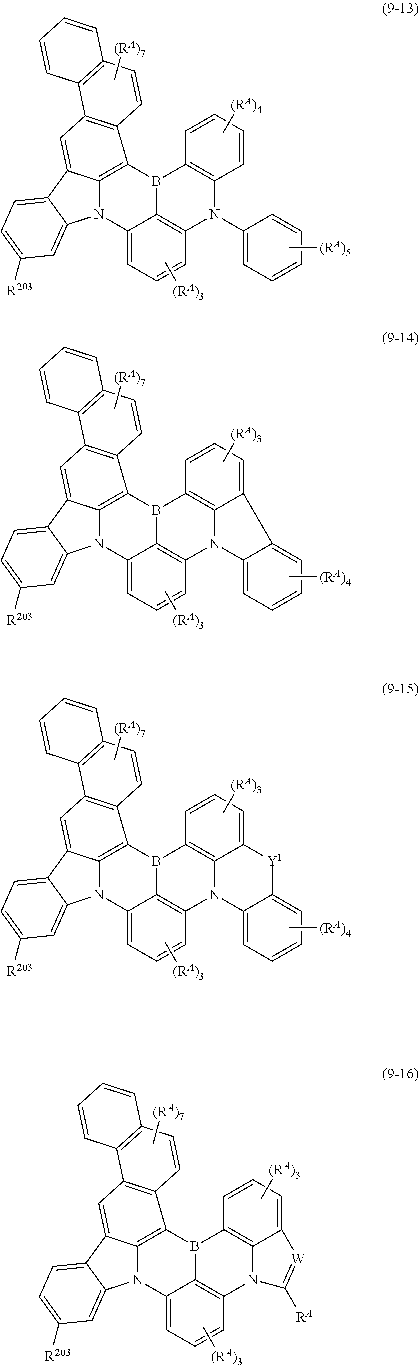

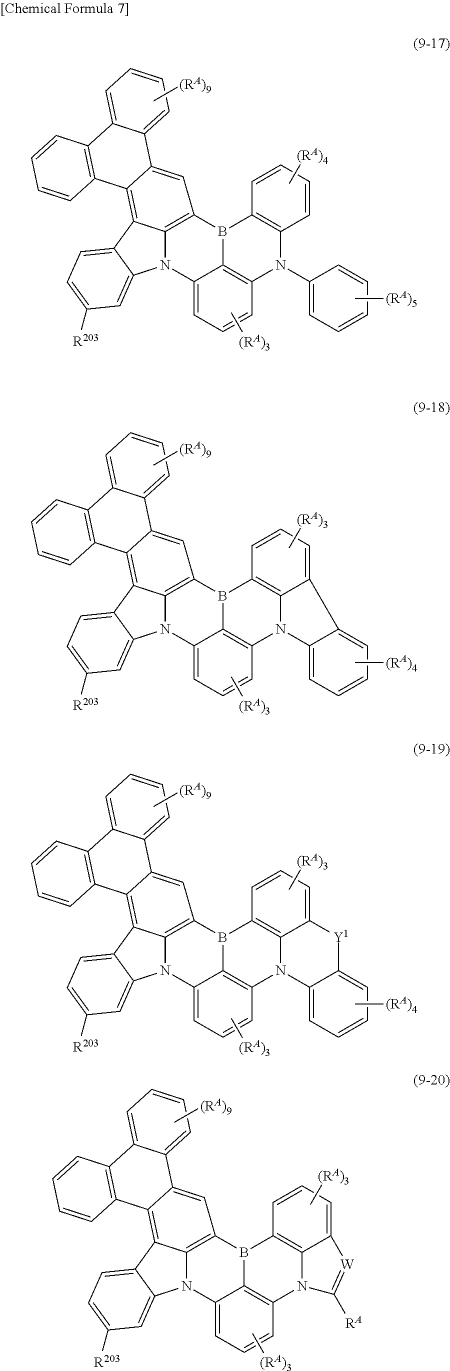

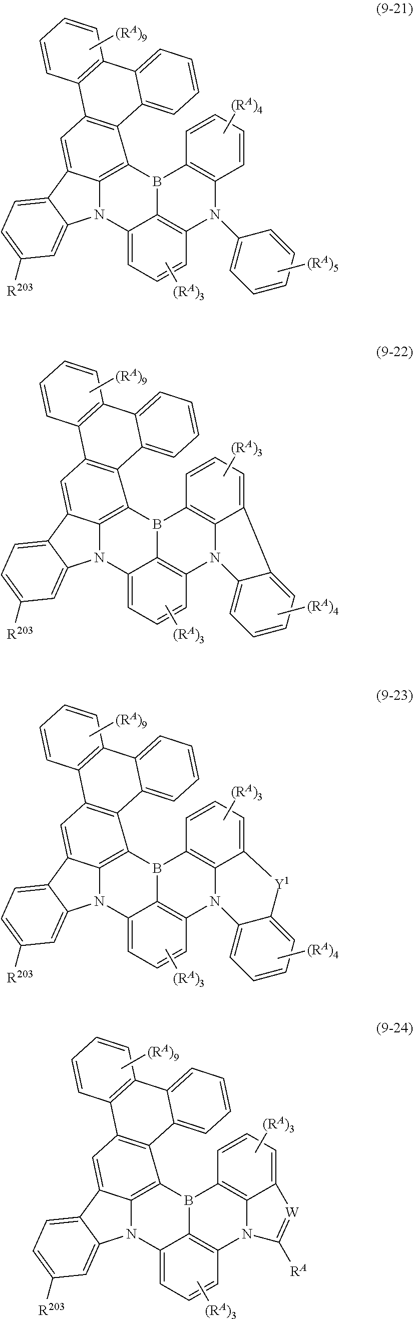

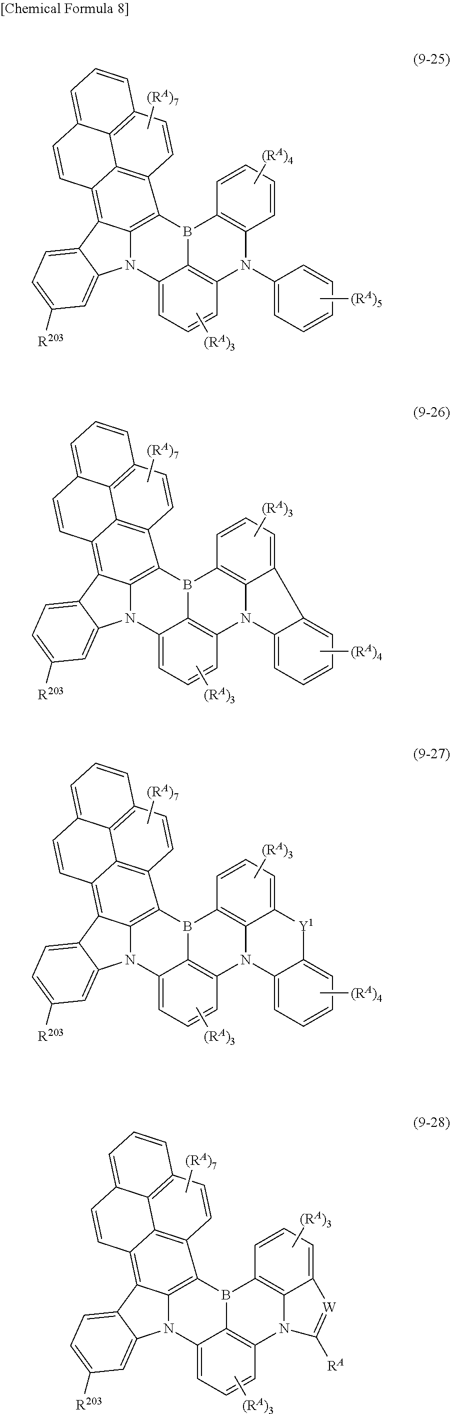

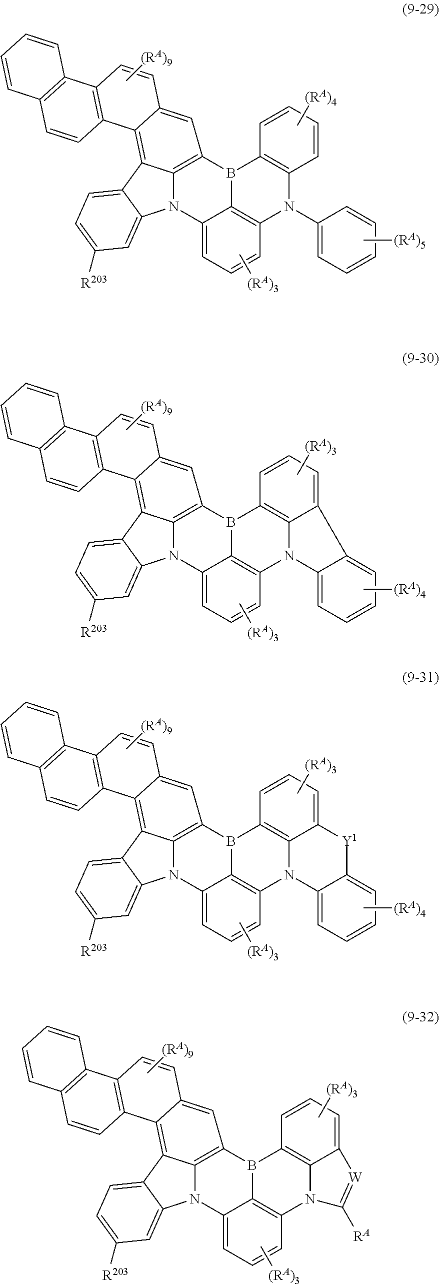

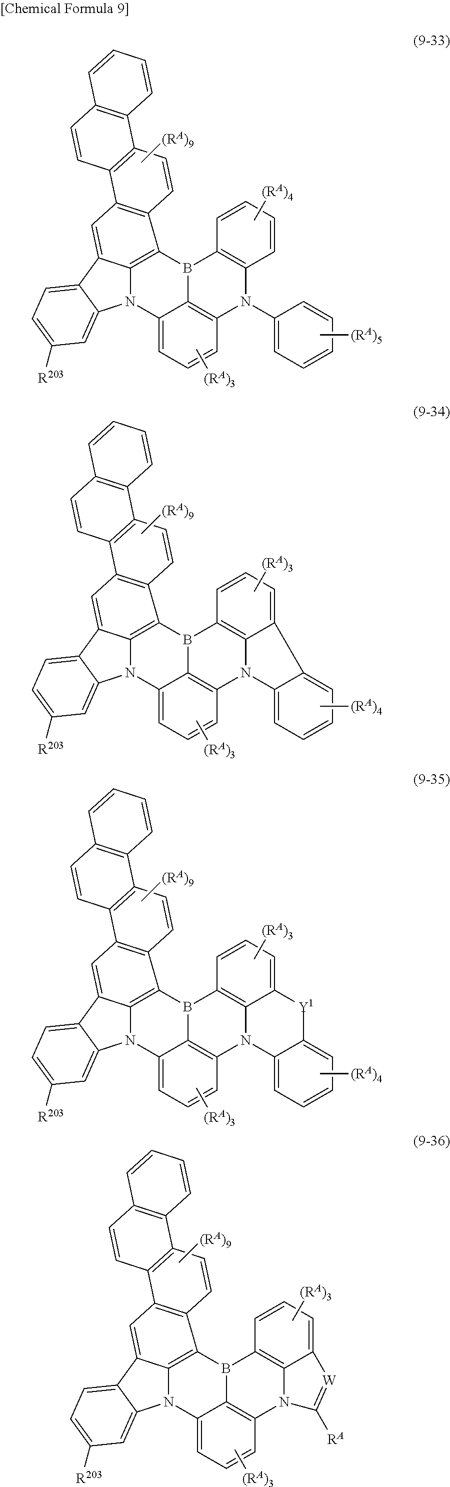

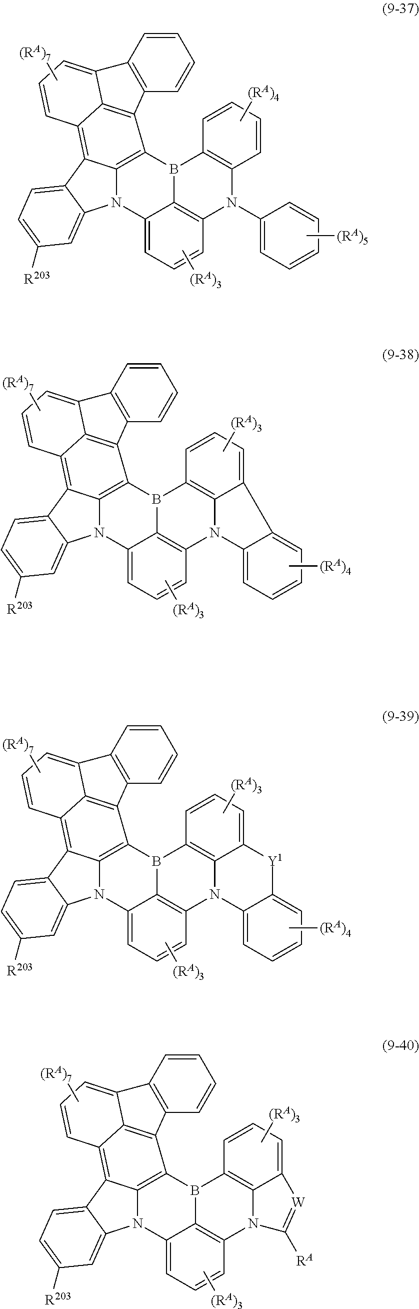

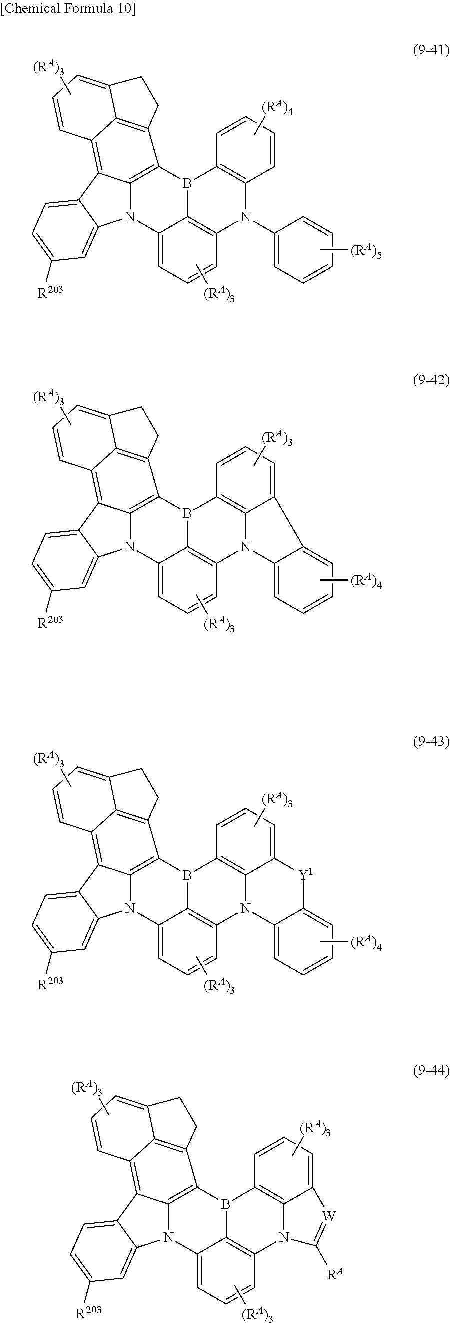

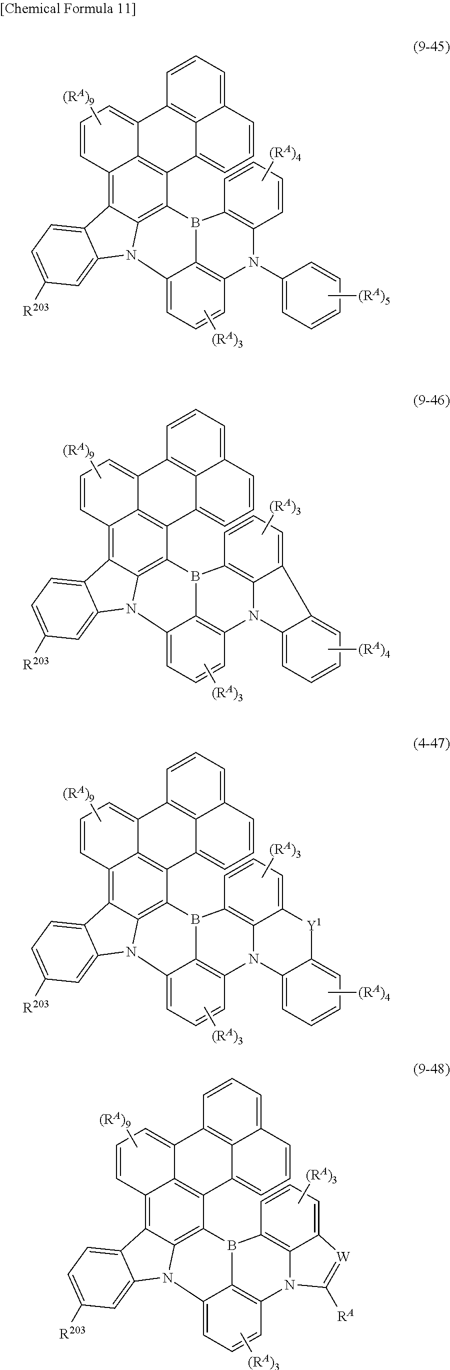

In the above general formulas (9-1) to (9-48), R²⁰³ has the same meaning as R²⁰³ in the general formula (2) R^{A}, Y¹ and W have the same meanings as R^{A}, Y¹ and W in the general formulas (4) to (8).

From the viewpoints of the light emitting element efficiency and element life, as one embodiment of the compound having a structure represented by the general formula (2), a compound represented by the general formula (5) is preferable, a compound represented by the general formula (9-2), (9-6), (9-10), (9-14), (9-18), (9-22), (9-26), (9-30), (9-34), (9-38), (9-42) or (9-46) is more preferable, a compound represented by (9-26) or (9-42) is particularly preferable, and a compound represented by (9-26) is most preferable.

The compound having a structure represented by the general formula (1) is preferably a compound represented by any one of the following general formulas (10) to (14).

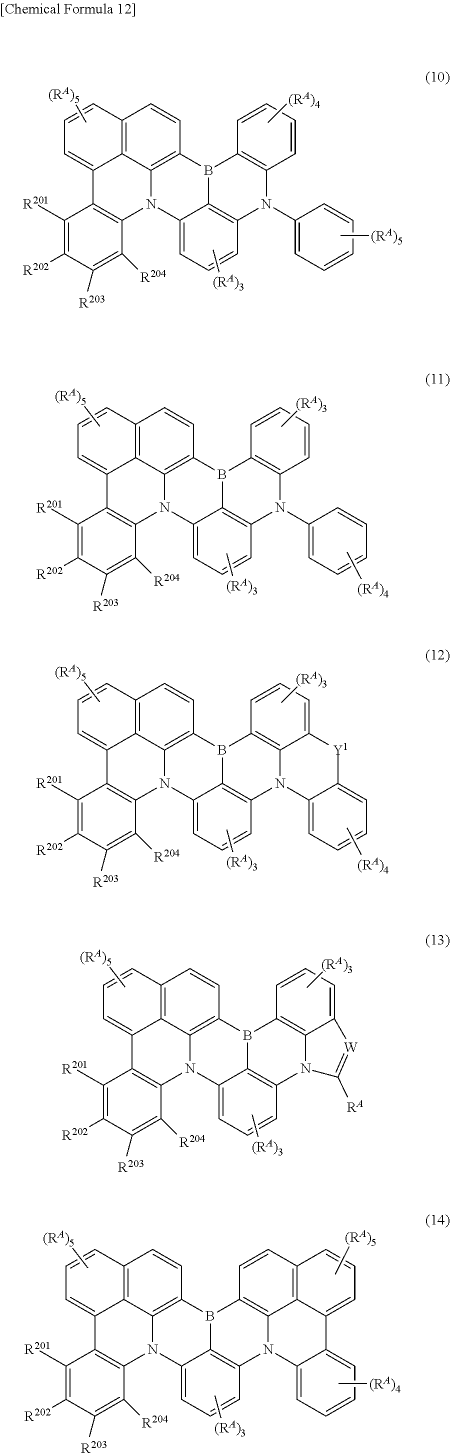

In the above general formulas (10) to (14), R²⁰¹ to R²⁰⁴ have the same meaning as R²⁰¹ to R²⁰⁴ in the general formula (2). R^{A}, Y¹ and W have the same meaning as R^{A}, Y¹ and W in the general formula (4) to (8). However, R^{A} in the general formulas (10) to (14) do not combine with each other in pairs consisting of two or more neighbors.

In all the groups of the present invention, a hydrogen atom may be a deuterium atom. The same applies to the compounds and partial structures thereof which will be described hereinafter.

In the following description, the term “unsubstituted” in the case of “substituted or unsubstituted” means that a hydrogen atom or a deuterium atom is bonded.

Halogen refers to fluorine, chlorine, bromine or iodine.

A cyano group is a group whose structure is represented by —C≡N. Here, it is a carbon atom which is bonded to the other group.

The alkyl group represents, for example, a saturated aliphatic hydrocarbon group such as a methyl group, an ethyl group, an n-propyl group, an isopropyl group, an n-butyl group, a sec-butyl group or a tert-butyl group, which may or may not have a substituent. The number of carbon atoms of the alkyl group is not particularly limited, but is preferably 1 or more and 20 or less, and more preferably 1 or more and 8 or less, from the viewpoint of the availability and cost. The number of carbon atoms mentioned here includes the number of carbon atoms contained in the substituent bonded to the alkyl group, and the same applies to other substituents that defines the number of carbon atoms.

The cycloalkyl group represents, for example, a saturated alicyclic hydrocarbon group such as a cyclopropyl group, a cyclohexyl group, a norbornyl group or an adamantyl group, which may or may not have a substituent. The number of carbon atoms of the cycloalkyl group is not particularly limited, but is preferably within a range of 3 or more and 20 or less.

The alkenyl group represents, for example, an unsaturated aliphatic hydrocarbon group having a double bond, such as a vinyl group, an allyl group or a butadienyl group, which may or may not have a substituent. The number of carbon atoms of the alkenyl group is not particularly limited, but is preferably within a range of 2 or more and 20 or less.

The cycloalkenyl group represents, for example, an unsaturated alicyclic hydrocarbon group having a double bond, such as a cyclopentenyl group, a cyclopentadienyl group or a cyclohexenyl group, which may or may not have a substituent. The number of carbon atoms of the cycloalkenyl group is not particularly limited, but is preferably within a range of 3 or more and 20 or less.

The alkynyl group represents, for example, an unsaturated aliphatic hydrocarbon group having a triple bond, such as an ethynyl group, which may or may not have a substituent. The number of carbon atoms of the alkynyl group is not particularly limited, but is preferably within a range of 2 or more and 20 or less.

The alkoxy group represents, for example, a functional group in which an aliphatic hydrocarbon group is bonded via an ether bond, such as a methoxy group, an ethoxy group or a propoxy group, which may or may not have a substituent. The number of carbon atoms of the alkoxy group is not particularly limited, but is preferably within a range of 1 or more and 20 or less.

The alkylthio group is an alkoxy group in which the oxygen atom of the ether bond is replaced with a sulfur atom. The hydrocarbon group of the alkylthio group may or may not have a substituent. The number of carbon atoms of the alkylthio group is not particularly limited, but is preferably within a range of 1 or more and 20 or less.

The aryl ether group represents, for example, a functional group in which an aromatic hydrocarbon group is bonded via an ether bond, such as a phenoxy group, which may or may not have a substituent. The number of ring-forming carbon atoms of the aryl ether group is not particularly limited, but is preferably within a range of 6 or more and 40 or less.

The arylthio ether group is an aryl ether group in which the oxygen atom of the ether bond is replaced with a sulfur atom. This may or may not have a substituent. The number of ring-forming carbon atoms of the arylthio ether group is not particularly limited, but is preferably within a range of 6 or more and 40 or less.

The aryl group represents, for example, an aromatic hydrocarbon group such as a phenyl group, a biphenyl group, a terphenyl group, a naphthyl group, a fluorenyl group, a benzofluorenyl group, a dibenzofluorenyl group, a phenanthryl group, an anthracenyl group, a benzophenanthryl group, a benzoanthracenyl group, a chrysenyl group, a pyrenyl group, a fluoranthenyl group, a triphenylenyl group, a benzofluoranthenyl group, a dibenzoanthracenyl group, a peryleneyl group or a helicenyl group. The aryl group may or may not have a substituent. Of these, a phenyl group, a biphenyl group, a terphenyl group, a naphthyl group, a fluorenyl group, a phenanthryl group, an anthracenyl group, a pyrenyl group, a fluoranthenyl group and a triphenylenyl group are preferable. The number of ring-forming carbon atoms is not particularly limited, but is preferably within a range of 6 or more and 40 or less, and more preferably 6 or more and 30 or less.

In the case of a substituted phenyl group, when there is a substituent on each of two adjacent carbon atoms in the phenyl group, the substituents may form a ring structure with each other. The resulting group can correspond to any one of “substituted phenyl group”, “aryl group having a structure in which two or more rings are fused” and “heteroaryl group having a structure in which two or more rings are fused” depending on the structure.

The heteroaryl group represents, for example, a cyclic aromatic group having an atom other than carbon in one or plural rings, such as a pyridyl group, a furanyl group, a thiophenyl group, a quinolinyl group, an isoquinolinyl group, a pyrazinyl group, a pyrimidyl group, a pyridadinyl group, a triazinyl group, a naphthyldinyl group, a cinnolinyl group, a phtalazinyl group, a quinoxalinyl group, a quinazolinyl group, a benzofuranyl group, a benzothiophenyl group, an indolyl group, a dibenzofuranyl group, a dibenzothiophenyl group, a carbazolyl group, a benzocarbazolyl group, a carbolinyl group, an indolocarbazolyl group, a benzofurocarbazolyl group, a benzothienocarbazolyl group, a dihydroindenocarbazolyl group, a benzoquinolinyl group, an acridinyl group, a dibenzoacrydinyl group, a benzoimidazolyl group, an imidazopyridyl group, a benzoxazolyl group, a benzothiazolyl group or a phenanthrolinyl group. However, the naphthyridinyl group represents any one of a 1,5-naphthyridinyl group, a 1,6-naphthyridinyl group, a 1,7-naphthyridinyl group, a 1,8-naphthyridinyl group, a 2,6-naphthyridinyl group and a 2,7-naphthyridinyl group. The heteroaryl group may or may not have a substituent. The number of ring-forming atoms is not particularly limited, but is preferably within a range of 3 or more and 40 or less, and more preferably 3 or more and 30 or less.

The amino group is a substituted or unsubstituted amino group. The number of carbon atoms of the amino group is not particularly limited, but is preferably within a range of 2 or more and 50 or less, more preferably 6 or more and 40 or less, and particularly preferably 6 or more and 30 or less.

The silyl group represents a functional group in which a substituted or unsubstituted silicon atom is bonded, and examples thereof include alkylsilyl groups such as a trimethylsilyl group, a triethylsilyl group, a tert-butyldimethylsilyl group, a propyldimethylsilyl group and a vinyldimethylsilyl group; and arylsilyl groups such as a phenyldimethylsilyl group, a tert-butyldiphenylsilyl group, a triphenylsilyl group and a trinaphthylsilyl group. The number of carbon atoms of the silyl group is not particularly limited, but is preferably within a range of 1 or more and 30 or less.

The carboxyl group, oxycarbonyl group and carbamoyl group may or may not have a substituent. Examples of the substituent include an alkyl group, a cycloalkyl group, an aryl group, a heteroaryl group and the like, and these substituents may be further substituted.

The imino group represents a functional group represented by C═NH such as imine or imide, or C¹—NH—C², which may or may not have a substituent. The number of carbon atoms of the imino group is not particularly limited, but is preferably within a range of 2 or more and 20 or less.

Examples of the aromatic hydrocarbon ring include a monocyclic benzene ring, a bicyclic biphenyl ring, a fused bicyclic naphthalene ring, a tricyclic terphenyl ring (m-terphenyl, o-terphenyl, p-terphenyl), a fused tricyclic acenaphthylene ring, fluorene ring, phenalene ring and phenanthrene ring, a fused tetracyclic triphenylene ring, a pyrene ring and a naphthacene ring, a fused pentacyclic perylene ring and pentacene ring, and the like.

Examples of the aromatic heterocyclic ring include a pyrrole ring, an oxazole ring, an isoxazole ring, a thiazole ring, an isothiazole ring, an imidazole ring, an oxadiazole ring, a thiadiazole ring, a triazole ring, a tetrazole ring, a pyrazole ring, a pyridine ring, a pyrimidine ring, a pyridazine ring, a pyrazine ring, a triazine ring, an indole ring, an isoindole ring, a 1H-indazole ring, a benzimidazole ring, a benzoxazole ring, a benzothiazole ring, a 1H-benzotriazole ring, a quinoline ring, an isoquinoline ring, a cinnoline ring, a quinazoline ring, a quinoxaline ring, a phthalazine ring, a naphthyridine ring, a purine ring, a pteridine ring, a carbazole ring, an acridine ring, a phenoxathiin ring, a phenoxazine ring, a phenothiazine ring, a phenazine ring, an indolizine ring, a furan ring, a benzofuran ring, an isobenzofuran ring, a dibenzofuran ring, a thiophene ring, a benzothiophene ring, a dibenzothiophene ring, a furazan ring, an oxadiazole ring, a thianthrene ring, and the like.

In all the above groups, the substituent when substituted is a halogen, a cyano group, an alkyl group, a cycloalkyl group, an alkenyl group, a cycloalkenyl group, an alkynyl group, an alkoxy group, an alkylthio group, an aryl ether group, an aryl thioether group, an aryl group, a heteroaryl group, a carboxyl group, an oxycarbonyl group, a carbamoyl group, an amino group, a nitro group or a silyl group, and specific substituents which are preferred in the description of each substituent are preferable. These substituents may be further substituted with the above-mentioned substituents.

Examples of the compound having a structure represented by the general formula (1) or (2) are shown below, but the invention is not limited thereto.

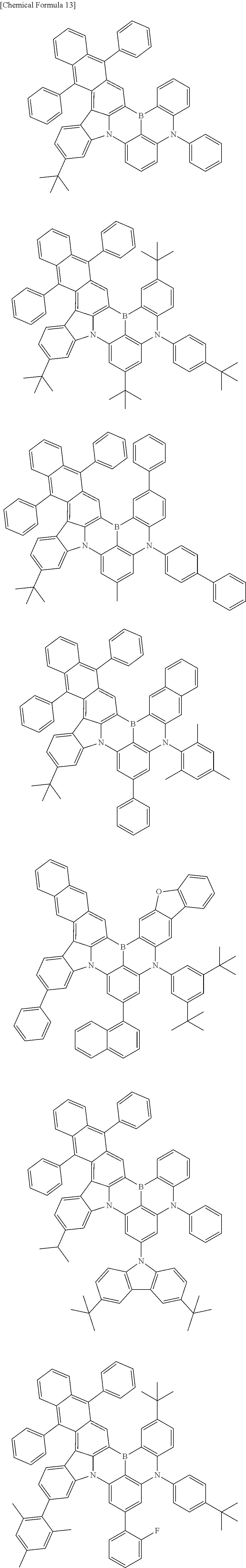

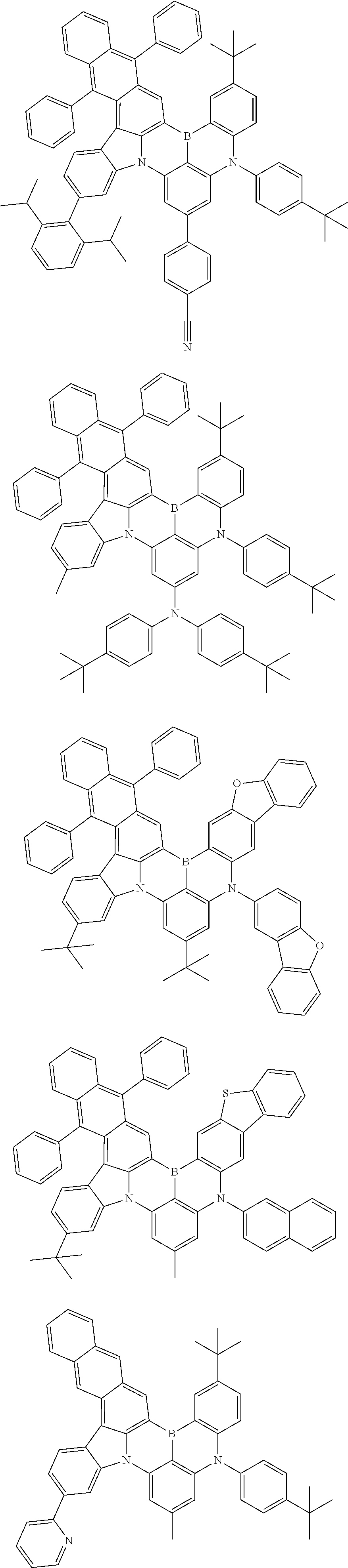

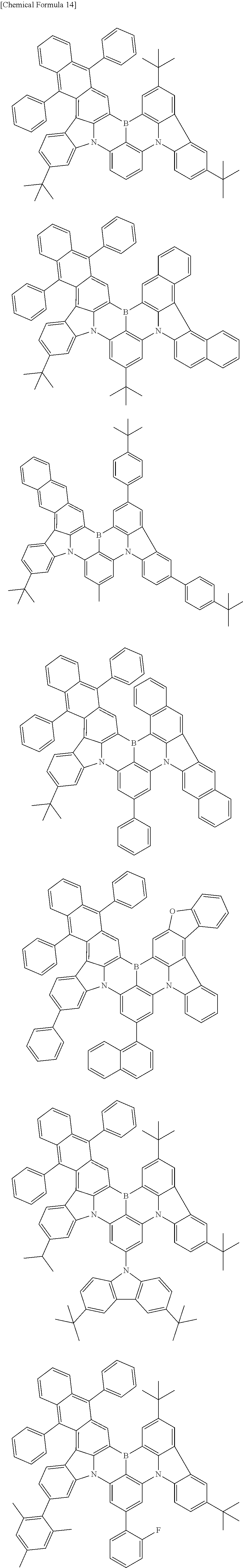

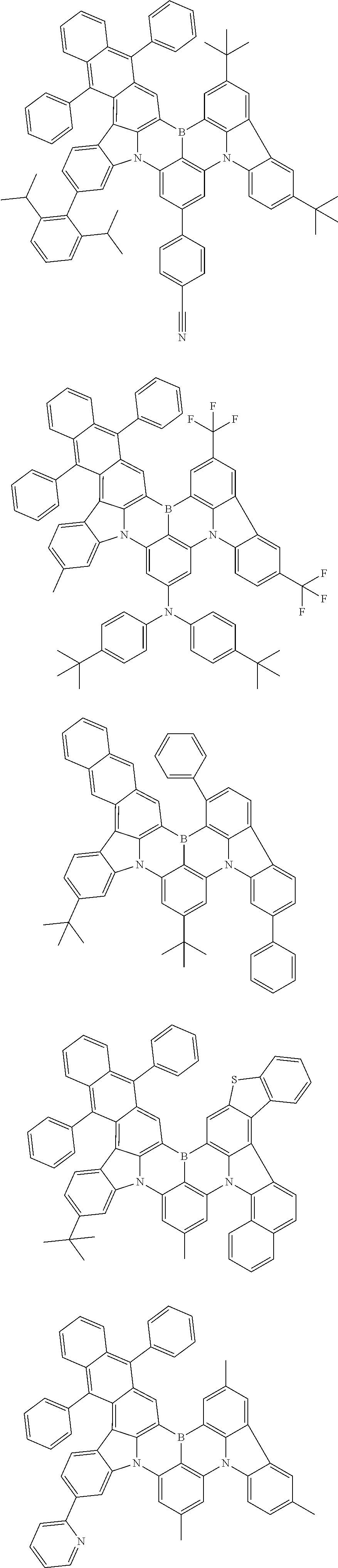

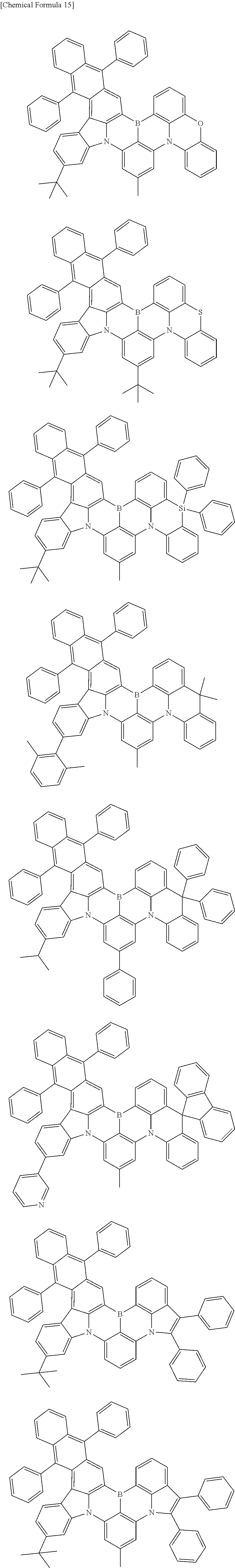

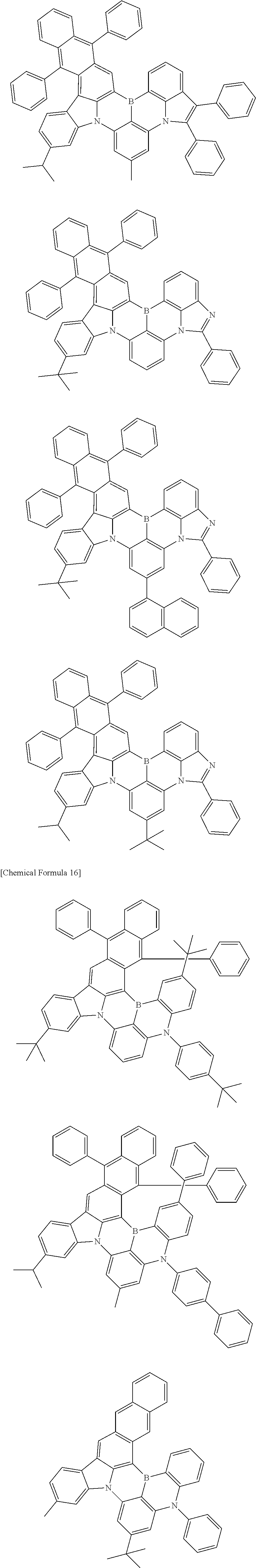

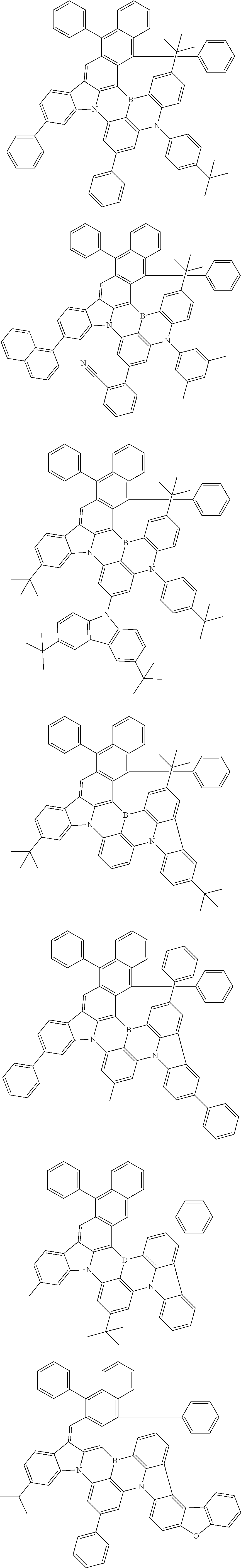

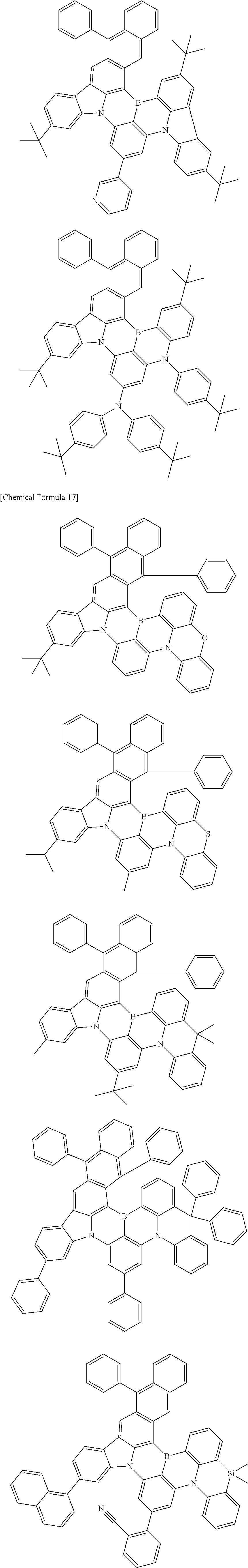

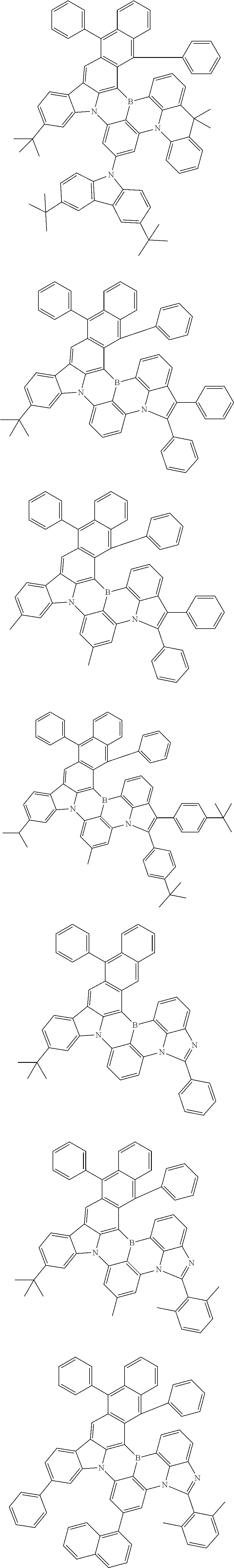

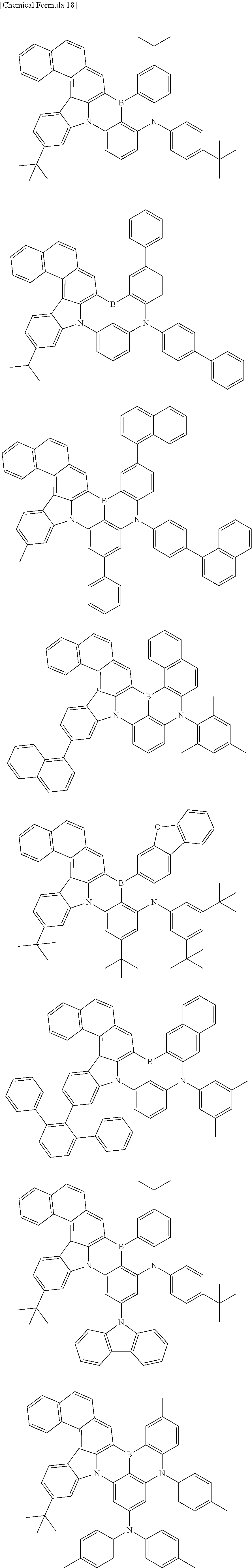

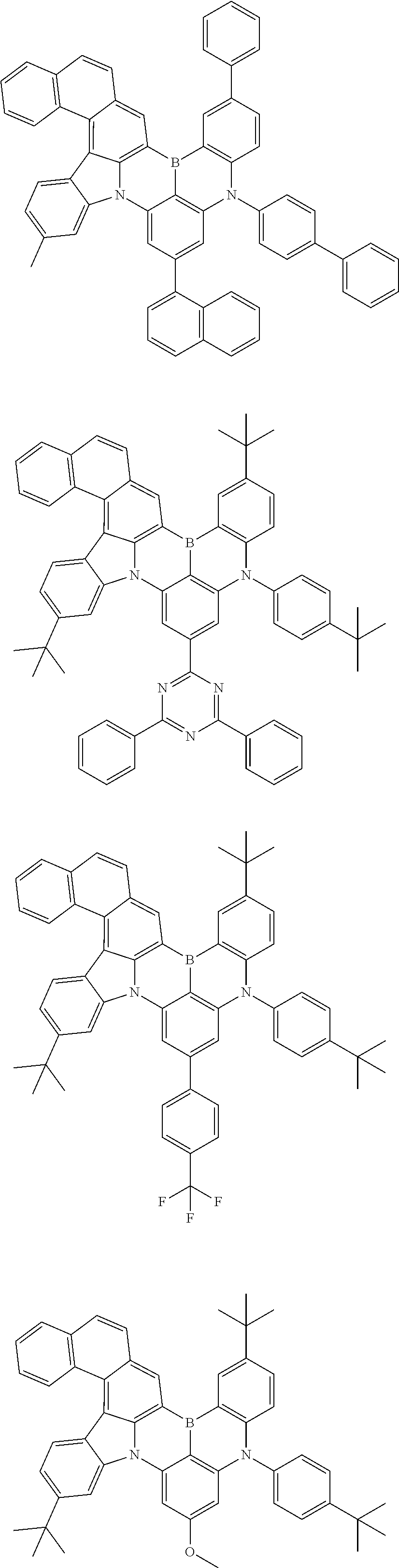

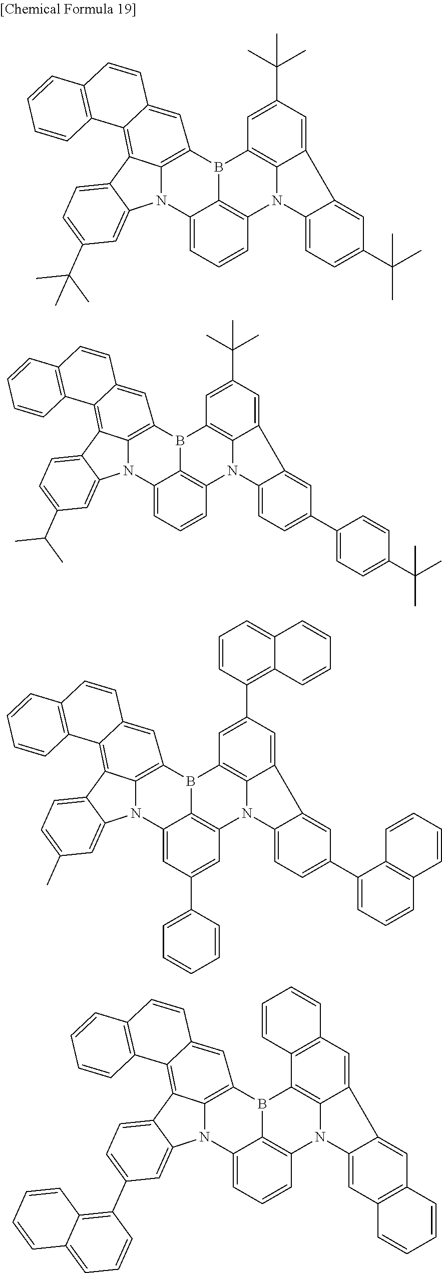

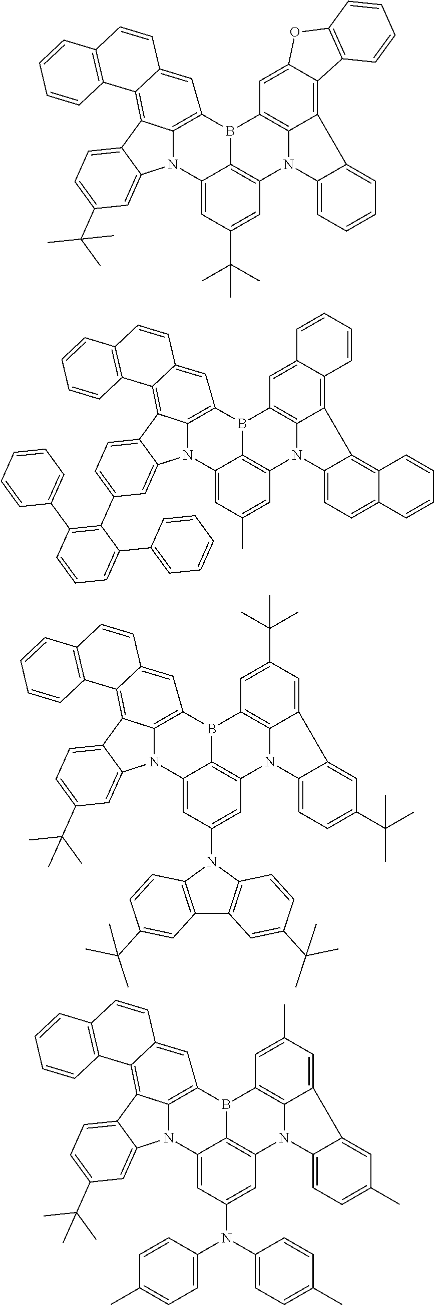

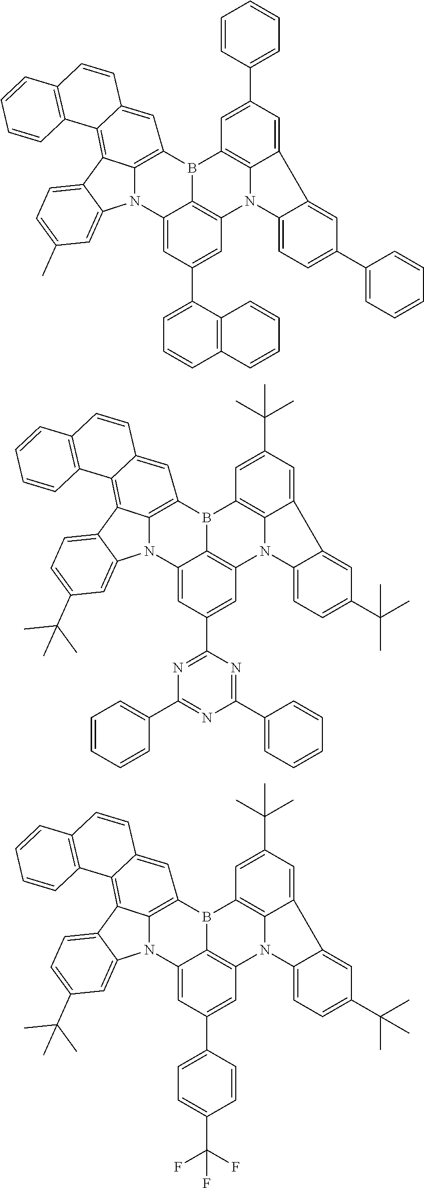

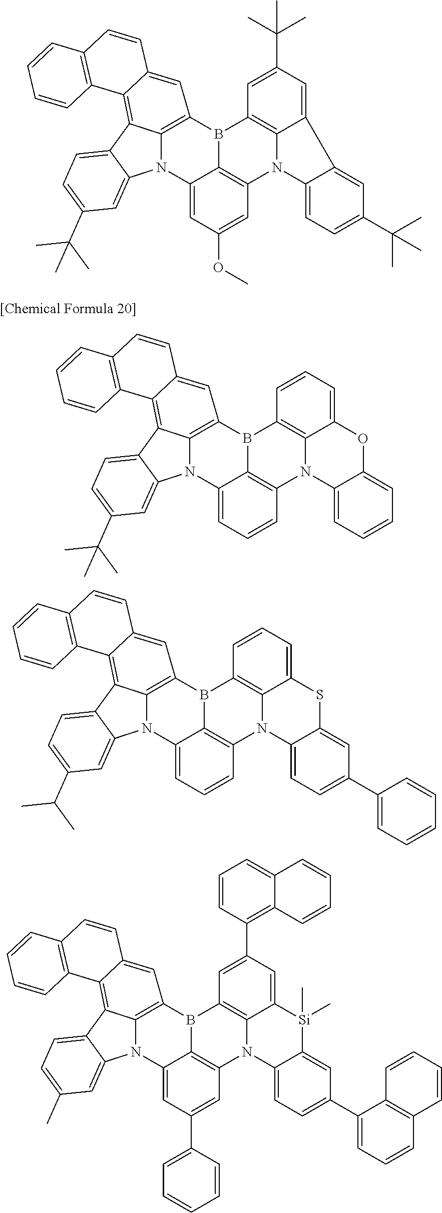

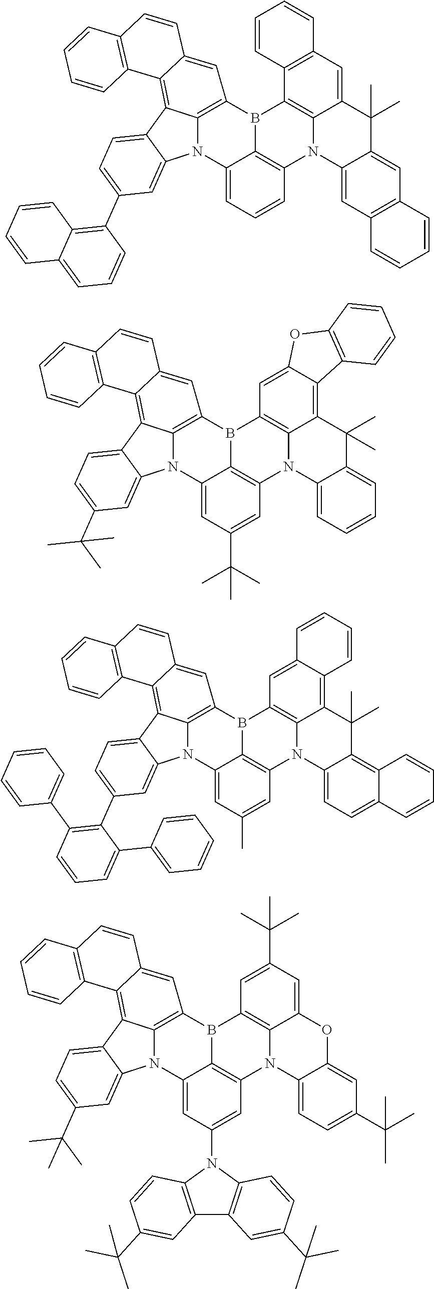

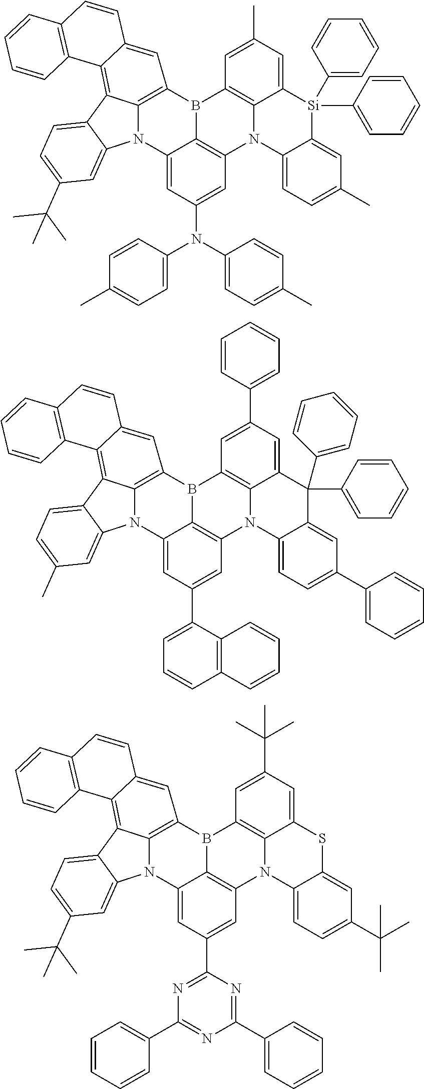

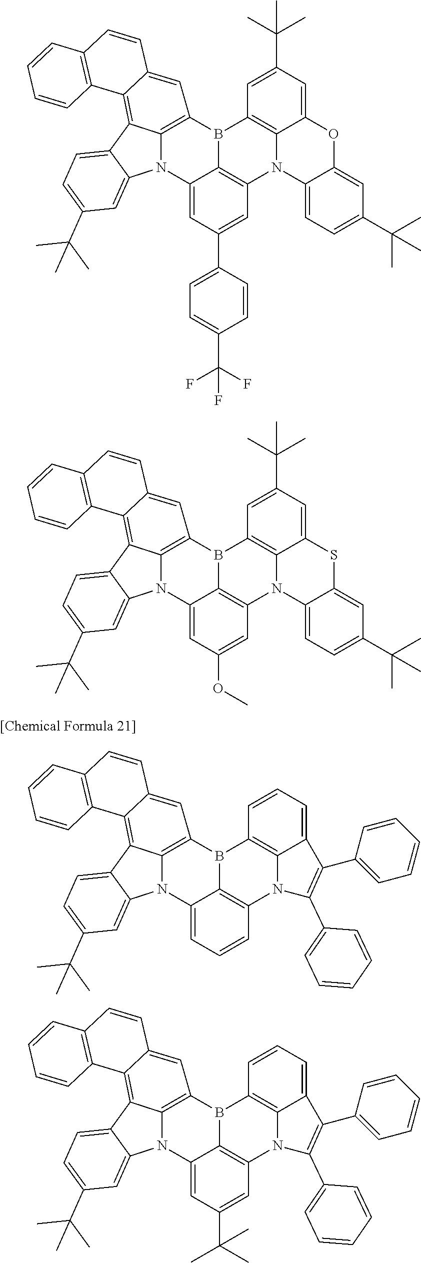

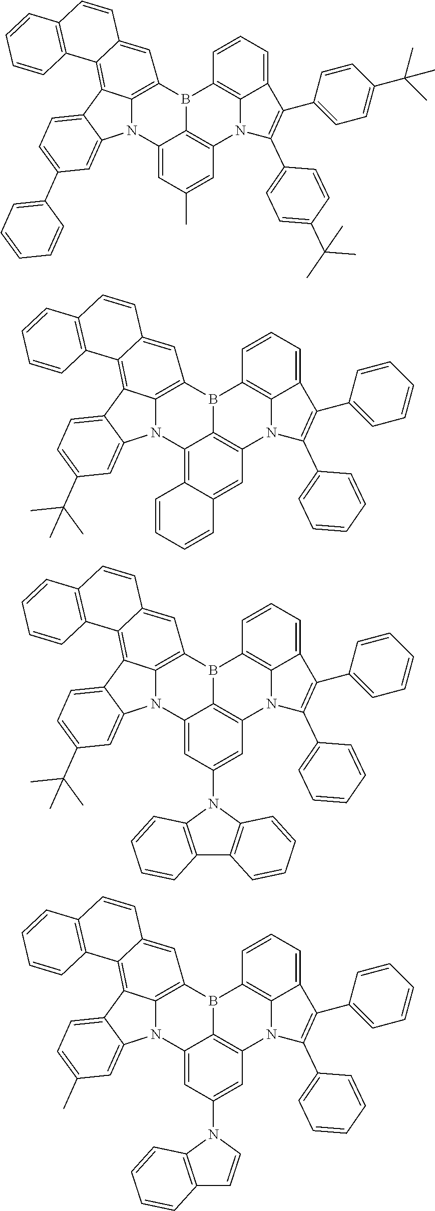

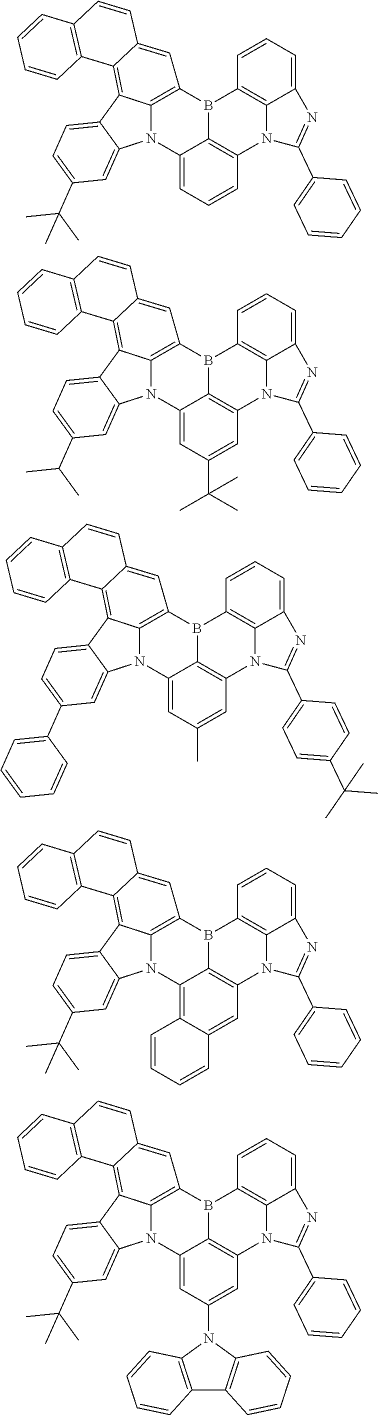

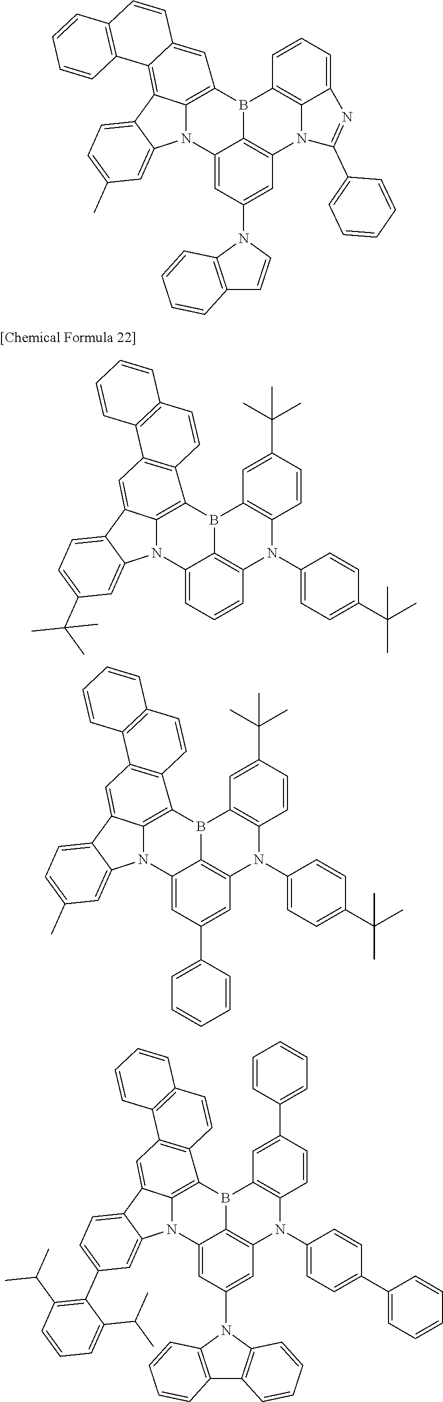

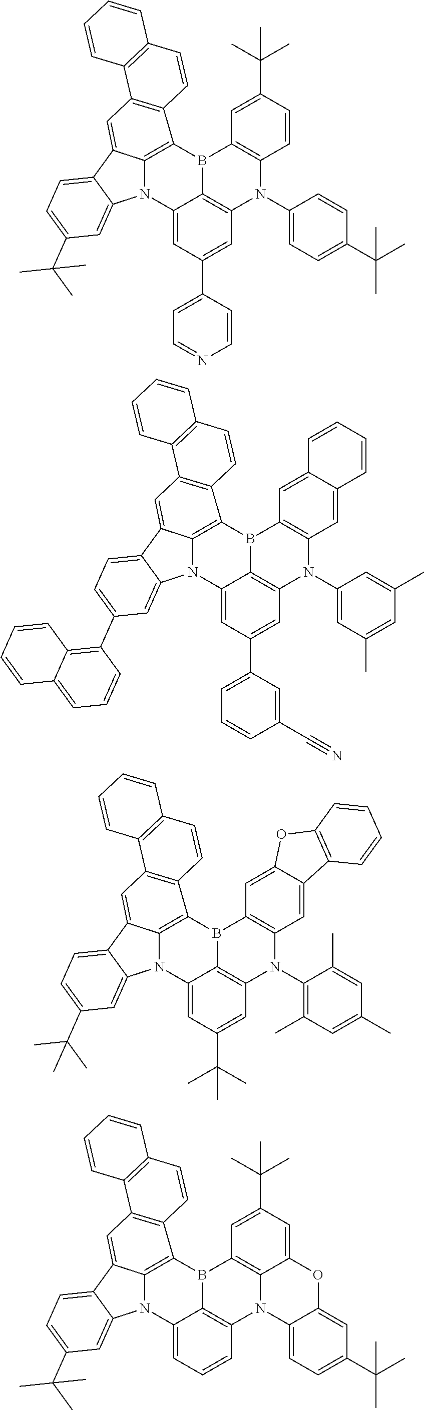

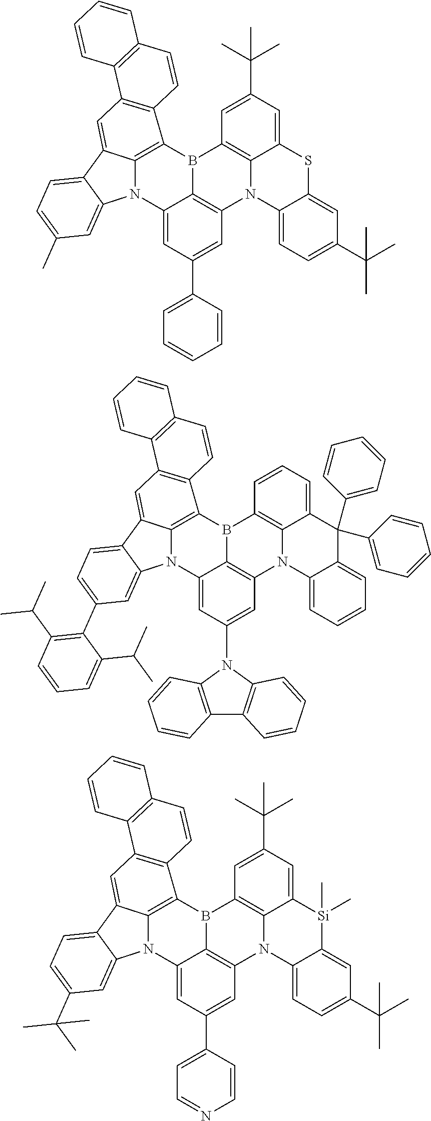

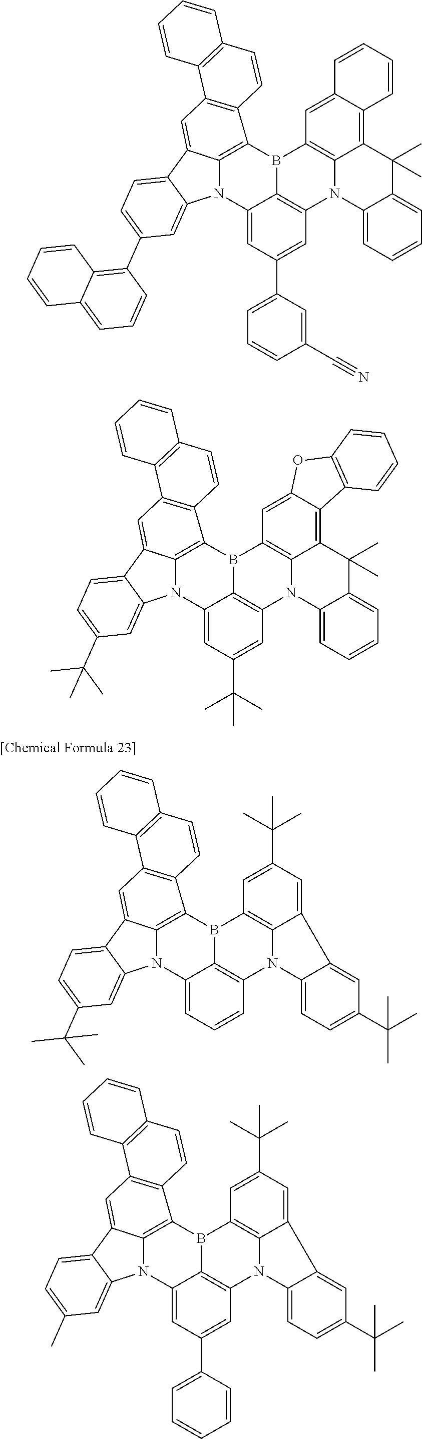

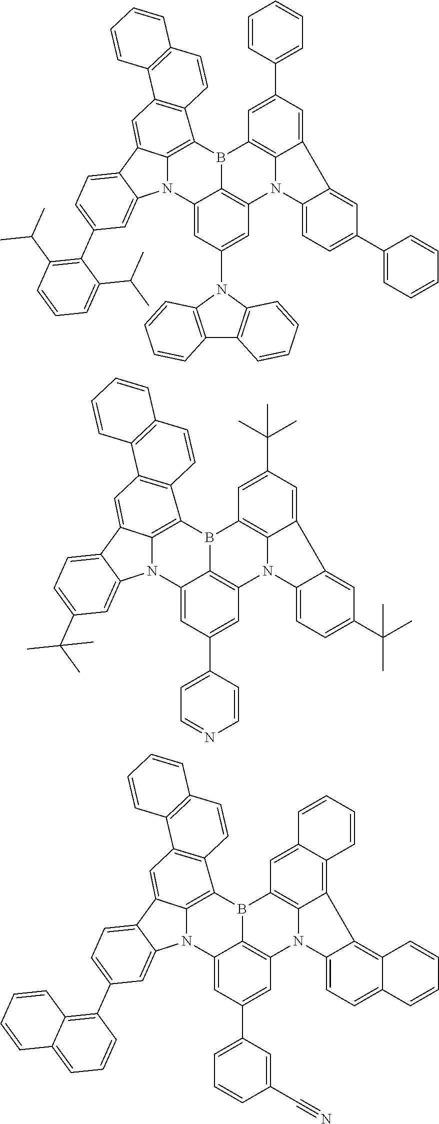

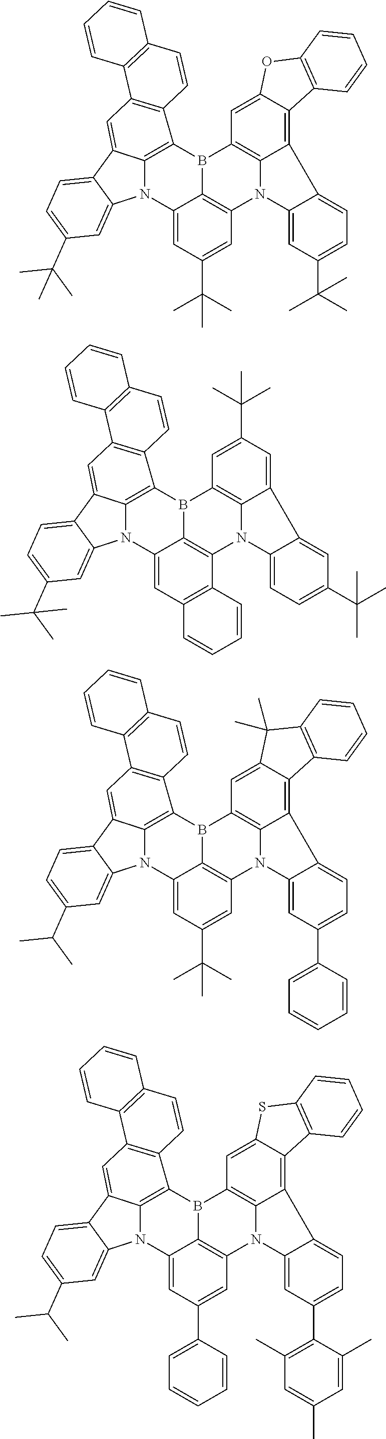

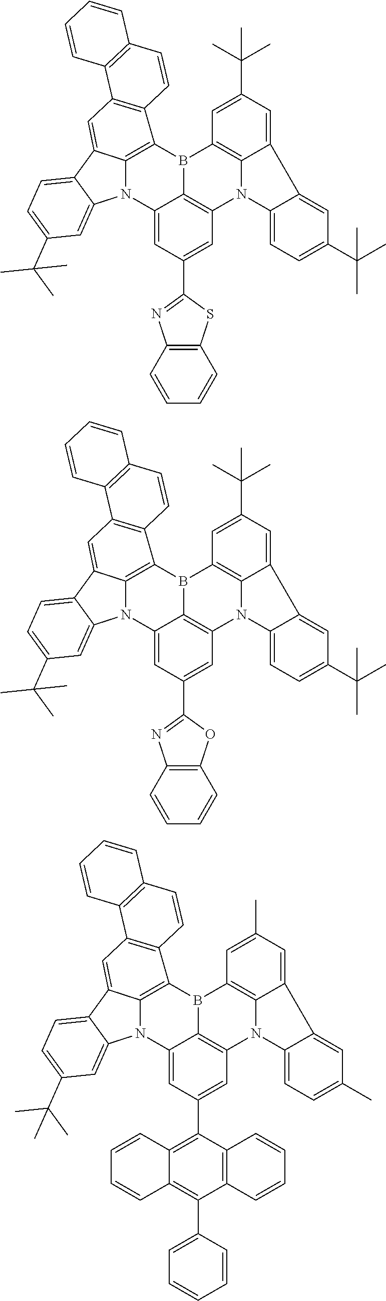

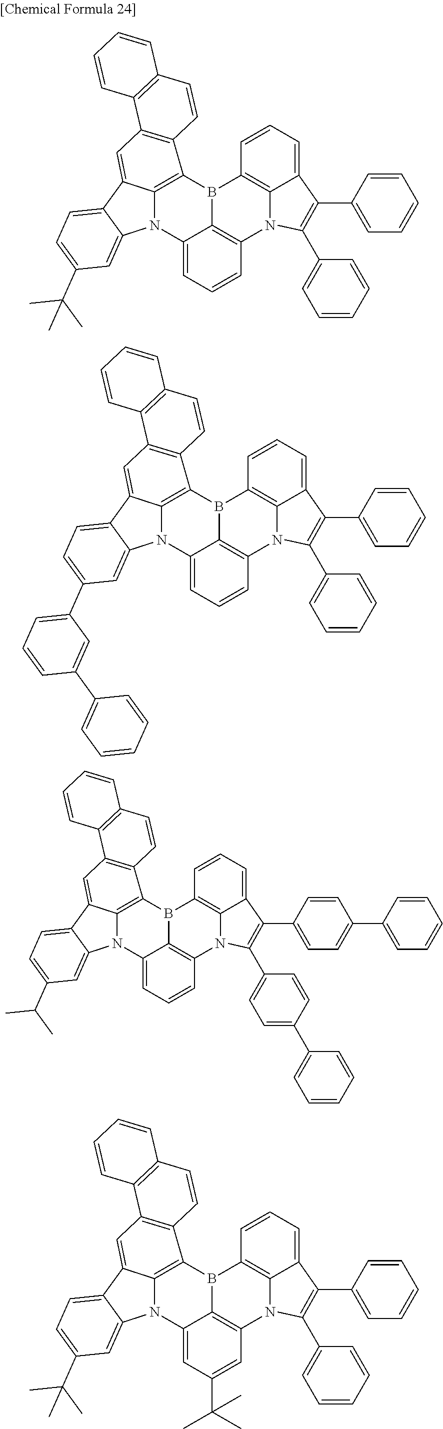

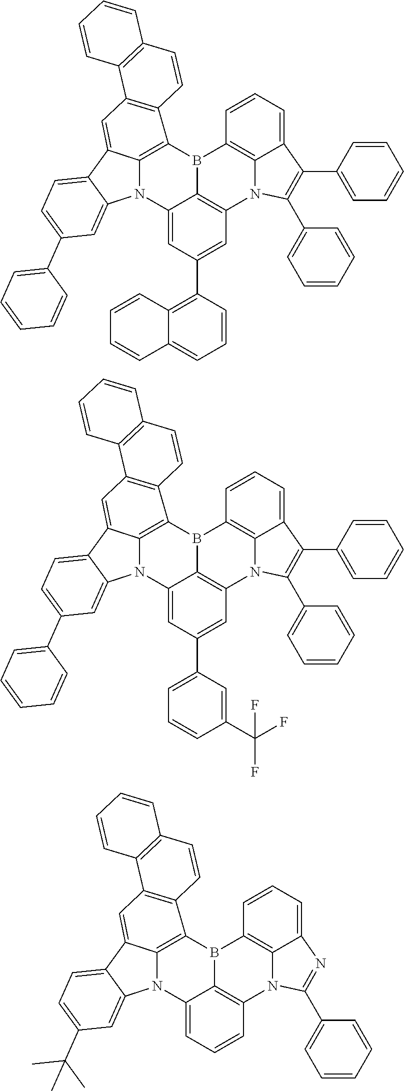

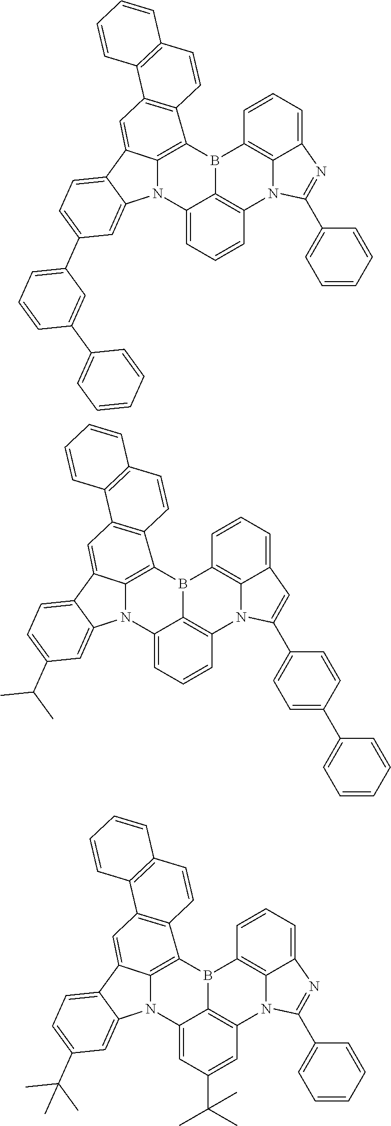

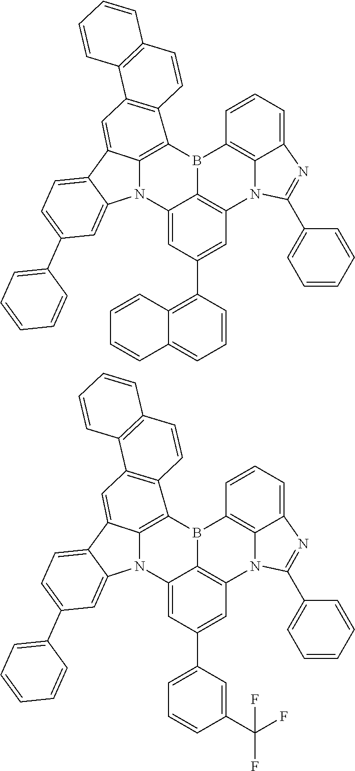

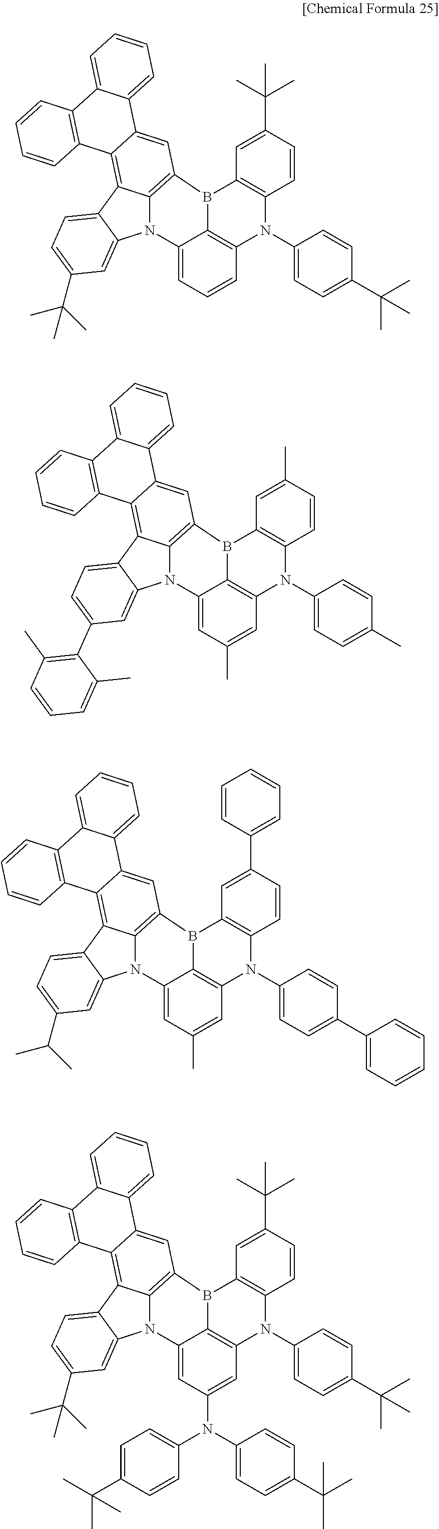

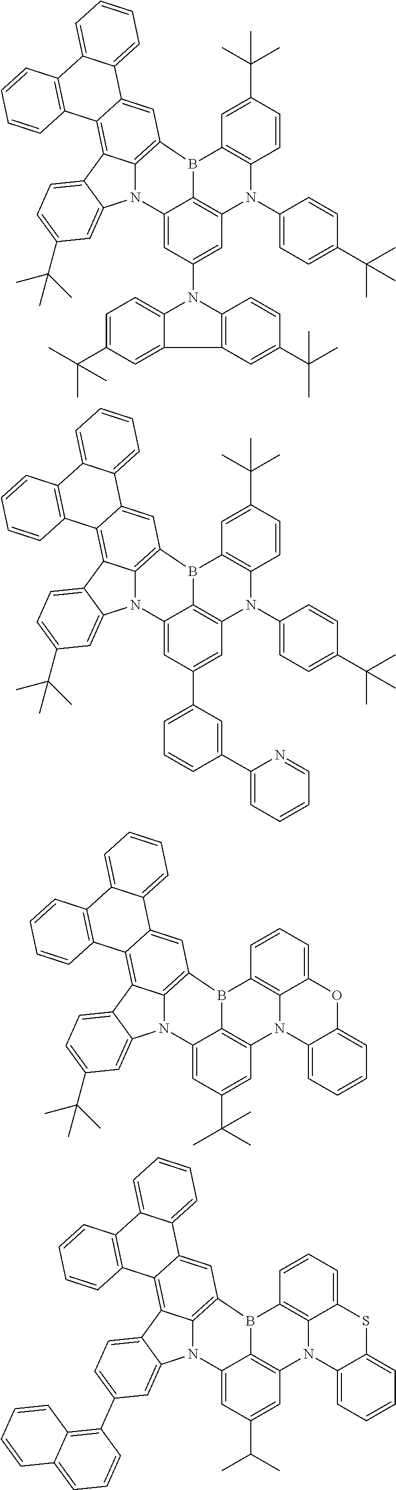

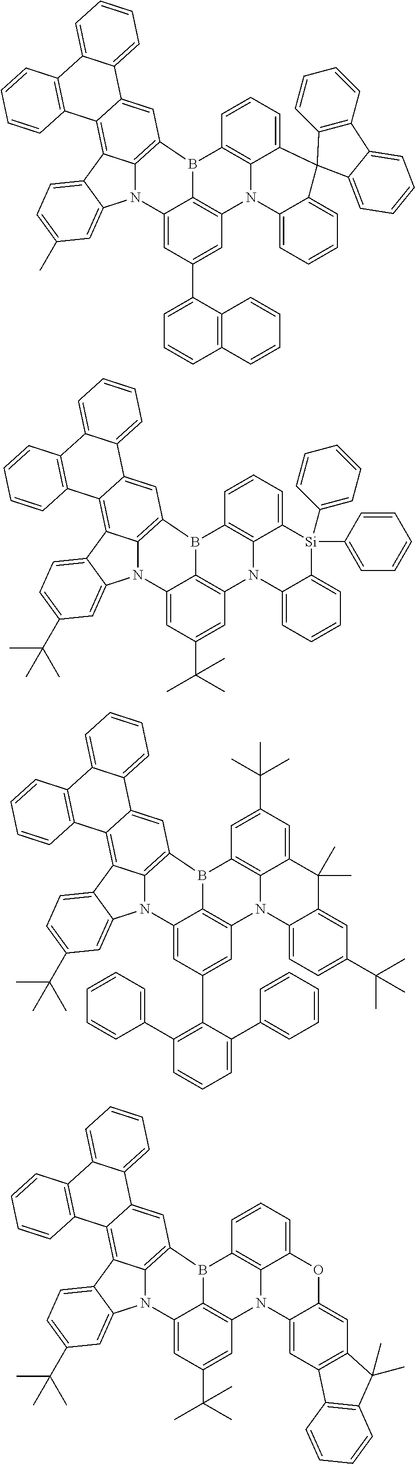

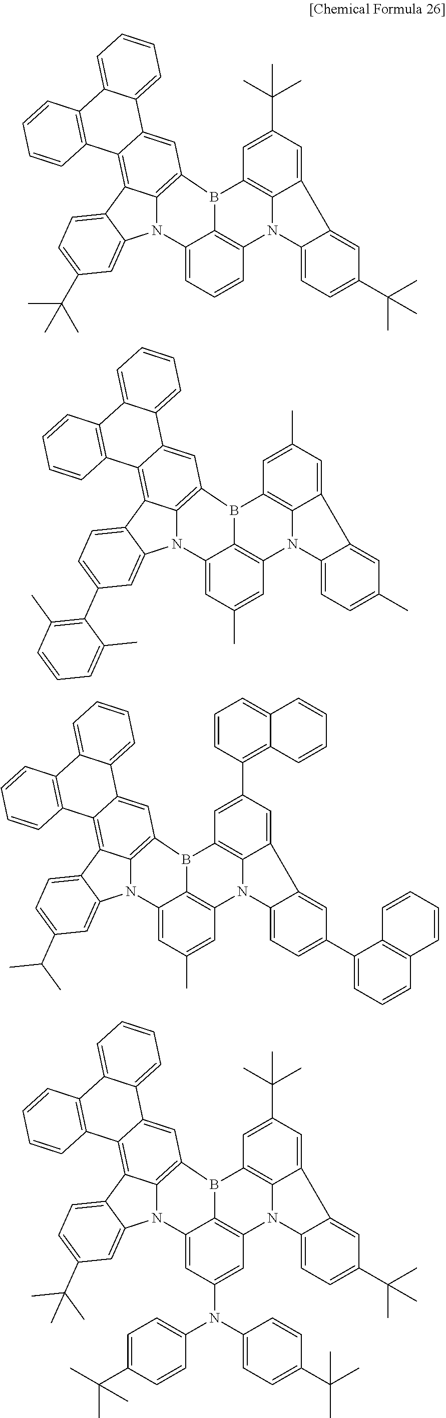

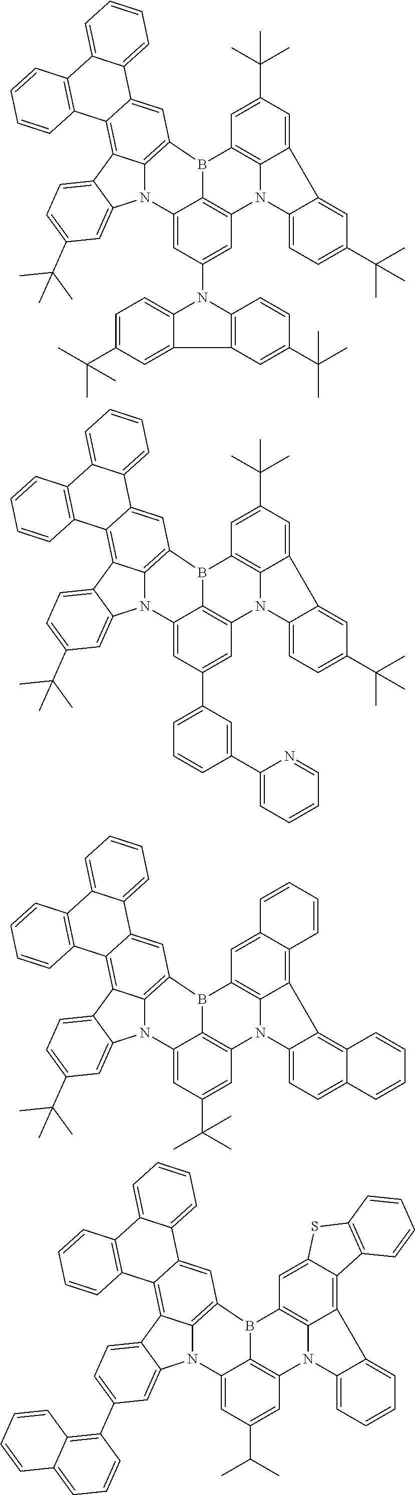

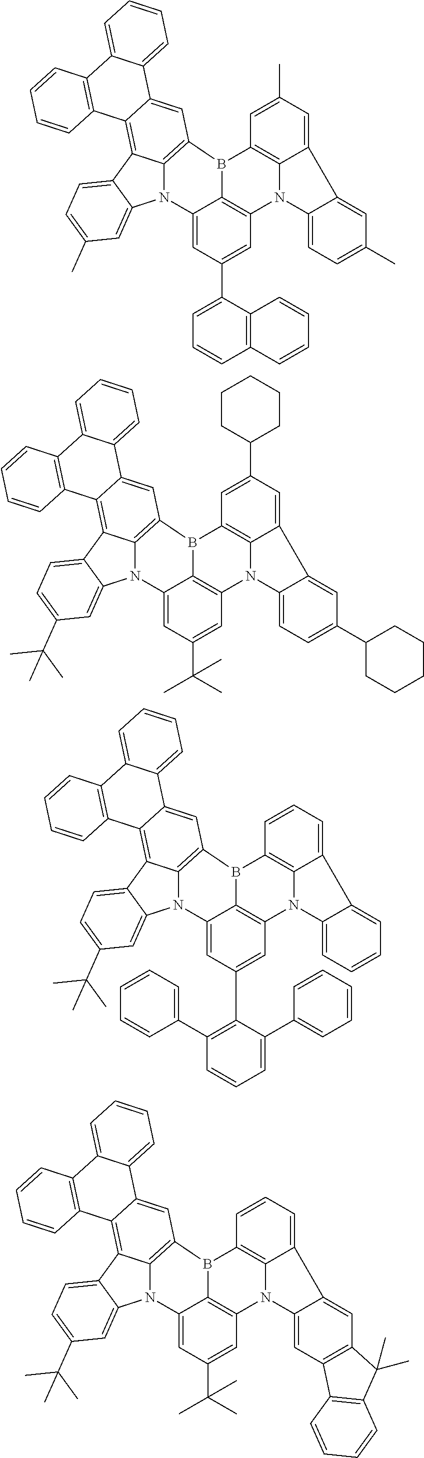

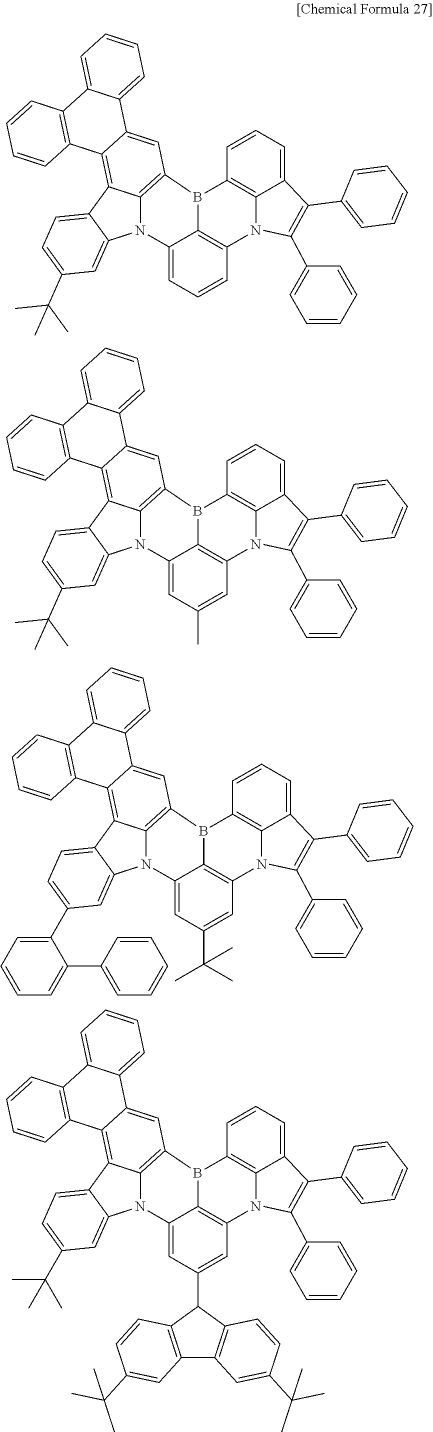

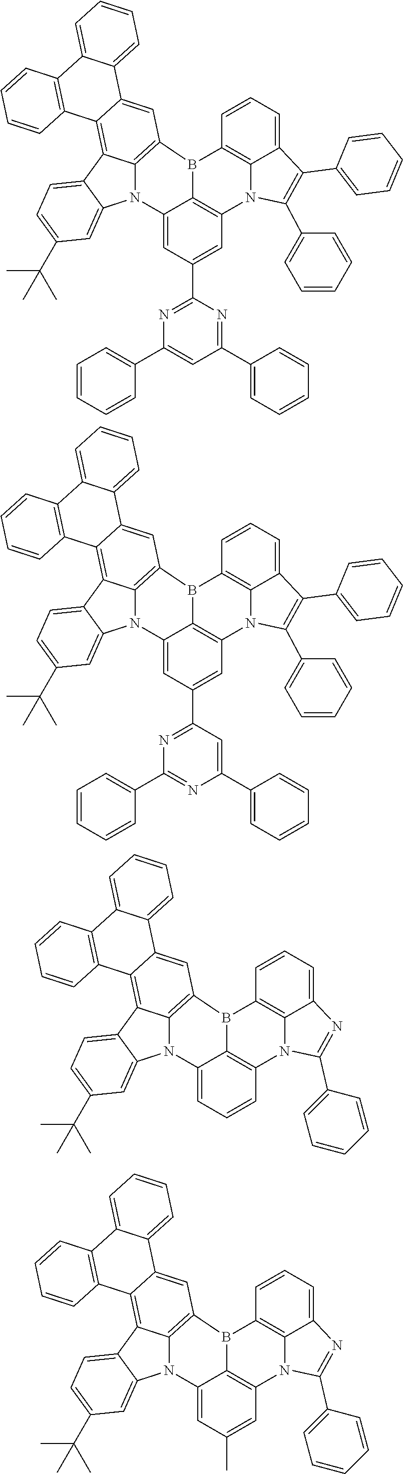

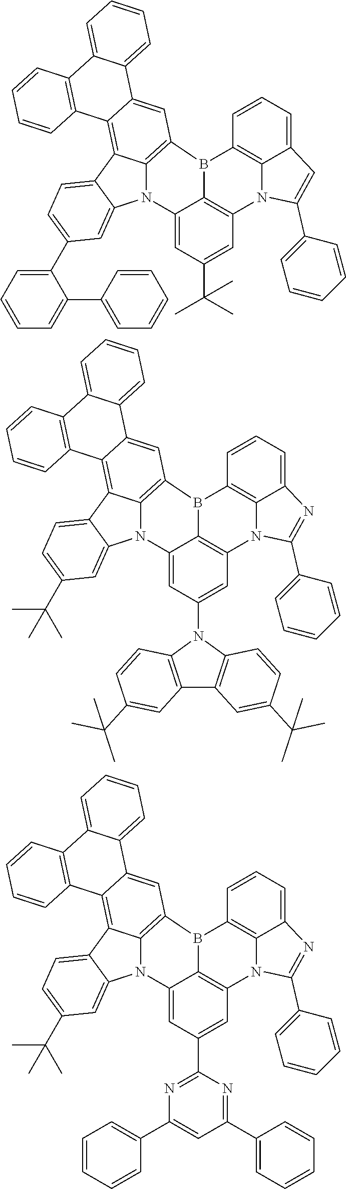

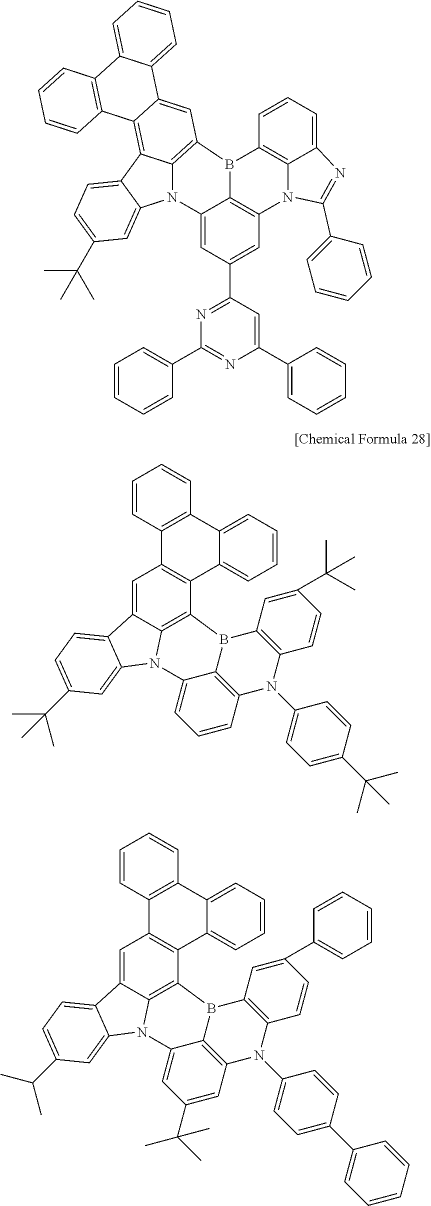

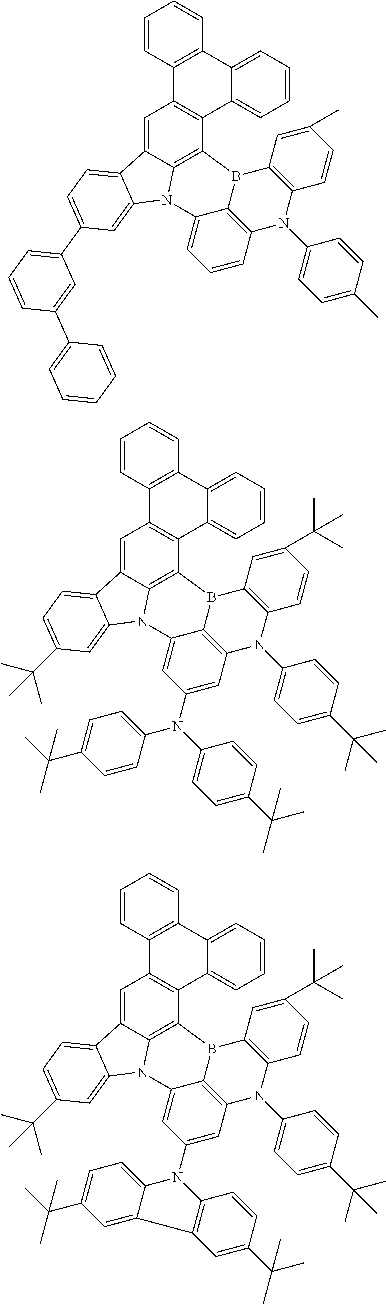

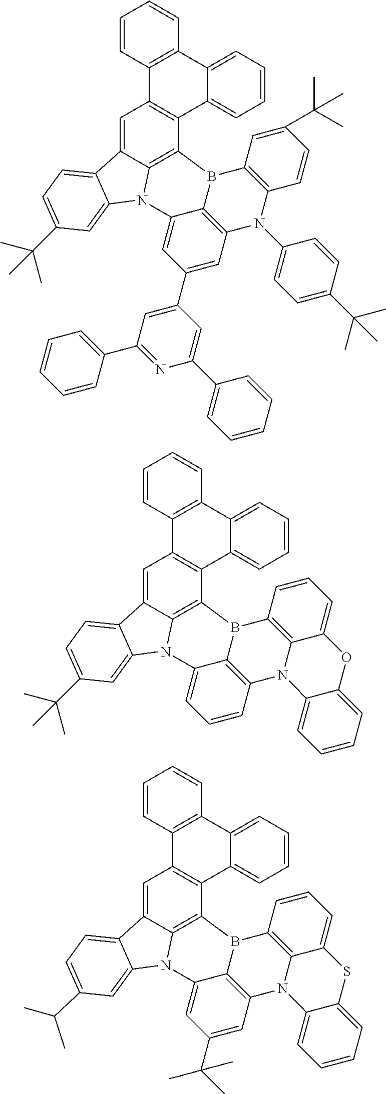

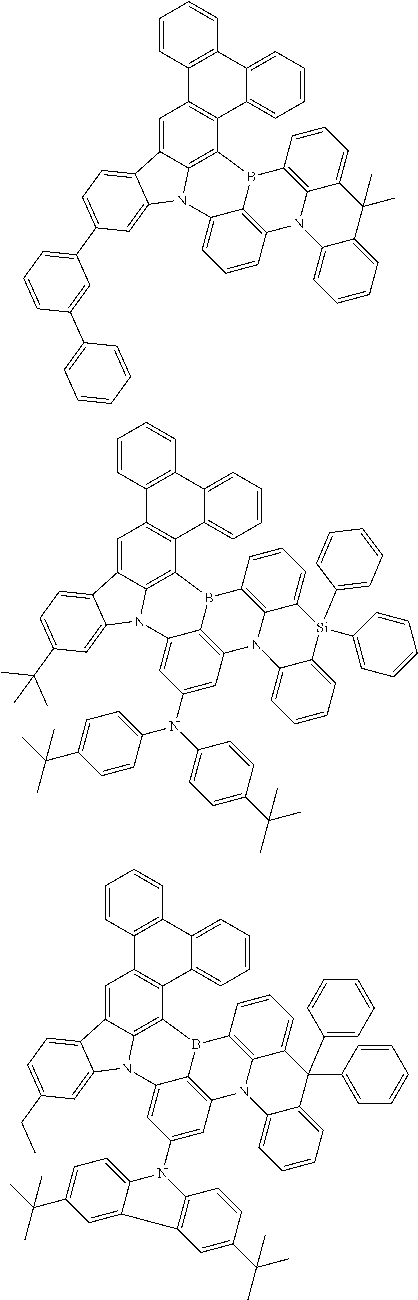

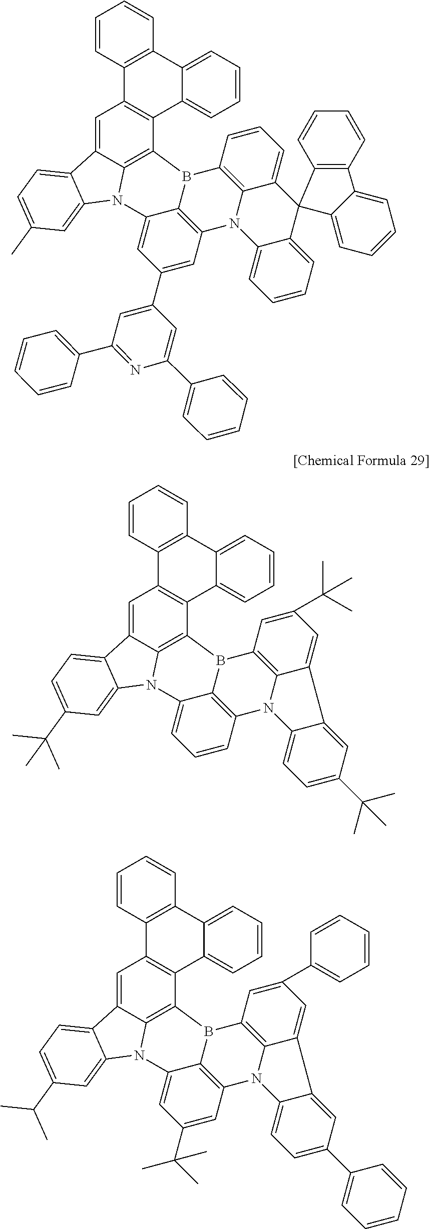

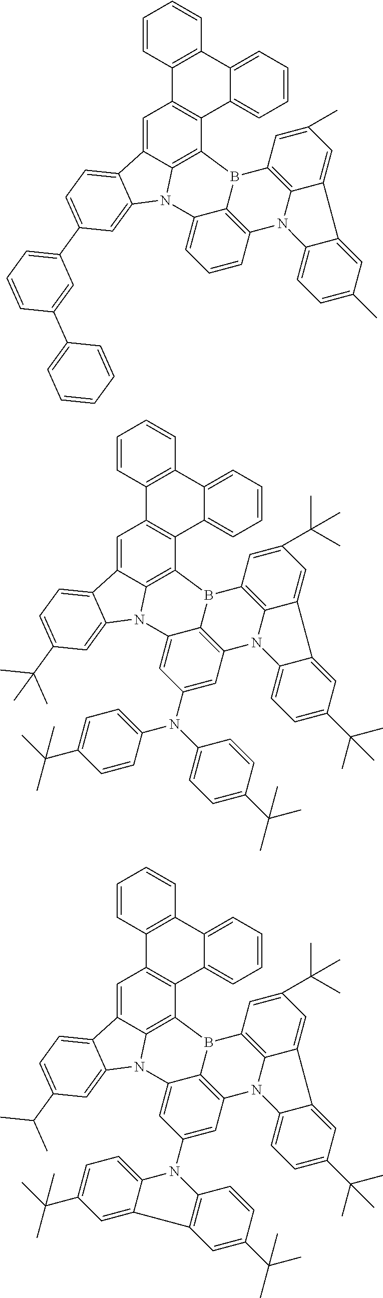

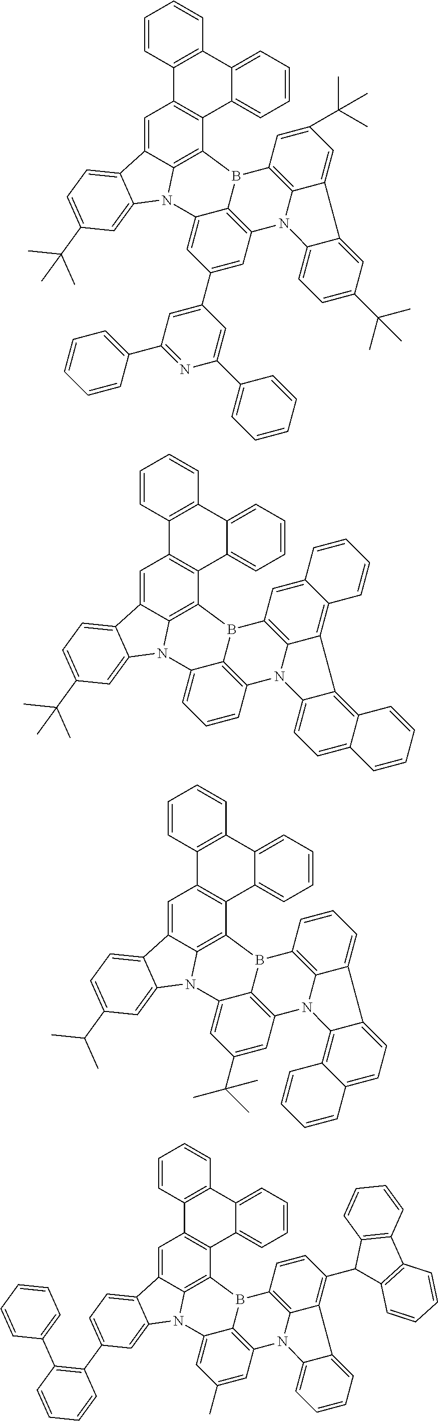

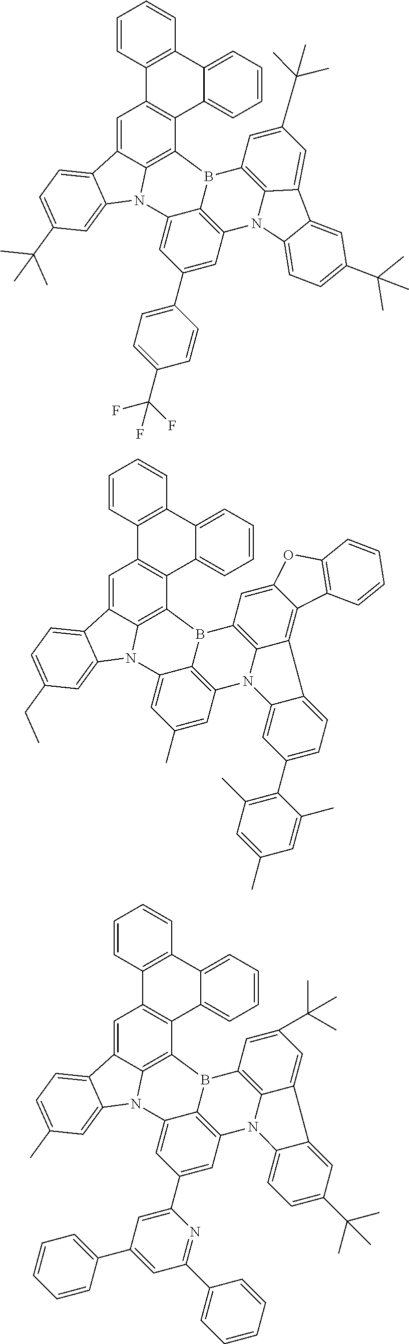

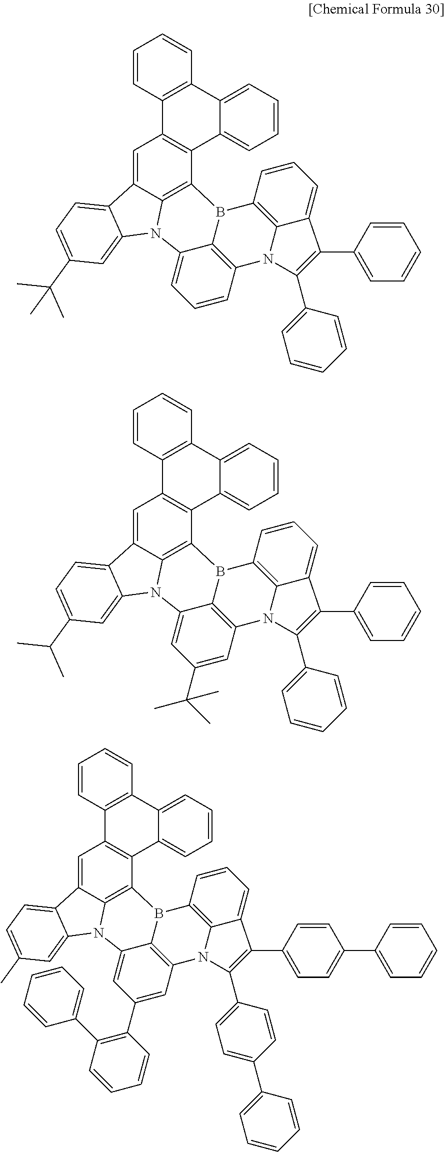

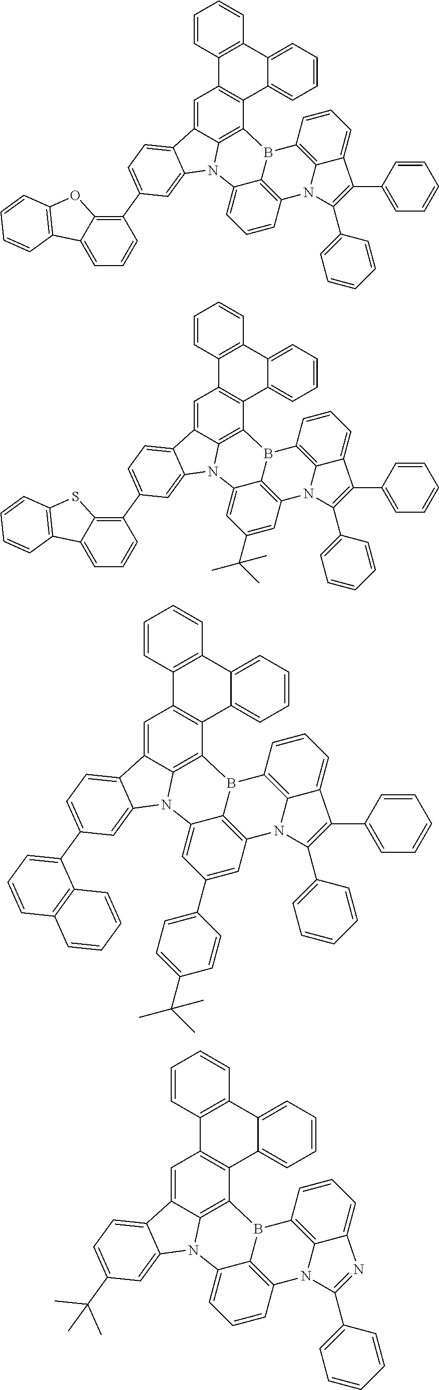

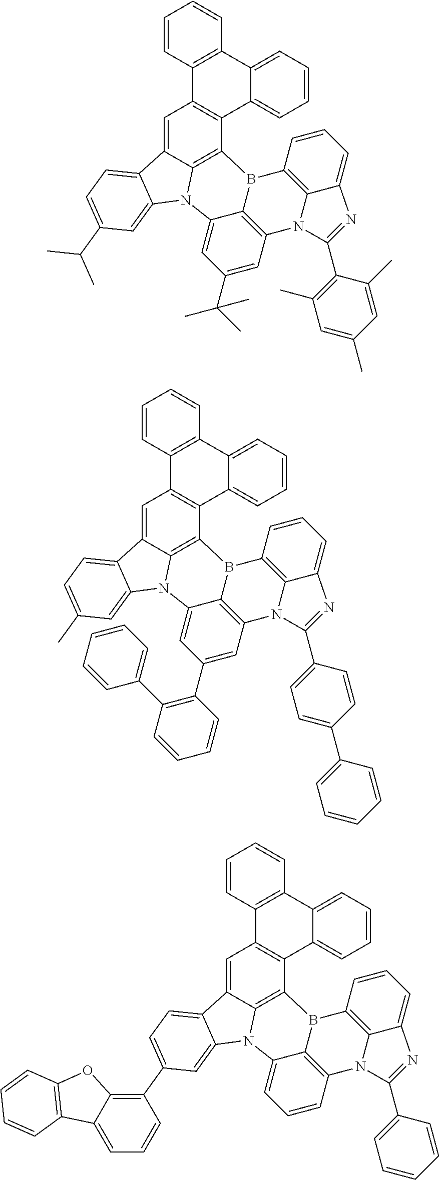

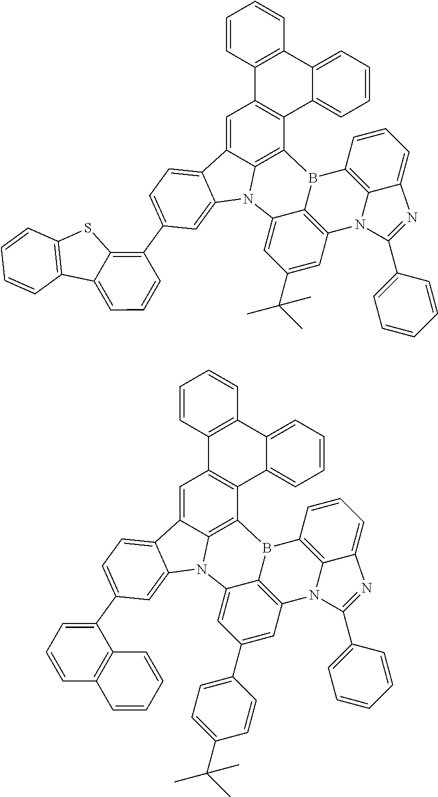

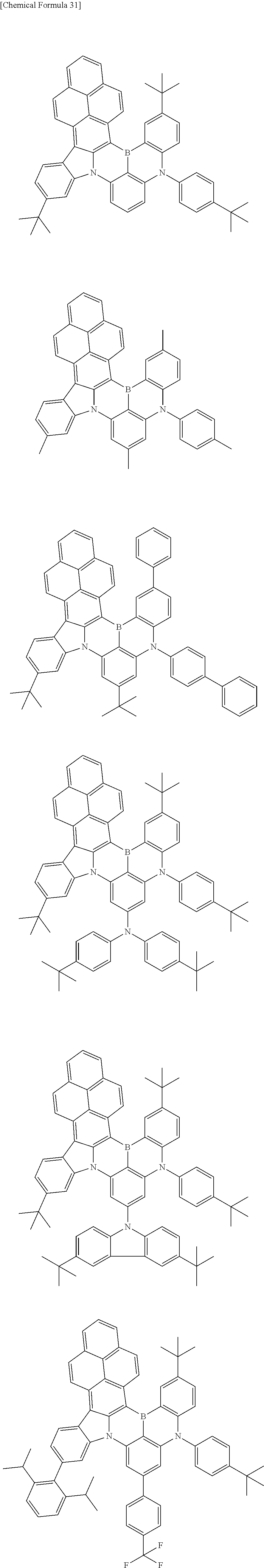

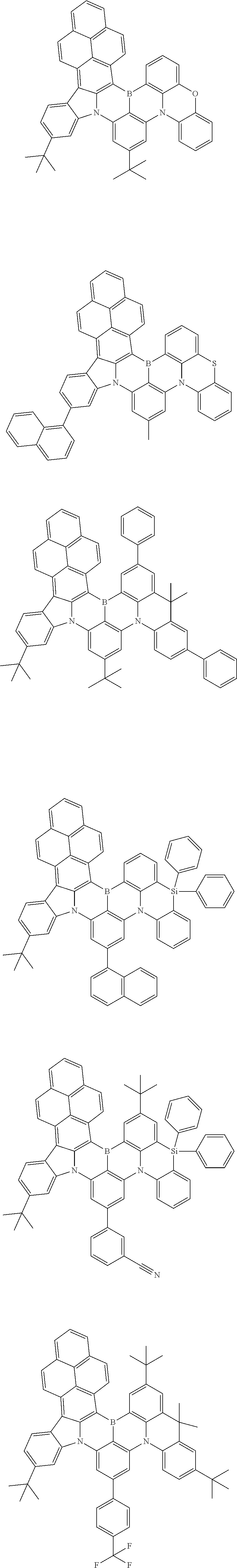

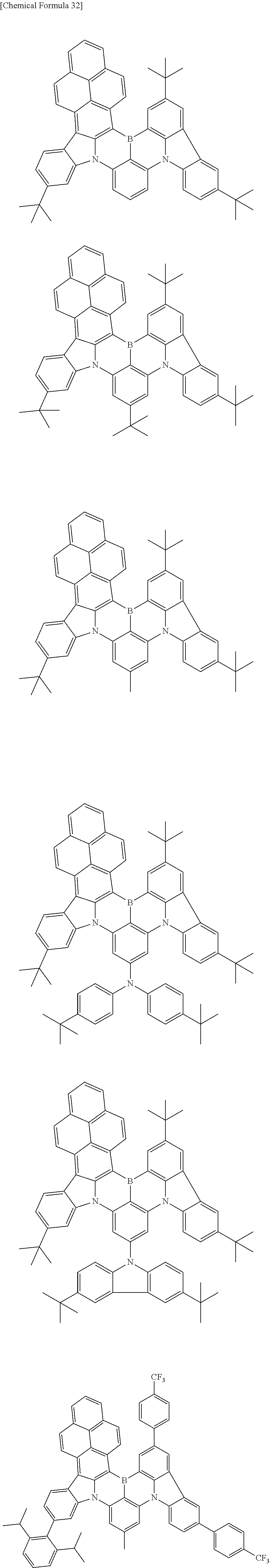

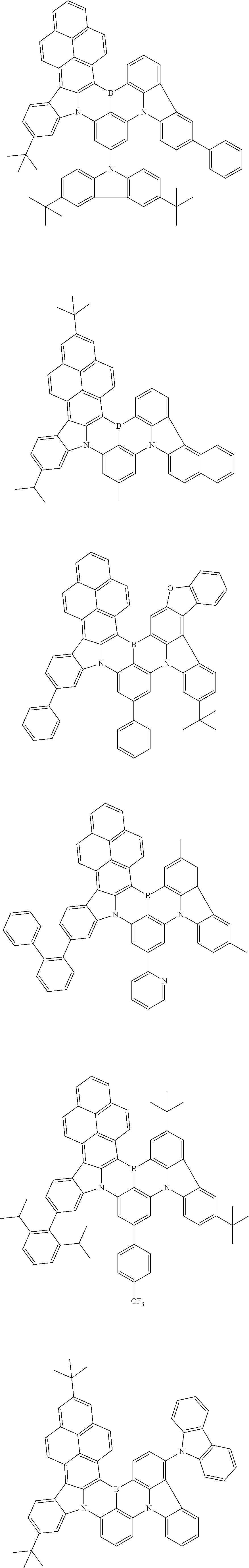

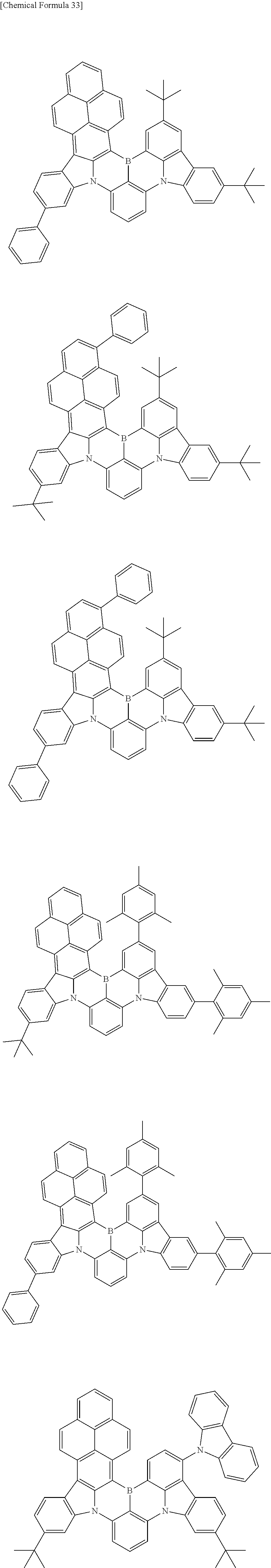

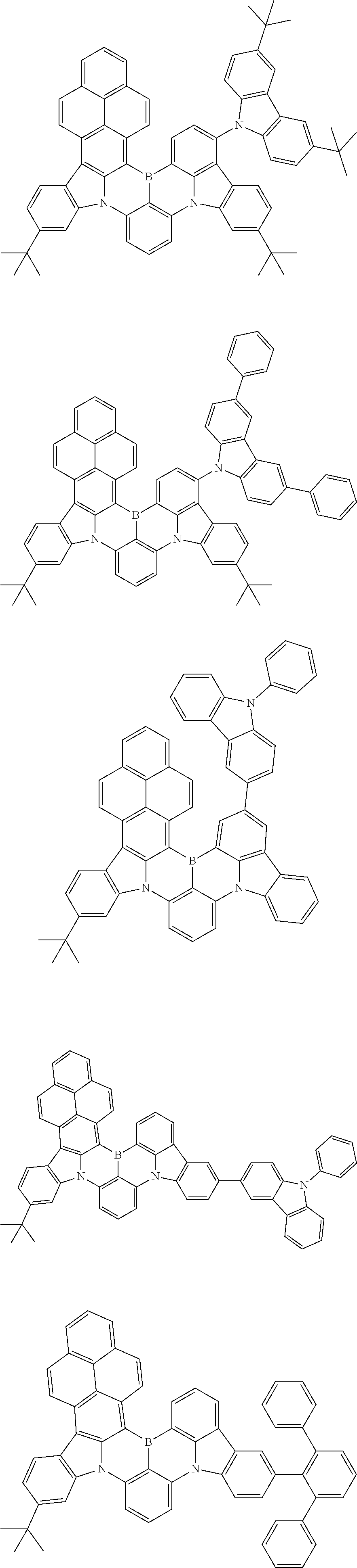

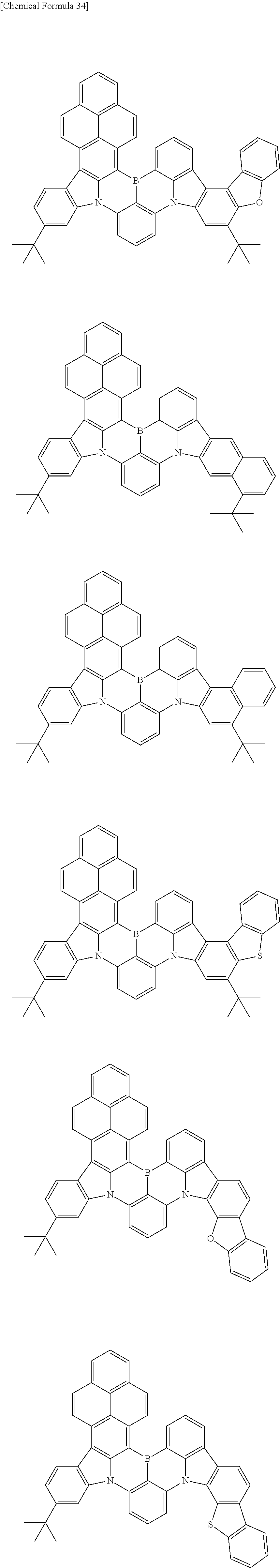

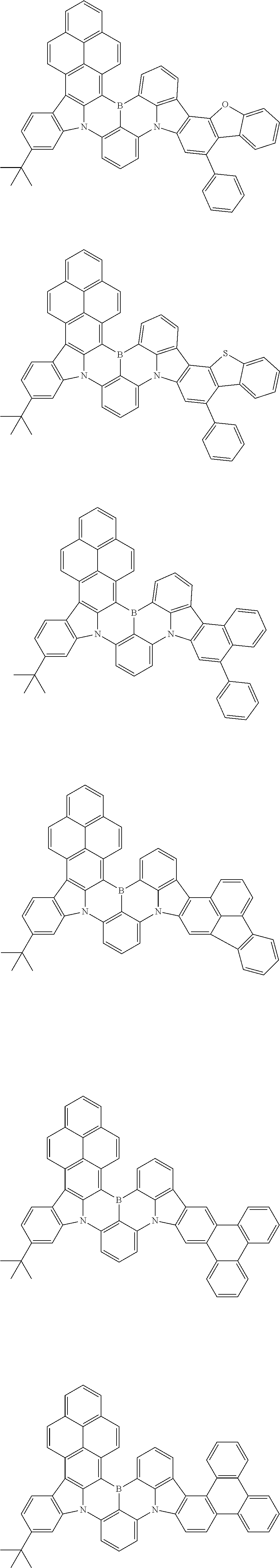

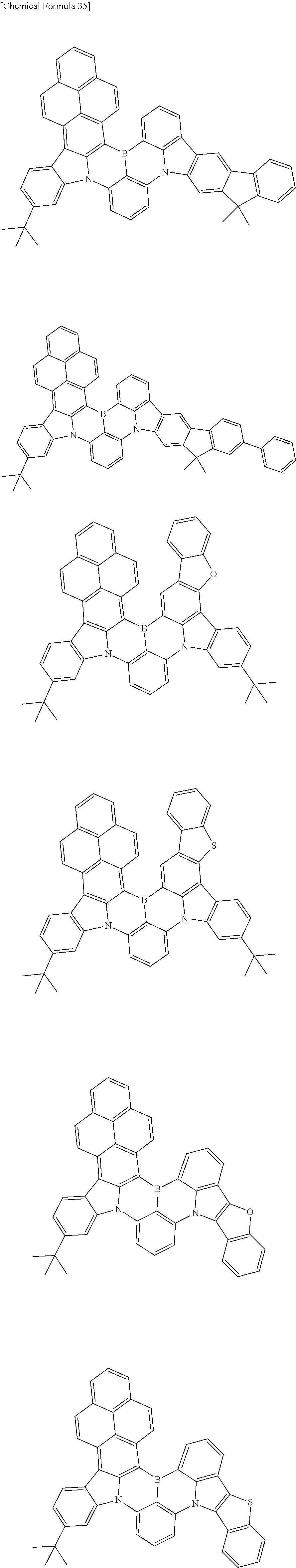

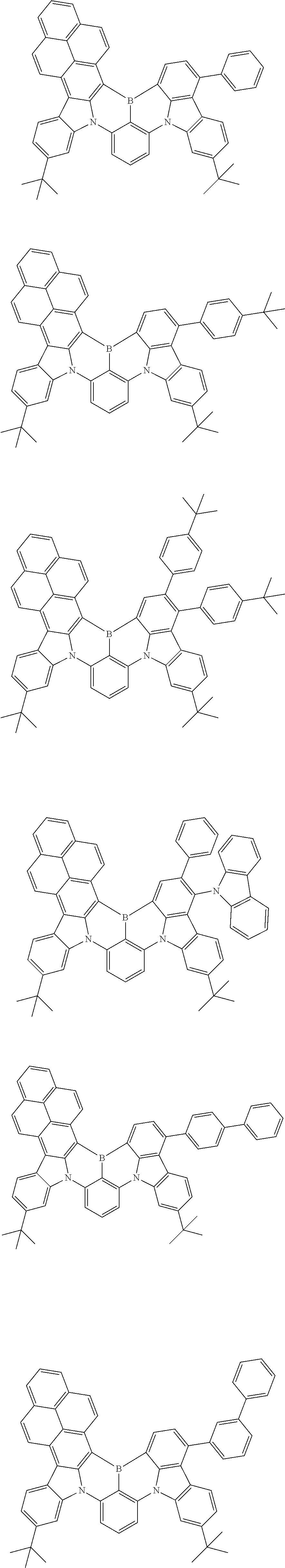

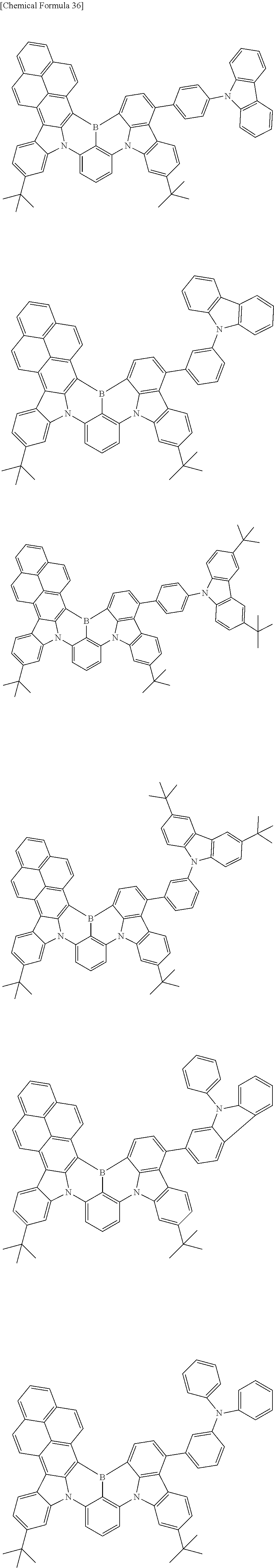

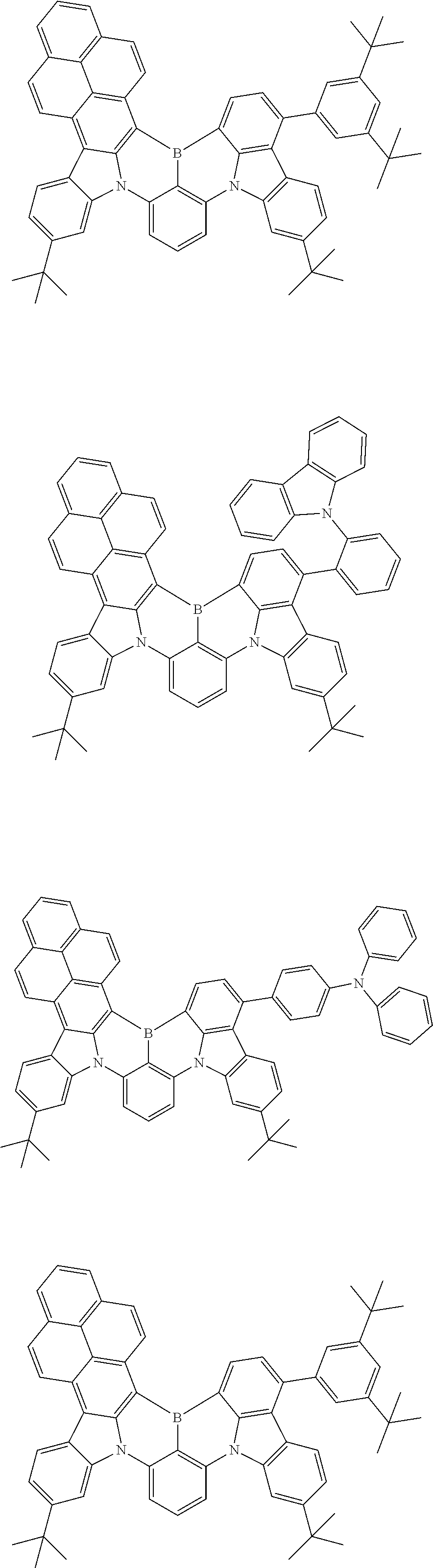

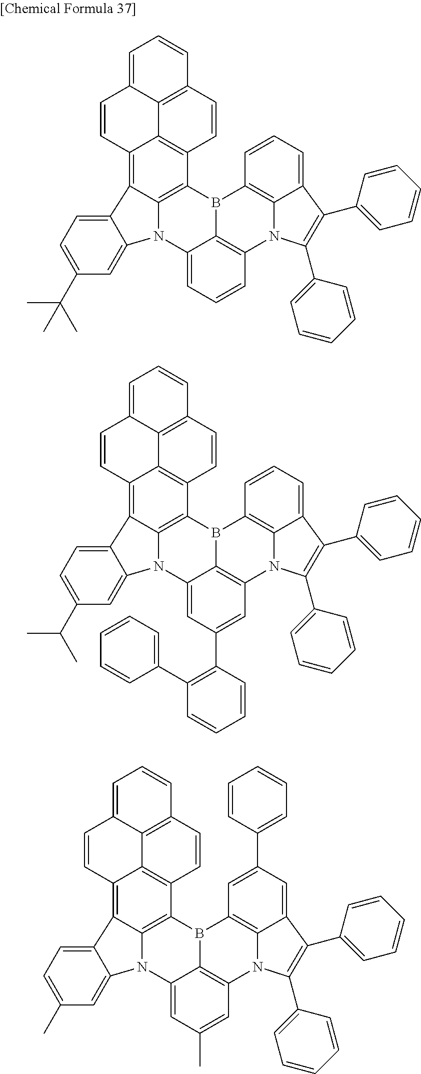

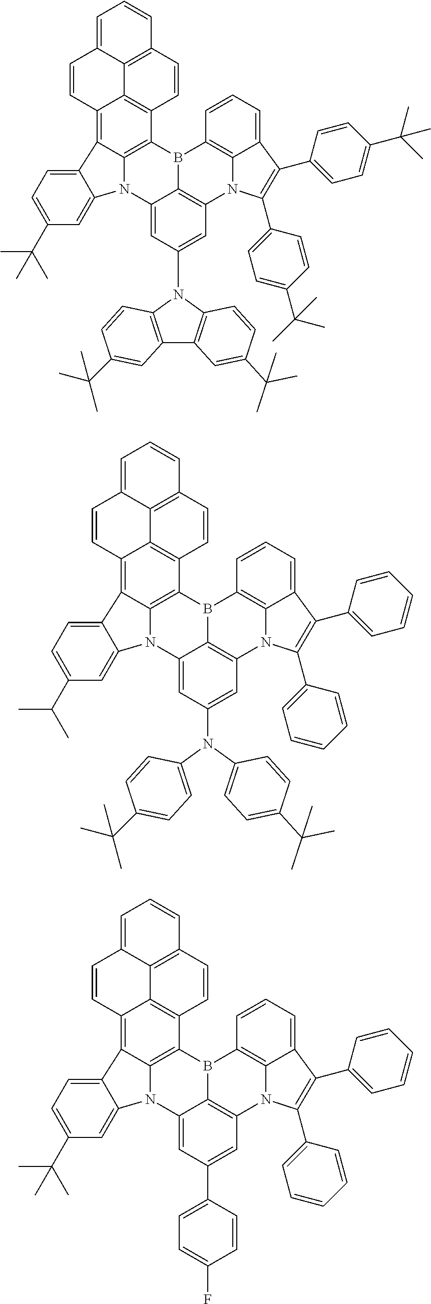

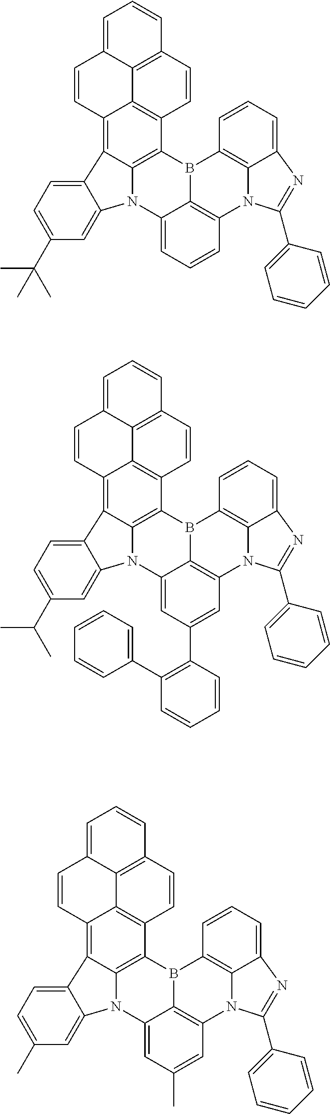

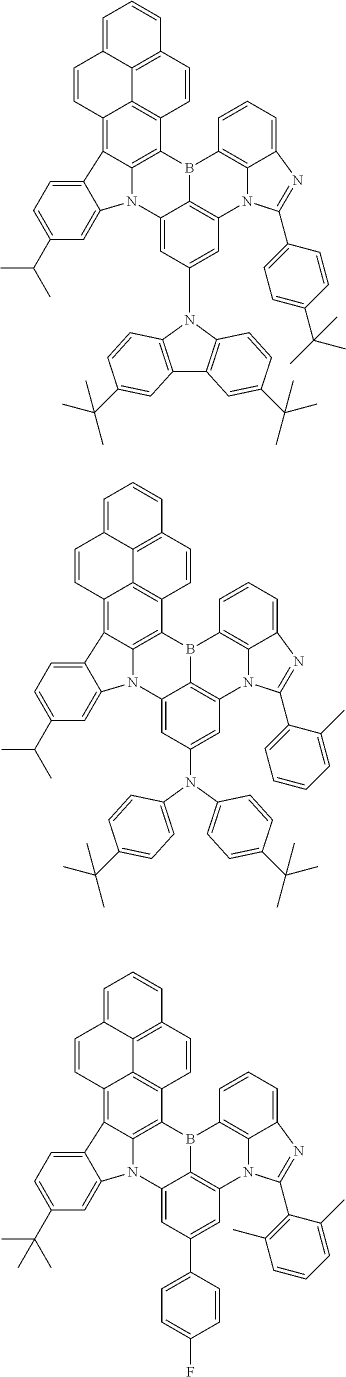

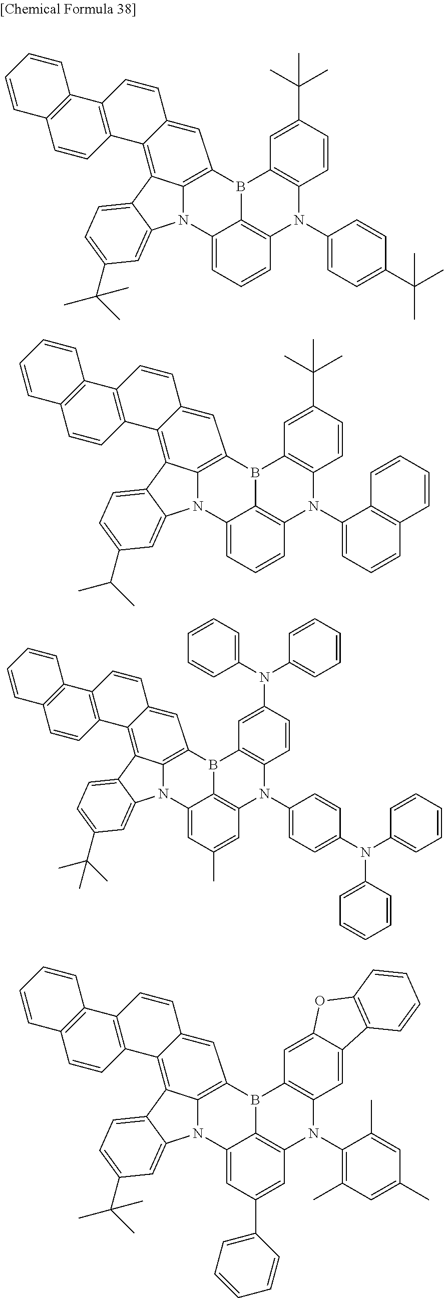

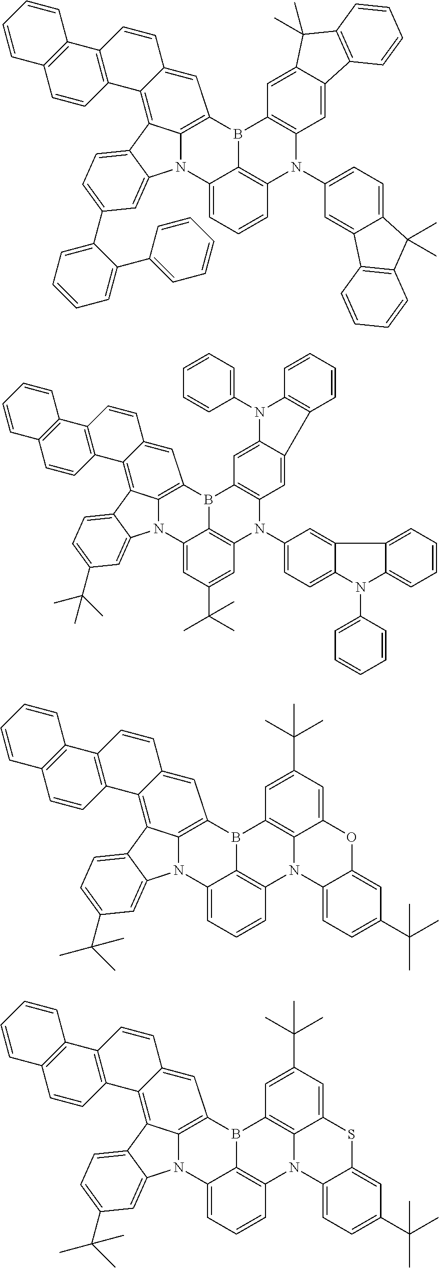

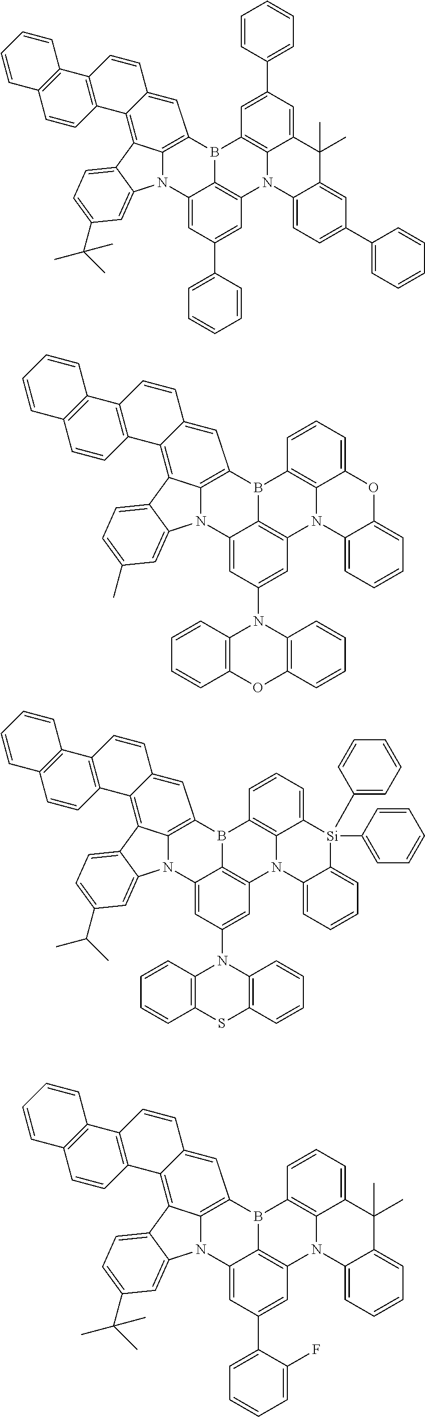

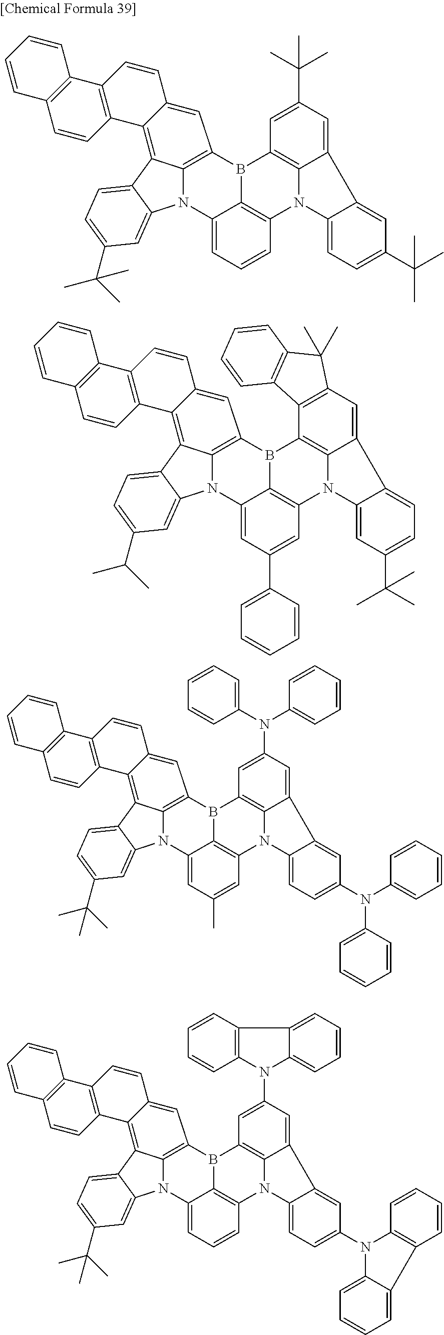

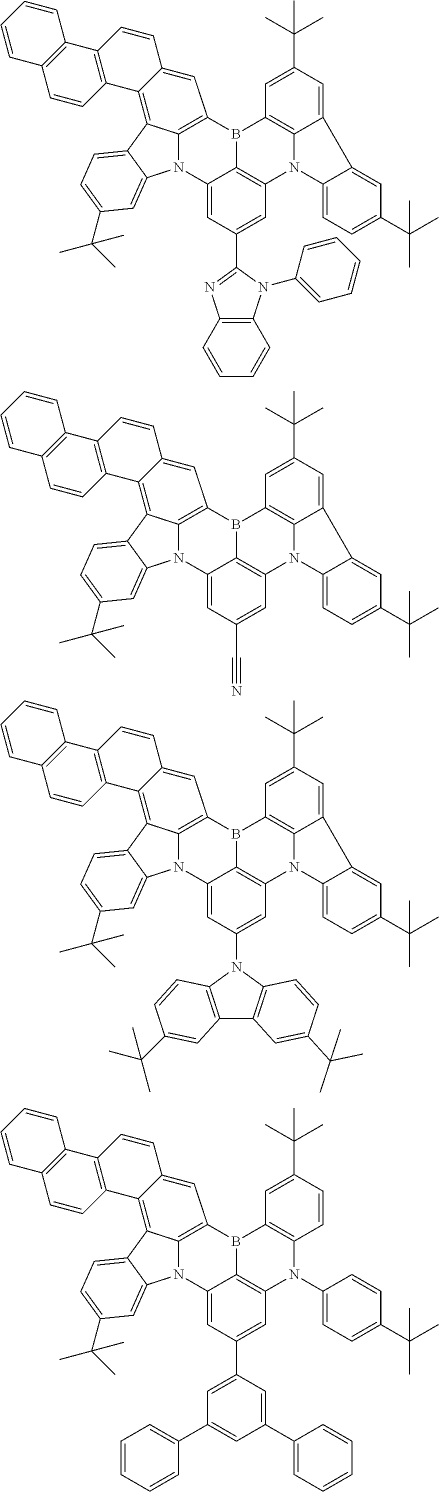

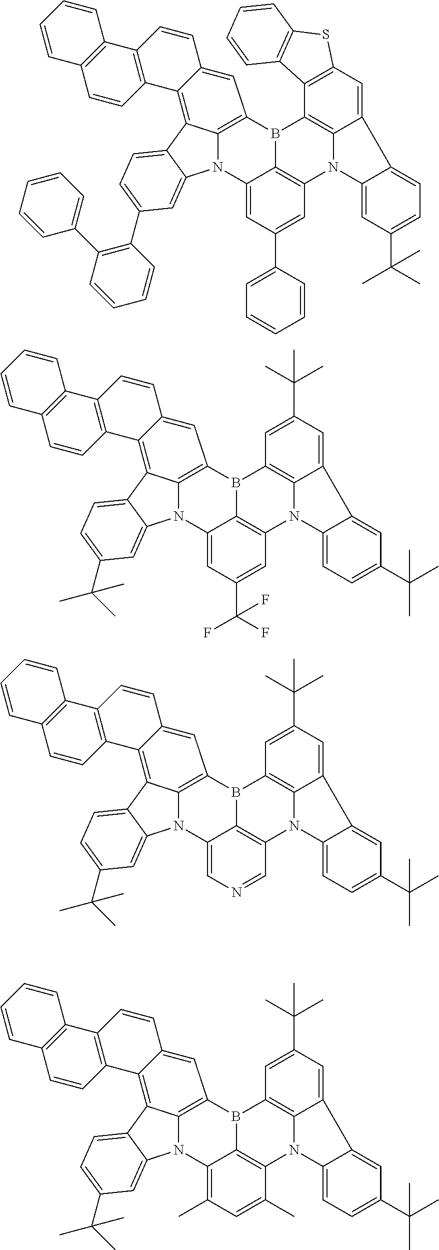

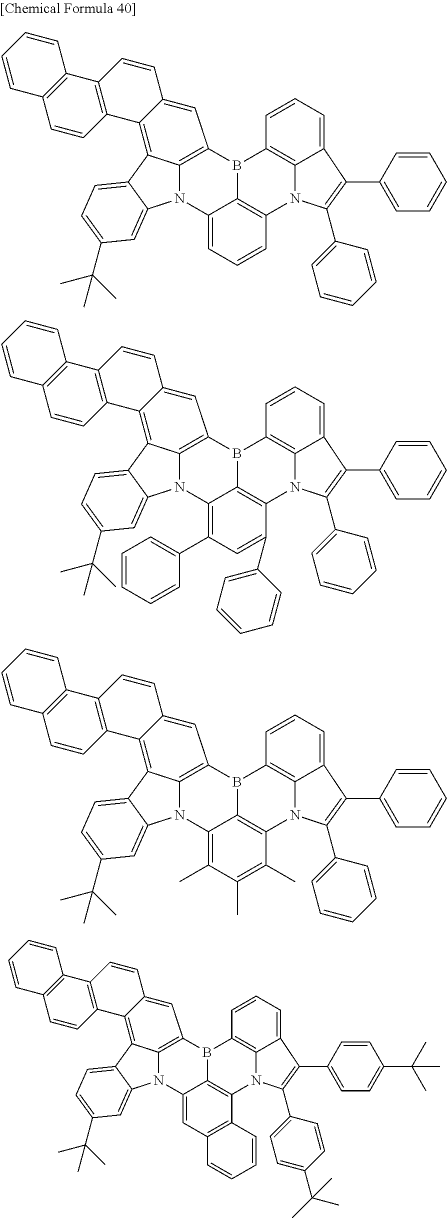

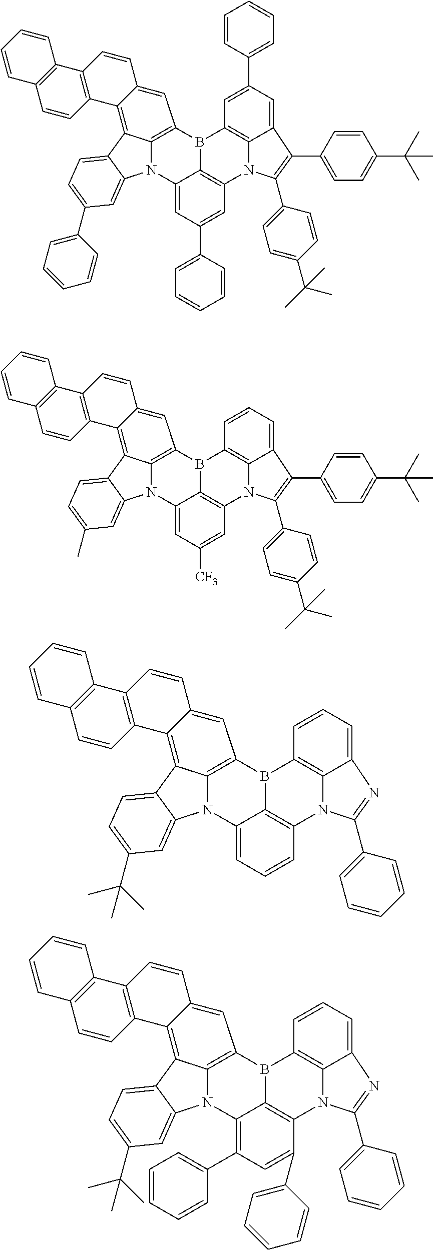

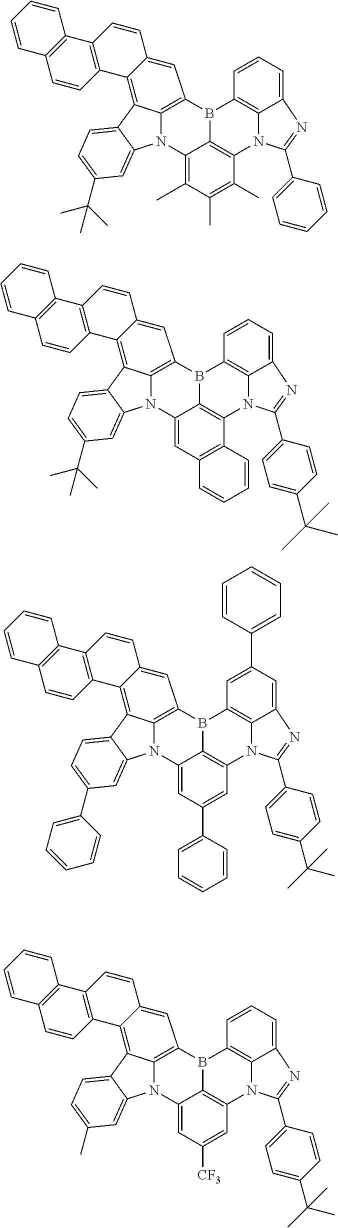

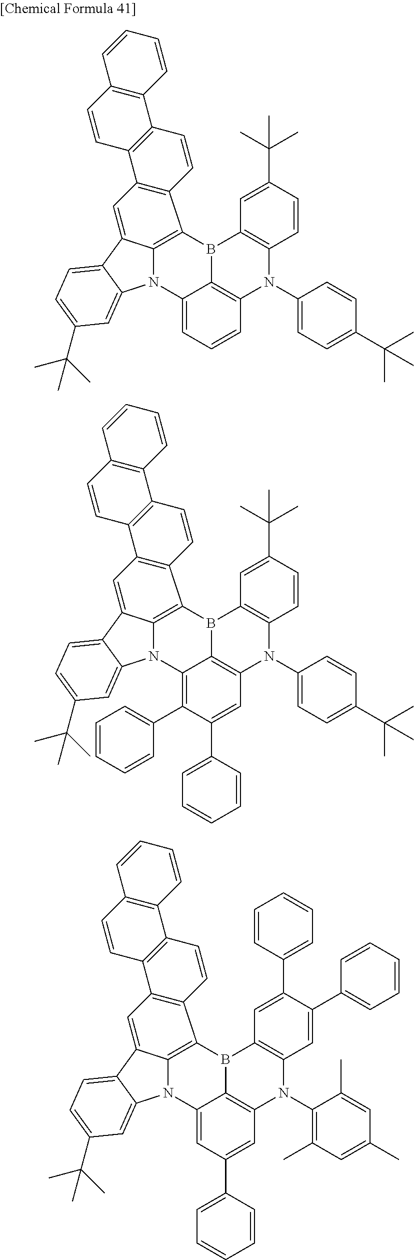

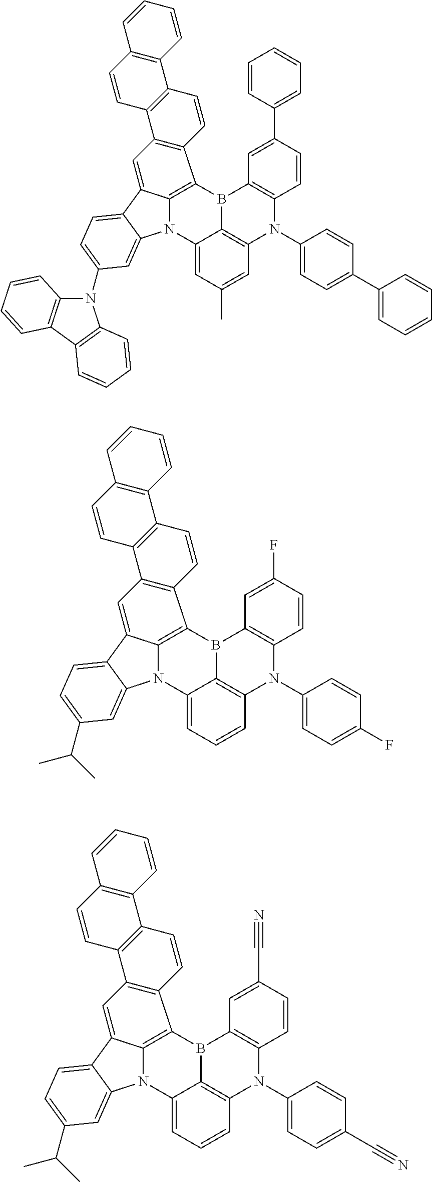

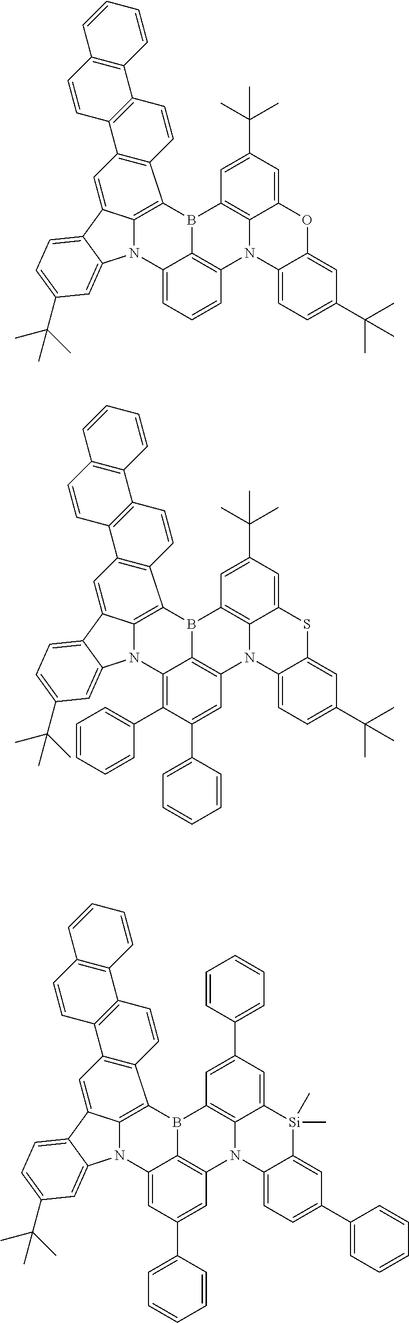

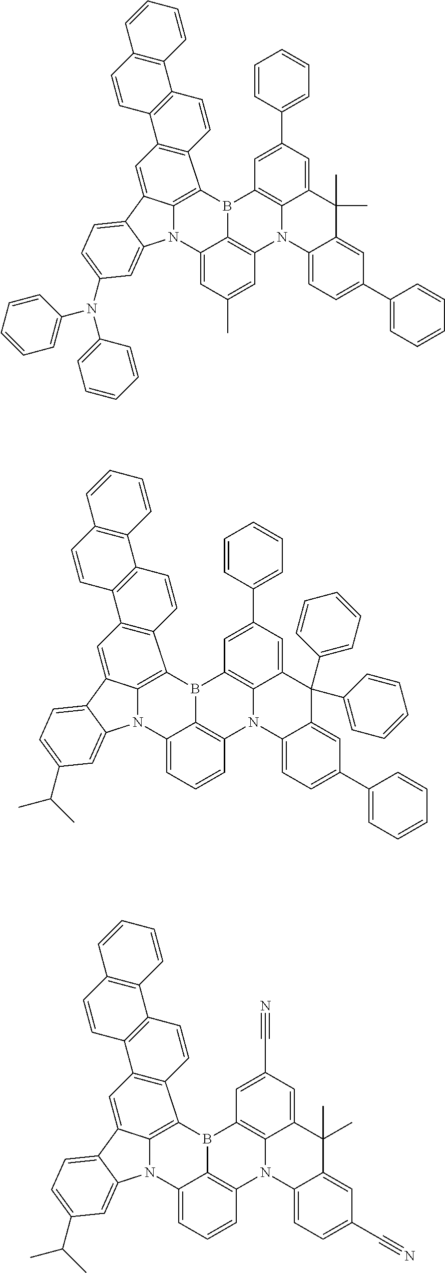

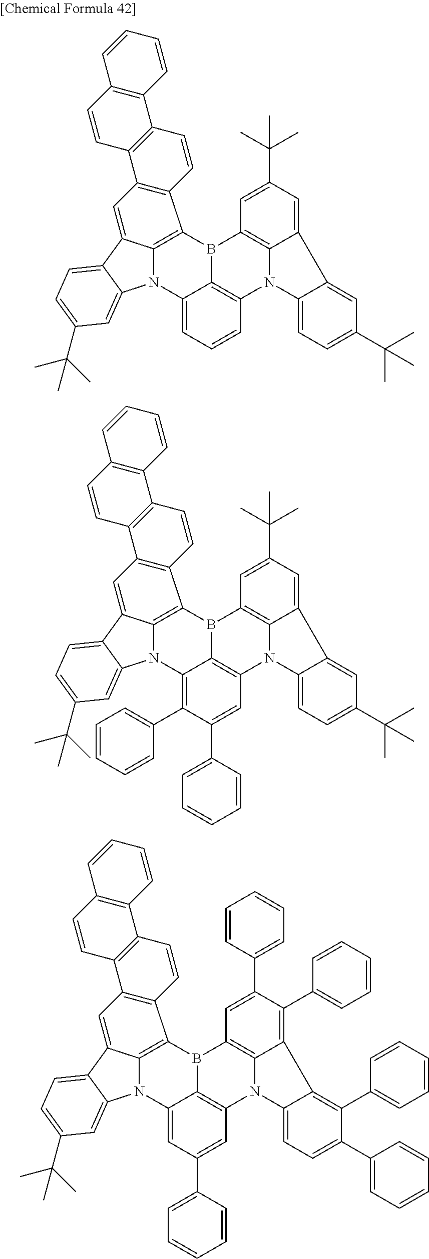

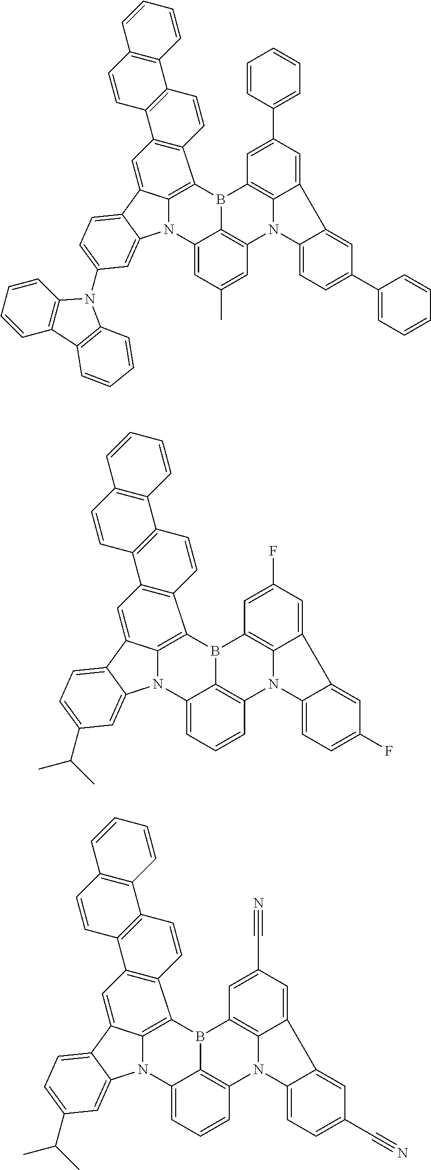

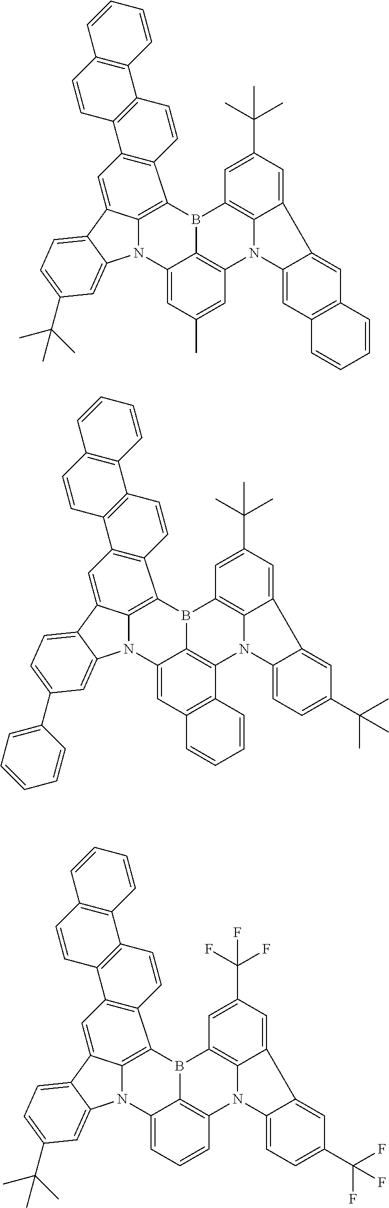

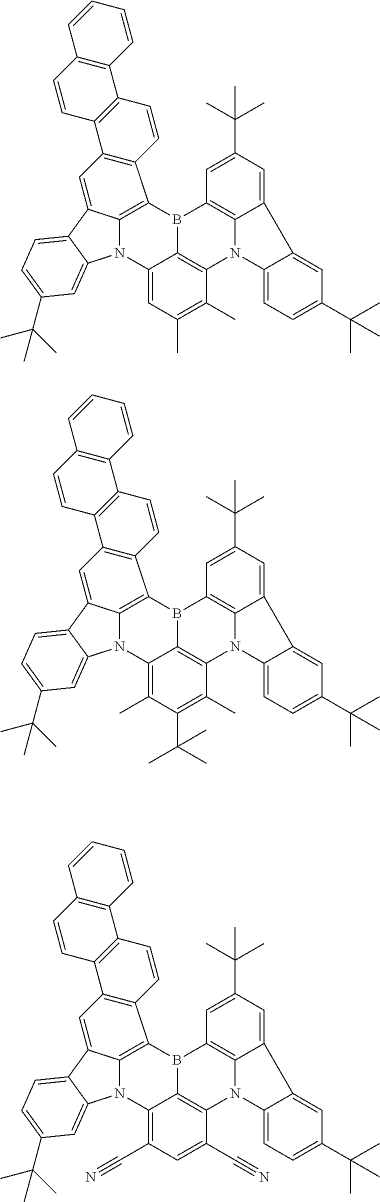

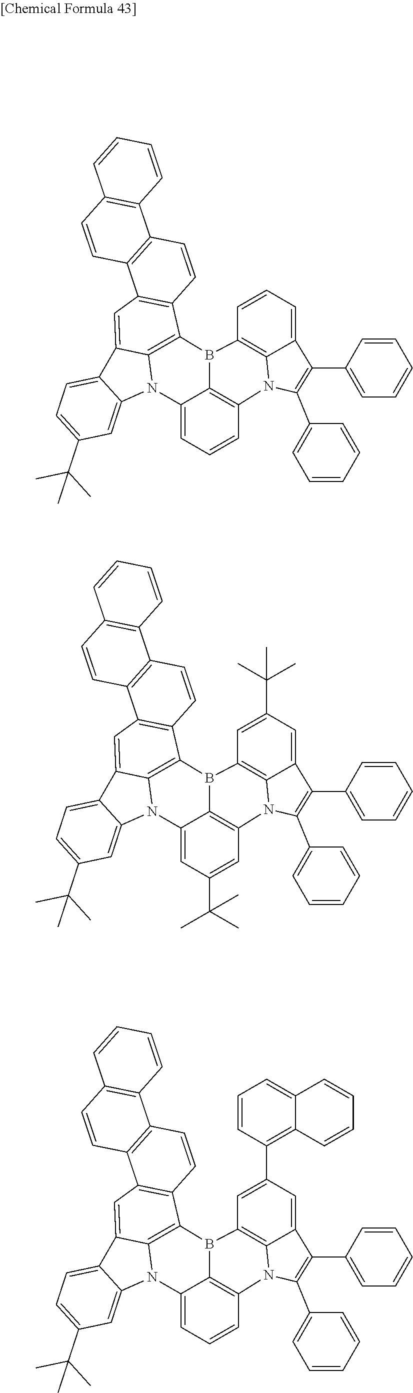

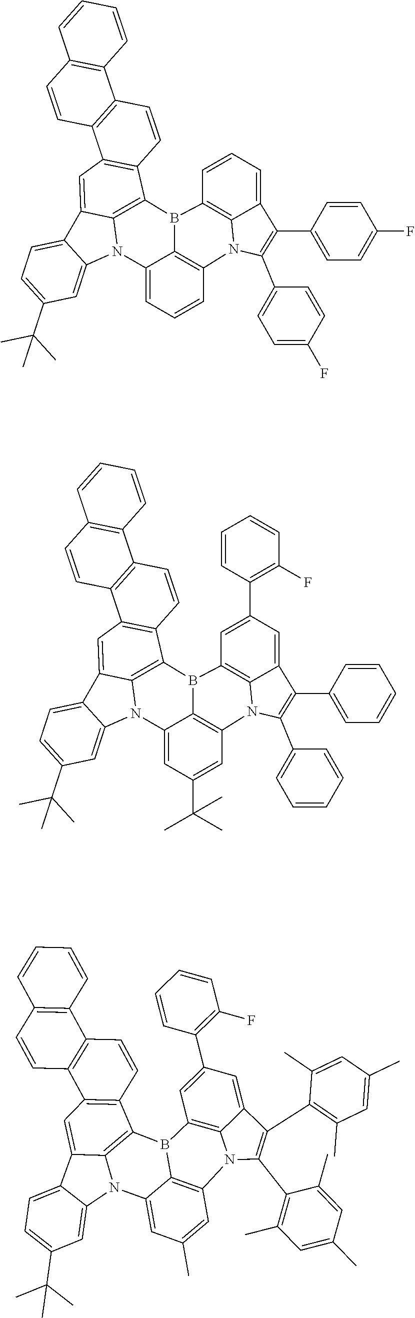

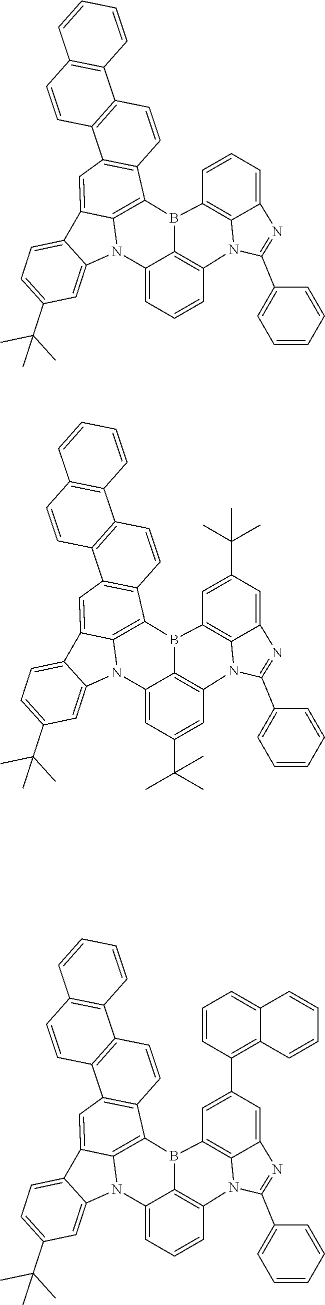

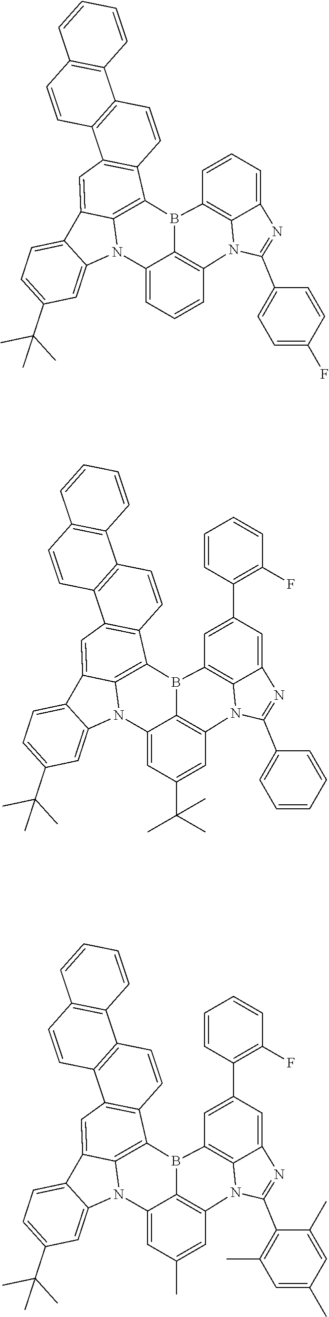

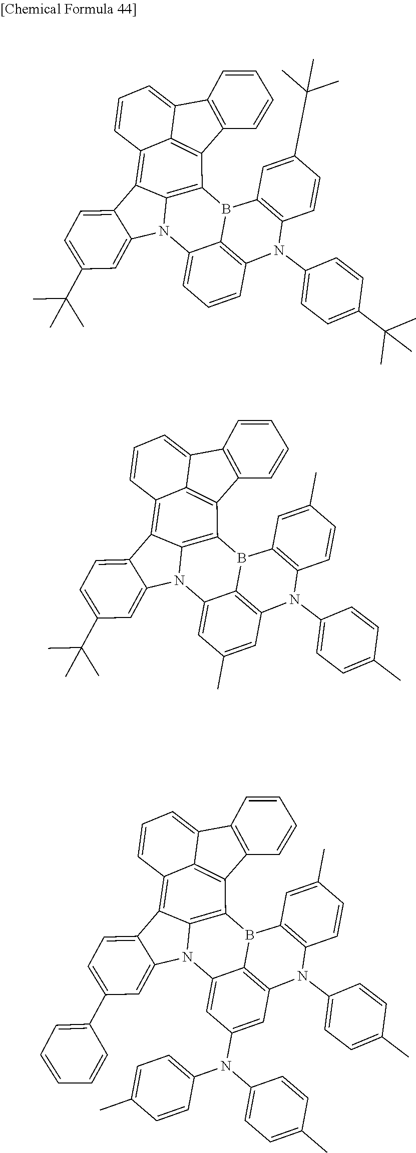

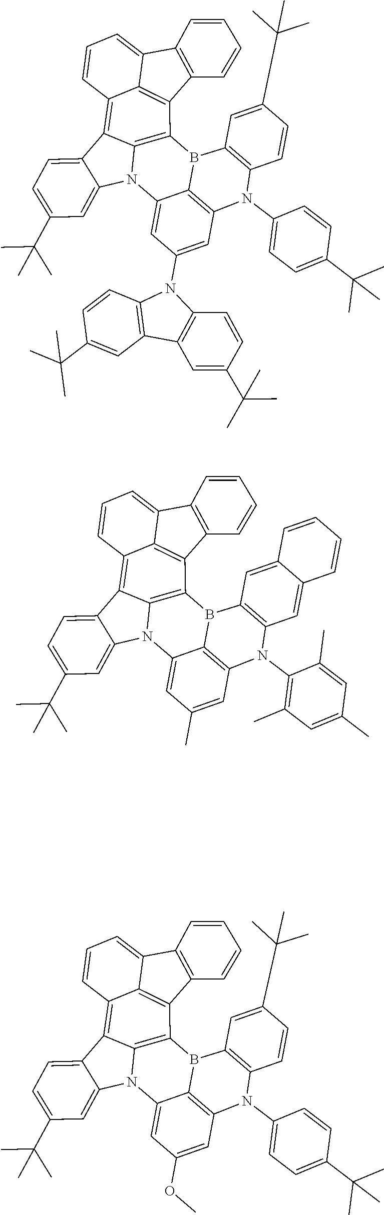

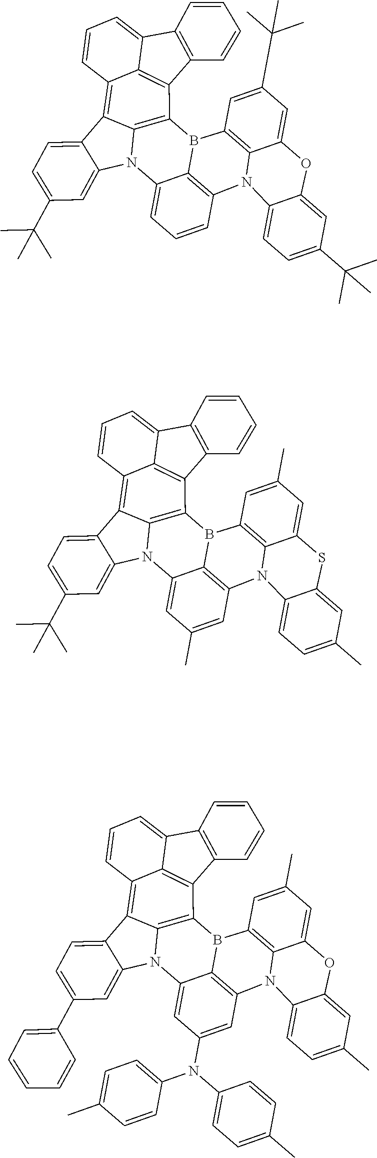

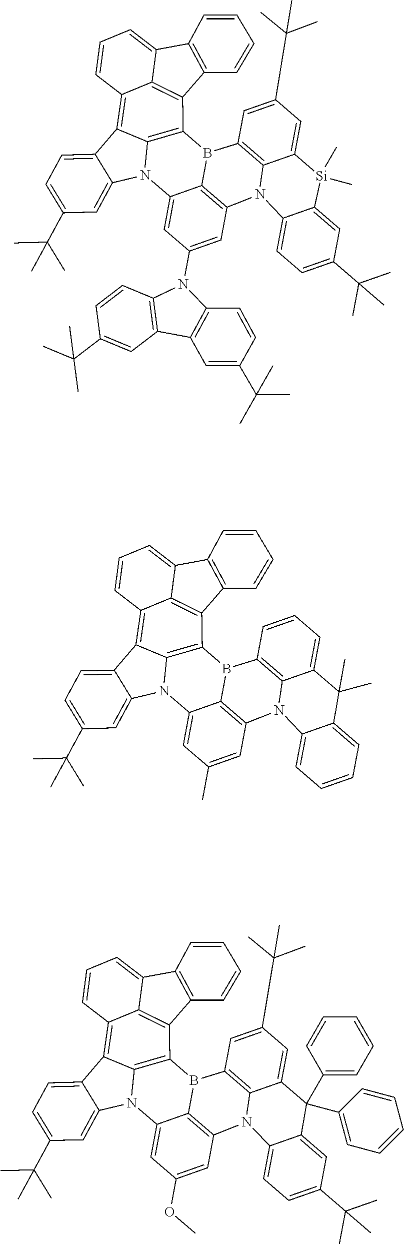

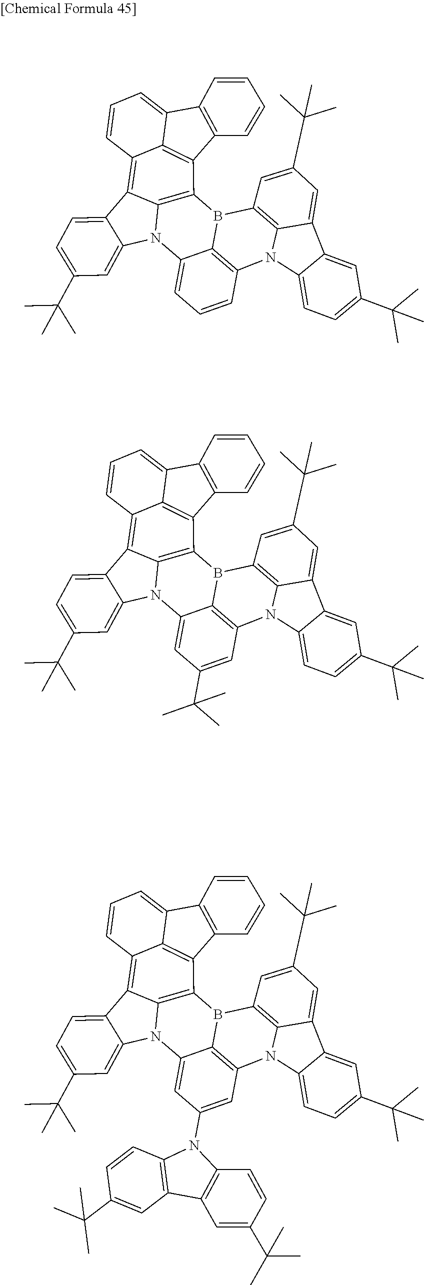

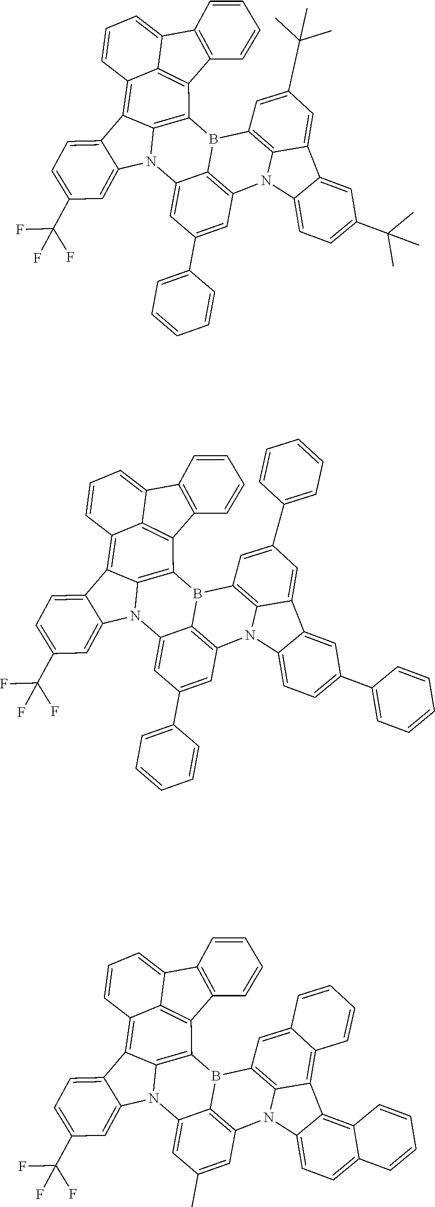

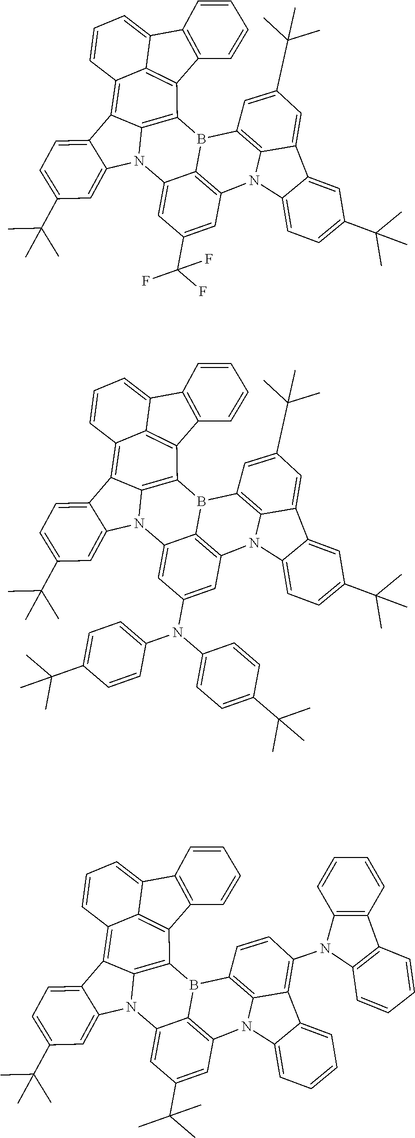

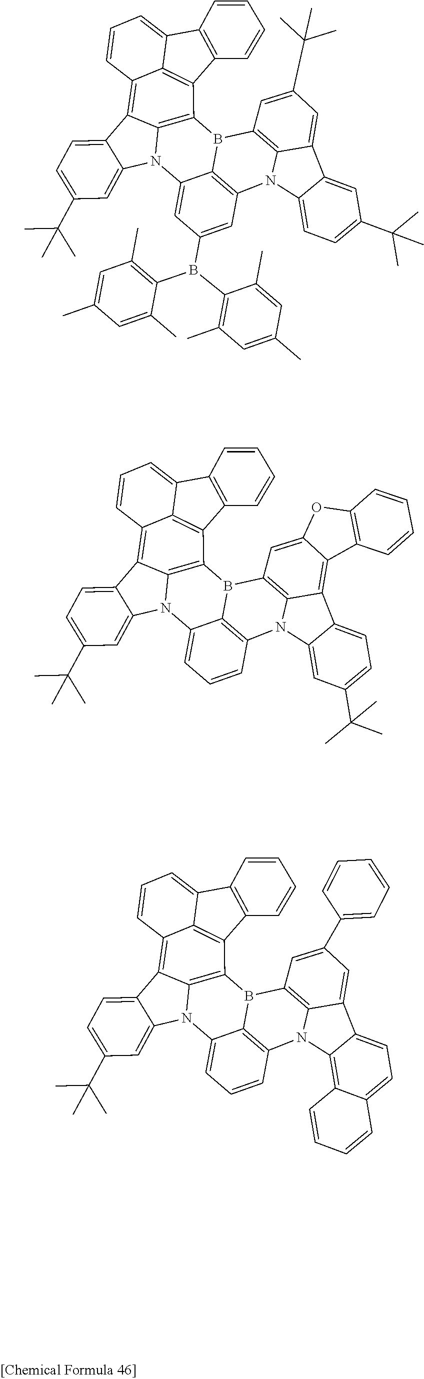

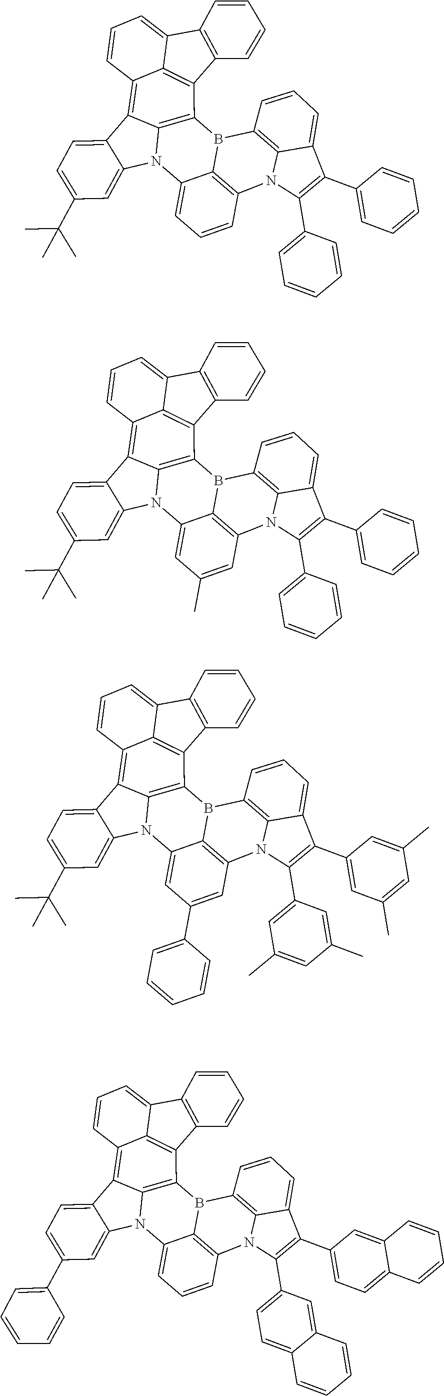

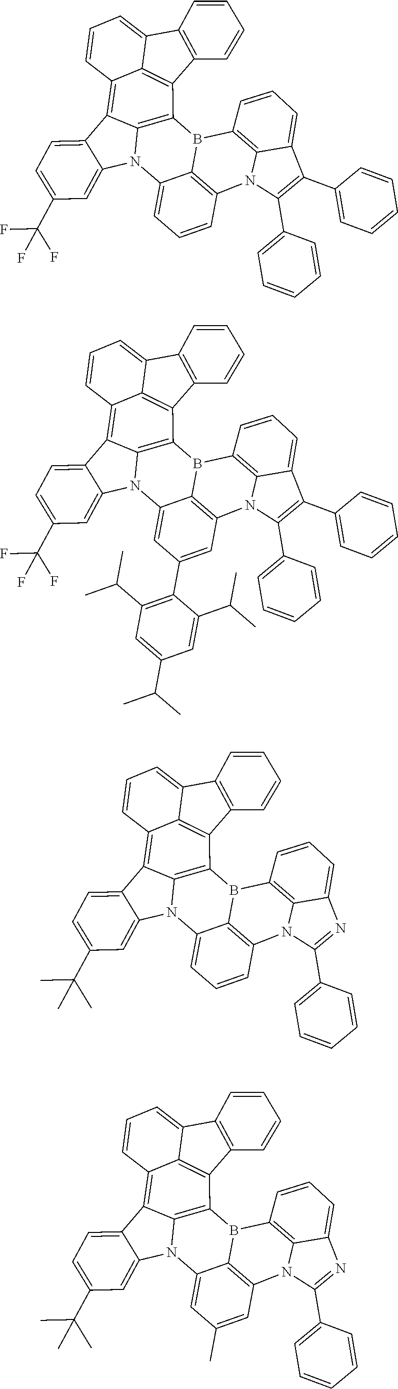

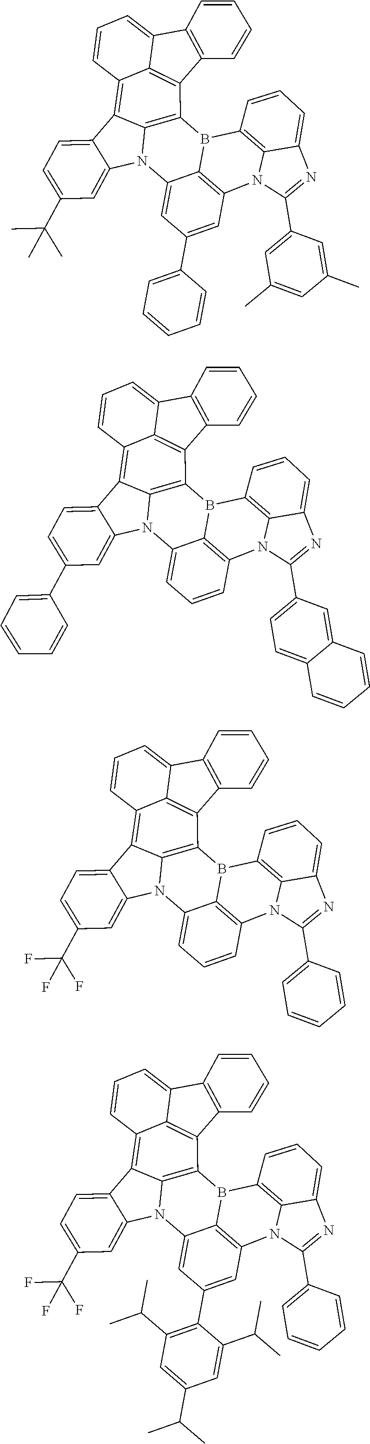

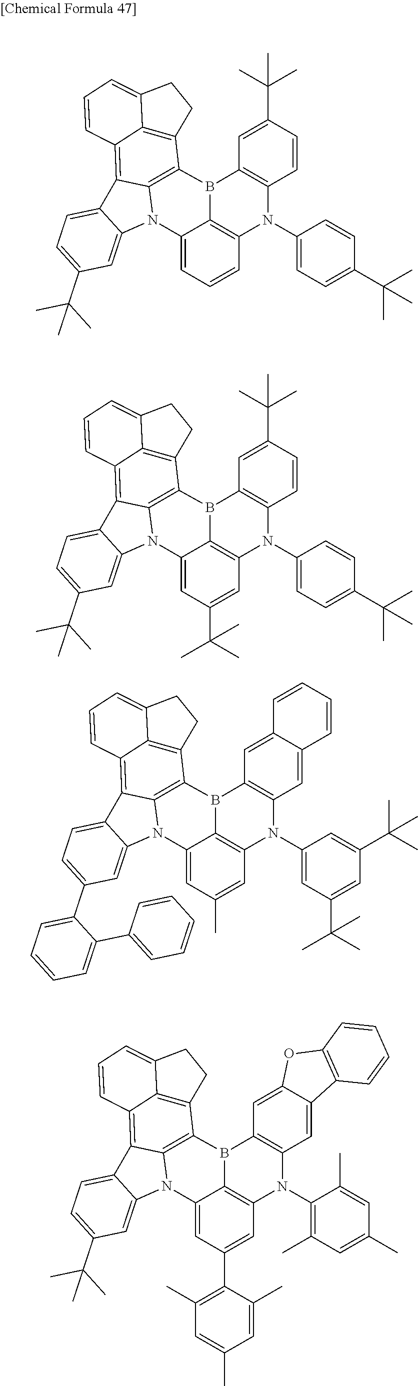

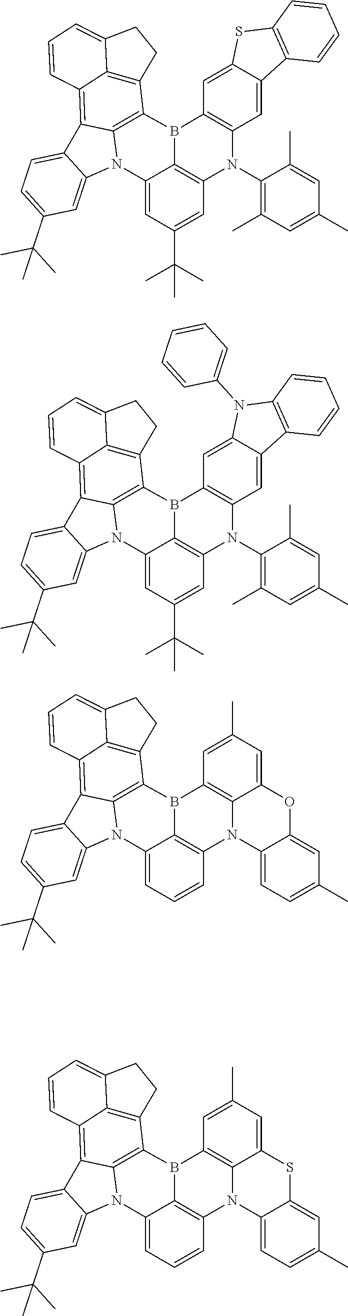

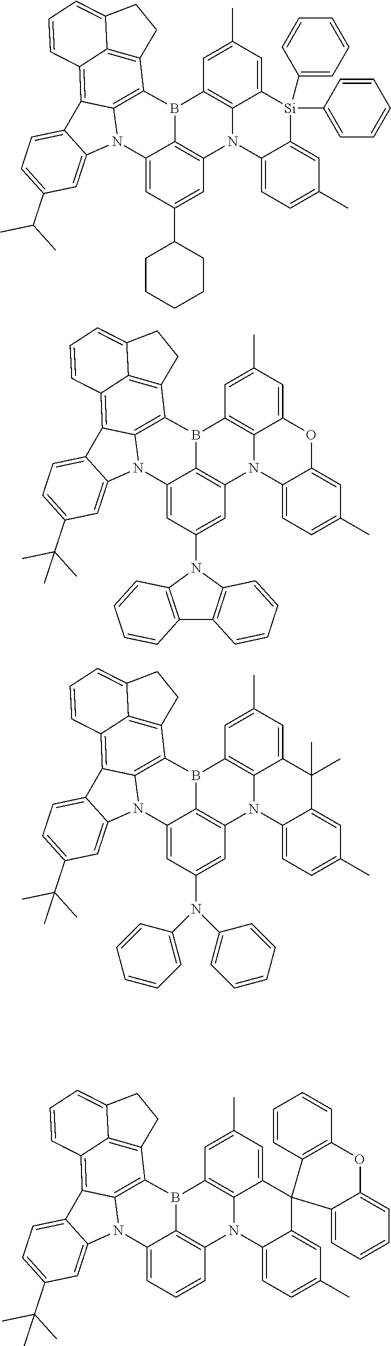

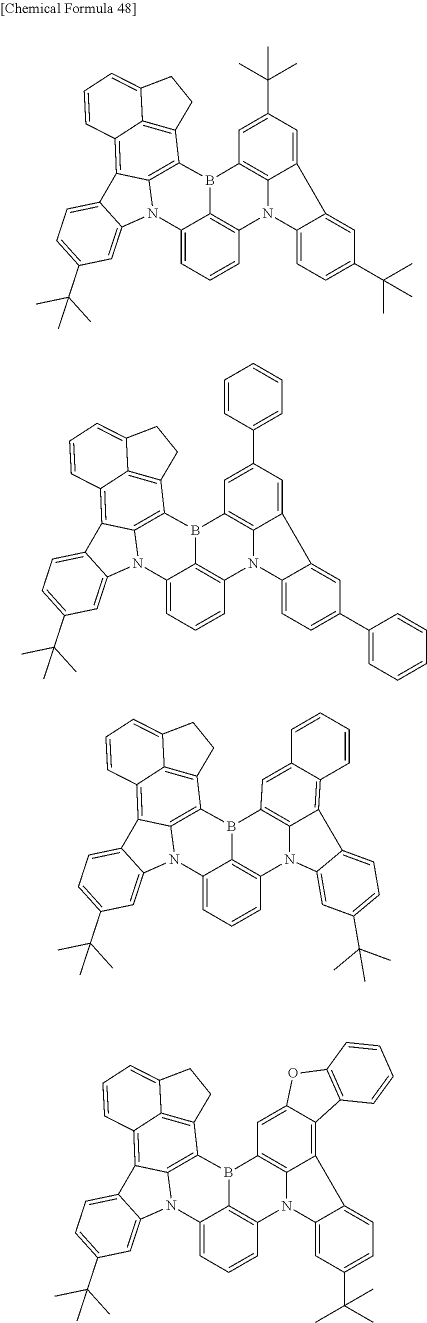

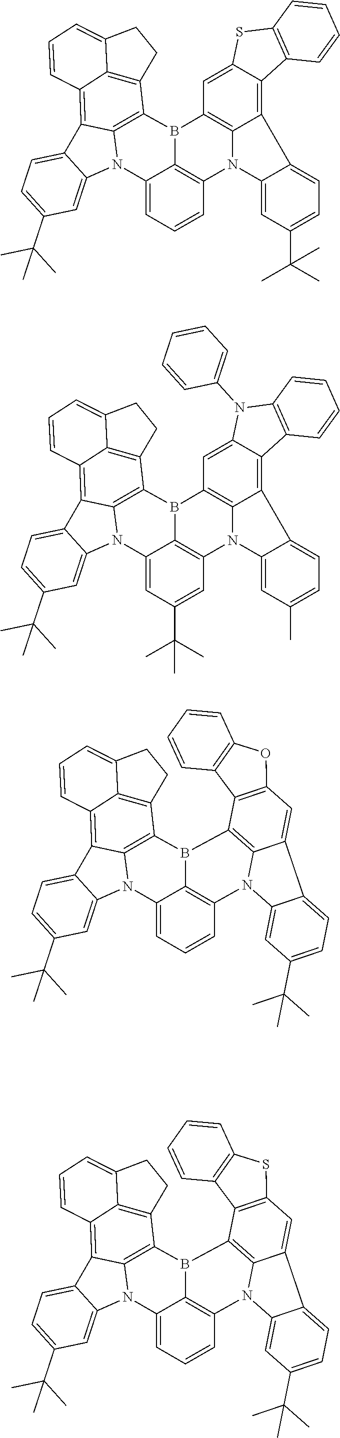

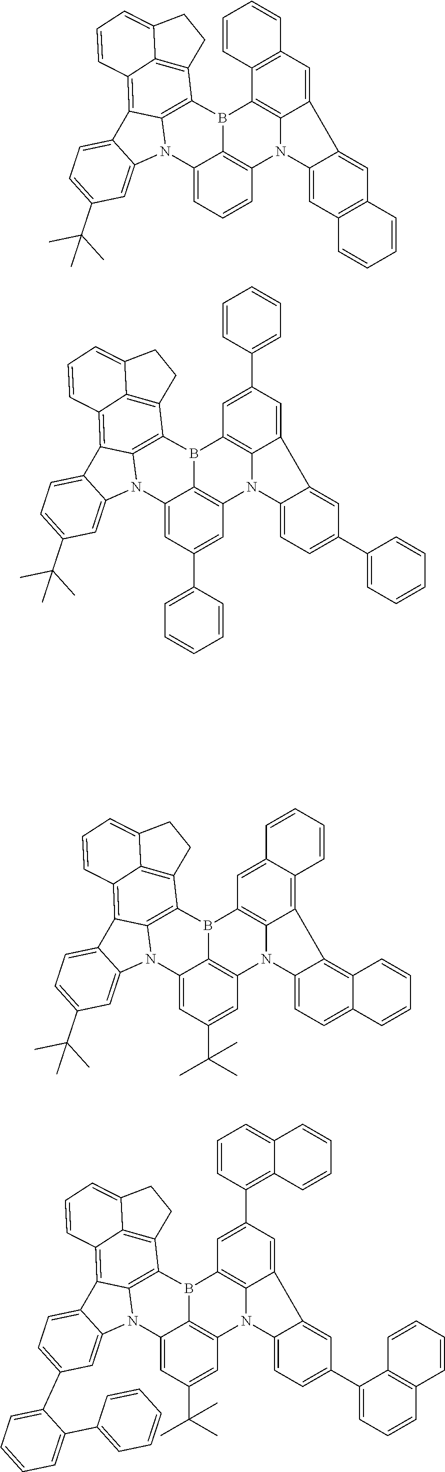

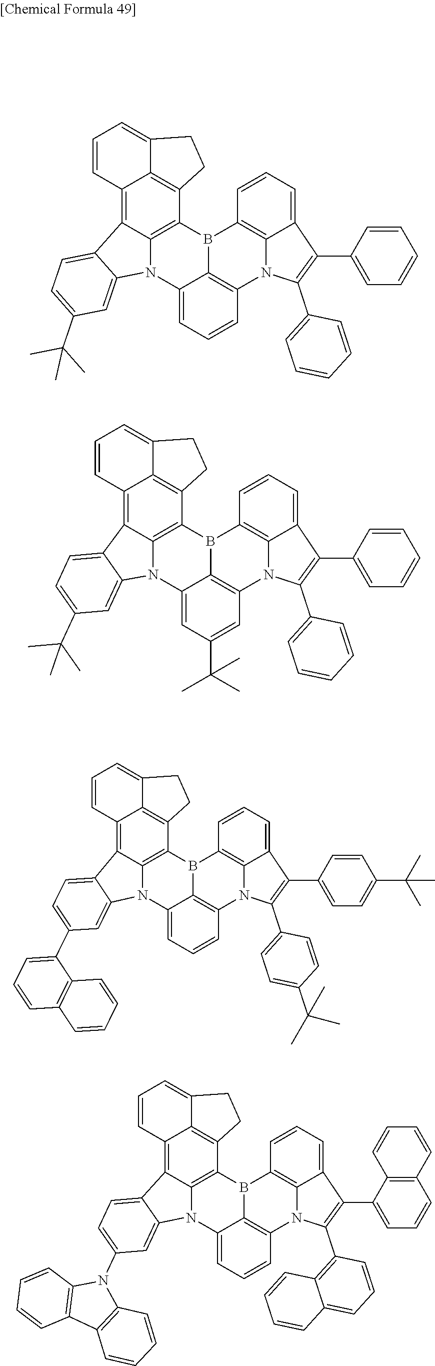

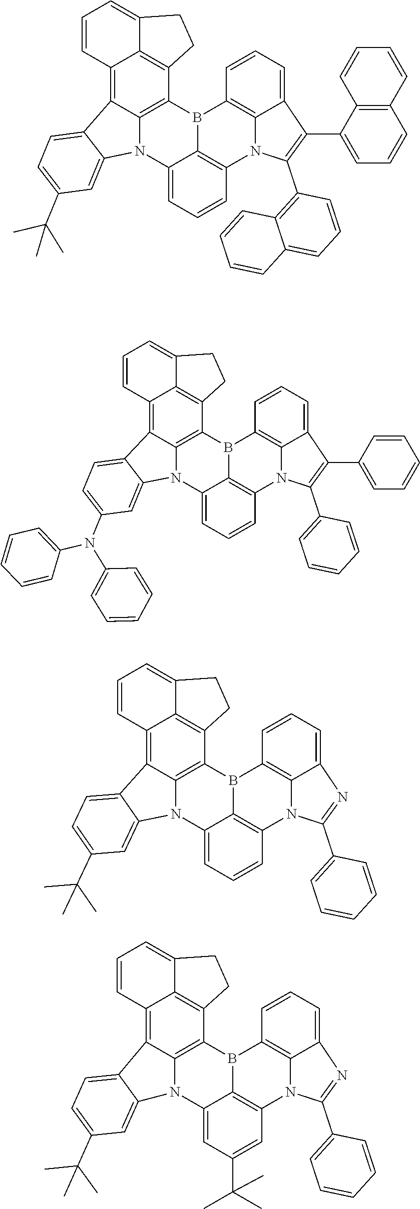

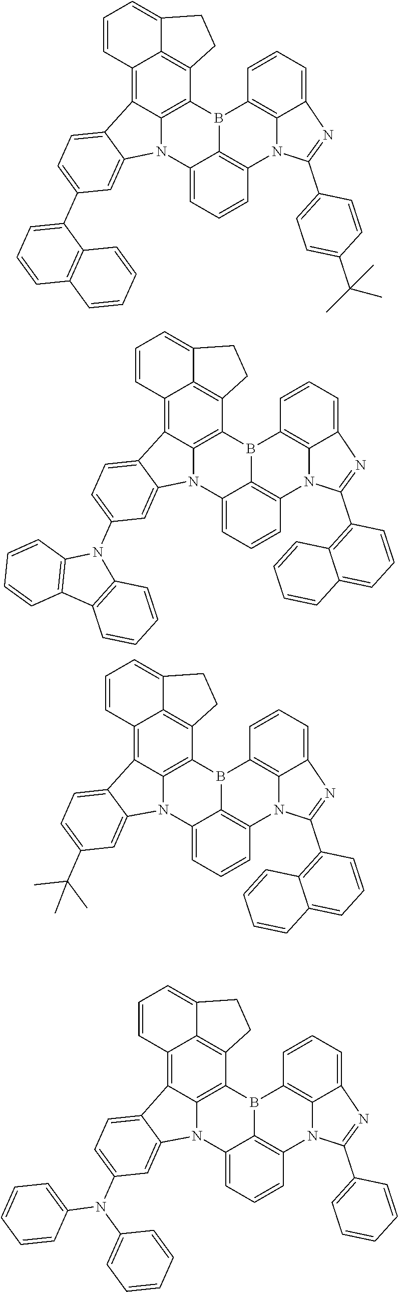

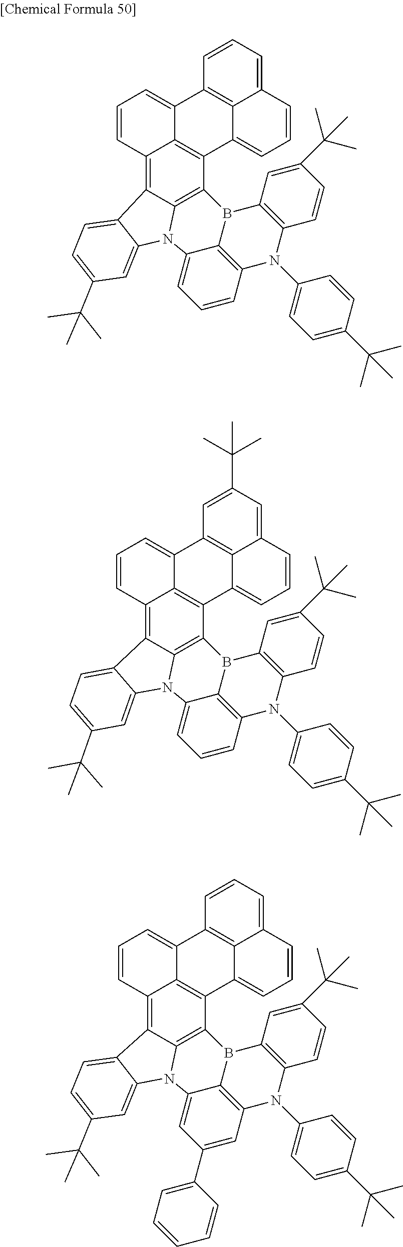

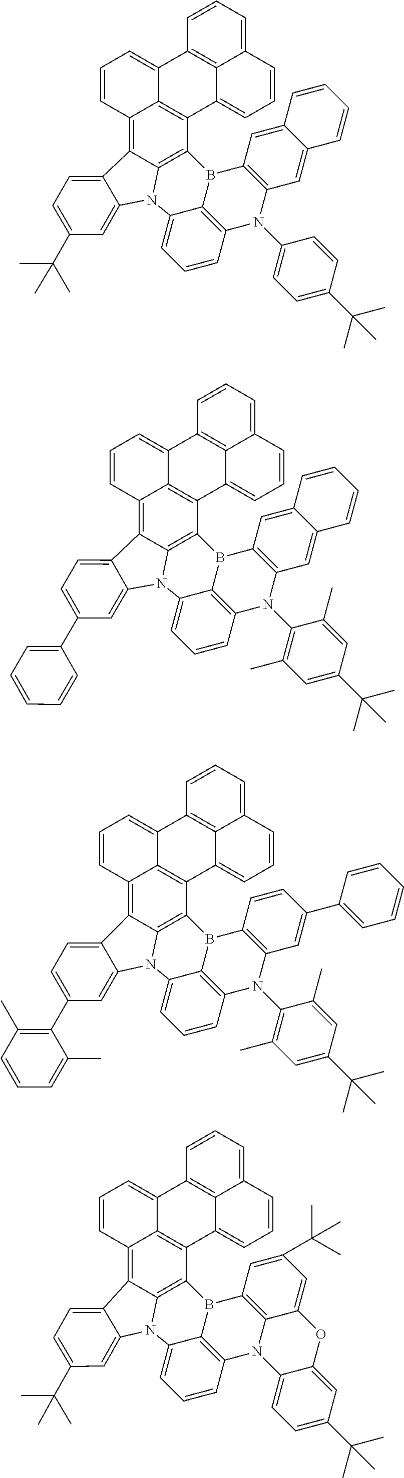

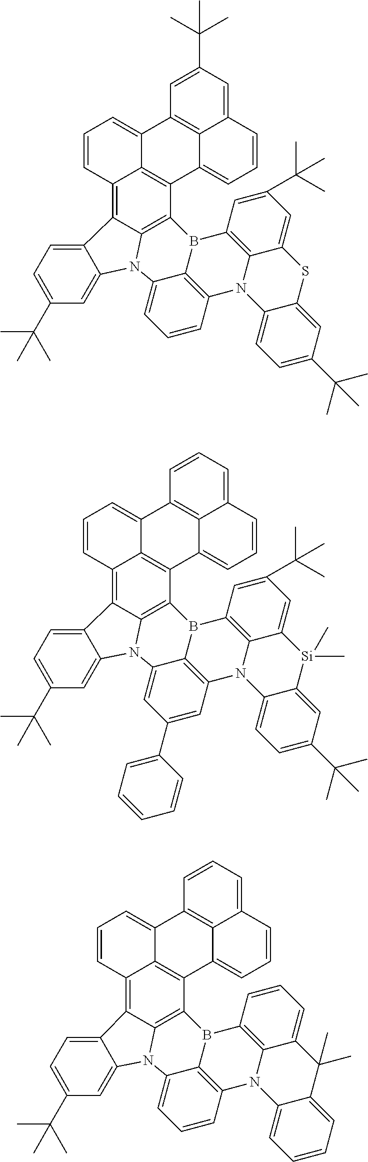

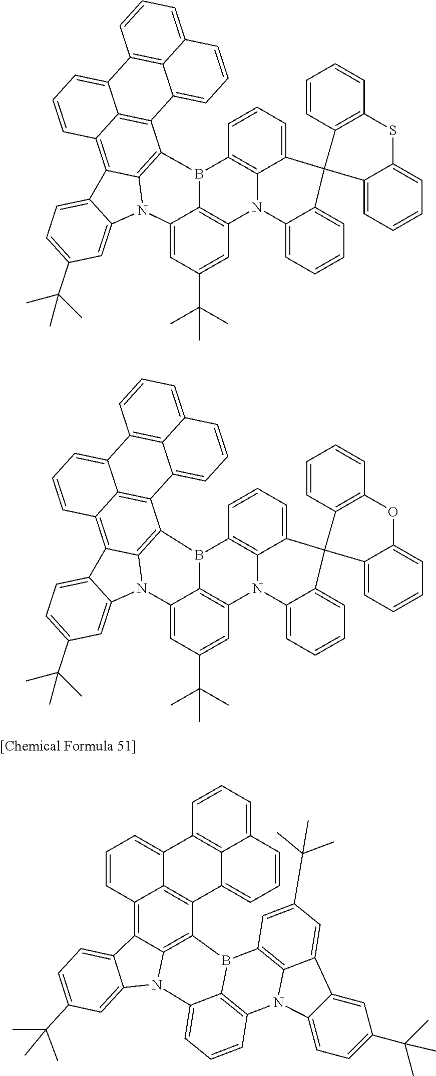

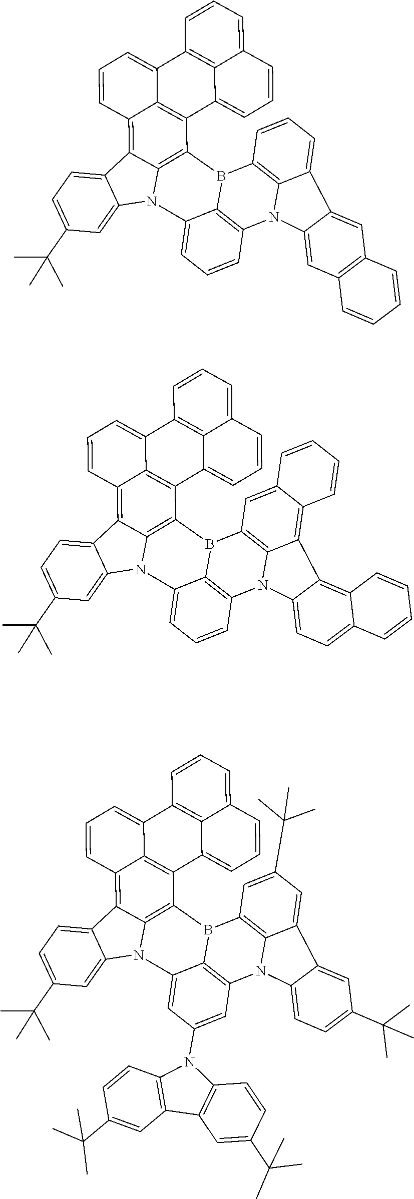

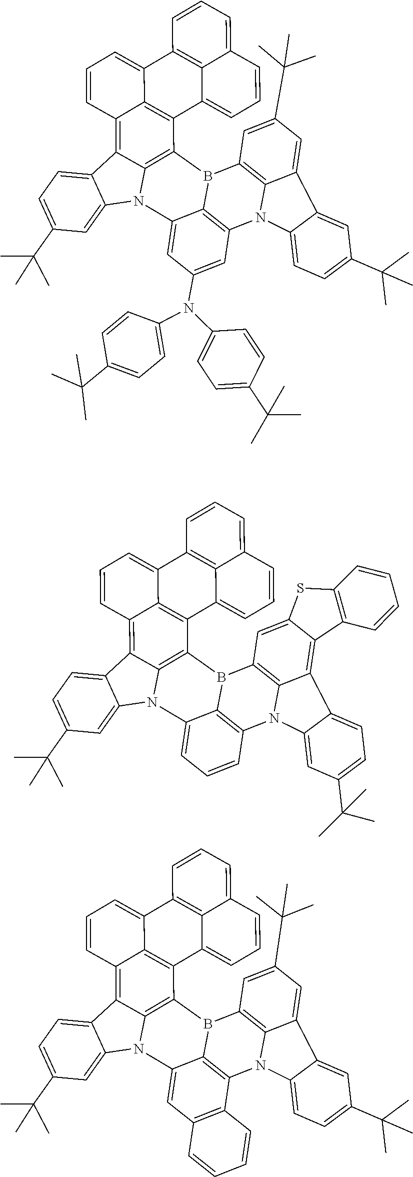

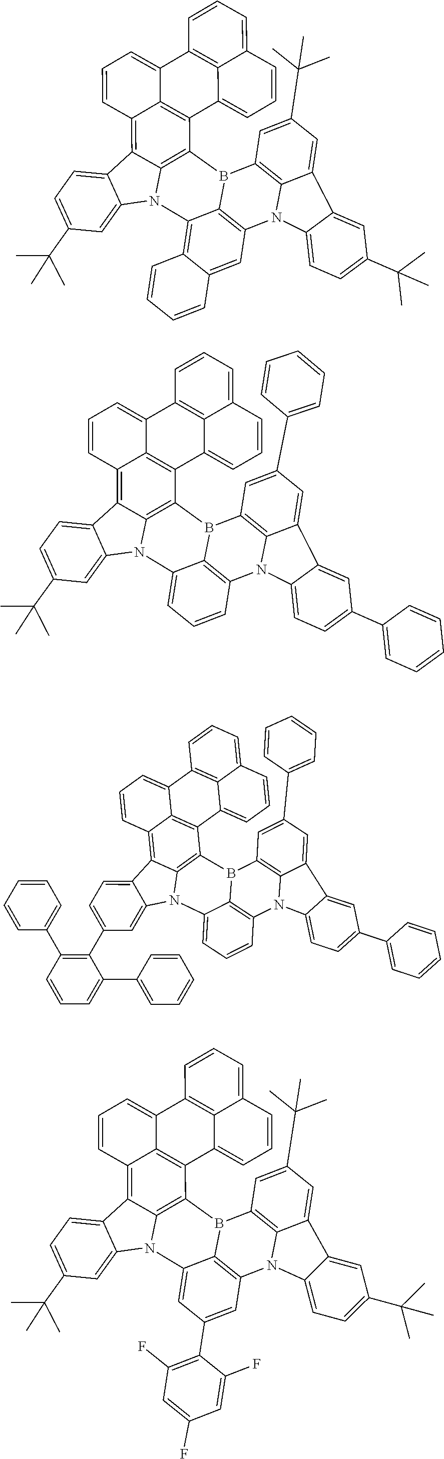

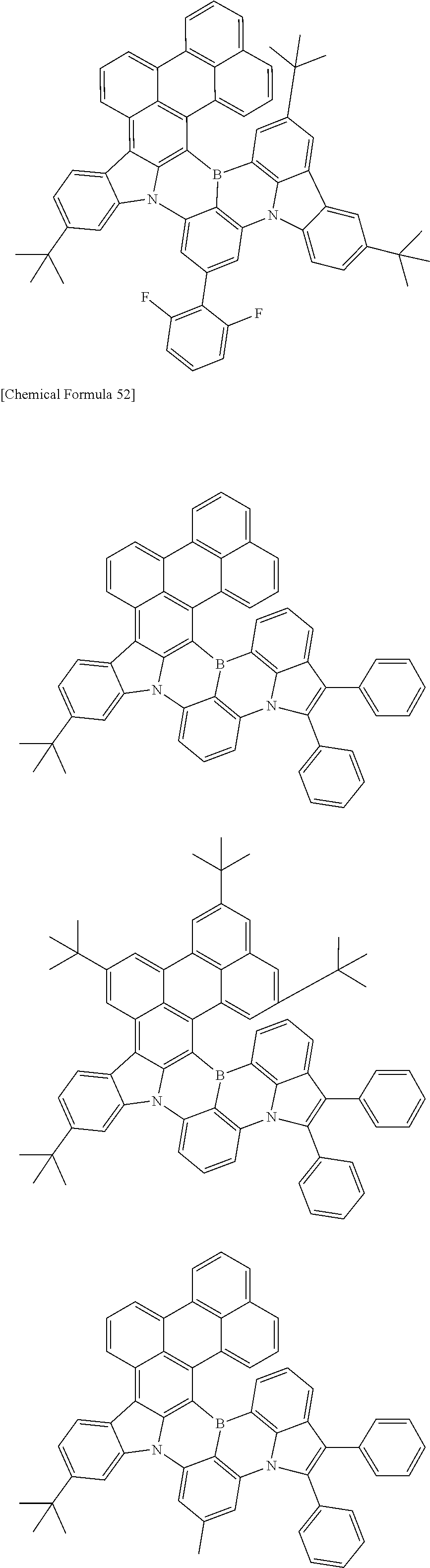

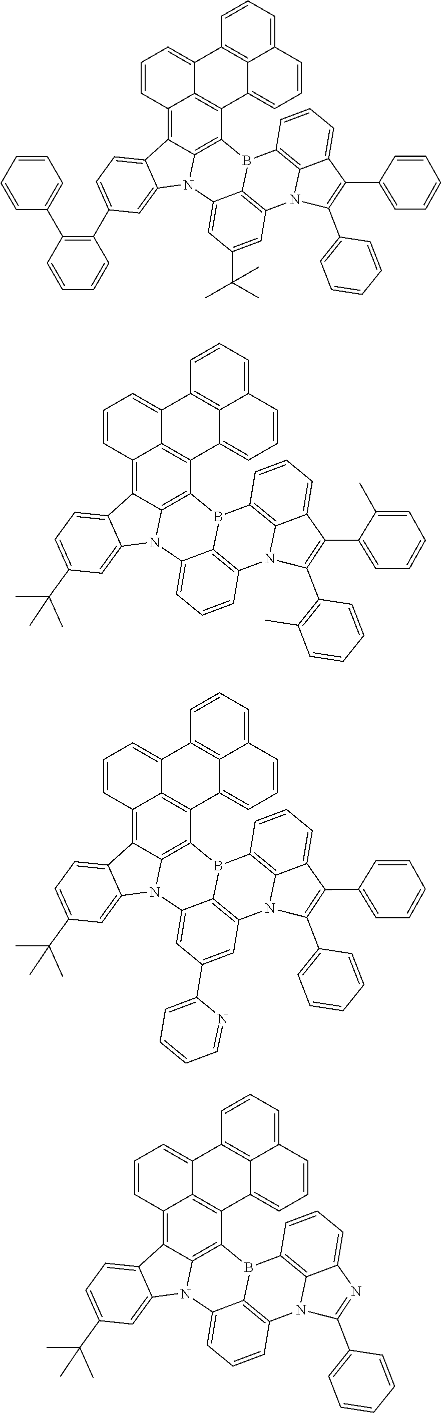

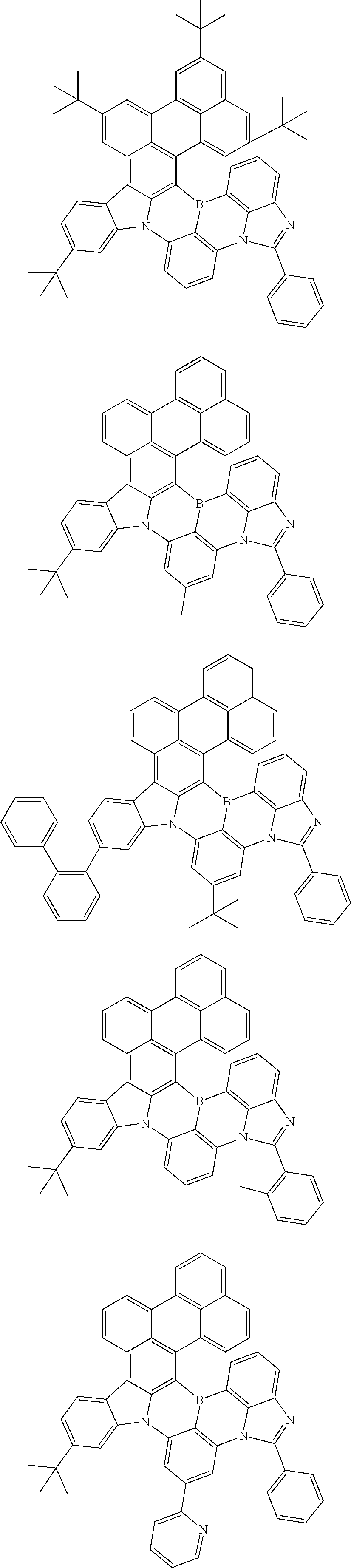

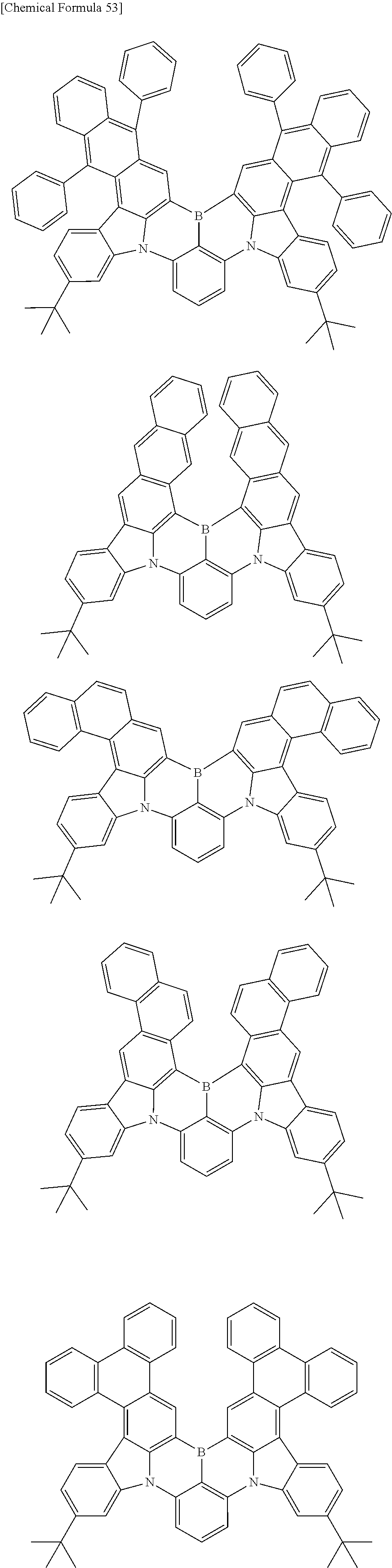

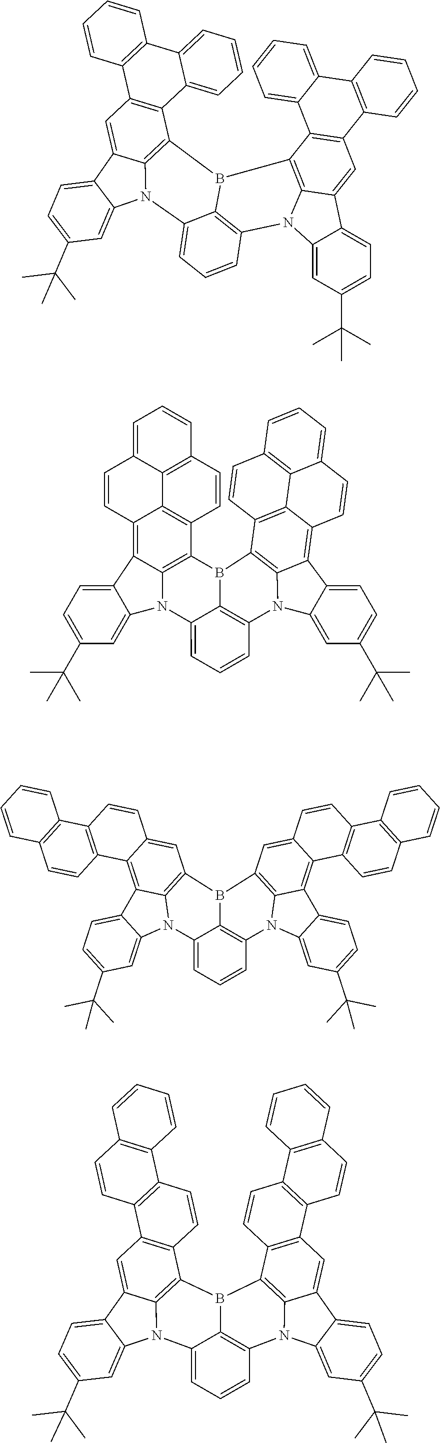

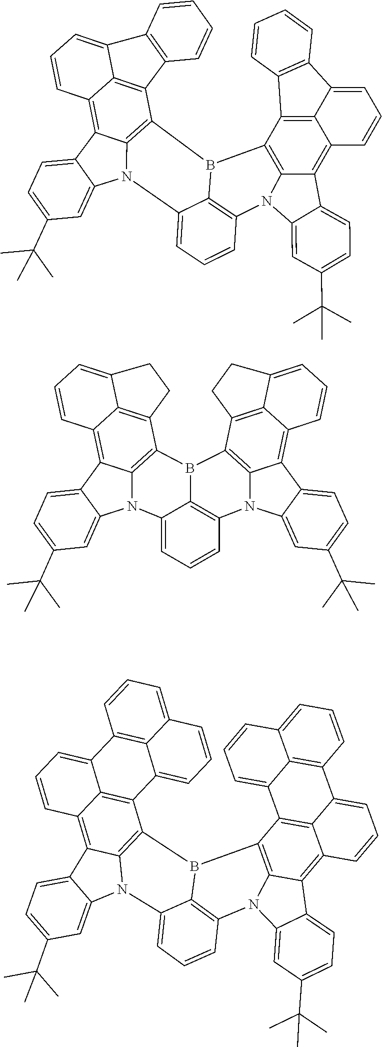

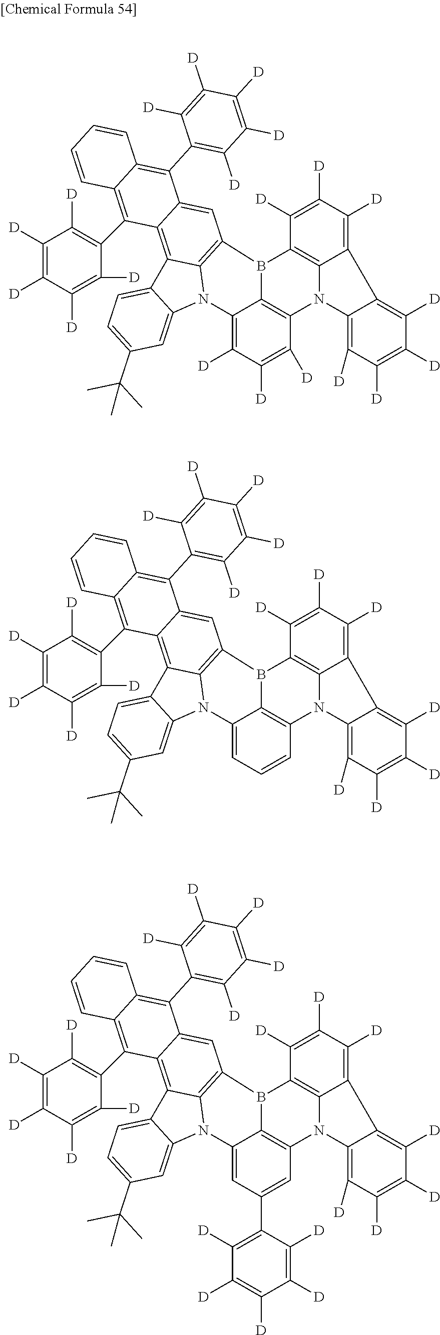

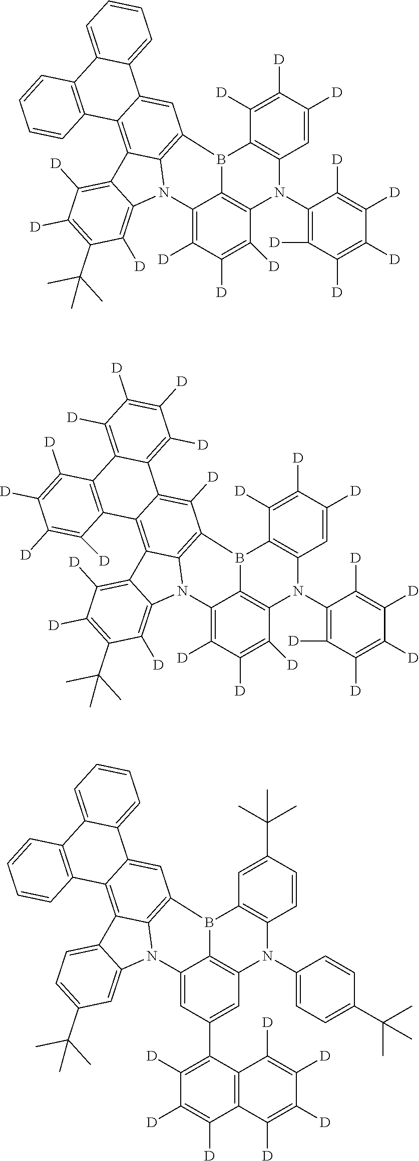

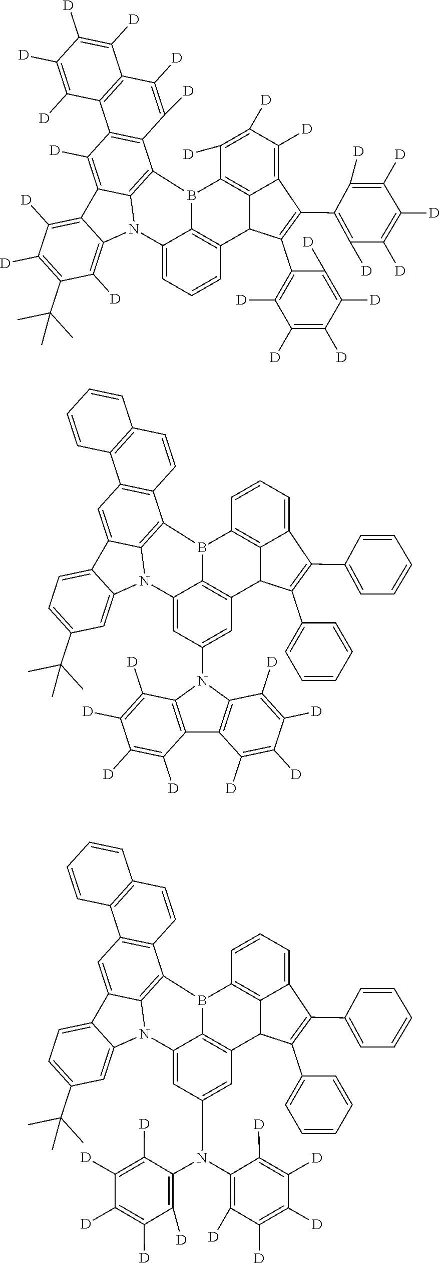

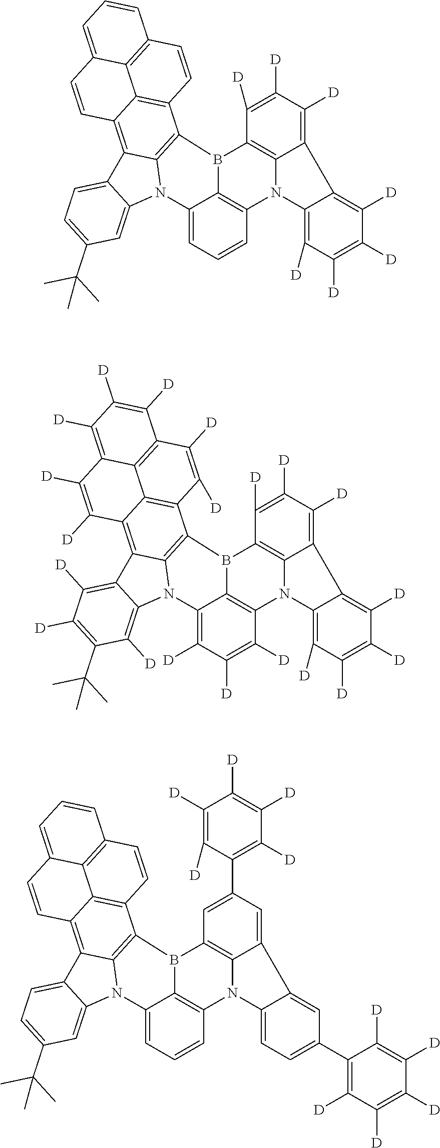

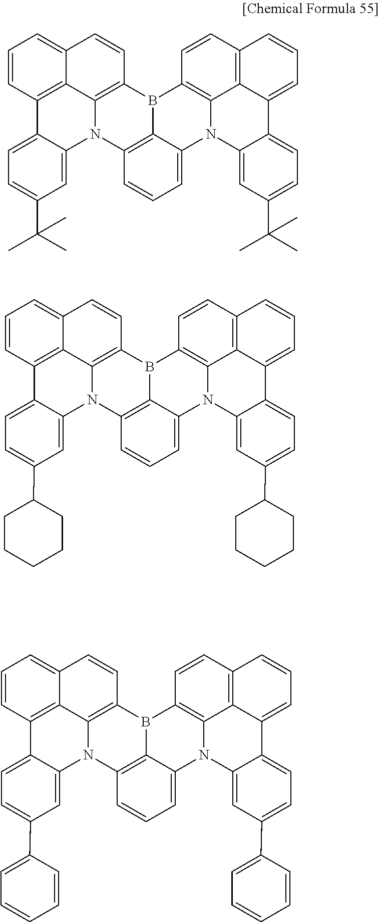

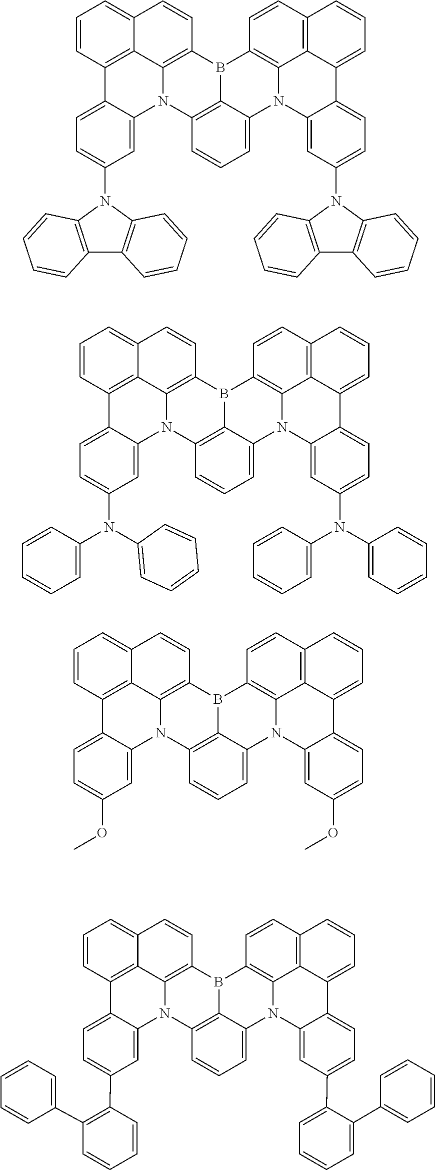

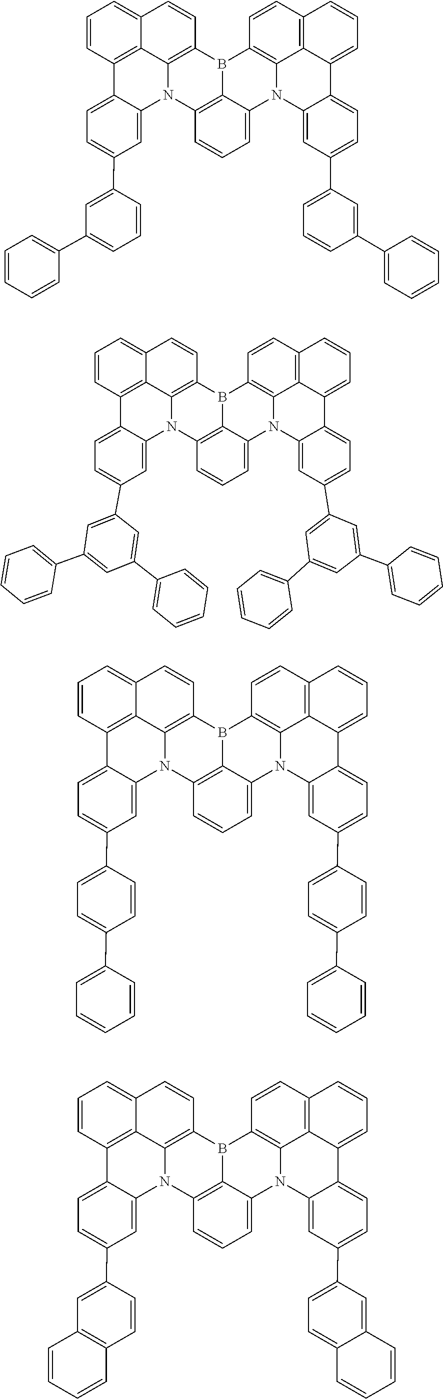

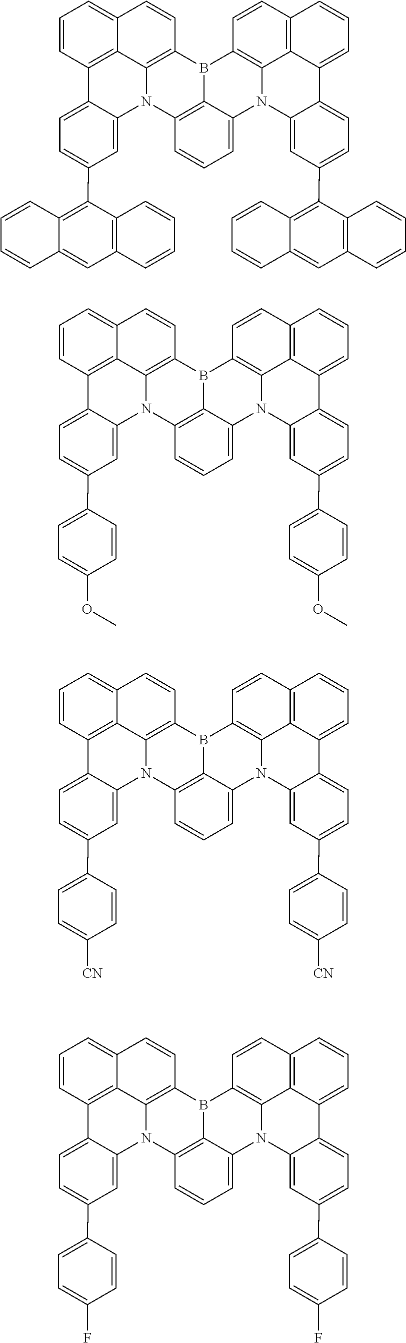

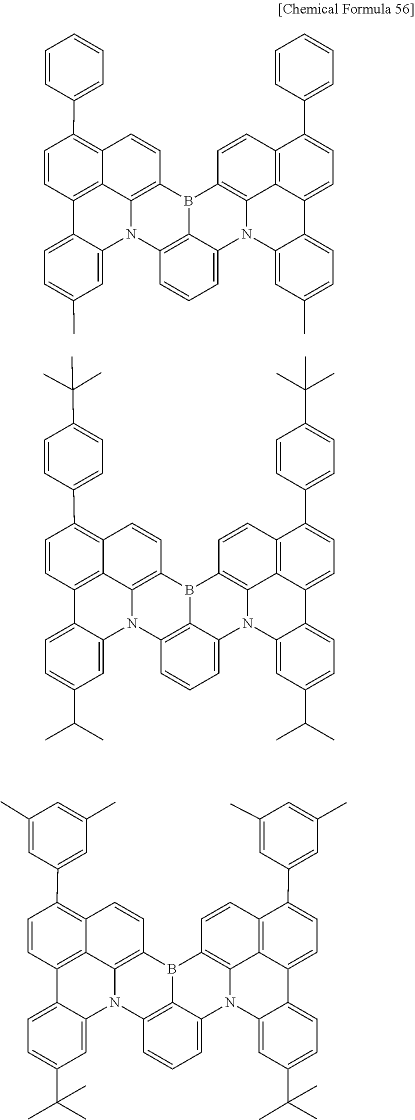

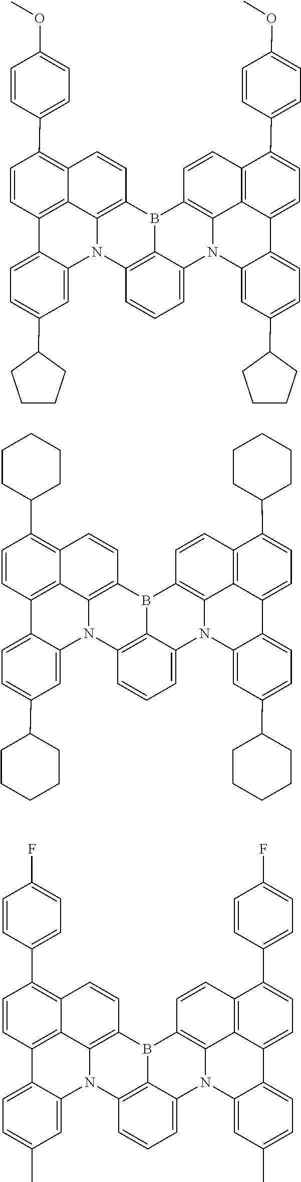

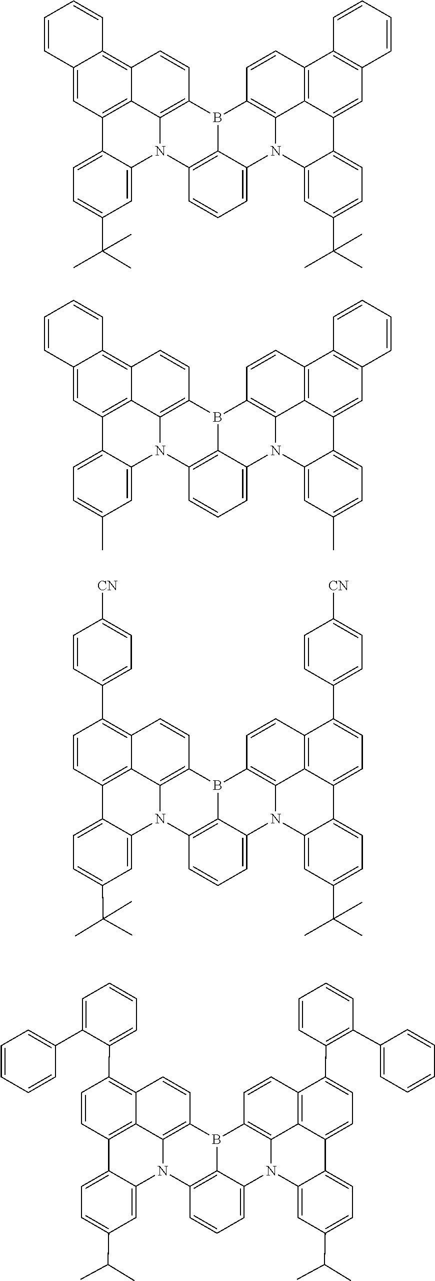

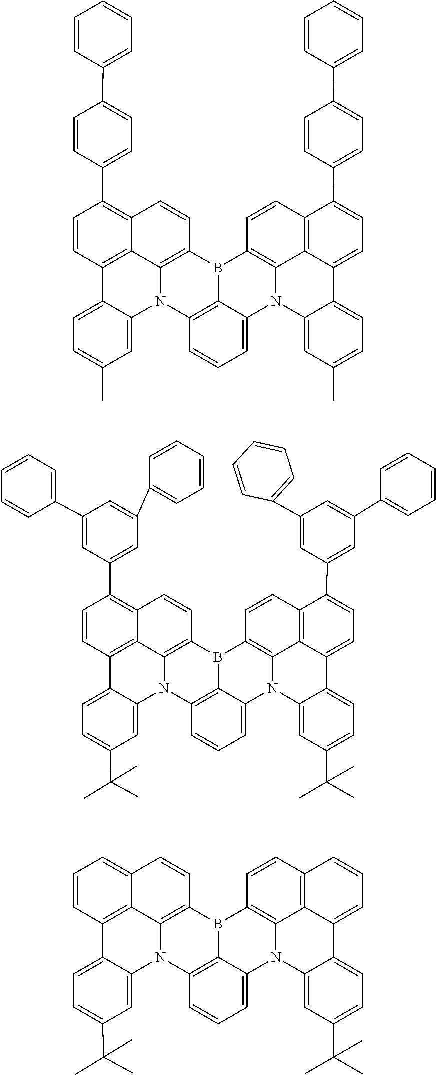

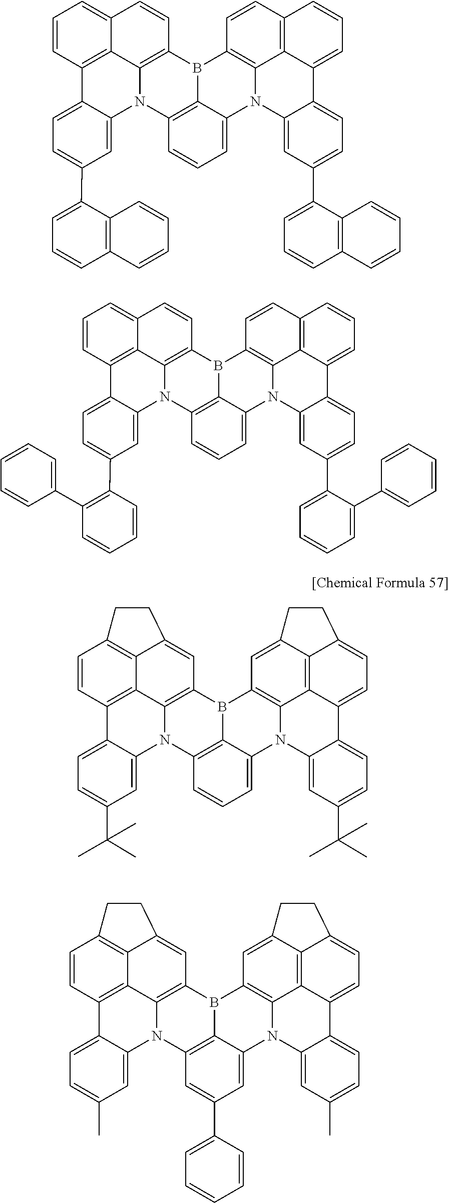

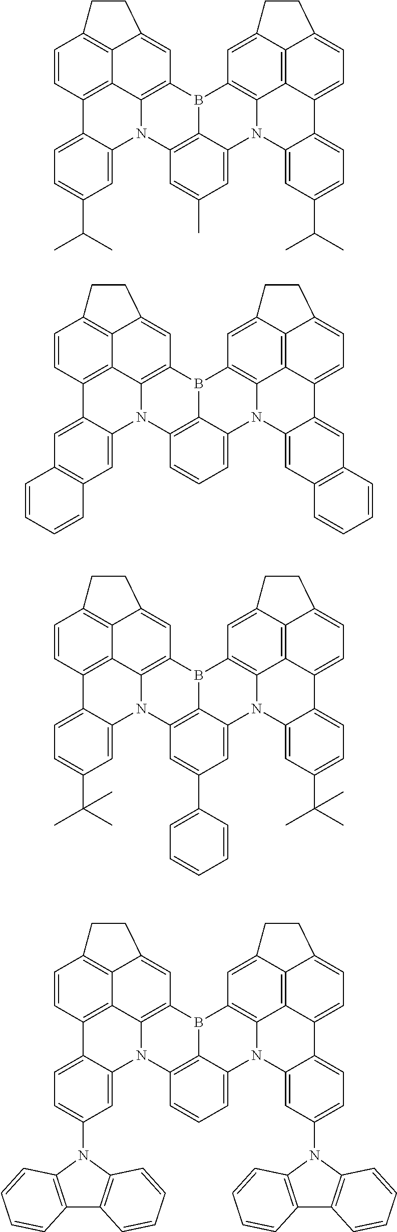

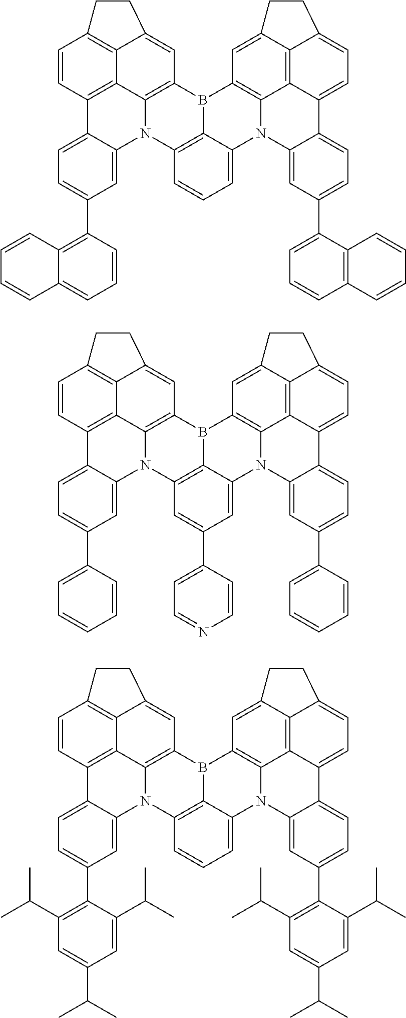

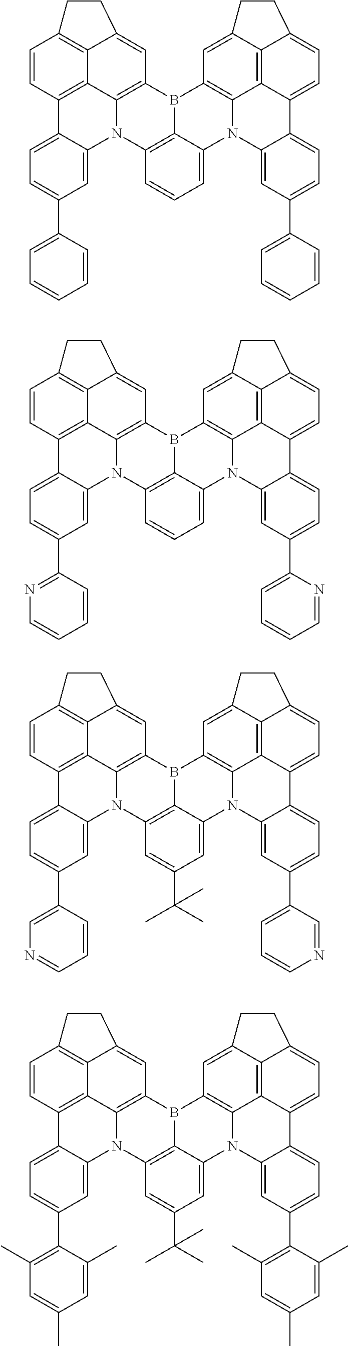

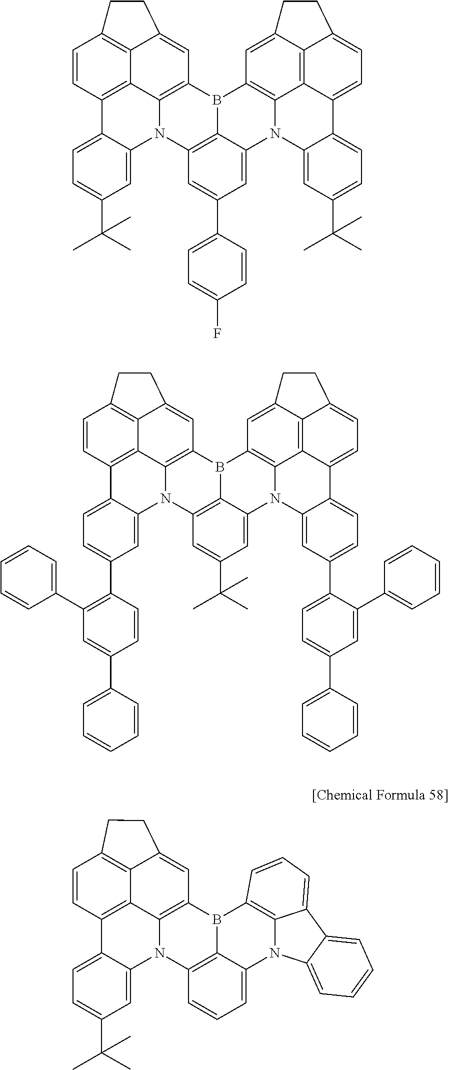

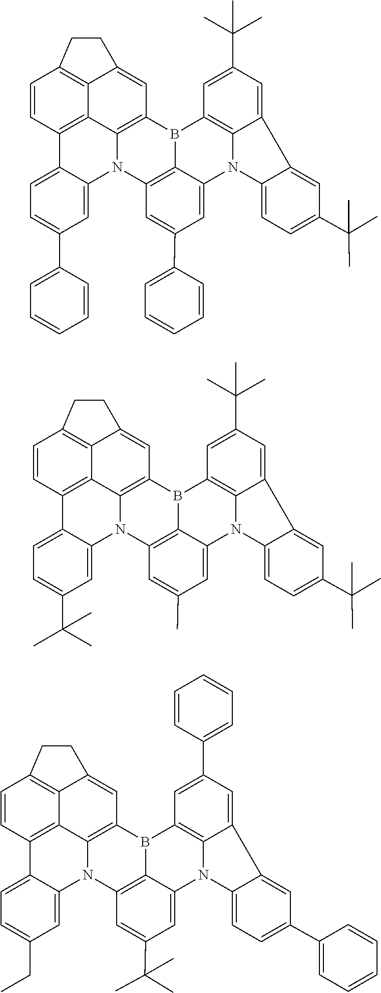

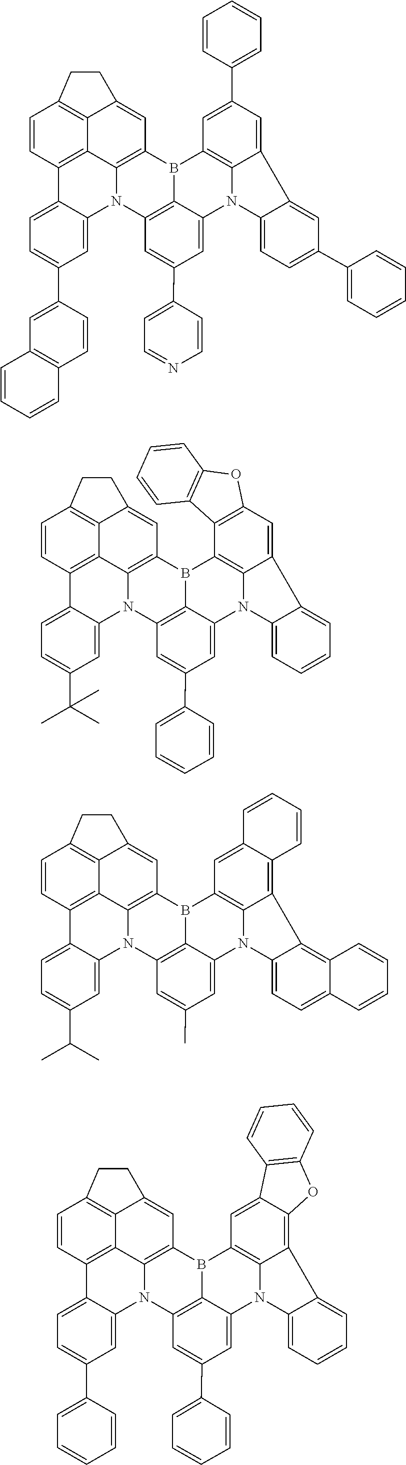

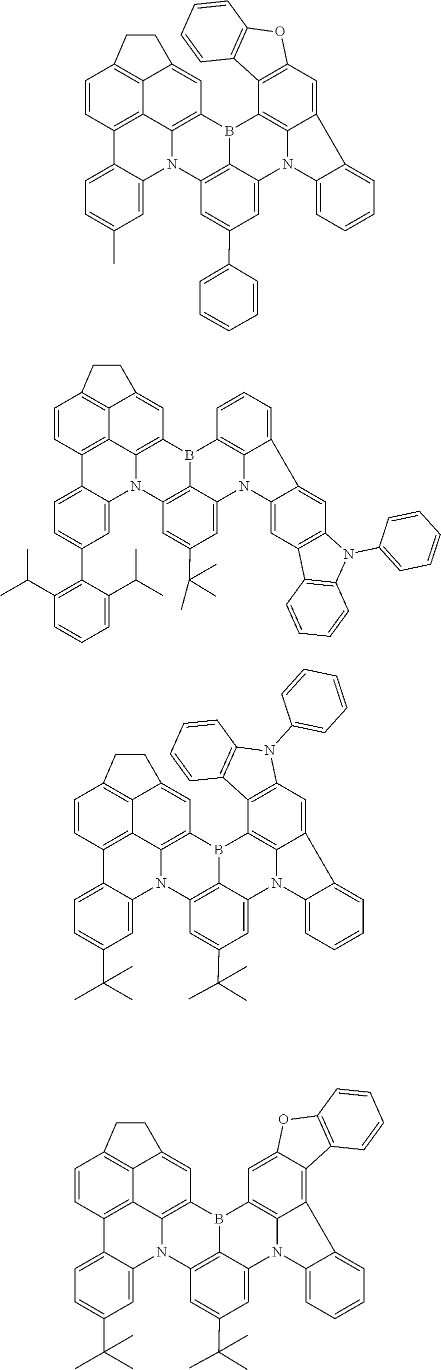

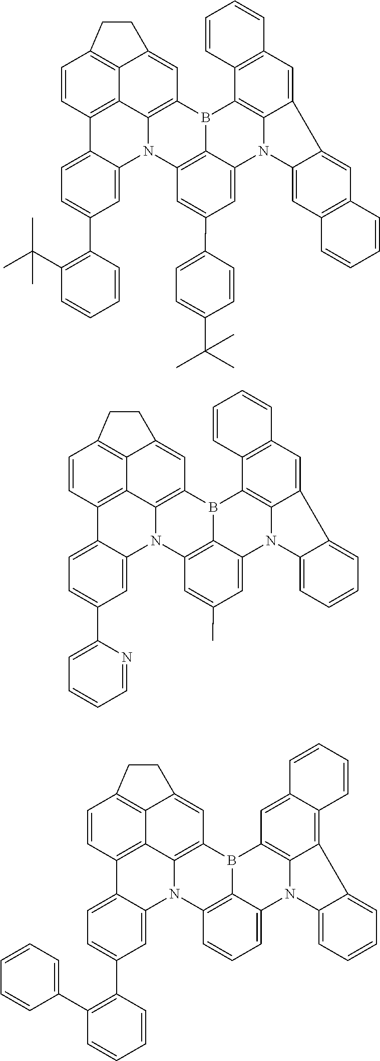

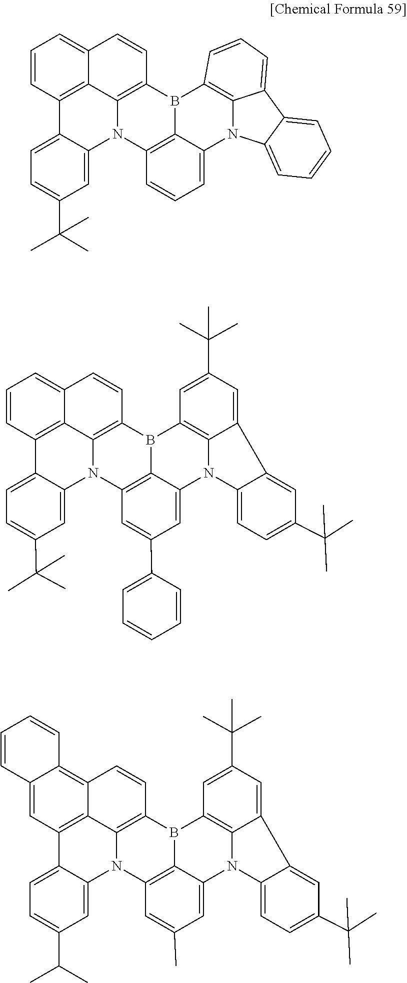

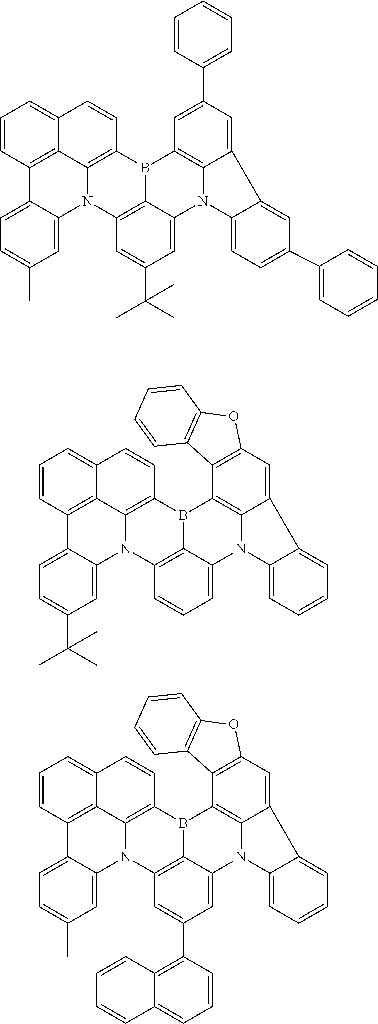

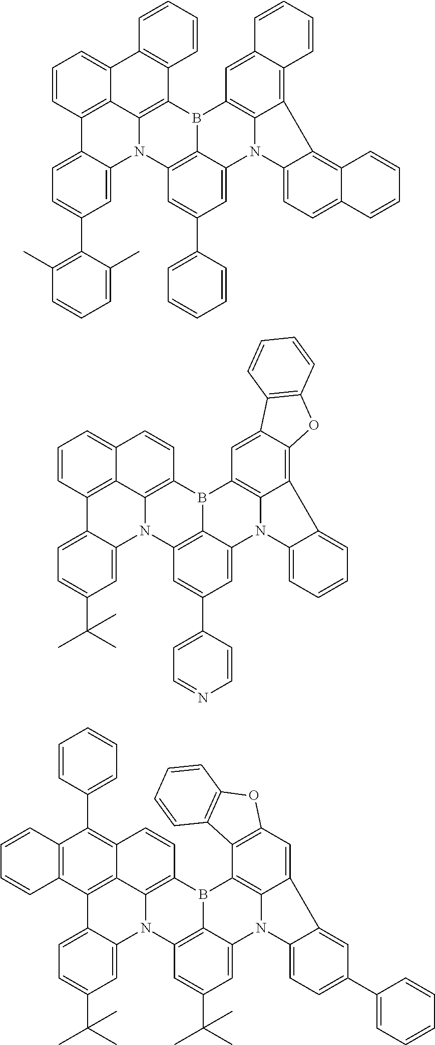

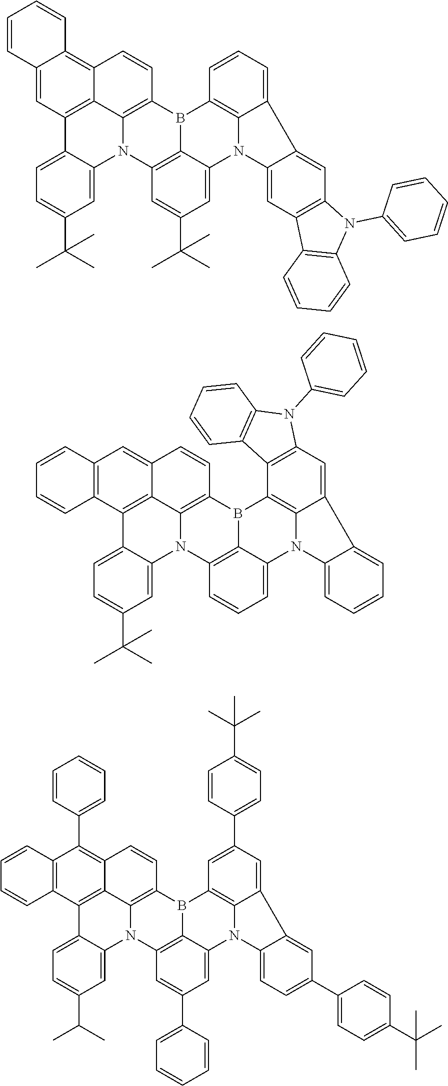

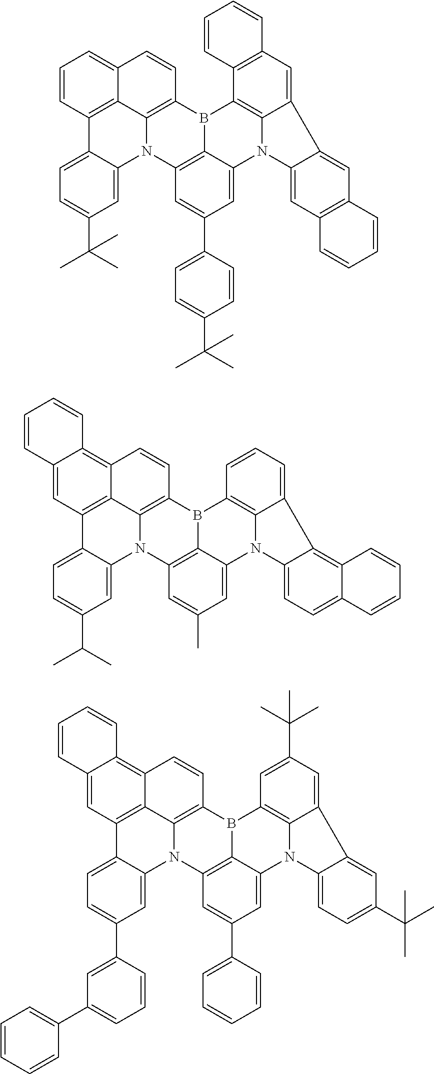

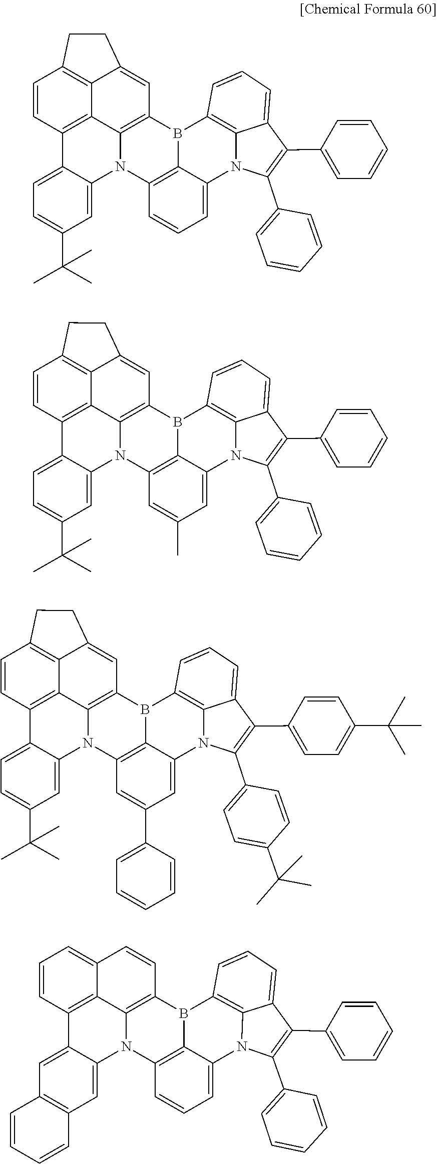

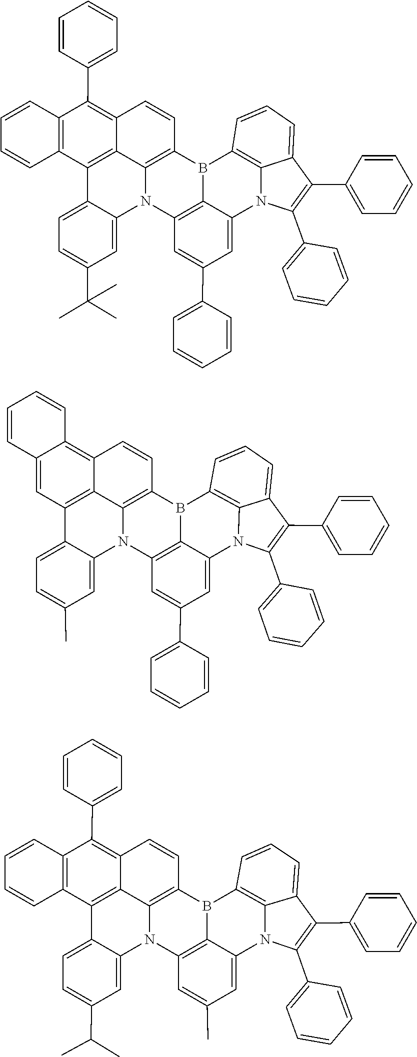

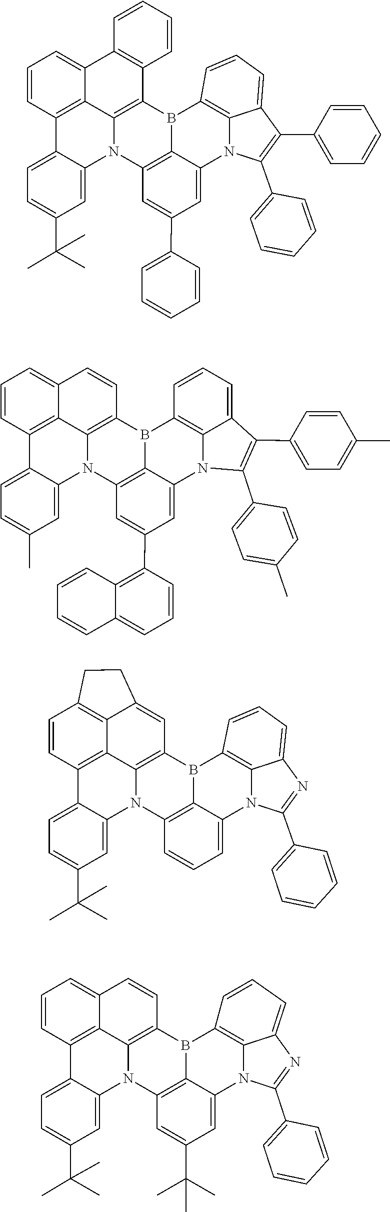

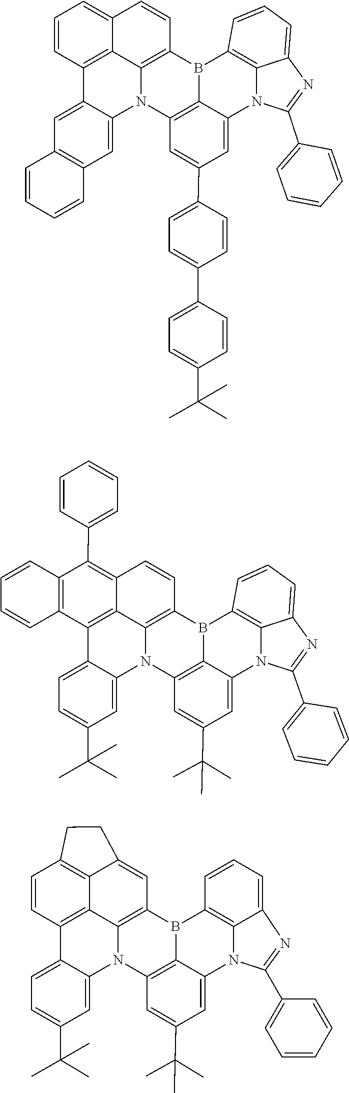

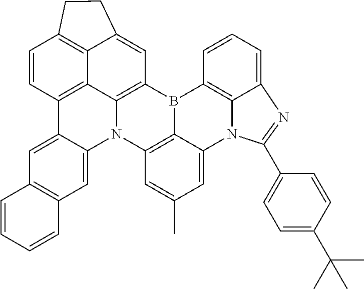

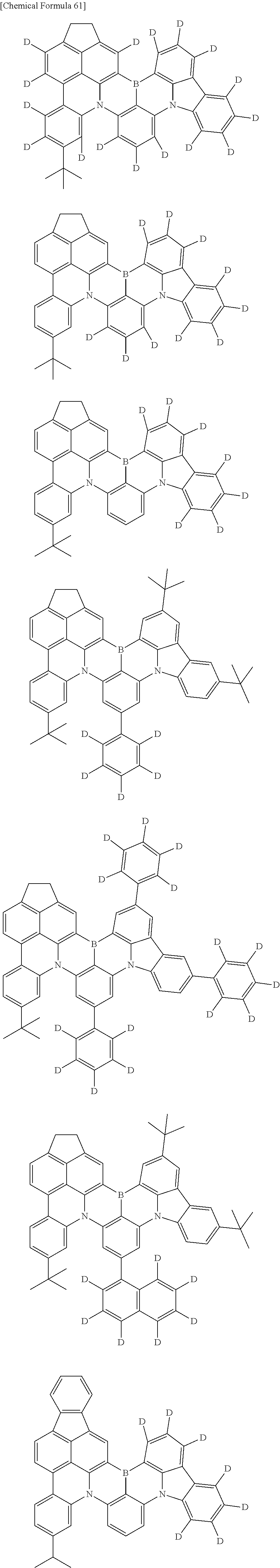

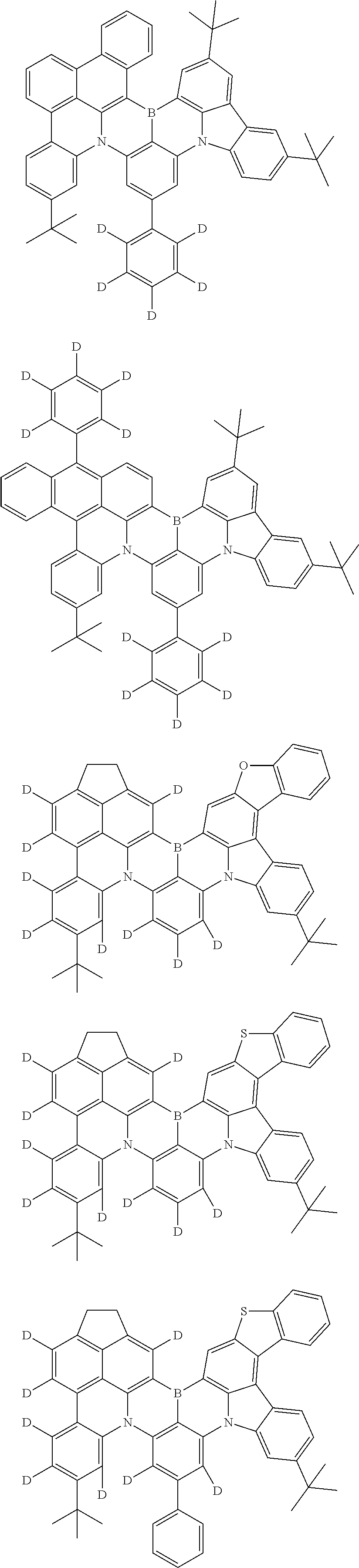

The compound having a structure represented by the general formula (1) or (2) can be produced, for example, by referring to the method mentioned in “Advanced. Materials”, 2016, vol. 28, p. 2777-2781.

It is preferable that the resulting compound having a structure represented by the general formula (1) or (2) is subjected to organic synthetic purification such as recrystallization or column chromatography, and then purified by heating under reduced pressure, which is generally called sublimation purification, to remove low boiling point components and improve the purity.

The purity of the compound having a structure represented by the general formula (1) or (2) is preferably 99% by weight or more, from the viewpoint of the stabilization of the light emitting element characteristics.

In the emission spectrum of the compound having a structure represented by the general formula (1) or (2), from the viewpoint of further improving the color purity of green emission, the emission peak wavelength is preferably 500 nm or more and 550 nm or less, and more preferably 510 nm or more and 540 nm or less. From the viewpoint of increasing the color purity, the half width of the emission peak in the emission spectrum is preferably 40 nm or less, more preferably 35 nm or less, and still more preferably 30 nm or less. Here, the emission wavelength and half width of the compound having a structure represented by the general formula (1) or (2) can be measured by a fluorescence spectrophotometer using a diluted solution having a concentration of 10⁻⁵ mol/L in toluene as a solvent.

### <Light Emitting Element Material>

The light emitting element material of the present invention contains a compound having a structure represented by the general formula (1) or (2). The light emitting element material in the present invention represents, a material used in any of the organic layers constituting the light emitting element. Here, examples of any of the organic layers of the light emitting element include a hole injection layer, a hole transporting layer, a light emitting layer, an electron transporting layer, and a protective film (capping layer) of electrodes, which will be mentioned later. Of these, the light emitting element material of the present invention has high light emitting element efficiency and color purity, and is therefore suitably used for the light emitting layer.

The light emitting element material of the present invention may contain, in addition to the compound having a structure represented by the general formula (1) or (2), other components. Examples of other components include those exemplified as materials constituting the hole injection layer, hole transporting layer, light emitting layer, electron transporting layer and/or protective film (capping layer) of electrodes, which are mentioned later.

### <Light Emitting Element>

The light emitting element according to the embodiments of the present invention includes a cathode, an anode, and one or more organic layers disposed therebetween, at least one of the organic layers containing a compound having a structure represented by the general formula (1) or (2) mentioned above. The organic layer containing the compound having a structure represented by the formula (1) or (2) may be any layer, but is preferably a light emitting layer.

The light emitting element according to the embodiments of the present invention may be either a bottom-emission type light emitting element or a top-emission type light emitting element. The bottom-emission type light emitting element refers to a light emitting element in which light emitted from the light emitting layer is extracted through a substrate which will be mentioned later. The top-emission type light emitting element is a light emitting element in which light emitted from the light emitting layer is extracted from the side opposite to the substrate. The top-emission type light emitting element can enhance the peak intensity of specific emission wavelength due to the resonance effect of the microcavity, thus making it possible to achieve improved color purity and high luminous efficiency. The narrower the half width of the light emitted from the light emitting layer, the greater the contribution of the resonance effect due to the microcavity to high luminous efficiency. Therefore, a light emitting element containing the compound of the present invention in the light emitting layer is suitable as a top-emission type light emitting element.

The layer structure of the organic layer disposed between the anode and the cathode in such light emitting element includes, in addition to the structure composed of a light emitting layer alone, laminated structures such as 1) light emitting layer/electron transporting layer, 2) hole transporting layer/light emitting layer, 3) hole transporting layer/light emitting layer/electron transporting layer, 4) hole injection layer/hole transporting layer/light emitting layer/electron transporting layer, 5) hole transporting layer/light emitting layer/electron transporting layer/electron injection layer, 6) hole injection layer/hole transporting layer/light emitting layer/electron transporting layer/electron injection layer, 7) hole injection layer/hole transporting layer/light emitting layer/hole blocking layer/electron transporting layer/electron injection layer, and 8) hole injection layer/hole transporting layer/electron blocking layer/light emitting layer/hole blocking layer/electron transporting layer/electron injection layer.

A plurality of the above laminated structures may be laminated via an intermediate layer to form a tandem-type light emitting element. Examples of the intermediate layer generally include an intermediate electrode, an intermediate conductive layer, a charge generation layer, an electron extraction layer, a connection layer, an intermediate insulating layer, and the like. It is possible to use, as the material of such layer, known material configurations. Preferred specific examples of the tandem-type layer structure include laminated structures such as 9) hole injection layer/hole transporting layer/light emitting layer/electron transporting layer/electron injection layer/charge generation layer/hole injection layer/hole transporting layer/light emitting layer/electron transporting layer/electron injection layer. In the above layer structure, the plurality of light emitting layers may be the same or different.

Each of the above layers may be either a single layer or a plurality of layers, and may be doped. It is also possible to have, in addition to the above layers, a protective layer (capping layer), which can further improve the efficiency of the light emitting element by optical interference effect.

Specific examples of the configuration of the light emitting element will be shown below, but the configuration of the present invention is not limited thereto.

### (Substrate)

In order to maintain the mechanical strength of the light emitting device, to minimize thermal deformation, and to create the configuration having a barrier property to prevent water vapor and oxygen from entering the light emitting layer, the light emitting device is preferably formed on a substrate. Examples of the substrate include, but are not particularly limited to, a glass plate, a ceramic plate, a resin film, a resin thin film, a metal thin plate, and the like. Of these, a glass substrate is preferably used from the viewpoints of being transparent and easy to process. In particular, in the case of a bottom-emission type light emitting element in which light is extracted through the substrate, a glass substrate having high transparency is preferable. Flexible displays and foldable displays are increasing mainly in mobile devices such as smartphones, and a resin film and a resin thin film obtained by curing varnish are preferably used as the substrate for this purpose. A heat-resistant film is used as the resin film, and specific examples thereof include a polyimide film, a polyethylene a naphthalate film, and the like.

Various wirings, circuits, and TFT switching elements for driving an organic EL may be provided on the surface of the substrate.

### (Anode)

The anode is preferably formed on the substrate. Various wirings, circuits and switching elements may be interposed between the substrate and the anode. The material used for the anode is not particularly limited as long as it can efficiently inject holes into the organic layer. A transparent or translucent electrode is preferable in the case of a bottom-emission type light emitting element. The anode is preferably a reflective electrode in the case of a top-emission type light emitting element.

Examples of the material of the transparent or translucent electrode include conductive metal oxides such as zinc oxide, tin oxide, indium oxide, indium tin oxide (ITO) and indium zinc oxide (IZO); metals such as gold, silver, aluminum and chromium; and conductive polymers such as polythiophene, polypyrrole and polyaniline. However, when using metal, it is preferable to reduce the thickness so that light can be semi-transmitted. Of these, indium tin oxide (ITO) is more preferable from the viewpoints of the transparency and stability.

The material of the reflective electrode is preferably a material with no absorption of all light and high reflectance, and examples thereof include metals such as aluminum, silver and platinum.

Two or more types of these electrode materials may be used, and a plurality of materials may be laminated.

The thickness of the anode is not particularly limited, but is preferably several nm to several hundred nm.

As the method for forming an anode, an optimum method can be selected depending on the forming material. Examples thereof include a sputtering method, a vapor deposition method, an inkjet method, and the like. For example, when the anode is formed of metal oxide, a sputtering method is preferably used, and when the anode is formed of metal, a vapor deposition method is preferably used.

### (Cathode)

The cathode is formed on the surface opposite to the anode with the organic layer interposed therebetween. It is particularly preferable that the cathode is formed on the surface of the electron transporting layer or the electron injection layer surface. The material used for the cathode is not particularly limited as long as it can efficiently inject electrons into the light emitting layer. The cathode is preferably a reflective electrode in the case of a bottom-emission type light emitting element. The cathode is preferably a translucent electrode in the case of a top-emission type light emitting element.

Generally, materials of the cathode are preferably metals such as platinum, gold, silver, copper, iron, tin, aluminum and indium; alloys and multilayered laminated films of these metals with metals of low-work function, such as lithium, sodium, potassium, calcium and magnesium; conductive metal oxides such as zinc oxide, indium tin oxide (ITO) and indium zinc oxide (IZO), and the like. Of these, metal selected from aluminum, silver and magnesium is preferable as a main component from the viewpoints of the electrical resistance, ease of film formation, film stability, light emitting element efficiency, and the like. The cathode is preferably made of magnesium and silver since electron injection into the electron transporting layer and the electron injection layer becomes easy, thus making it possible to reduce the driving voltage. The thickness of the cathode is not particularly limited, but is preferably 5 nm to 100 nm.

### (Capping Layer)

In order to protect the cathode, it is preferable to laminate a protective layer (capping layer) on the cathode. Examples of the material constituting the capping layer include, but are not particularly limited to, metals such as platinum, gold, silver, copper, iron, tin, aluminum and indium; alloys using these metals; inorganic substances such as silica, titania and silicon nitride; and organic polymer compounds such as polyvinyl alcohol, polyvinyl chloride and hydrocarbon-based polymer compounds. However, in the case of a top-emission type light emitting element, the material used for the protective layer is preferably selected from materials which are optically transparent in the visible light region.

### (Hole Injection Layer)

The hole injection layer is a layer which is inserted between the anode and the hole transport layer to facilitate hole injection. The hole injection layer may be either a single layer or a plurality of laminated layers. The hole injection layer is preferably present between the hole transporting layer and the anode since driving at a lower voltage is possible and the durability is improved and, furthermore, the carrier balance of the element is also improved, leading to an improvement in light emitting element efficiency.

A preferable example of the hole injection material includes electron donating hole injection materials (donor materials). These are materials capable of reducing the energy barrier with the anode since the HOMO level is shallower than that of the hole transporting layer and is close to the work function of the anode. Specific examples thereof include group of aromatic amine-based materials, for example, benzidine derivatives, and starburst arylamines such as 4,4′,4″-tris(3-methylphenyl(phenyl)amino)triphenylamine (m-MTDATA) and 4,4′,4″-tris(1-naphthyl(phenyl)amino)triphenylamine (1-TNATA); heterocyclic compounds such as carbazole derivatives, pyrazoline derivatives, stilbene-based compounds, hydrazone-based compounds, benzofuran derivatives, thiophene derivatives, oxadiazole derivatives, phthalocyanine derivatives and porphyrin derivatives; and polymers such as polycarbonate and styrene derivative having the above monomers in the side chain, polythiophenes such as PEDOT/PSS, polyanilines, polyfluorenes, polyvinylcarbazoles and polysilanes. Two or more types thereof may be used. A plurality of materials may be laminated to form the hole injection layer.

Another preferable example of the hole injection material includes electron accepting hole injection materials (acceptor materials). Here, the hole injection layer may be composed of the acceptor material alone, or may be used by doping the donor material with the acceptor material. The acceptor material is a material which forms a charge-transfer complex with an adjacent hole transporting layer when used alone, or forms a charge-transfer complex with a donor material when used as a dopant in the donor material. It is more preferable to use such material since it contributes to an improvement in conductivity of the hole injection layer and reduction in the driving voltage of the element, thus obtaining effects such as an improvement in light emitting material efficiency and an improvement in durability. Examples of the acceptor material include metal oxides such as molybdenum oxide, vanadium oxide, tungsten oxide and ruthenium oxide; charge-transfer complexes such as tris(4-bromophenyl)aminium hexachloroantimonate (TBPAH); n-type organic semiconductor compounds such as 1,4,5,8,9,11-hexaazatriphenylene-hexacarbonitrile (HAT-CN6), 2,3,5,6-tetrafluoro-7,7,8,8-tetracyanoquinodimethane (F4-TCNQ) and fluorinated copper phthalocyanine; and fullerenes. When the hole injection layer contains an accepter compound, the hole injection layer may be a single layer, and a plurality of layers may be laminated and configured.

### (Hole Transporting Layer)

The hole transporting layer is a layer which transports holes injected from the anode to the light emitting layer. The hole transporting layer may be a single layer, or a plurality of layers may be laminated to form the structure.

The hole transport layer is formed of the hole transporting material alone, or by laminating or mixing two or more types of hole transport materials. The hole transport material is preferably a material which has high hole injection efficiency and efficiently transports the injected holes. For this purpose, the hole transporting material is required to be a substance which has appropriate ionization potential, high hole mobility and excellent stability, and is less likely to generate impurities which become traps.

Examples of the substance satisfying these conditions include, but not particularly limited to, benzidine derivatives; group of aromatic amine-based materials called starburst arylamine; heterocyclic compounds such as carbazole derivatives, pyrazoline derivatives, stilbene-based compounds, hydrazone-based compounds, benzofuran derivatives, dibenzofuran derivatives, thiophene derivatives, benzothiophene derivatives, dibenzothiophene derivatives, fluorene derivatives, spirofluorene derivatives, oxadiazole derivatives, phthalocyanine derivatives and porphyrin derivatives; polymers such as polycarbonate and styrene derivative having the above monomers in the side chain, polythiophenes, polyanilines, polyfluorenes, polyvinylcarbazoles, polysilanes and the like.

### (Light Emitting Layer)

The light emitting layer is a layer which emits light by excitation energy generated by the recombination of holes and electrons. The light emitting layer may be composed of a single material, but preferably contains a dopant material emitting light with a narrow half width and a matrix material, from the viewpoint of the color purity.

It is preferable to use the compound having a structure represented by the general formula (1) or (2) as the dopant material of the light emitting layer since it has particularly excellent fluorescence quantum yield and an emission wavelength peak suitable for green emission, narrow half width and excellent color purity. That is, in one embodiment of the light emitting element according to the embodiments of the present invention, the light emitting layer preferably contains a compound having a structure represented by the general formula (1) or (2) and a matrix material.

The content of the dopant material in the light emitting layer is preferably 5% by weight or less, and more preferably 2% by weight or less, from the viewpoint of further suppressing the concentration quenching. Meanwhile, from the viewpoint of more efficient energy transfer, the content of the dopant material in the light emitting layer is preferably 0.1% by weight or more, and more preferably 0.5% by weight or more.

The matrix material is preferably an organic compound having high charge transporting ability and high glass transition temperature. Examples of the matrix material include, but are not particularly limited to, compounds having a fused aryl ring, such as naphthacene, pyrene, anthracene and fluoranthene, and derivatives thereof; aromatic amine derivatives such as N,N′-dinaphthyl-N,N′-diphenyl-4,4′-diphenyl-1,1′-diamine; metal chelated oxynoid compounds such as tris(8-quinolinate)aluminum(III); and bistyryl derivatives such as distyrylbenzene derivatives, tetraphenylbutadiene derivatives, indene derivatives, coumarin derivatives, oxadiazole derivatives, pyrrolopyridine derivatives, perinone derivative, pyrrolopyrrole derivatives, thiadiazolopyridine derivatives, dibenzofuran derivative, carbazole derivatives, indolocarbazole derivatives, triazine derivatives, and polymers such as polyphenylene vinylene derivatives, polyparaphenylene derivatives, polyfluorene derivatives, polyvinylcarbazole derivatives and polythiophene derivatives. Two or more types of these materials may be used, or two or more types of matrix materials may be laminated. Of these, compounds selected from carbazole derivatives, anthracene derivatives and naphthacene derivatives are preferable.

As the dopant material, a fluorescence emitting material other than the compound having a structure represented by the general formula (1) or (2) may be contained. Specific examples thereof include compounds having a fused aryl ring, such as naphthacene, pyrene, anthracene and fluoranthene, and derivatives thereof; compounds having a heteroaryl ring and derivatives thereof; distyrylbenzene derivatives, aminostyryl derivatives, tetraphenylbutadiene derivatives, stylben derivatives, aldazine derivatives, pyrromethene derivatives, diketopyrrolo[3,4-c]pyrrole derivatives, coumarin derivatives, azole derivatives, and metal complexes thereof, aromatic amine derivatives, and the like. Two or more types thereof may be used.

The phosphorescent light emitting material may be contained as the dopant material. The phosphorescent light emitting material is preferably a metal complex compound containing at least one metal selected from the group consisting of iridium (Ir), ruthenium (Ru), palladium (Pd), platinum (Pt), osmium (Os) and rhenium (Re), and more preferably an iridium complex or a platinum complex from the viewpoint of high efficiency emission. The ligand preferably has, but is not limited to, a nitrogen-containing aromatic heteroaryl group such as a phenylpyridine skeleton, a phenylquinoline skeleton or a carbene skeleton.

However, from the viewpoint of further improving the color purity, it is preferable that the dopant material is only a compound having a structure represented by the general formula (1) or (2).

In one embodiment of the light emitting element according to the embodiments of the present invention, the light emitting layer preferably contains, in addition to the compound having a structure represented by the general formula (1) or (2), a compound which exhibits delayed fluorescence. Examples of the compound which exhibits delayed fluorescence include a material which utilizes triplet-triplet annihilation (TTA) and a thermally activated delayed fluorescent material. Of these, the thermally activated delayed fluorescent material is a material in which the energy gap between the singlet excited state and the triplet excited state is small and transition occurs from the triplet excited state to the singlet excited state, and triplet excitons can be used as delayed fluorescence. When this delayed fluorescence is utilized in an organic light emitting element, the light emitting element efficiency can be further improved. When Förster energy transfer occurs from the singlet excited state of the compound which exhibits delayed fluorescence to the singlet excited state of a dopant material, fluorescence emission from the singlet excited state of the dopant material is observed. Here, when the dopant material is a fluorescent material having a sharp emission wavelength, a light emitting element having superior light emitting efficiency and color purity can be obtained. In this way, when the light emitting layer contains a compound which exhibits delayed fluorescence, the efficiency of the light emitting element is further improved, which contributes to lower power consumption of the display. The compound which exhibits delayed fluorescence is preferably a thermally activated delayed fluorescence material, and the thermally activated delayed fluorescence material may be a single material or a plurality of materials such as in the case of forming an exciplex complex.

The compound which exhibits delayed fluorescence may be a single material or a plurality of materials, and known materials can be used. Specific examples thereof include benzonitrile derivatives, triazine derivatives, disulfoxide derivatives, carbazole derivatives, indolocarbazole derivatives, dihydrophenazine derivatives, thiazole derivatives, oxadiazole derivatives and the like. Examples of the compound exhibiting such delayed fluorescence include, but are not particularly limited to, the following.

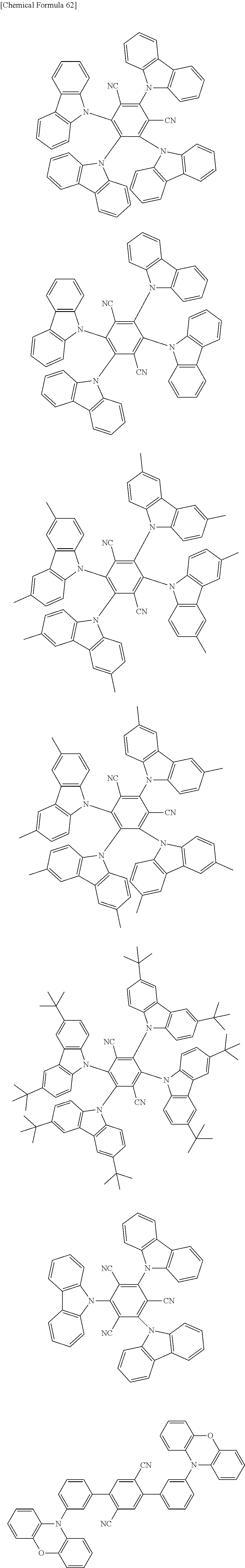

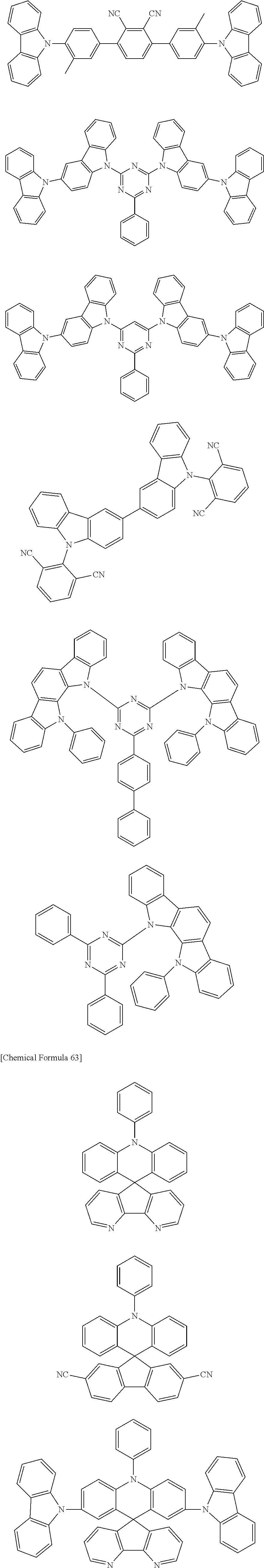

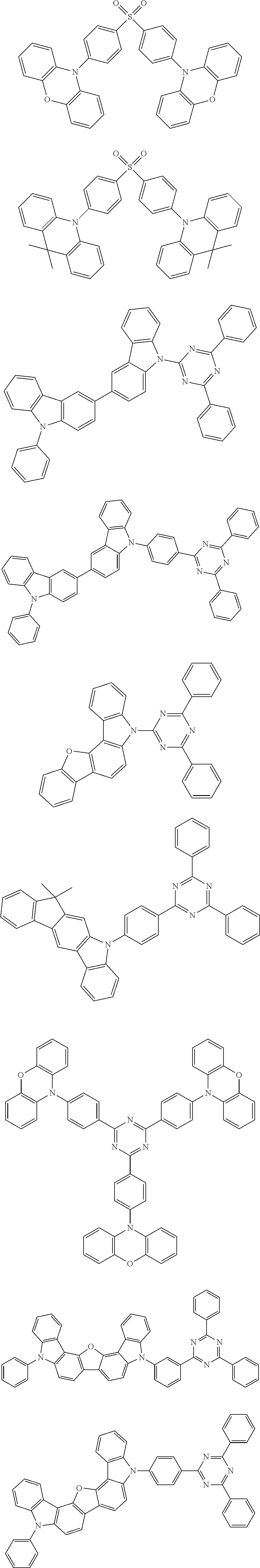

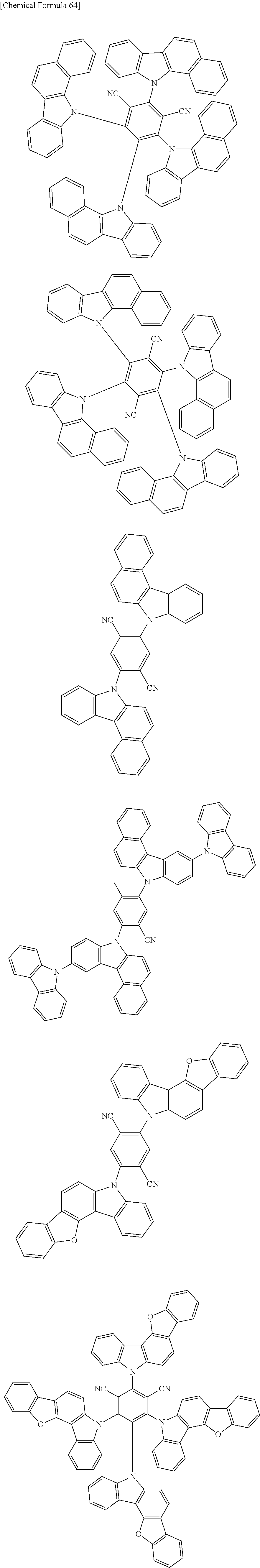

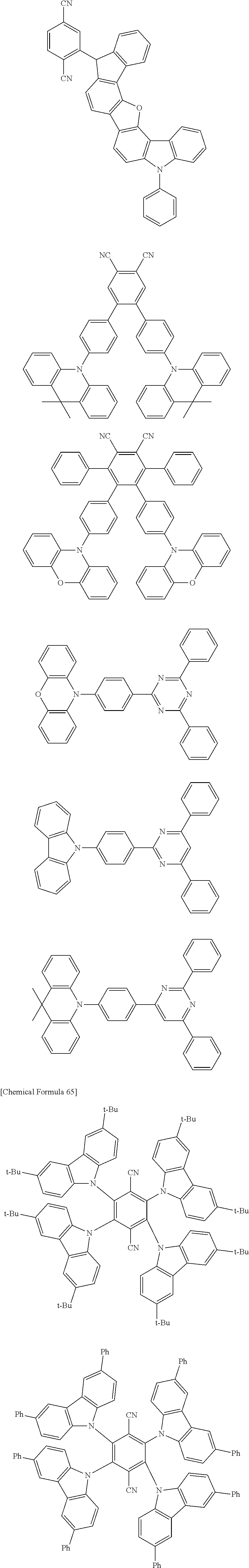

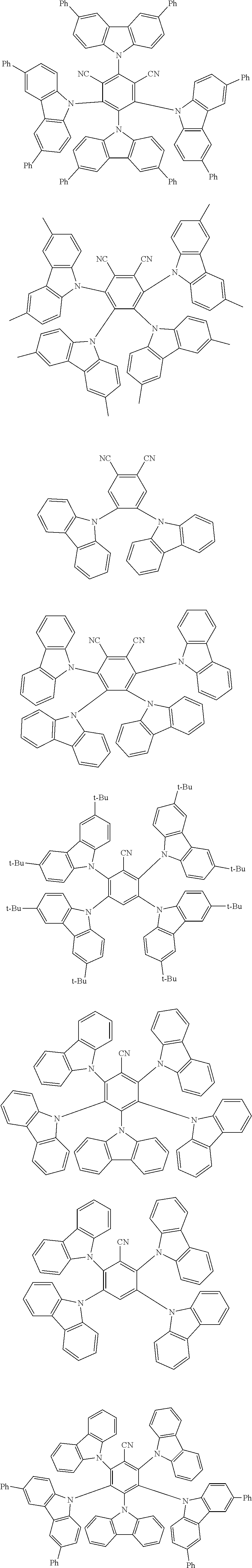

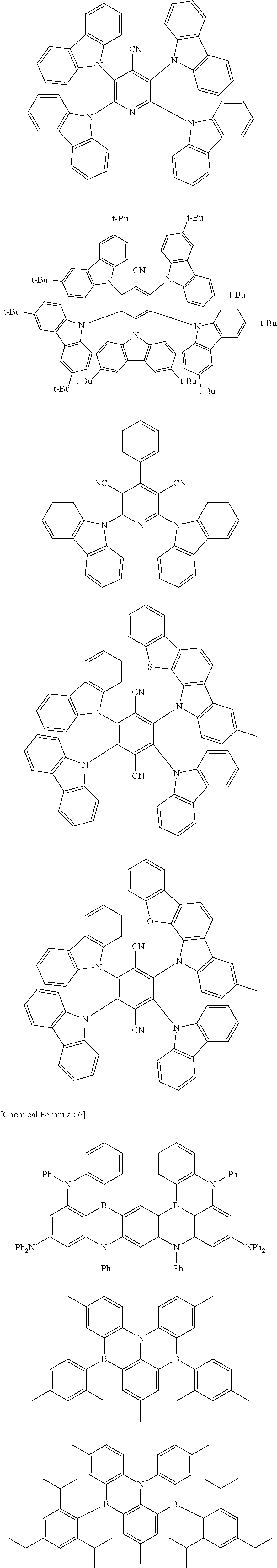

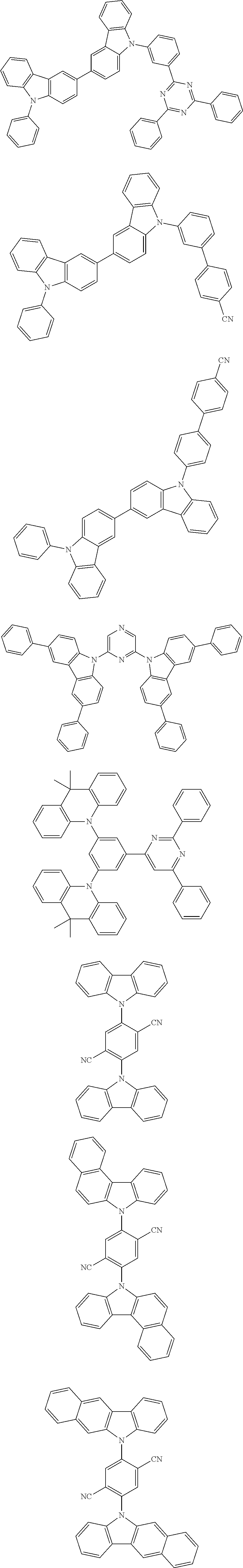

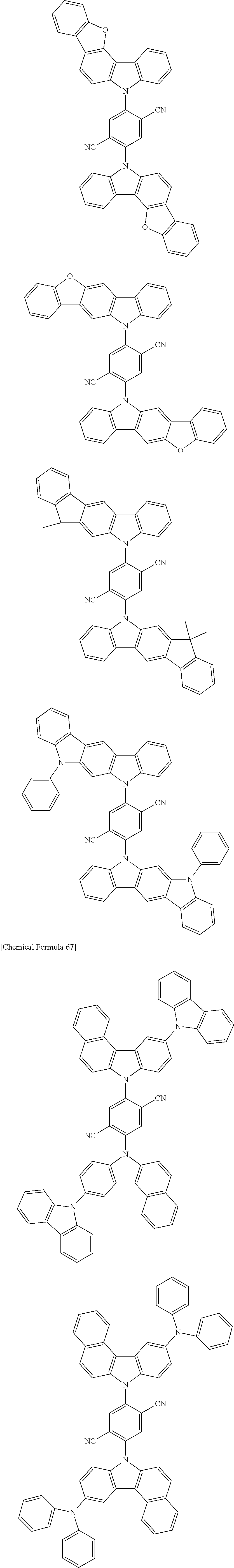

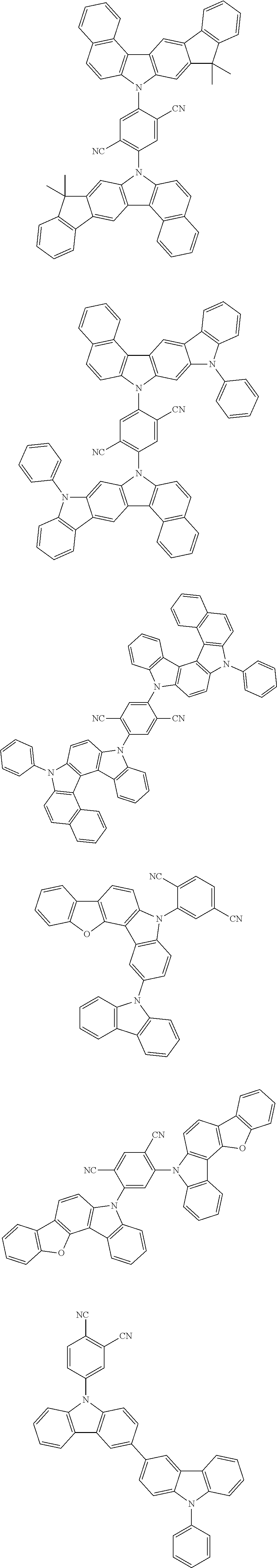

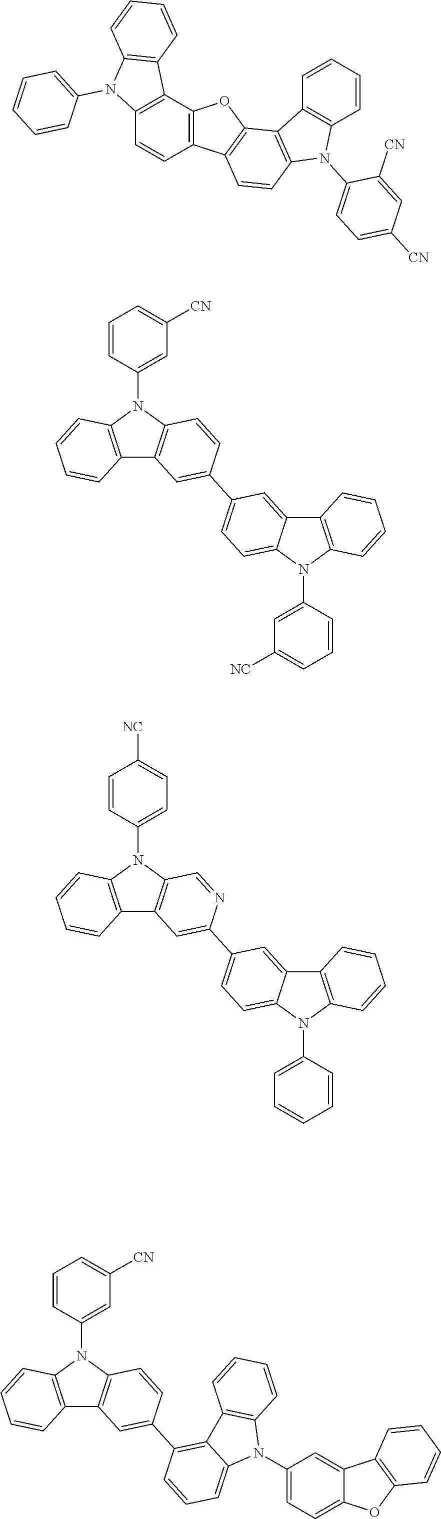 [SMILES: N#Cc1ccc(-n2c3ccccc3c3c4oc5c(ccc6c5c5ccccc5n6-c5ccccc5)c4ccc32)c(C#N)c1 ; N#Cc1cccc(-n2c3ccccc3c3cc(-c4ccc5c(c4)c4ccccc4n5-c4cccc(C#N)c4)ccc32)c1 ; N#Cc1ccc(-n2c3ccccc3c3cc(-c4ccc5c(c4)c4ccccc4n5-c4ccccc4)ncc32)cc1 ; N#Cc1cccc(-n2c3ccccc3c3cc(-c4cccc5c4c4ccccc4n5-c4ccc5oc6ccccc6c5c4)ccc32)c1]

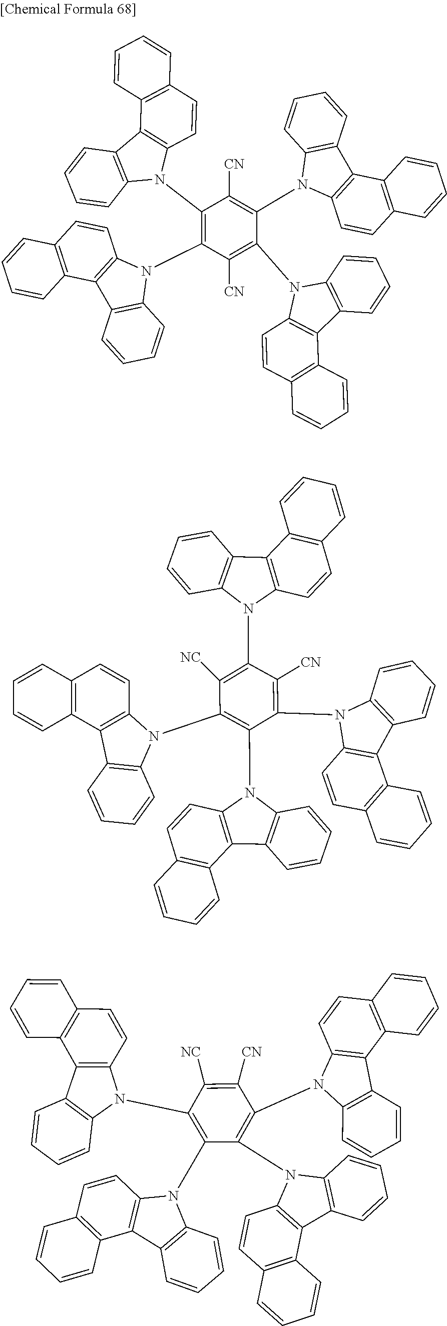 [SMILES: N#Cc1c(-n2c3ccccc3c3c4ccccc4ccc32)c(-n2c3ccccc3c3c4ccccc4ccc32)c(C#N)c(-n2c3ccccc3c3c4ccccc4ccc32)c1-n1c2ccccc2c2c3ccccc3ccc21 ; N#Cc1c(-n2c3ccccc3c3c4ccccc4ccc32)c(C#N)c(-n2c3ccccc3c3c4ccccc4ccc32)c(-n2c3ccccc3c3c4ccccc4ccc32)c1-n1c2ccccc2c2c3ccccc3ccc21 ; N#Cc1c(C#N)c(-n2c3ccccc3c3c4ccccc4ccc32)c(-n2c3ccccc3c3c4ccccc4ccc32)c(-n2c3ccccc3c3c4ccccc4ccc32)c1-n1c2ccccc2c2c3ccccc3ccc21]

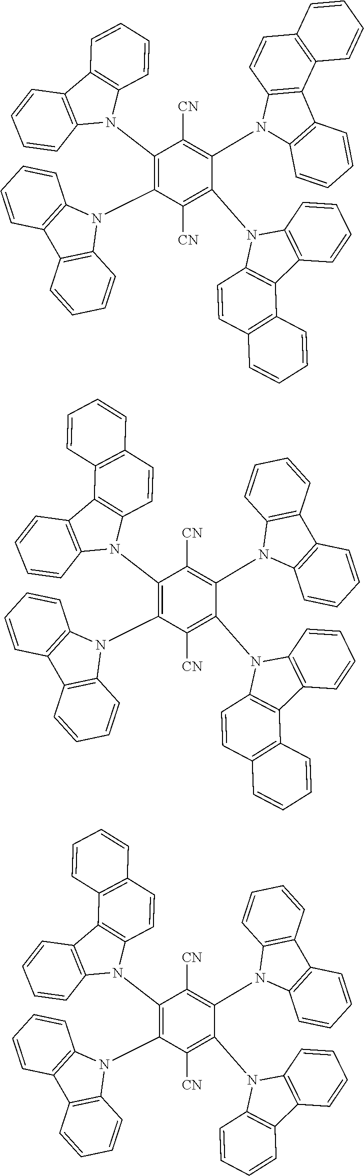 [SMILES: N#Cc1c(-n2c3ccccc3c3ccccc32)c(-n2c3ccccc3c3ccccc32)c(C#N)c(-n2c3ccccc3c3c4ccccc4ccc32)c1-n1c2ccccc2c2c3ccccc3ccc21 ; N#Cc1c(-n2c3ccccc3c3ccccc32)c(-n2c3ccccc3c3c4ccccc4ccc32)c(C#N)c(-n2c3ccccc3c3ccccc32)c1-n1c2ccccc2c2c3ccccc3ccc21 ; N#Cc1c(-n2c3ccccc3c3ccccc32)c(-n2c3ccccc3c3ccccc32)c(C#N)c(-n2c3ccccc3c3c4ccccc4ccc32)c1-n1c2ccccc2c2ccccc21]

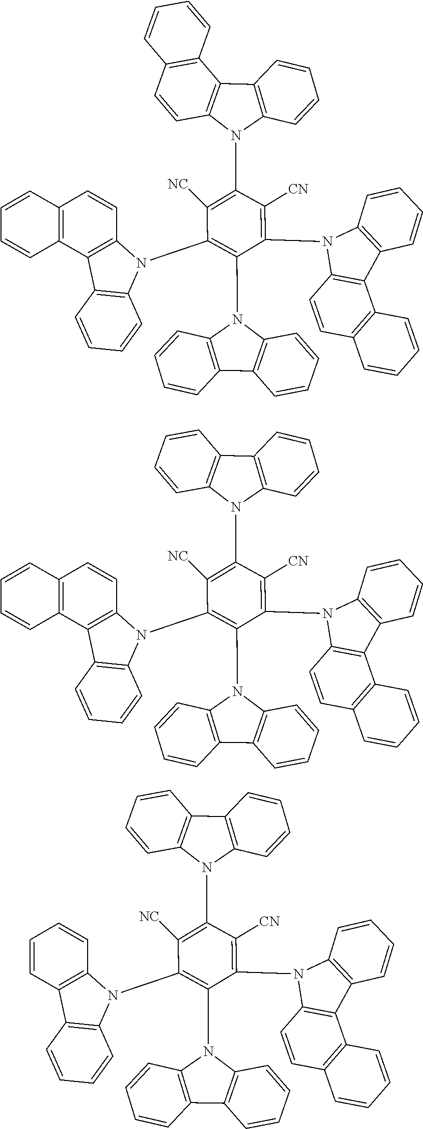

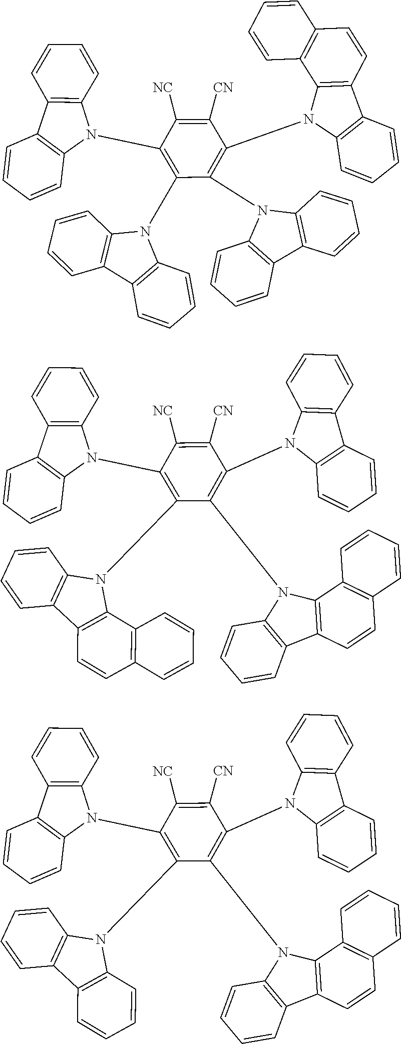 [SMILES: N#Cc1c(C#N)c(-n2c3ccccc3c3ccc4ccccc4c32)c(-n2c3ccccc3c3ccccc32)c(-n2c3ccccc3c3ccccc32)c1-n1c2ccccc2c2ccccc21 ; N#Cc1c(C#N)c(-n2c3ccccc3c3ccccc32)c(-n2c3ccccc3c3ccc4ccccc4c32)c(-n2c3ccccc3c3ccc4ccccc4c32)c1-n1c2ccccc2c2ccccc21 ; N#Cc1c(C#N)c(-n2c3ccccc3c3ccccc32)c(-n2c3ccccc3c3ccc4ccccc4c32)c(-n2c3ccccc3c3ccccc32)c1-n1c2ccccc2c2ccccc21]

In one embodiment of the light emitting element according to the embodiments of the present invention, it is more preferable that the light emitting layer contains a compound having a structure represented by the general formula (1) or (2) as a dopant material, and further contains a matrix material and a compound which exhibits delayed fluorescence. In this case, when the excited singlet energy of the matrix material is S₁ (1), the excited singlet energy of a compound which exhibits delayed fluorescence is S₁ (2), and the excited singlet energy of a compound having one or more structures represented by the general formula (1) or (2) is S₁ (3), it is preferable that the relationship of formula 1 is satisfied.

$${S}_{1} ( 1 ) > {S}_{1} ( 2 ) > {S}_{1} ( 3 ) \qquad ( Formula 1 )$$

This enables the matrix material to have the function of trapping the energy of a compound which exhibits delayed fluorescence and the dopant material within the light emitting layer. This allows the light emitting element to emit light efficiently, and the light emitting element efficiency can be further improved. Examples of the matrix material which satisfies the relationship of formula 1 between the compound having a structure represented by the general formula (1) or (2) or the above-mentioned a compound which exhibits delayed fluorescence include, but are not particularly limited to, the following examples.

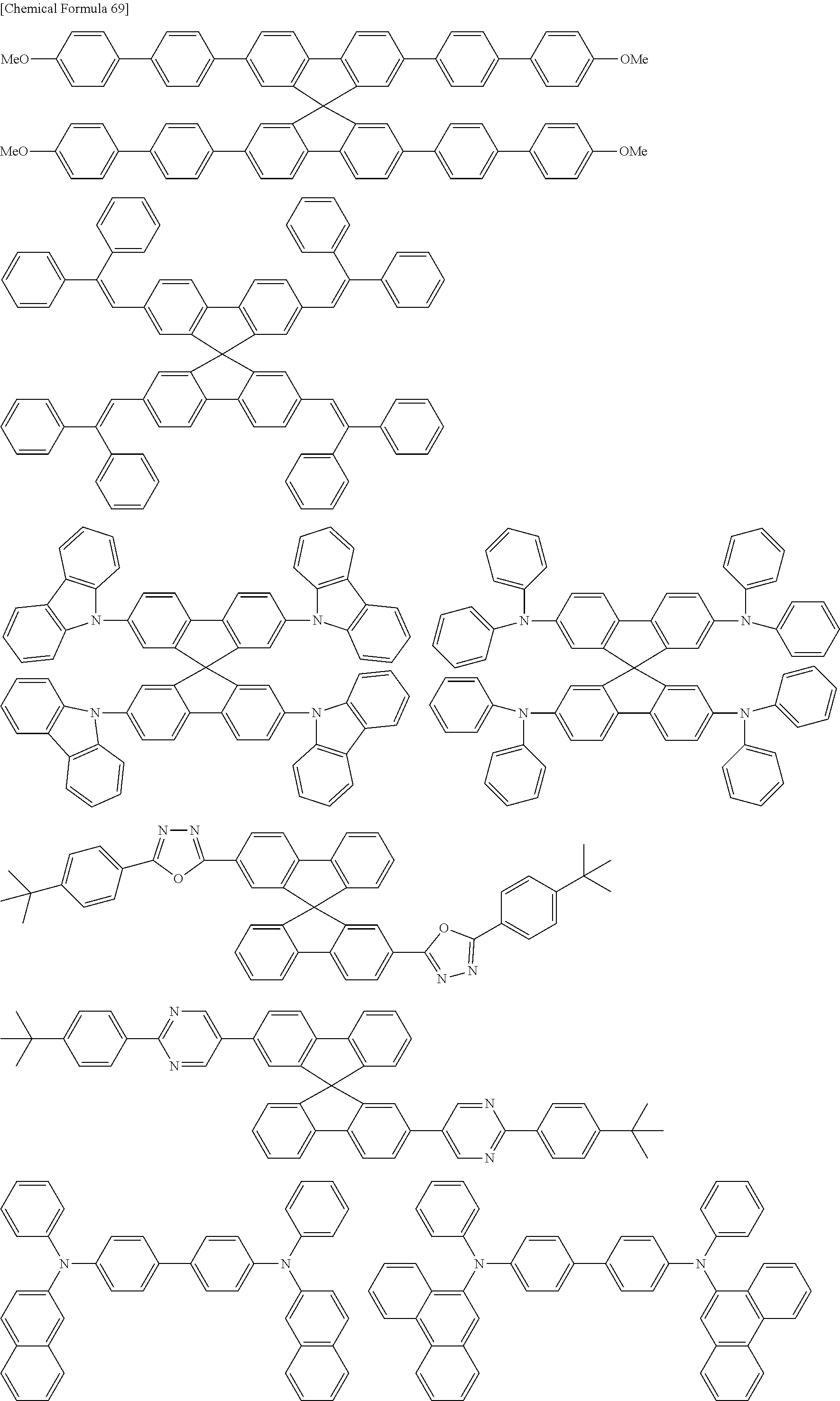

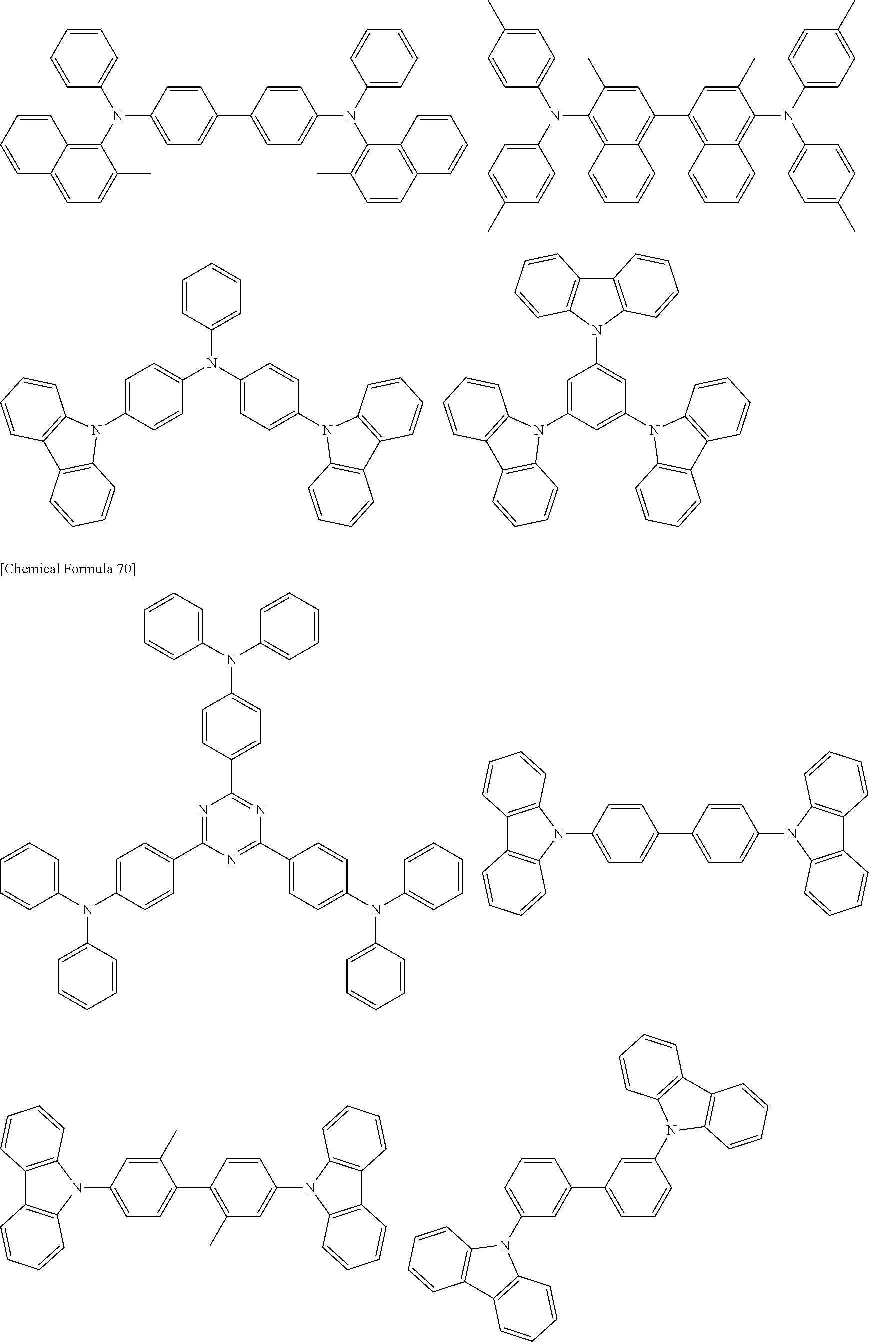

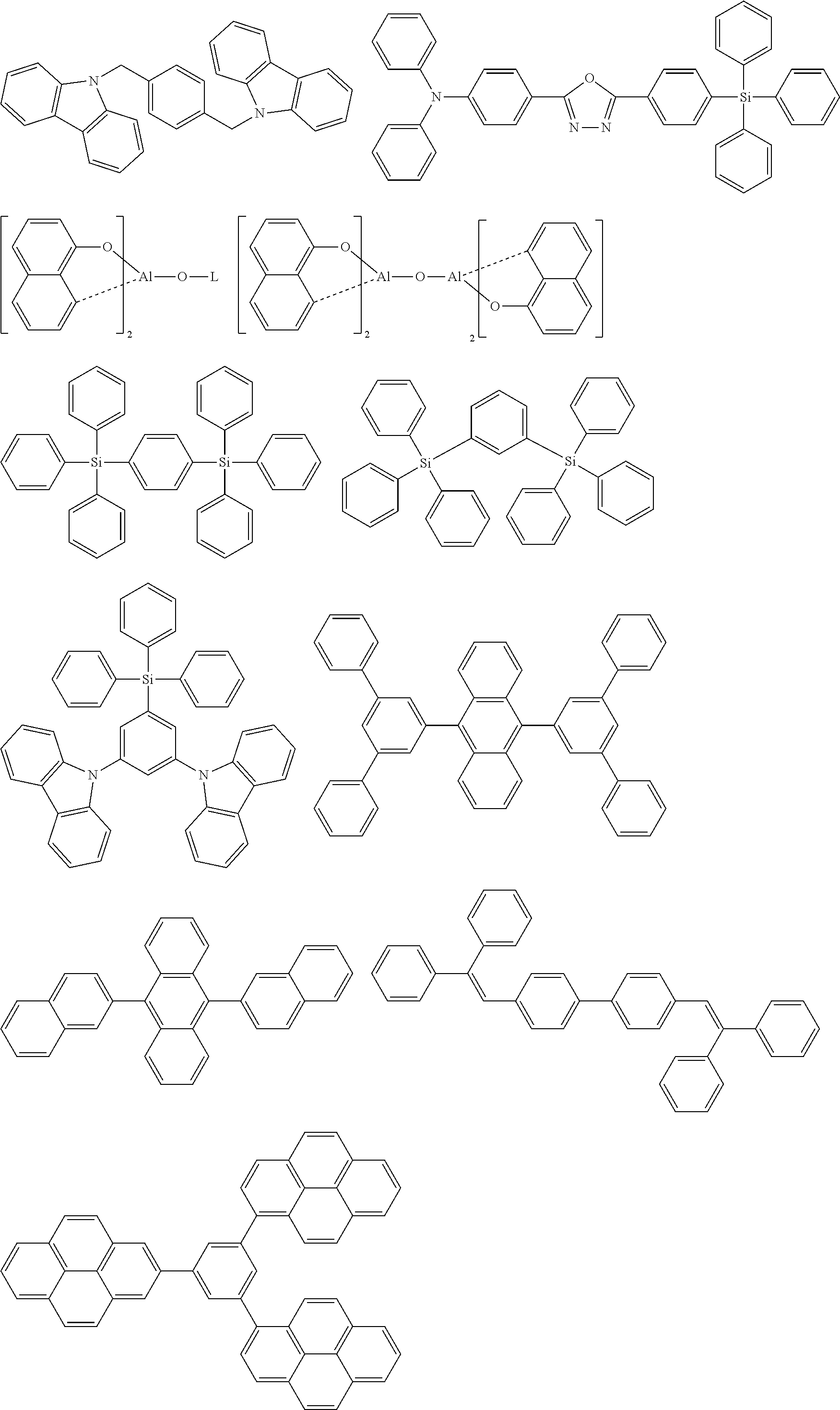

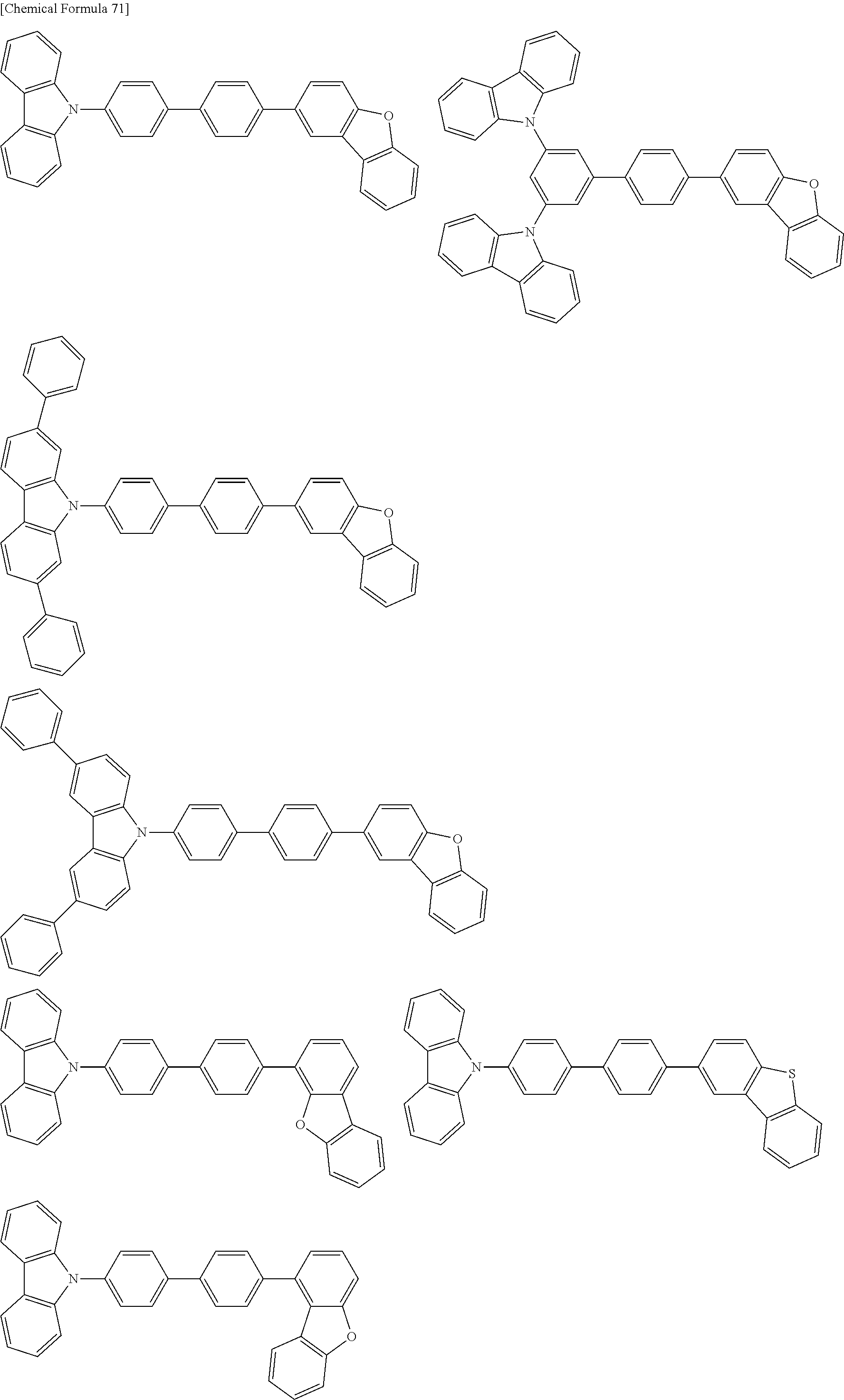

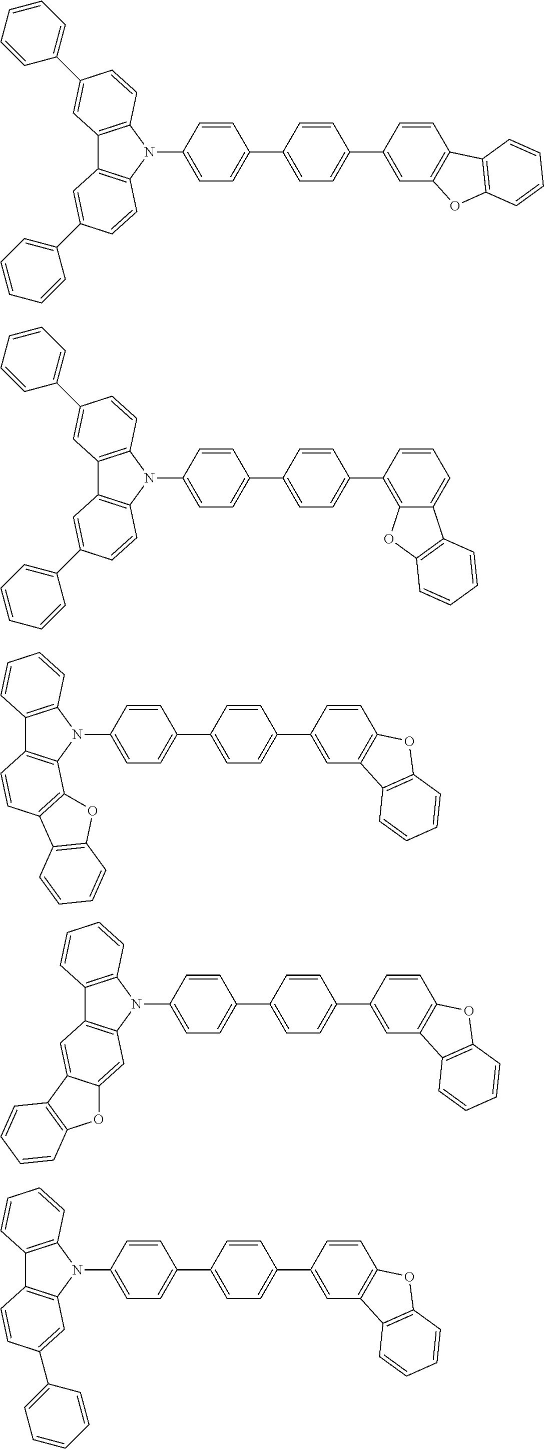

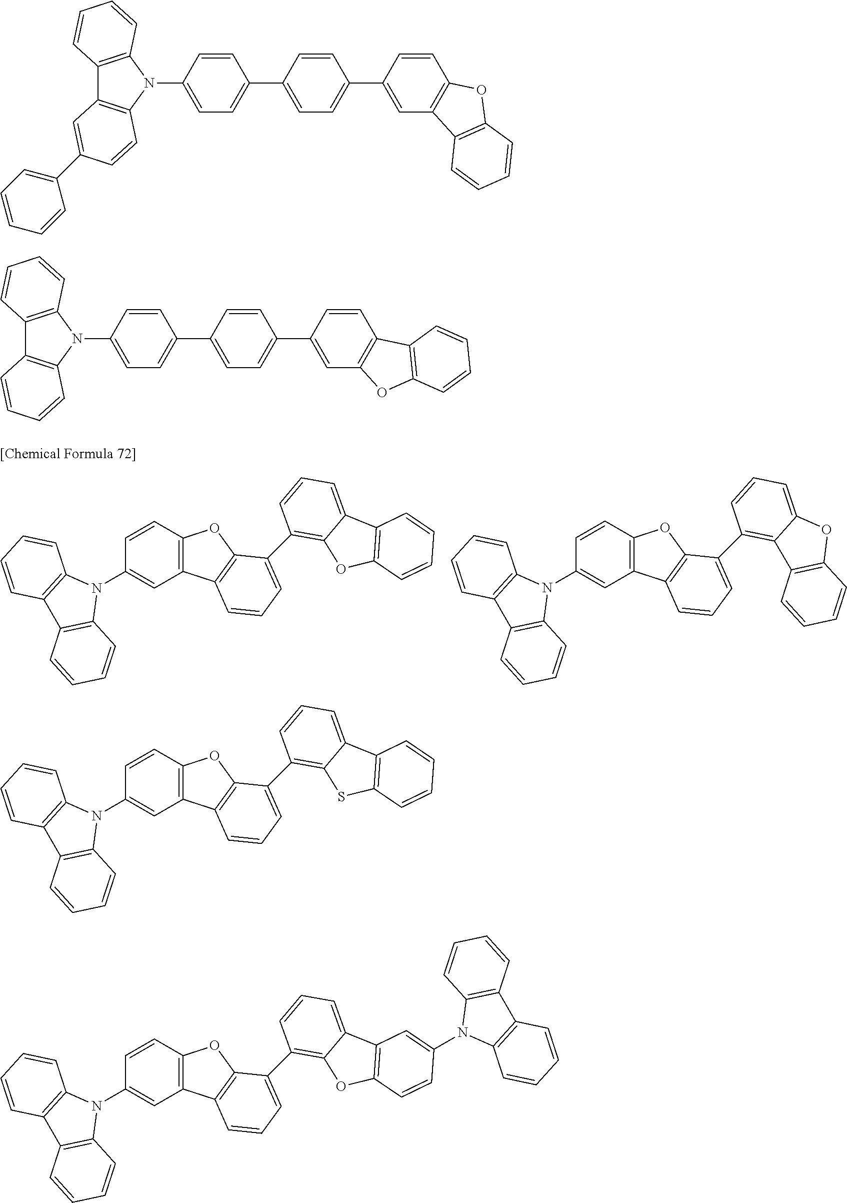

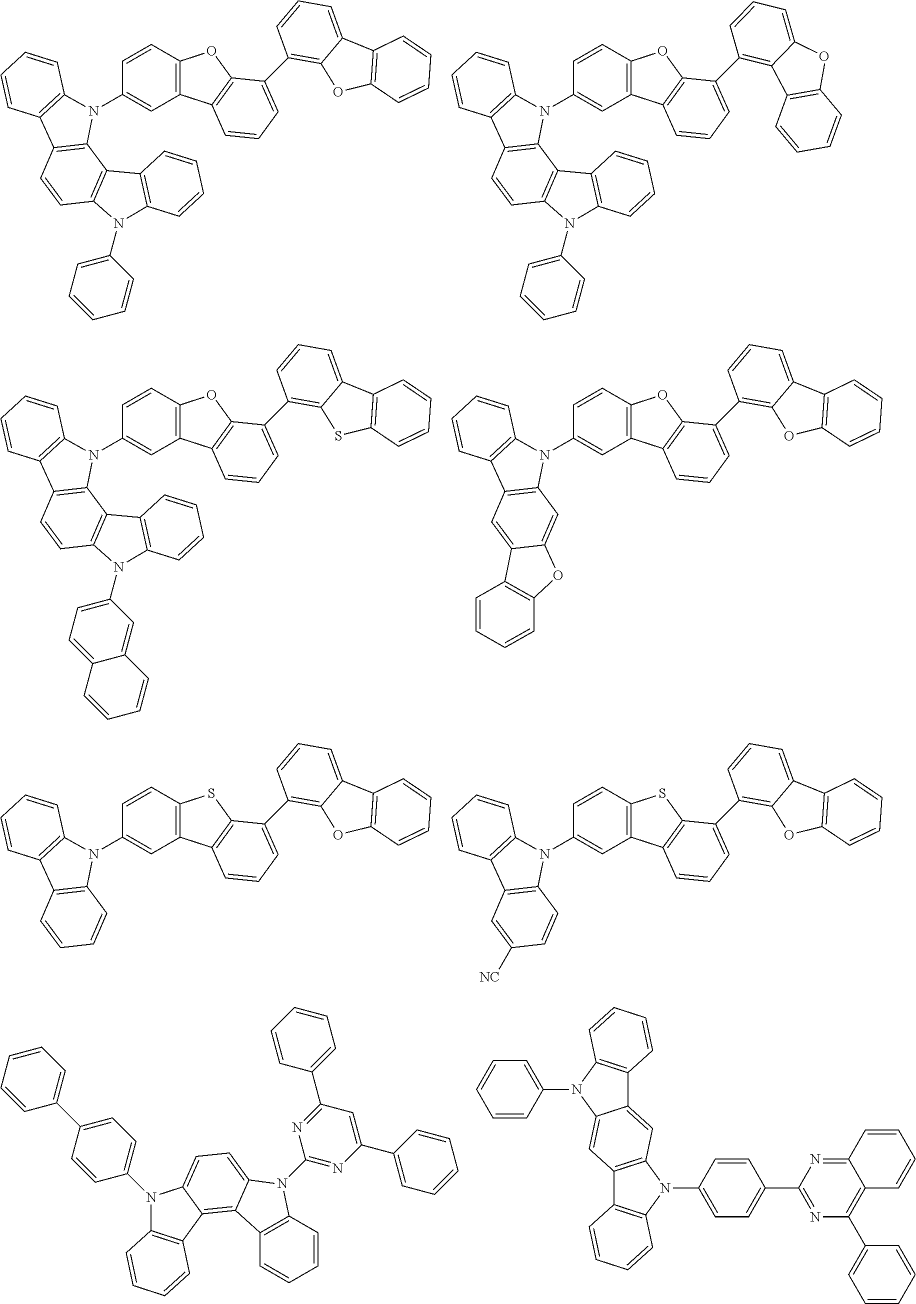

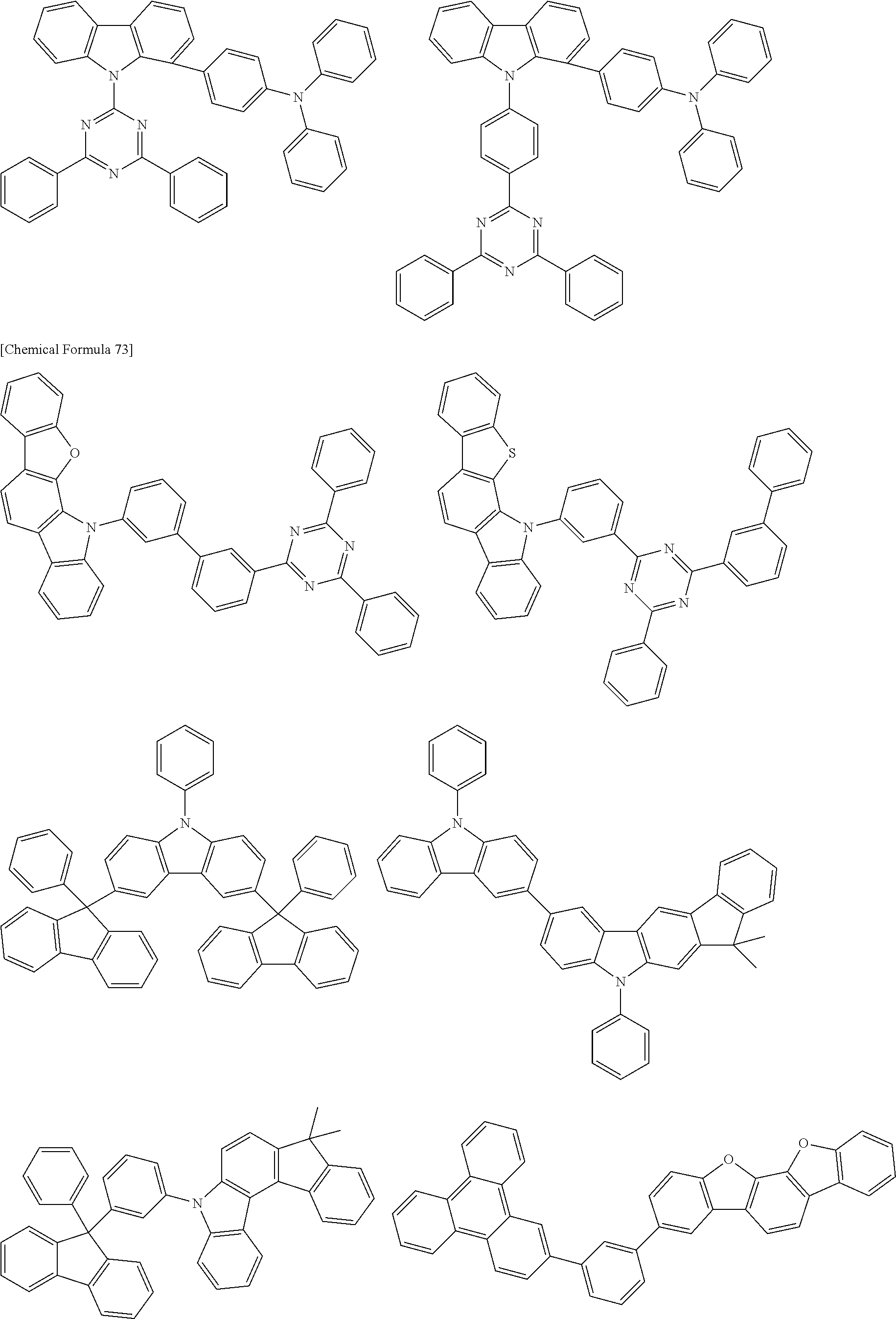

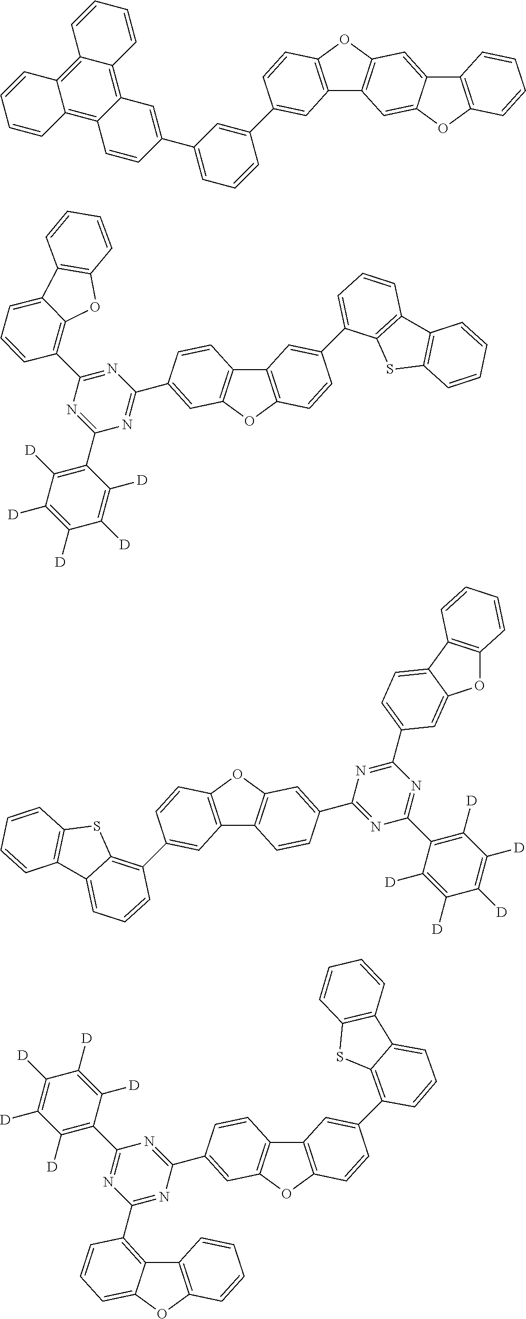

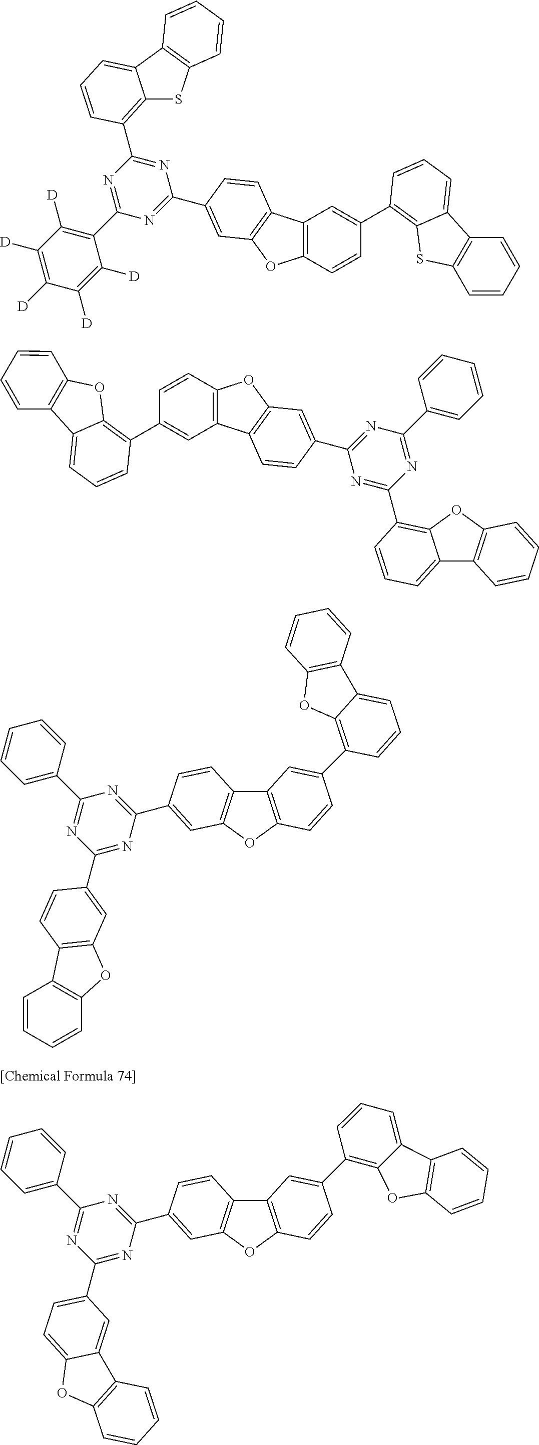

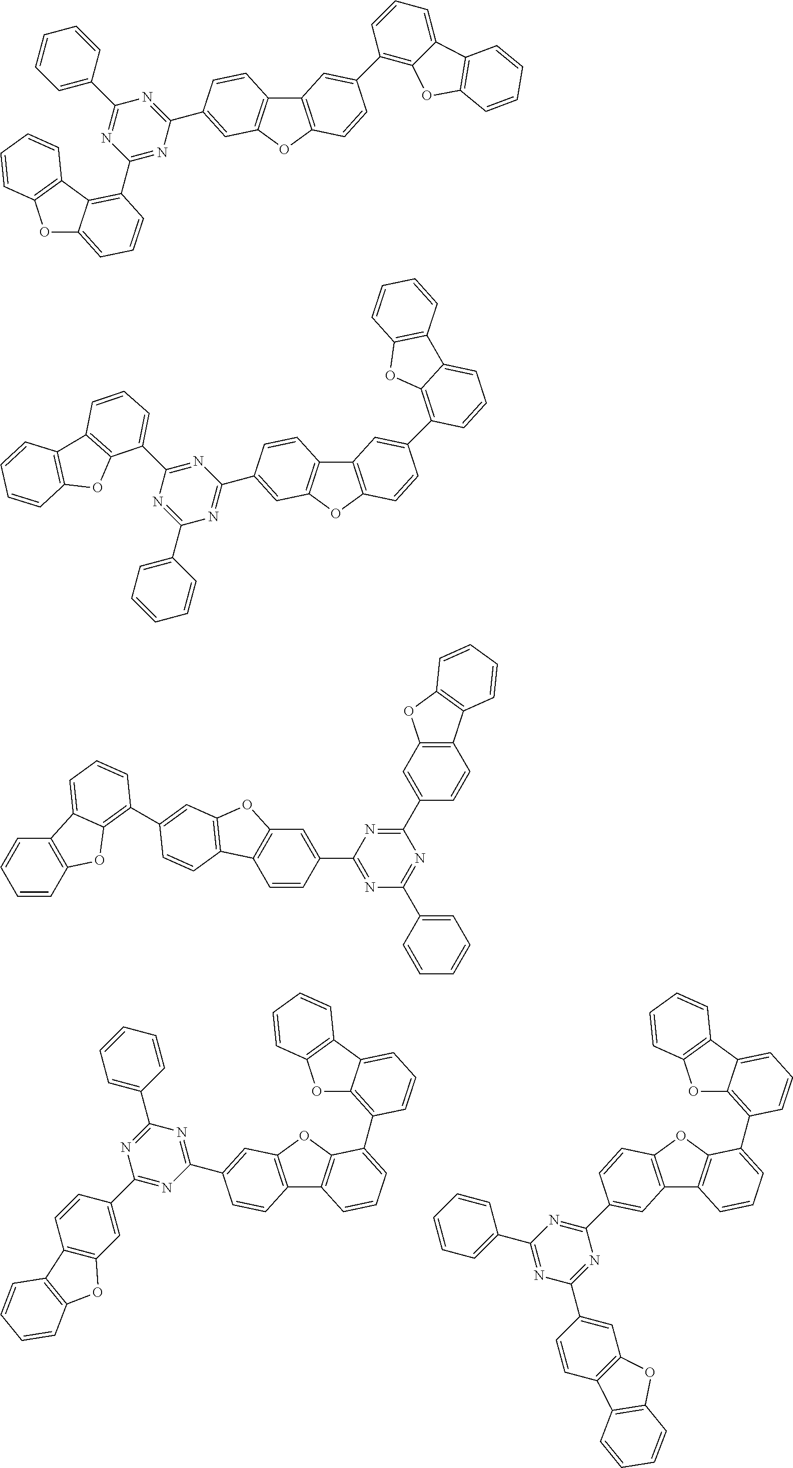

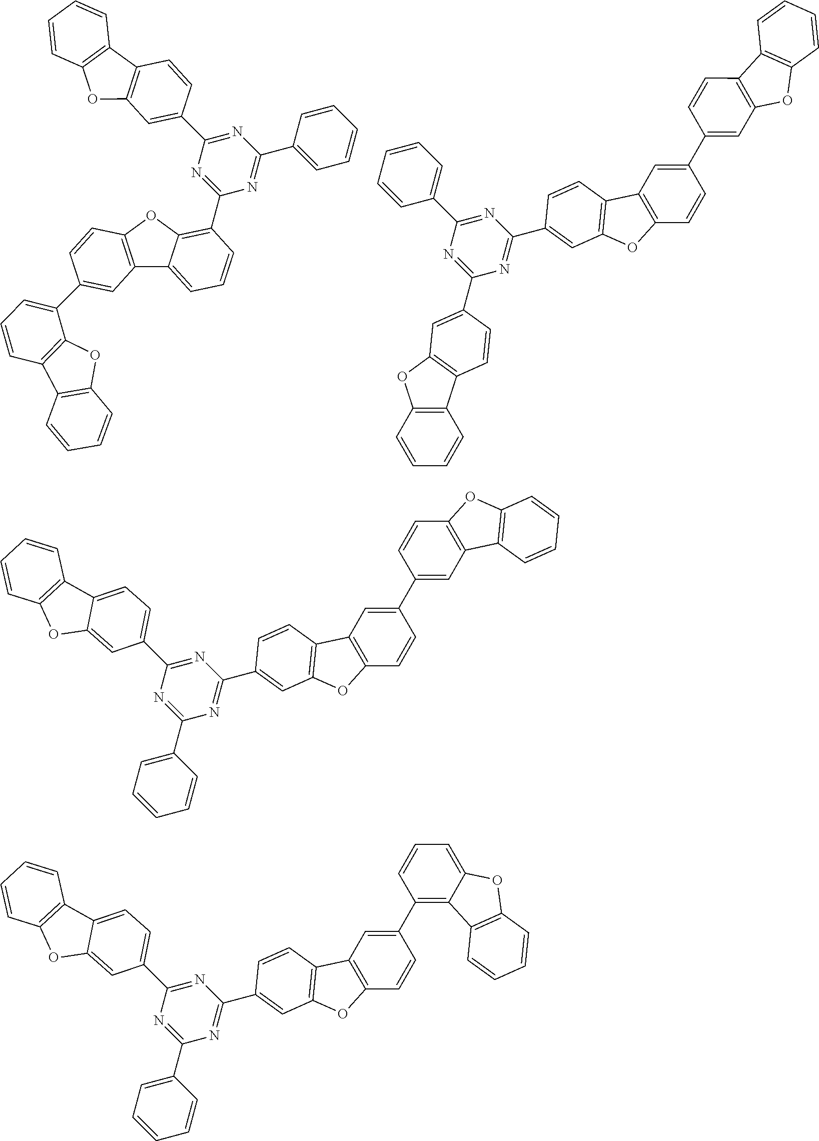

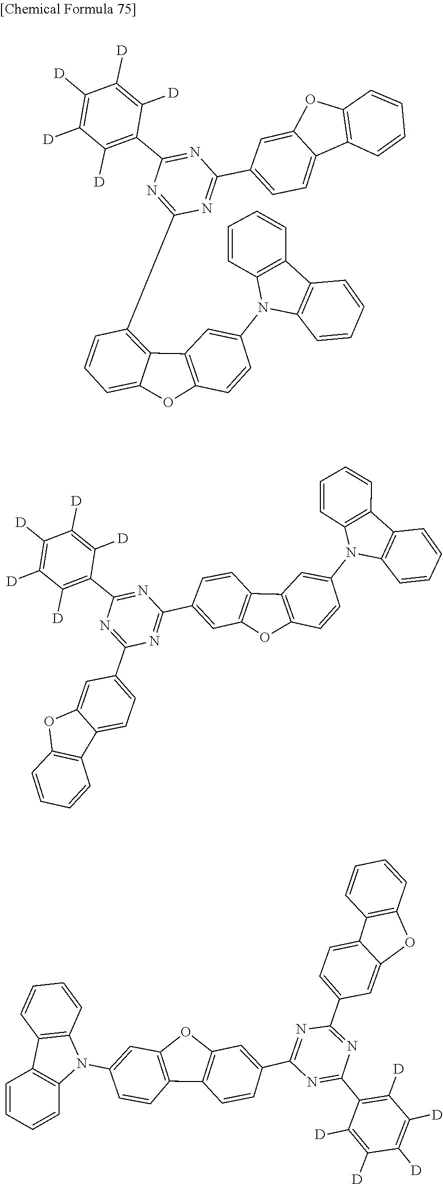

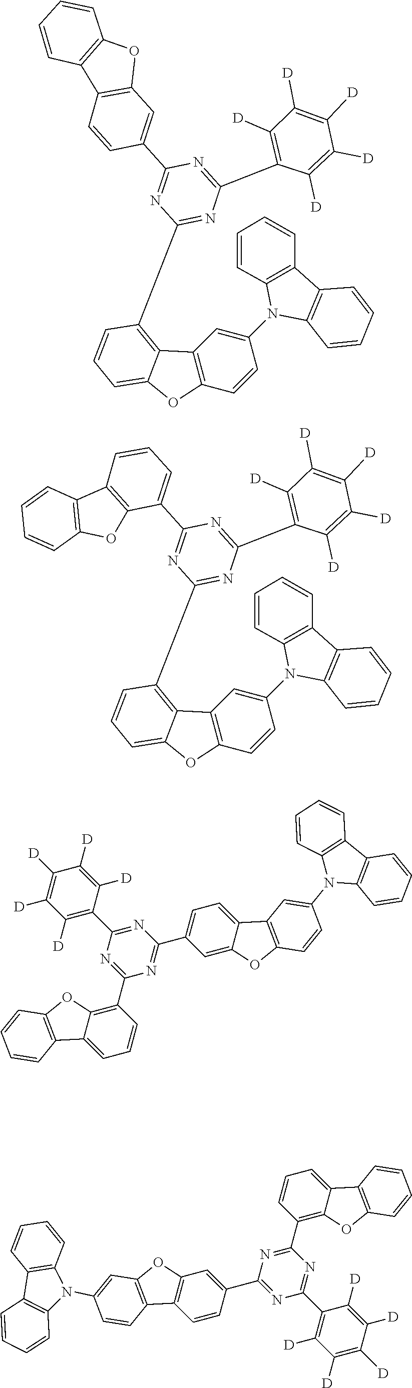

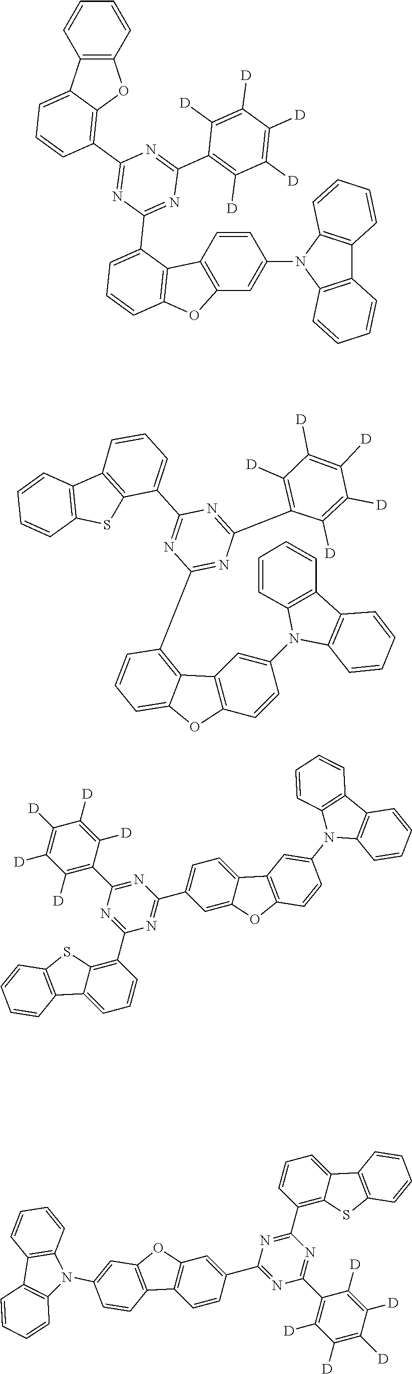

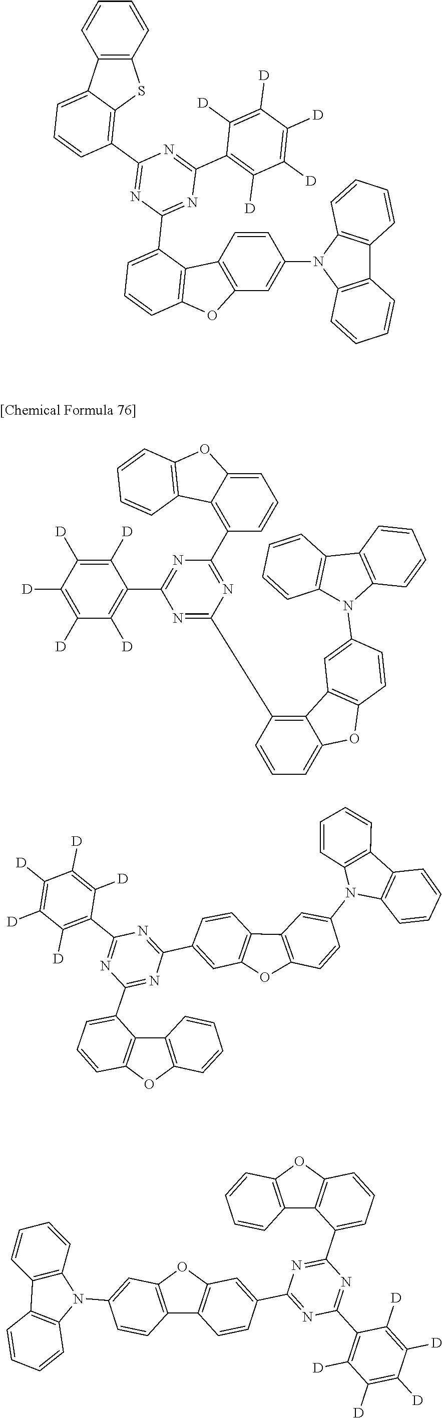

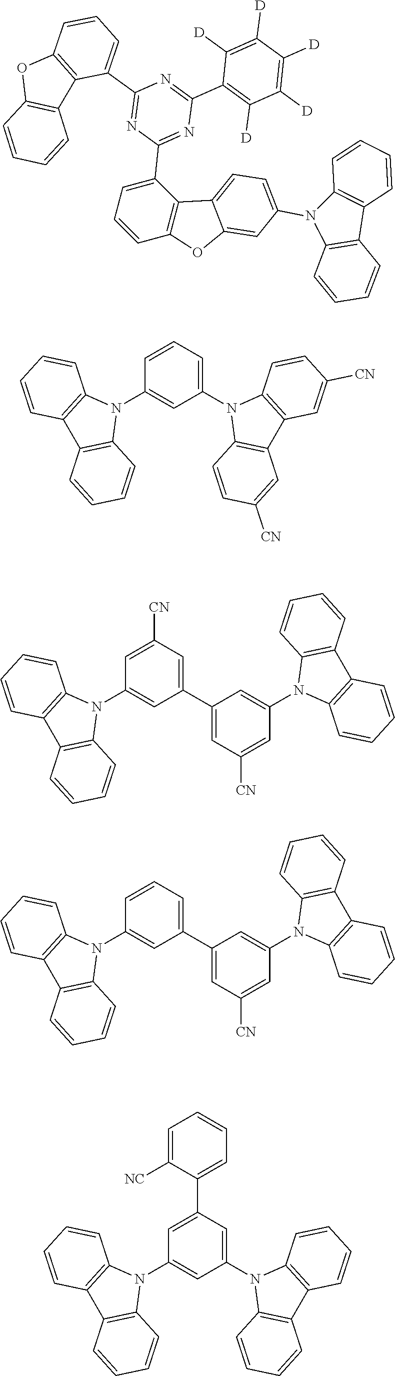

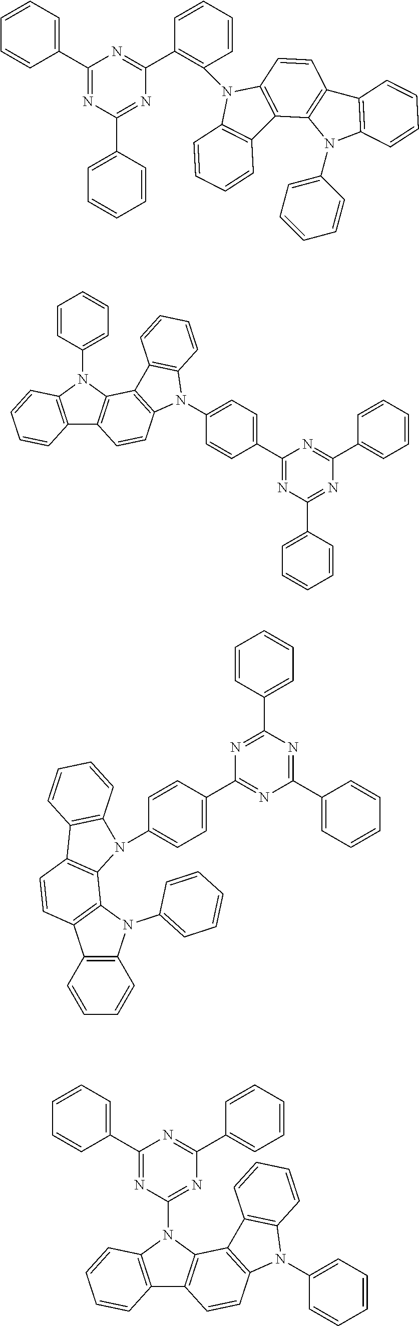

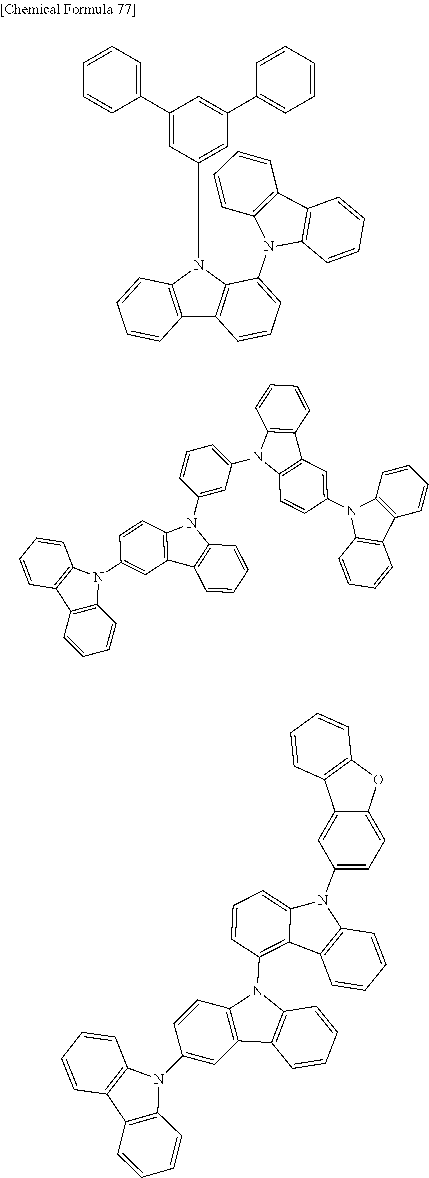

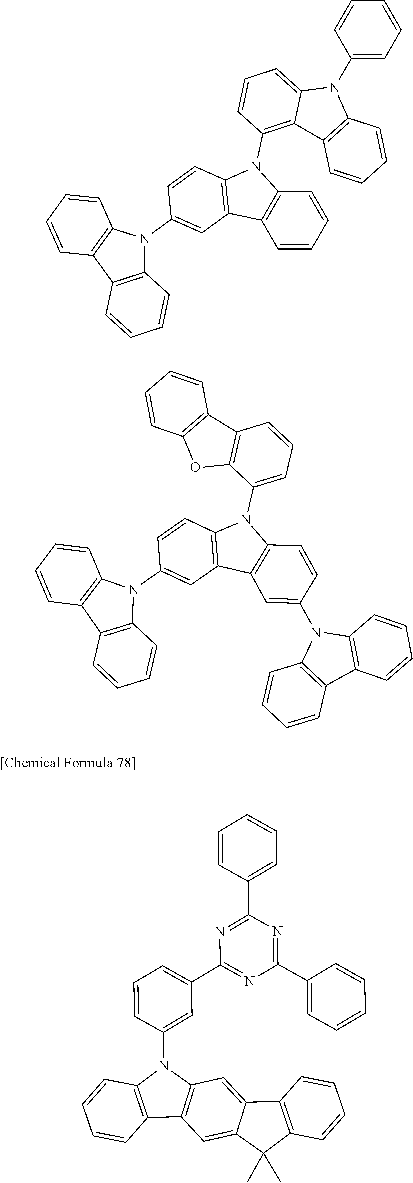

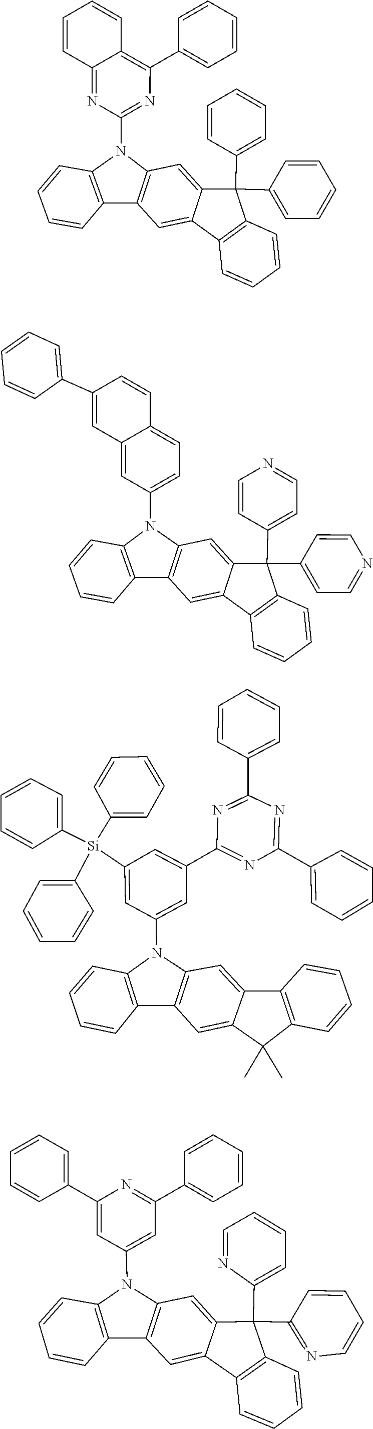

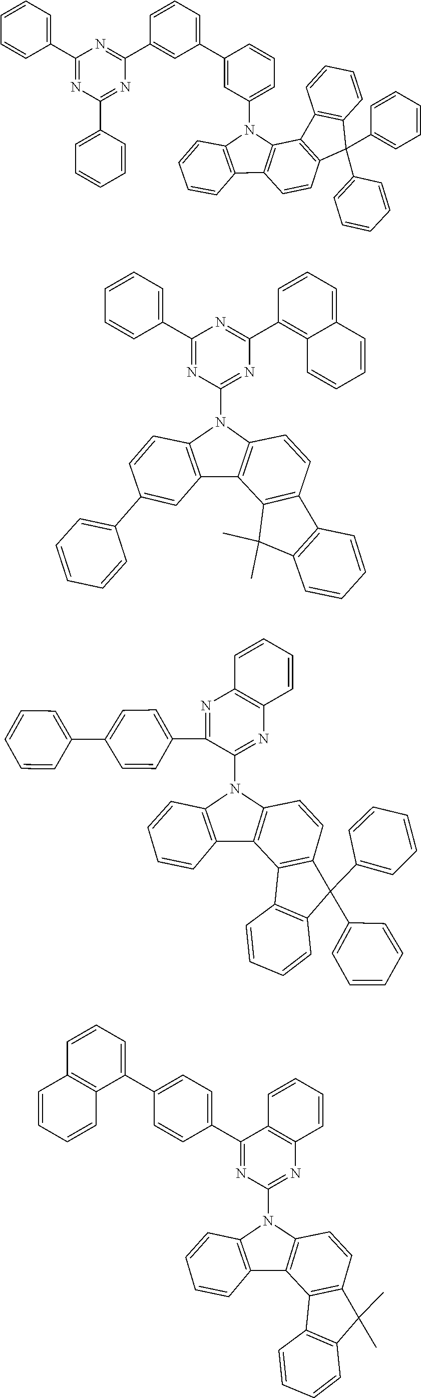

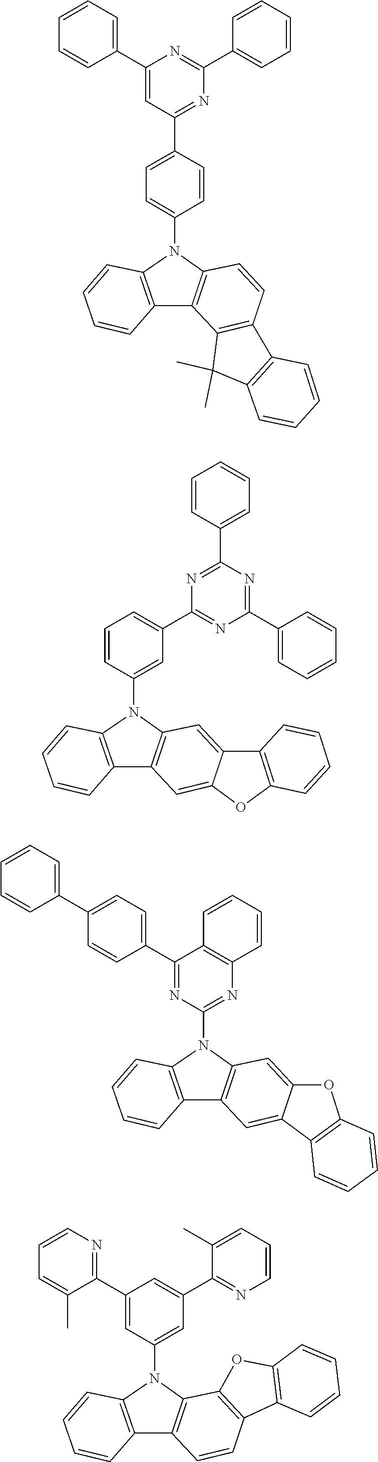

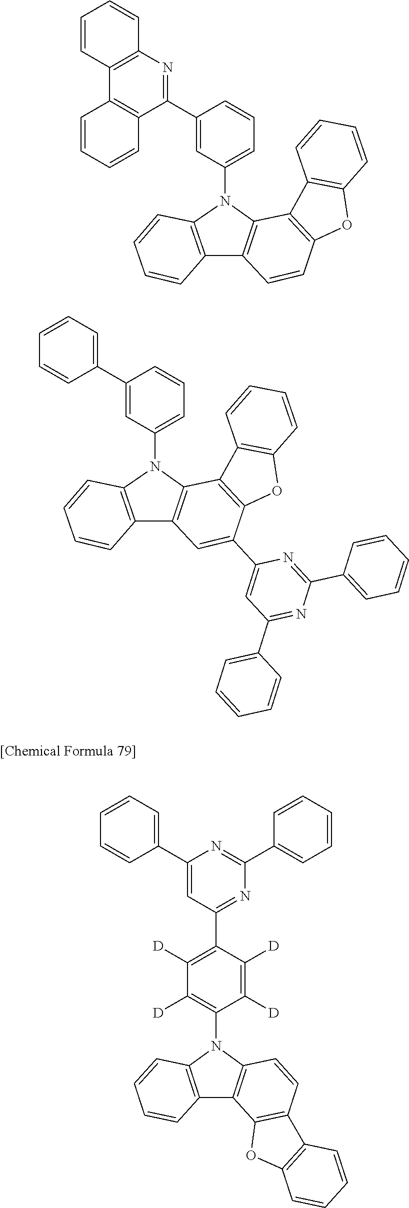

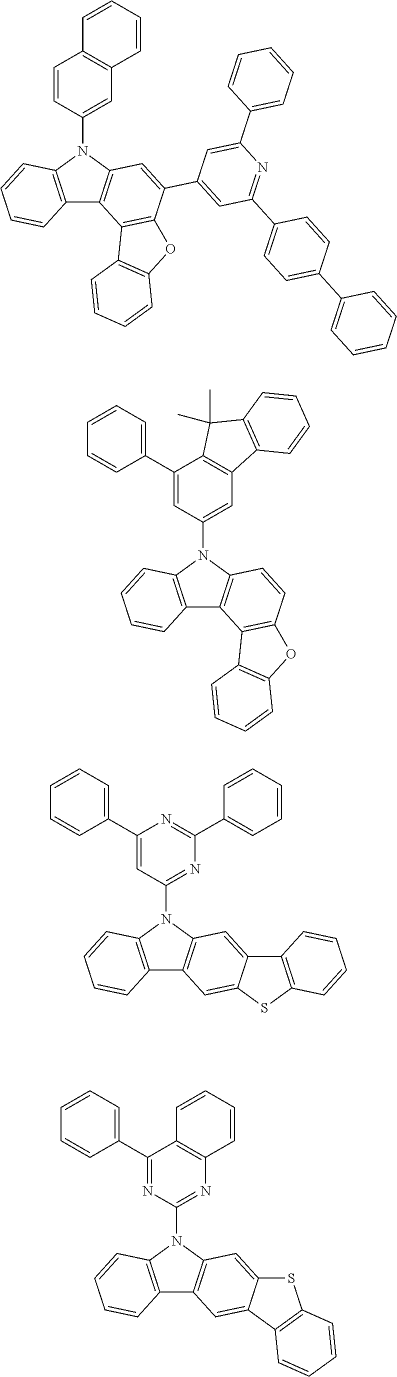

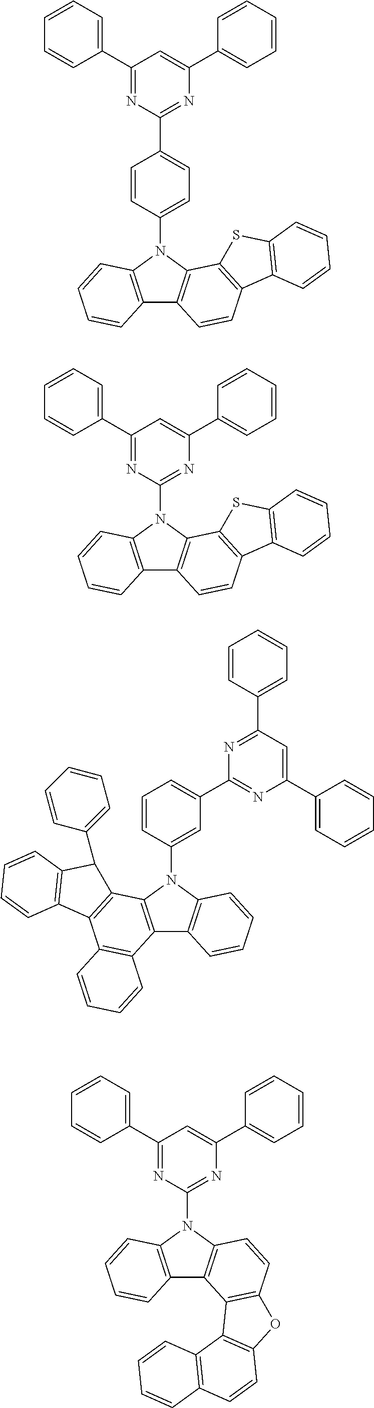

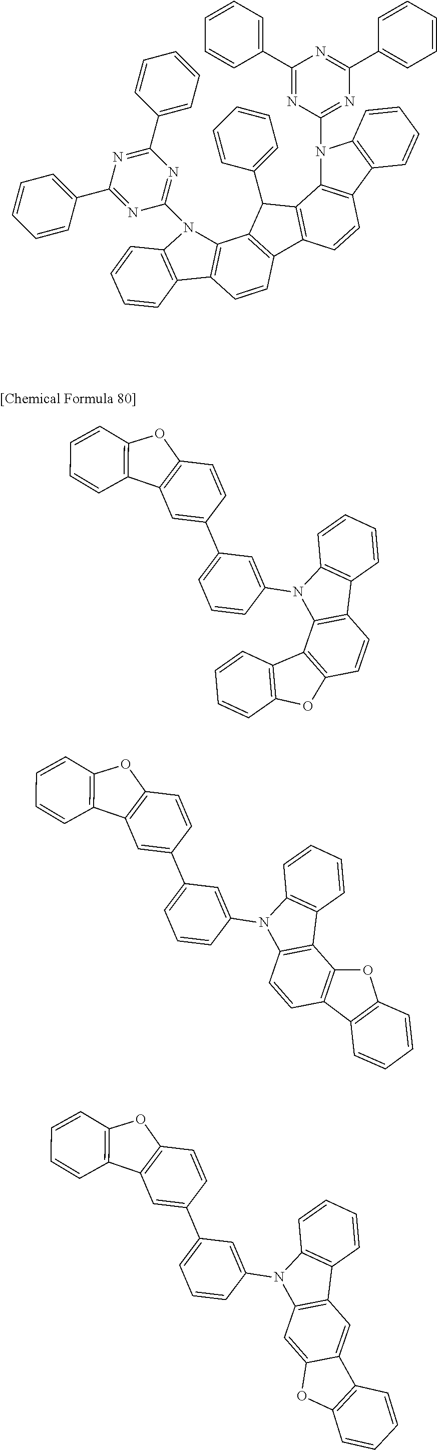

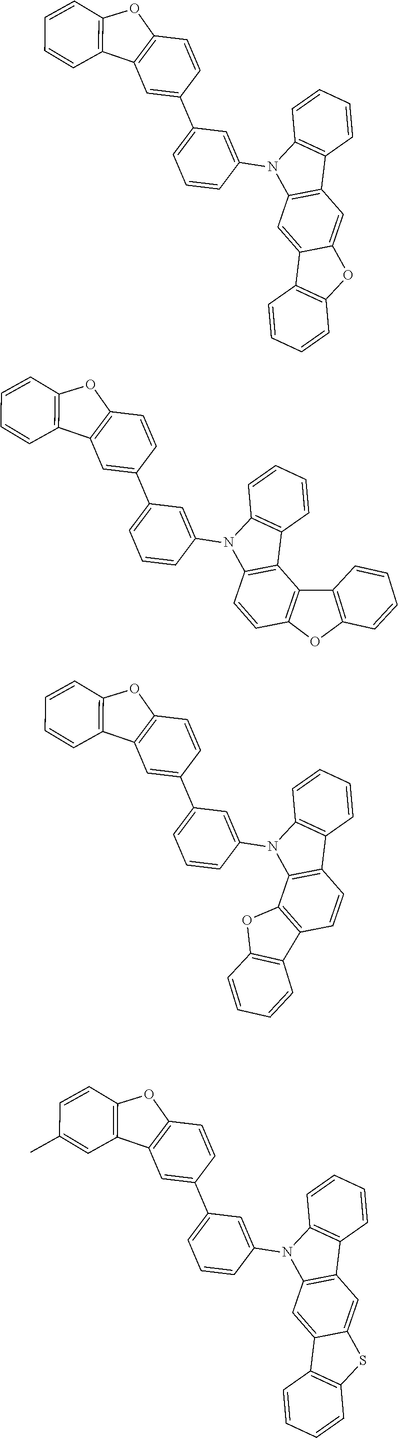

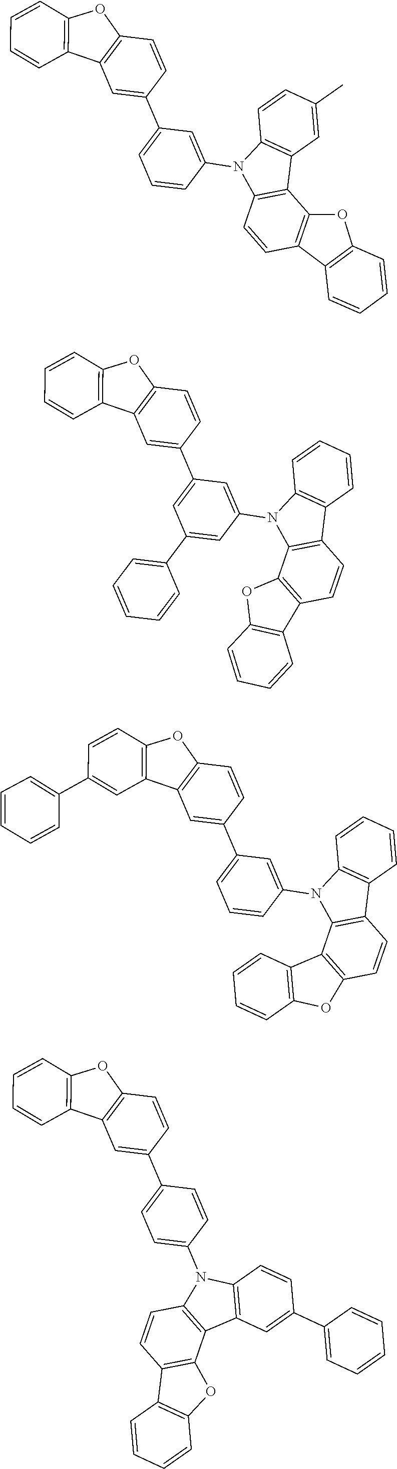

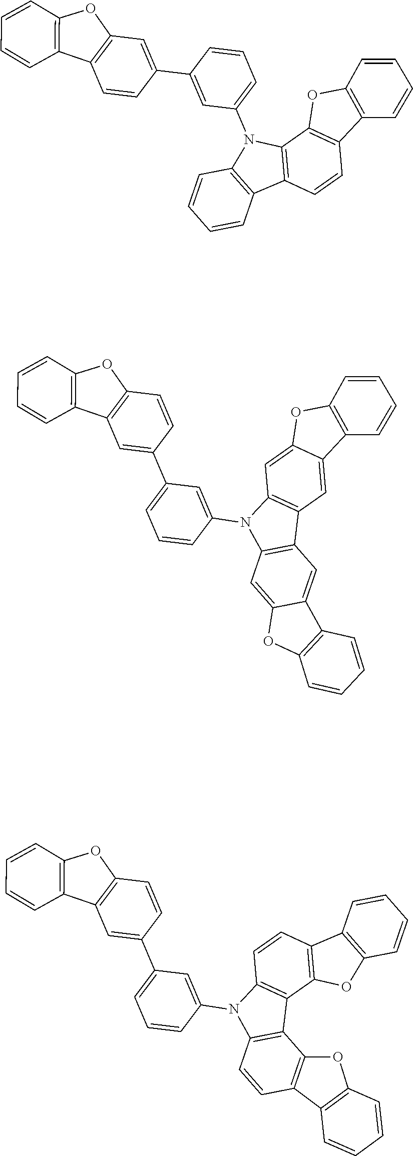

### (Electron Transporting Layer)

The electron transporting layer is a layer which transports electrons injected from the cathode to the light emitting layer. It is required for the electron transporting material to be used for the electron transporting layer to have high electron affinity, high degree of electron transfer, excellent stability, and which is less likely to generate impurities which become traps. From the viewpoint of suppressing deterioration of film quality due to crystallization, a compound having a molecular weight of 400 or more is preferable.

The electron transporting layer in the present invention also includes a hole blocking layer capable of efficiently blocking the transfer of holes. The hole blocking layer and the electron transporting layer may be a single layer, or a plurality of materials may be laminated.

Examples of the electron transporting material used for the electron transporting layer include polycyclic aromatic derivatives, styryl-based aromatic ring derivatives, quinone derivatives such, phosphorus oxide derivatives, and various metal complexes such as quinolinol complexes including tris(8-quinolinolato)aluminum(III), benzoquinolinol complexes, hydroxyazole complexes, azomethine complexes, tropolone metal complexes and flavonol metal complexes. From the viewpoints of reducing the driving voltage and further improving the light emitting element efficiency, it is preferable to use a compound having a heteroaryl group containing an electron-accepting nitrogen. Here, the electron accepting nitrogen represents a nitrogen atom forming a multiple bond with an adjacent atom. Since the heteroaryl group containing the electron-accepting nitrogen has high electron affinity, it becomes easy to inject electrons from the cathode, thus enabling lower voltage drive. The supply of electrons to the light emitting layer increases and the recombination probability is increased, leading to an improvement in light emitting element efficiency. Examples of compound having a heteroaryl group structure containing the electron-accepting nitrogen include pyridine derivatives, triazine derivatives, pyrazine derivatives, pyrimidine derivatives, quinoline derivatives, quinoxaline derivatives, quinazoline derivatives, naphthyridine derivatives, benzoquinoline derivatives, phenanthroline derivative, imidazole derivatives, oxazole derivatives, thiazole derivatives, triazole derivatives, oxadiazole derivatives, thiadiazole derivatives, benzimidazole derivatives, benzoxazole derivatives, benzthiazole derivatives, phenanthroimidazole derivatives, and oligopyridine derivatives such as bipyridine and terpyridine. Two or more types of these materials may be used.

It is more preferable that the electron transporting material has a fused polycyclic aromatic skeleton since the glass transition temperature is improved and the degree of electron transfer increases, thus making it possible to reduce the drive voltage. Such a fuse polycyclic aromatic skeleton is preferably a quinolinol skeleton, a triazine skeleton, a fluoranthene skeleton, an anthracene skeleton, a pyrene skeleton or a phenanthroline skeleton.

The electron transporting layer may also contain a donor material. Here, the donor material is a compound which facilitates electron injection from the cathode or the electron injection layer to the electron transporting layer by improving the electron injection barrier, and which further improves the electrical conductivity of the electron transporting layer.

Preferred examples of donor material include alkali metals such as Li; inorganic salts containing alkali metals, such as LiF; complexes of alkali metals and organic substances, such as lithium quinolinol; alkaline earth metals; inorganic salts containing alkaline earth metals; complexes of alkaline earth metals and organic substances; rare earth metals such as Eu and Yb; inorganic salts containing rare earth metals; complexes of rare earth metals and organic substances, and the like. Two or more types thereof may be used. Of these, metallic lithium, rare earth metals and lithium quinolinol (Liq) are preferable.

### (Electron Injection Layer)

In the present invention, an electron injection layer may be provided between the cathode and the electron transporting layer. In general, the electron injection layer is formed for the purpose of assisting the injection of electrons from the cathode to the electron transporting layer. The electron injection layer is composed of a compound having a heteroaryl ring structure containing electron-accepting nitrogen, or the above-mentioned donor material. Two or more types of these materials may be contained. Of these, materials of the electron injection layer are preferably triazine derivatives, phenanthroline derivatives or oligopyridine derivatives, more preferably phenanthroline derivatives or terpyridine derivatives, and still more preferably phenanthroline derivatives having a structure represented by the following general formula (15). That is, the light emitting element of the present invention preferably contains phenanthroline derivatives having a structure represented by the general formula (15) in the electron injection layer.

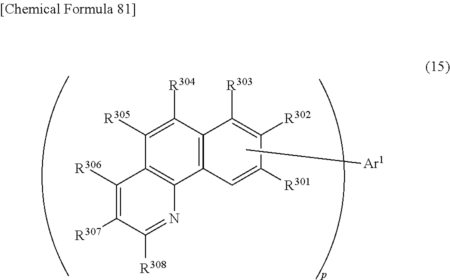

In the above general formula (15), Ar¹ is a group selected from the group consisting of p-valent aromatic hydrocarbon groups and a p-valent aromatic heterocyclic group. p is a natural number from 1 to 3. R³⁰¹ to R³⁰⁸ each may be the same or different and are groups selected from the group consisting of a hydrogen atom, an alkyl group, a cycloalkyl group, a heterocyclic group, an aryl group and a heteroaryl group. Of Ar¹, the substitution positions of p phenanthrolyl groups are any positions.

Examples of the monovalent aromatic hydrocarbon group include a phenyl group, a biphenyl group, a terphenyl group, a naphthyl group, a fluorenyl group, a benzofluorenyl group, a dibenzofluorenyl group, a phenanthryl group, an anthracenyl group, a benzophenanthryl group, a benzanthracenyl group, a chrysenyl group, a pyrenyl group, a fluoranthenyl group, a triphenylenyl group, a benzofluoranthenyl group, a dibenzoanthracenyl group, a perylenyl group, a helicenyl group, and the like. Of these, from the viewpoints of ease of synthesis and sublimability, preferred are a phenyl group, a biphenyl group, a terphenyl group, a naphthyl group, a fluorenyl group, a phenanthryl group, an anthracenyl group, a pyrenyl group, a fluoranthenyl group, a triphenylenyl group, and groups in which at least a portion of hydrogen atoms of these groups are removed. The aromatic hydrocarbon group may or may not have a substituent. The number of ring-forming carbon atoms is not particularly limited, but is preferably within a range of 6 or more and 40 or less, and more preferably 6 or more and 30 or less. When two adjacent carbon atoms each have a substituent, these substituents may be bonded with each other to form a ring structure.

The aromatic heterocyclic group represents a cyclic aromatic group having one or more atoms other than carbon in the ring, and examples of the monovalent aromatic group include a pyridyl group, a furanyl group, a thiophenyl group, a quinolinyl group, an isoquinolinyl group, a pyrazinyl group, a pyrimidyl group, a pyridazinyl group, a triazinyl group, a naphthyridinyl group, a cinnolinyl group, a phthalazinyl group, a quinoxalinyl group, a quinazolinyl group, a benzofuranyl group, a benzothiophenyl group, an indolyl group, a dibenzofuranyl group, a dibenzothiophenyl group, a carbazolyl group, a benzocarbazolyl group, a carbolinyl group, an indolocarbazolyl group, a benzofurocarbazolyl group, a benzothienocarbazolyl group, a dihydroindenocarbazolyl group, a benzoquinolinyl group, an acridinyl group, a dibenzoacridinyl group, a benzimidazolyl group, an imidazopyridyl group, a benzoxazolyl group, a benzothiazolyl group, a phenanthrolinyl group, and the like. However, the naphthyridinyl group represents any one of a 1,5-naphthyridinyl group, a 1,6-naphthyridinyl group, a 1,7-naphthyridinyl group, a 1,8-naphthyridinyl group, a 2,6-naphthyridinyl group and a 2,7-naphthyridinyl group. The aromatic heterocyclic group may or may not have a substituent. The number of ring-forming carbon atoms of the aromatic heterocyclic group is not particularly limited, but is preferably within a range of 2 or more and 40 or less, and more preferably 2 or more and 30 or less.

The aromatic hydrocarbon group or aromatic heterocyclic group may further have a substituent other than the phenanthryl group.

From the viewpoint of the sublimability and thin-film formability, p is preferably 2.

An example of the phenanthroline derivative having a structure represented by the general formula (15) is shown below.

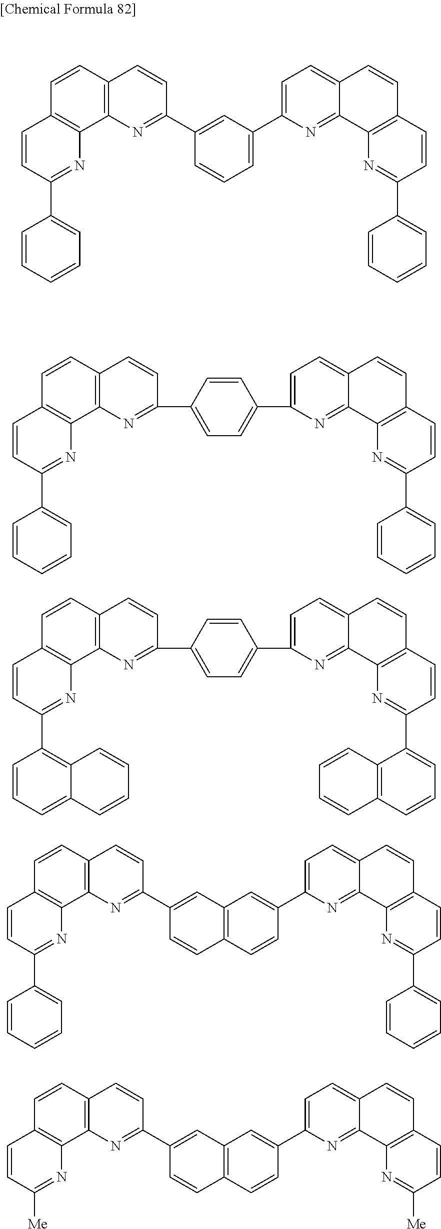

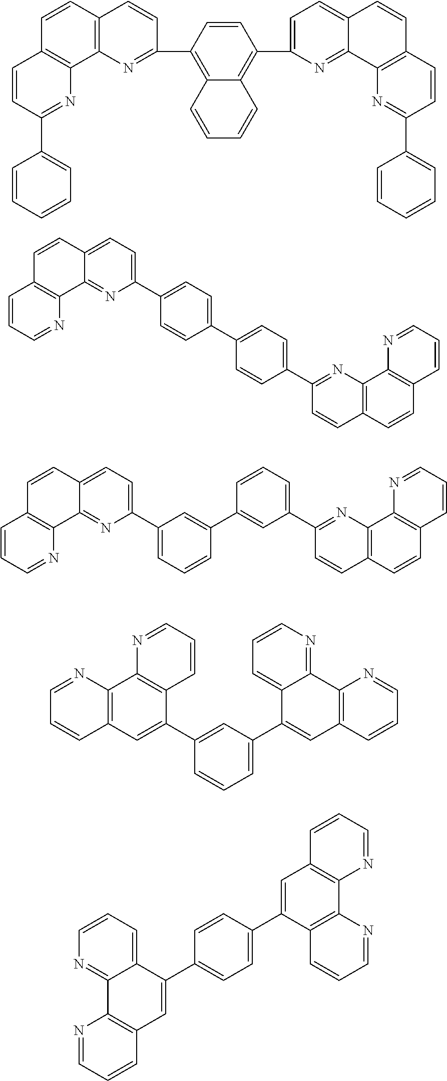

It is also possible to use an insulator or a semiconductor inorganic substance for the electron injection layer. It is preferable to use these materials since it is possible to prevent a short circuit of the light emitting element and improve the electron injection property.

It is preferable to use, as such insulator, metal compounds such as alkali metal chalcogenides, alkaline earth metal chalcogenides, alkali metal halides and alkaline earth metal halides. Two or more types thereof may be used.

### (Charge Generation Layer)

The light emitting element according to the embodiments of the present invention preferably contains a compound having a structure represented by the general formula (1) or (2) in the light emitting layer, and further has a charge generation layer. The charge generation layer is preferably composed of a double layer. Specifically, it is possible to use as a pn junction charge generation layer composed of an n-type charge generation layer and a p-type charge generation layer. The pn junction charge generation layer generates a charge when a voltage is applied in the light emitting element, or separates the charge into holes and electrons, and these holes and electrons are injected into the light emitting layer through the hole transporting layer and the electron transporting layer. The charge generation layer functions as an intermediate layer in a light emitting element in the above tandem-type layer structure. Specifically, the n-type charge generation layer supplies electrons to the first light emitting layer existing on the anode side, and the p-type charge generation layer supplies holes to the second light emitting layer existing on the cathode side. Therefore, it is possible to improve the light emitting element efficiency in the light emitting element in which a plurality of light emitting layers are laminated and to reduce the driving voltage, leading to an improvement in durability of the light emitting element.

The n-type charge generation layer is composed of an n-type dopant and a host, and conventional materials can be used for them. For example, n-type dopant includes alkali metals, alkaline earth metals, and rare earth metals, and the like. Two or more types thereof may be used. Of these, alkali metals or salts thereof, and rare earth metals are preferable, and metallic lithium, lithium fluoride (LiF), lithium quinolinol (Liq) and metallic ytterbium are more preferable. Examples of the host include triazine derivatives, phenanthroline derivatives and oligopyridine derivatives. Two or more thereof may be used. Of these, triazine derivatives, phenanthroline derivatives and oligopyridine derivatives are preferable, phenanthroline derivatives and terpyridine derivatives are more preferable, phenanthroline derivatives having a structure represented by the above general formula (15) are still more preferable, and phenanthroline derivatives represented by the following general formula (16) are particularly preferable. The light emitting element of the present invention preferably contains phenanthroline derivatives having a structure represented by the general formula (15) in the charge generation layer, and more preferably contains phenanthroline derivatives represented by the general formula (16).

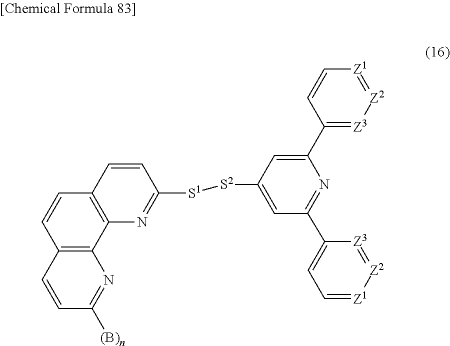

In the above general formula (16), any one of Z¹ to Z³ is a nitrogen atom, and the others are methine groups. S¹ is a substituted or unsubstituted phenylene group, a substituted or unsubstituted naphthylene group, or a substituted or unsubstituted anthrylene group, and S² is a single bond, a substituted or unsubstituted phenylene group, a substituted or unsubstituted naphthylene group, or a substituted or unsubstituted anthrylene group. However, when these groups are substituted, the substituent is an alkyl group or an alkoxy group. B is a phenyl group or a pyridyl group, and n is 0 or 1.

An example of the phenanthroline derivative represented by the general formula (16) is shown below.

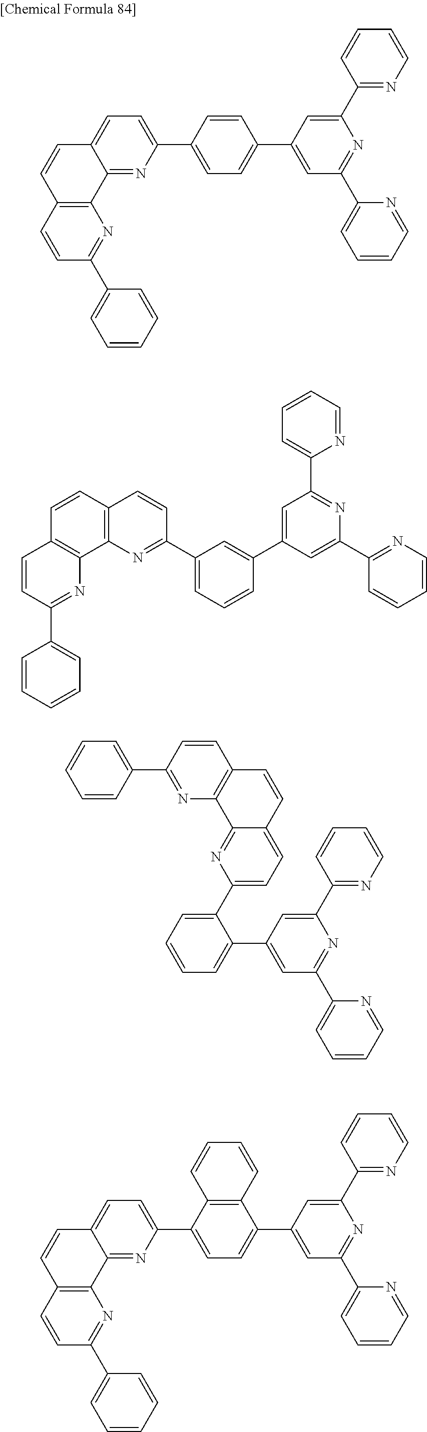

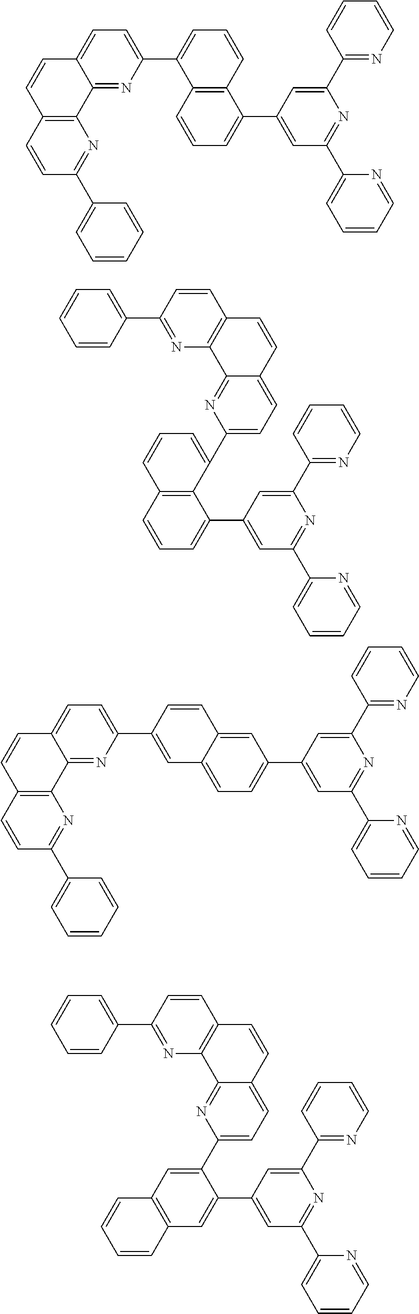

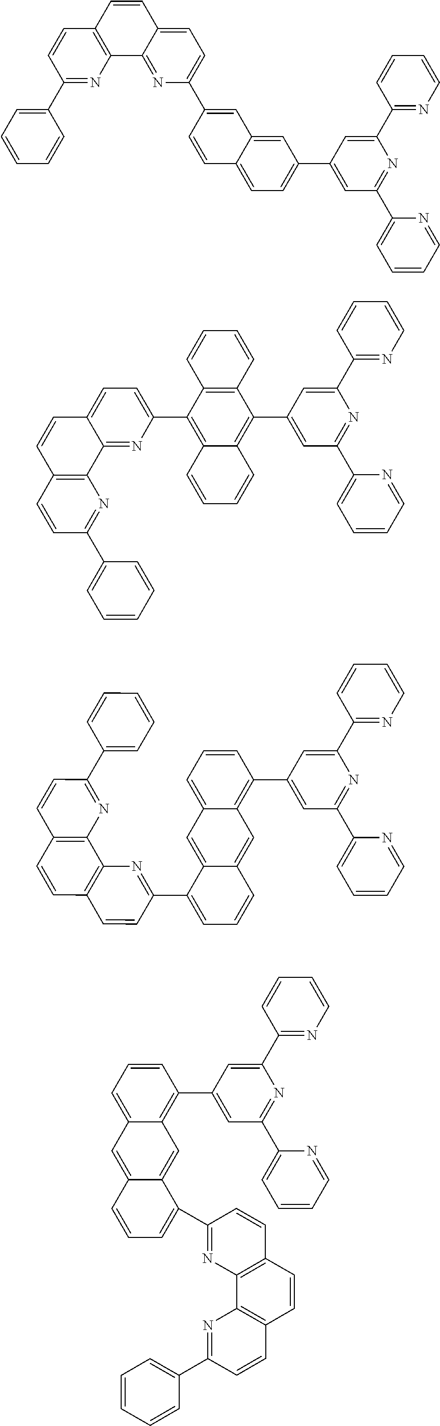

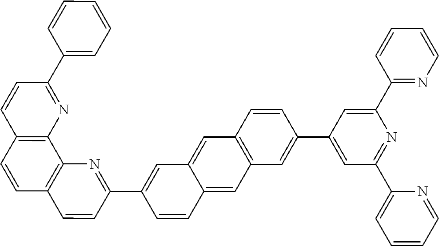

The p-type charge generation layer is composed of a p-type dopant and a host, and conventional materials can be used for them. For example, the p-type dopant includes tetrafluoro-7,7,8,8-tetracyanoquinodimethane (F4-TCNQ), tetracyanoquinodimethane derivatives, radialene derivatives, iodine, FeCl₃, FeF₃, SbCl₅, and the like. Two or more types thereof may be used. Of these, arylamine derivatives are preferable.

### (Method for Forming Light Emitting Element)

The method of forming each of the above layers constituting the light emitting element may be either a dry process or a wet process. Examples thereof include resistance heating vapor deposition, electron beam vapor deposition, sputtering, molecular lamination, coating, ink jet method, printing method, and the like. Of these, resistance heating vapor deposition is preferable from the viewpoint of the element characteristics.

The thickness of the organic layer is not limited, but is preferably 1 to 1,000 nm. The thickness of each of the light emitting layer, the electron transporting layer and the hole transporting layer is preferably 1 nm or more and 200 nm or less, and more preferably 5 nm or more and 100 nm or less.

### (Characteristics of Light Emitting Element)

The light emitting element according to the embodiments of the present invention has a function capable of converting electrical energy into light. For the electrical energy herein, the direct current is mainly used, but the pulse current and alternating current can also be used. The current value and voltage value are not particularly limited, and the characteristic values required for the element vary depending on the purpose of the element, but it is preferable to obtain high luminance with the low voltage from the viewpoint of the power consumption and durability of the element.

In the light emitting element according to the embodiments of the present invention, from the viewpoint of further improving the color purity of green emission in the emission spectrum when energized, the emission peak wavelength is preferably 500 nm or more and 550 nm or less, and more preferably 510 nm or more and 540 nm or less. From the viewpoint of improving the color purity, the half width of the emission peak in the emission spectrum when energized is preferably 45 nm or less, more preferably 40 nm or less, and still more preferably 35 nm or less.

### (Applications of Light Emitting Element)

The light emitting element according to the embodiment of the present invention can achieve both high efficiency emission and high color purity, and can provide thinner and lighter devices, and is therefore suitable for use, for example, as a display device or a lighting device.

Examples of the display device include a display device using the light emitting element of the present invention for display based on a matrix system, and a display device using the light emitting element of the present invention as a backlight. The backlight is mainly used for the purpose of improving the visibility of display devices which does not emit light by itself, such as displays, and is used in display devices such as liquid crystal displays, clocks, audio devices, automobile panels, display boards and signs. Of these, the light emitting element of the present invention can be preferably used for a liquid crystal display, particularly for a backlight for personal computers which have been attempted to be thinner.

Examples of the illumination device include devices for medical lighting and interior lighting, and it is possible to realize an illumination device with low power consumption, bright emission colors and excellent designability.

### <Color Conversion Composition>

The compound of the present invention may be used in a color conversion composition which converts incident light from an illuminant such as a light source into light of a different wavelength than the incident light. The color conversion composition preferably contains a compound represented by the above general formula (1) or (2) and a binder resin. Here, the phrase “converts incident light into light of a wavelength different from the wavelength of the incident light” preferably means converting incident light into light of a wavelength longer than the wavelength of the incident light.

### <Method for Producing Color Conversion Composition>

The color conversion composition of the present invention can be obtained, for example, by mixing a binder resin, a compound having a structure represented by the general formula (1) or (2), and, if necessary, additives, solvents, etc. to a predetermined composition, and then mixing or kneading the mixture homogeneously using a stirrer/kneader. Examples of the stirring/kneader include a homogenizer, a planetary centrifugal mixer, a three-roller stirrer, a ball mill, a planetary ball mill, a bead mill, and the like. After mixing or dispersing, or during the mixing or dispersing process, degassing is preferably carried out under vacuum or reduced pressure conditions. Certain specific components may be mixed in advance, or a treatment such as aging may be carried out. It is also possible to remove the solvent using an evaporator to obtain a desired solid content concentration.

### <Color Conversion Sheet>

The color conversion sheet of the present invention is a sheet which converts incident light from an illuminant such as a light source into light of a different wavelength from the incident light, and contains the above-mentioned color conversion composition of the present invention or a cured product thereof. It is preferable to convert the incident light into light with a longer wavelength than that of the incident light.

The color conversion sheet of the present invention preferably includes a color conversion layer which is a layer formed from the above-mentioned color conversion composition. The amount of residual solvent in the color conversion layer is preferably 0.5% by weight or less from the viewpoint of further improving the durability of the color conversion sheet. Meanwhile, the amount of the residual solvent in the color conversion layer is preferably 0.1% by weight or more from the viewpoint of further improving the luminous efficiency of the color conversion sheet.

### <Method for Producing Color Conversion Sheet>

Next, an example of a method for producing a color conversion sheet of the present invention will be described. The color conversion composition prepared by the above-mentioned method is applied on a substrate and dried to form a color conversion layer. When the binder resin is a thermosetting resin, the color conversion composition may be applied on a substrate and then cured by heating to form a color conversion layer. When the binder resin is a photocurable resin, the color conversion composition may be applied on a substrate and then photocured to form a color conversion layer.

### <Light Source Unit>

The light source unit of the present invention includes at least a light source and the above-mentioned color conversion sheet of the present invention. The light source included in the light source unit of the present invention serves as a source of the above-mentioned excitation light. There is no particular limitation on the method of arranging the light source and the color conversion sheet, and the light source and the color conversion sheet may be in close contact with each other, or a remote phosphor type in which the light source and the color conversion sheet are separated from each other may be used. The light source unit may further include a color filter for the purpose of increasing the color purity.

### <Light Source>

Any light source can be used as long as it emits light in the wavelength range which can be absorbed by the light emitting material. For example, in principle, it is possible to use any light source such as a hot cathode tube, a cold cathode tube, a fluorescent light source such as an inorganic EL, an organic electroluminescence element light source, an LED light source, an incandescent light source or sunlight. Of these, LED is preferred light source. For display (display device) and lighting applications, a blue LED having an emission peak within a range of 430 to 500 nm is a more suitable light source because it can enhance the color purity of blue light.

The light source may have one emission peak or two or more emission peaks, but is preferably one having one emission peak in order to increase the color purity. It is also possible to use any combination of a plurality of light sources having different types of emission peaks.

The light source unit of the present invention is useful as various light sources such as space illumination and backlighting. Specifically, it can be used for applications such as display devices, lighting, interior design, signs and signboards. It is particularly suitable for use in display devices and lighting applications.

### <Display Device, Illumination Device>

The display device of the present invention includes at least the above-mentioned light emitting element of the present invention and/or the above-mentioned light source unit. For example, in a display device such as a liquid crystal display, the above-mentioned light source unit of the present invention is preferably used as a backlight unit. By using the above-mentioned light emitting element, it is possible to produce a display device such as an organic EL display which displays in a matrix and/or segment system and has high light emitting efficiency and excellent durability.

The illumination device of the present invention includes at least the above-mentioned light emitting element of the present invention and/or the above-mentioned light source unit of the present invention. For example, this illumination device is configured to emit white light by combining a blue LED light source as a light source unit with a color conversion sheet which converts the blue light from this blue LED light source into light with a longer wavelength. An illumination device can also be obtained by using the above-mentioned light emitting element of the present invention. These illumination devices include, for example, devices for medical lighting and interior lighting, and are capable of achieving both vivid luminous color, high durability and excellent designability.

### <Photoelectric Conversion Material>

The compound of the present invention may be used as a photoelectric conversion material constituting a photoelectric conversion layer in a photoelectric conversion element having a photoelectric conversion layer between an anode and a cathode. The photoelectric conversion material may be composed only of a compound having a structure represented by the general formula (1) or (2) of the present invention, but may further contain other components in order to further increase the photoelectric conversion efficiency.

### EXAMPLES

The present invention will be described below by way of Examples, but the present invention is not limited to these Examples.

First, the evaluation methods used in the Examples and Comparative Examples will be described below.

### (¹H-NMR)

Deuterated chloroform solutions of the compounds obtained in Examples 1 and 3 to 11 were subjected to ¹H-NMR measurements using a superconducting FTNMR EX-270 (manufactured by JEOL Ltd.) to identify the structures of the compounds.

### (Emission Characteristics)

For diluted solutions with a concentration of 10⁻⁵ mol/L prepared by dissolving the compounds obtained in Examples 1, 3 to 11 and Comparative Examples 1 and 2 in toluene, the emission wavelengths were measured using a fluorescence spectrophotometer (FluoroMax-4P) manufactured by Horiba, Ltd., and the peak wavelength and half width were determined.

### (Light Emitting Element Characteristics)

A voltage was applied to the light emitting elements obtained in Examples 12 to 35 and Comparative Examples 3 to 6 so that the current density became 0.1 mA/cm², and the emission wavelength was measured using a spectroradiometer CS-1000 manufactured by Konica Minolta, Inc. From the emission wavelength thus obtained, the light emitting element efficiency was calculated on the assumption that Lambertian radiation was carried out.

The emission wavelength was measured in the same manner when a voltage was applied to the light emitting element so that the current density became 10 mA/cm², and the peak wavelength and half width were calculated.

A voltage was applied to the light emitting elements obtained in Examples 12 to 35 and Comparative Examples 3 to 6 so that the current density became 10 mA/cm², and the luminance of the light emitting element was measured using a photodiode to obtain an initial luminance. Furthermore, a voltage was continuously applied so that the current density became 10 mA/cm², and the time required for the luminance to reach 90% of the initial luminance (LT90) was measured and defined as an index of durability.

### Example 1

1-Pyreneboronic acid (25 g), 1-bromo-4-tert-butyl-2-nitrobenzene (28.7 g), tetrakis(triphenylphosphine)palladium(0) (1.17 g), potassium phosphate (30.2 g), 1,2-dimethoxyethane (500 ml) and water (60 ml) were charged in a flask, followed by heating and stirring at 100° C. for 2 hours under a nitrogen atmosphere. After heating and stirring, the reaction mixture was cooled to room temperature, water and toluene were added thereto, followed by separation. The solvent was removed from the organic layer under reduced pressure, and the residue was purified by silica gel column chromatography to obtain an intermediate 1 (yield of 70%).

The intermediate 1 (5.7 g), triphenylphosphine (9.8 g) and 1,2-dichlorobenzene (30 ml) were charged in a flask, followed by heating and stirring at 180° C. for 8 hours. After heating and stirring, the solvent was distilled off under reduced pressure. Purification was carried out by silica gel column chromatography to obtain an intermediate 2 (yield of 51%).

A raw material 1 shown in the following reaction scheme was prepared. The raw material 1 can be synthesized by the method disclosed in Journal of American Chemical Society, 2020, vol. 142, pp. 19468-19472.

The raw material 1 (2.9 g), the intermediate 2 (2.6 g), potassium phosphate (2.0 g) and N,N-dimethylformamide (32 ml) were charged in a flask, followed by heating and stirring at 150° C. for 6 hours under a nitrogen atmosphere. After heating and stirring, the reaction mixture was cooled to room temperature, and water and toluene were added thereto, followed by separation. The solvent was removed from the organic layer under reduced pressure, and the residue was purified by silica gel column chromatography to obtain an intermediate 3 (yield of 62%).

A flask containing the intermediate 3 (3.2 g) and xylene (40 ml) added therein was cooled to −50° C., and a 1.6 M n-butyllithium hexane solution (3.1 ml) was added dropwise. After completion of the dropwise addition, the mixture was stirred for 1 hour while being heated to 0° C. The mixture was cooled again to −50° C., and boron tribromide (1.2 g) was added dropwise. After completion of the dropwise addition, the mixture was stirred for 1 hour while raising the temperature to room temperature and cooled to 0° C., and then N,N-diisopropylethylamine (1.1 g) was added, followed by heating and stirring at 150° C. for 5 hours. The reaction solution was cooled to room temperature, and water and dichloromethane were added thereto, followed by separation. The solvent was removed from the organic layer under reduced pressure, and the residue was purified by silica gel column chromatography to obtain D-1 (yield of 29%). The results of the ¹H-NMR measurement of the compound D-1 thus obtained are shown below.

¹H-NMR (CDCl₃ (d=ppm)): 9.59 (d, 1H), 9.19 (d, 1H), 8.90 (s, 1H), 8.84 (d, 1H), 8.68 (s, 1H), 8.30-8.46 (m, 8H), 8.17 (d, 1H), 8.05 (t, 2H), 7.70 (m, 2H), 1.60 (s, 9H), 1.57 (s, 9H), 1.55 (s, 9H).

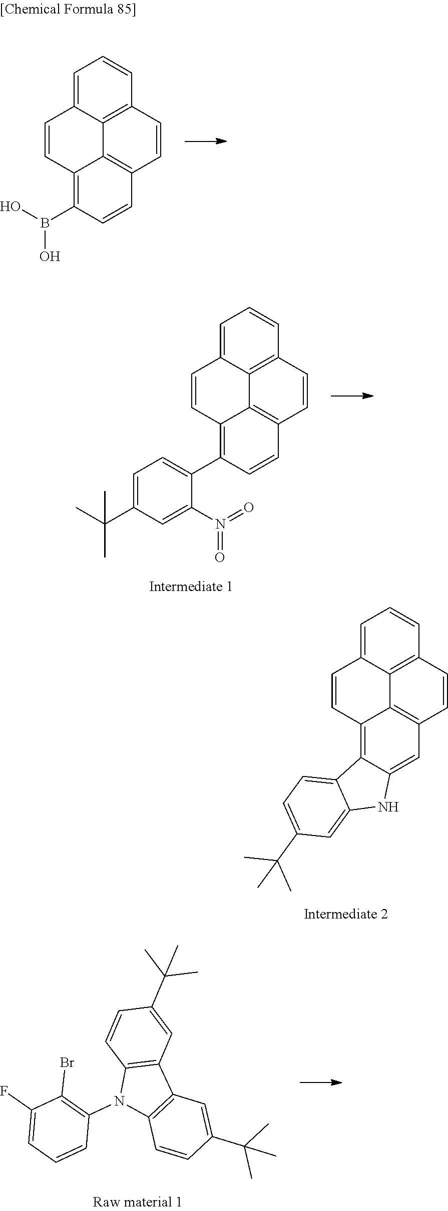 [SMILES: OB(O)c1ccc2ccc3cccc4ccc1c2c34 ; CC(C)(C)c1ccc(-c2ccc3ccc4cccc5ccc2c3c45)c([N+](=O)[O-])c1 ; CC(C)(C)c1ccc2c(c1)[nH]c1cc3ccc4cccc5ccc(c12)c3c45 ; CC(C)(C)c1ccc2c(c1)c1cc(C(C)(C)C)ccc1n2-c1cccc(F)c1Br]

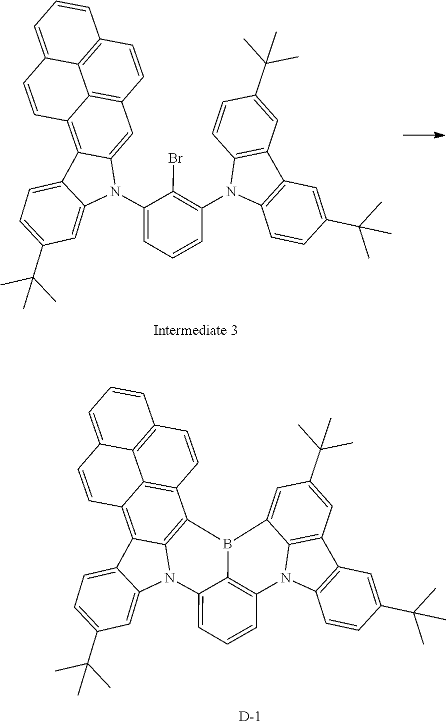

The compound D-1 was purified by sublimation at 370° C. under a pressure of 1×10⁻³ Pa using an oil diffusion pump, and then used as a light emitting element material. The evaluation results of the emission characteristics of compound D-1 are shown in Table 1.

### Example 2

In the same manner as in the synthesis of the intermediate 1 of Example 1, except that 1-bromo-4-tert-butyl-2-nitrobenzene was replaced with 1-bromo-2-nitrobenzene, synthesis was carried out to obtain an intermediate 4 (yield of 68%).

In the same manner as in the synthesis of the intermediate 2, except that the intermediate 1 was changed to the intermediate 4, synthesis was carried out to obtain an intermediate 5 (yield of 45%).

In the same manner as in the synthesis of the intermediate 3, except that the intermediate 2 was changed to the intermediate 5, synthesis was carried out to obtain an intermediate 6 (yield of 70%).

In the same manner as in the synthesis of D-1, except that the intermediate 3 was changed to the intermediate 6, synthesis was carried out. The reaction solution was analyzed by LC-MS, and it was confirmed that D-2 and its structural isomer D-3 are mixed in a ratio of 78:22. From a comparison between Example 1 and Example 2, it can be seen that less isomers are formed in Example 1 where R²⁰³ is a substituent other than hydrogen, and that the substituent of R²⁰³ suppresses formation of isomers.

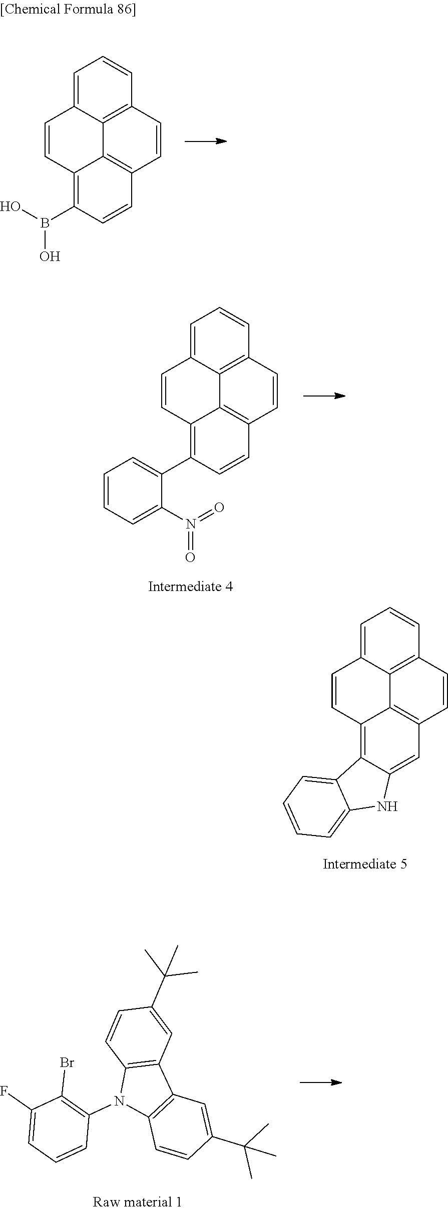 [SMILES: OB(O)c1ccc2ccc3cccc4ccc1c2c34 ; O=[N+]([O-])c1ccccc1-c1ccc2ccc3cccc4ccc1c2c34 ; c1cc2ccc3cc4[nH]c5ccccc5c4c4ccc(c1)c2c34 ; CC(C)(C)c1ccc2c(c1)c1cc(C(C)(C)C)ccc1n2-c1cccc(F)c1Br]

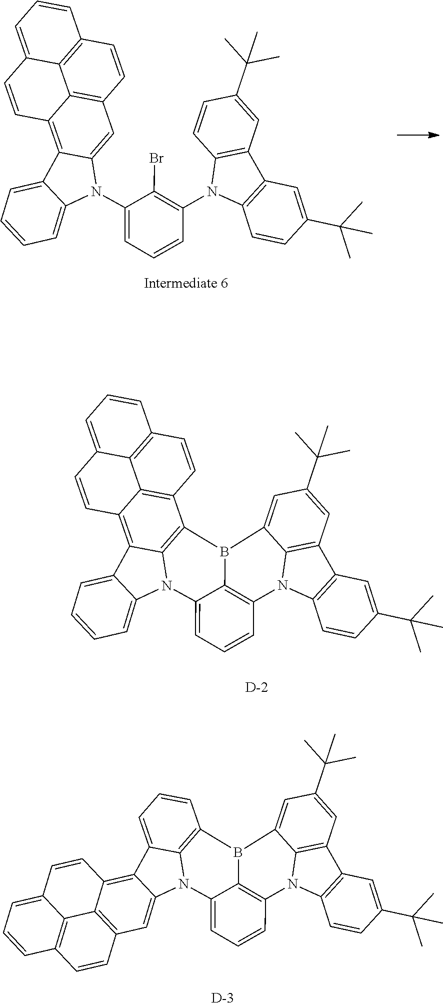

### Example 3

A raw material 2 was prepared as shown in the reaction scheme below. The raw material 2 can be synthesized by the method disclosed in Journal of Materials Chemistry C, 2022, vol. 10, pp. 1698-1710.

In the same manner as in the synthesis of the intermediate 1 of Example 1, except that 1-pyreneboronic acid was changed to the raw material 2, synthesis was carried out to obtain an intermediate 7 (yield of 80%).

In the same manner as in the synthesis of the intermediate 2, except that the intermediate 1 was changed to the intermediate 7, synthesis was carried out to obtain an intermediate 8 (yield of 53%).

1-Bromo-2,6-difluorobenzene (4.9 g), the intermediate 8 (16.0 g), potassium phosphate (13.5 g) and N,N-dimethylformamide (127 ml) were charged in a flask, followed by heating and stirring at 150° C. for 7 hours under a nitrogen atmosphere. After heating and stirring, the reaction solution was cooled to room temperature, and water and toluene were added thereto, followed by separation. The solvent was removed from the organic layer under reduced pressure, and the residue was purified by silica gel column chromatography to obtain an intermediate 8 (yield of 47%).

A flask containing the intermediate 8 (9.0 g) and xylene (120 ml) added therein was cooled to −50° C., and a 1.6 M n-butyllithium hexane solution (8.2 ml) was added dropwise. After completion of the dropwise addition, the mixture was stirred for 1 hour while temperature rising to 0° C. The mixture was cooled again to −50° C., and boron tribromide (3.6 g) was added dropwise. After completion of the dropwise addition, the mixture was stirred for 1 hour while temperature rising to room temperature and cooled to 0° C., and then N,N-diisopropylethylamine (3.1 g) was added, followed by heating and stirring at 150° C. for 8 hours. The reaction solution was cooled to room temperature, and water and dichloromethane were added thereto, followed by separation. The solvent was removed from the organic layer under reduced pressure, and the residue was purified by silica gel column chromatography to obtain D-4 (yield of 36%). The results of the ¹H-NMR measurement of the compound D-4 thus obtained are shown below.

¹H-NMR (CDCl₃ (d=ppm)): 8.56 (m, 4H), 8.50 (d, 2H), 8.35 (d, 2H), 8.04 (t, 1H), 7.82 (t, 2H), 7.63 (d, 2H), 7.43 (d, 2H), 4.23 (m, 2H), 3.70 (m, 2H), 3.42 (m, 4H), 1.60 (s, 18H).

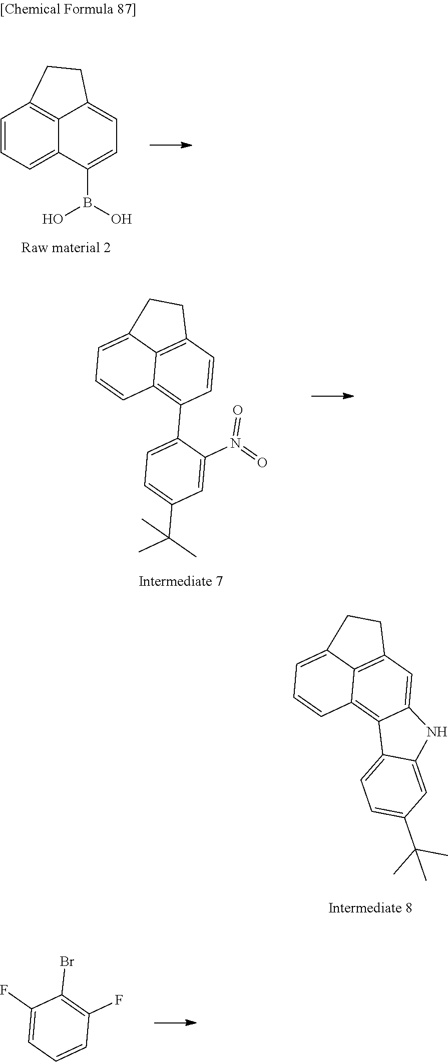 [SMILES: OB(O)c1ccc2c3c(cccc13)CC2 ; CC(C)(C)c1ccc(-c2ccc3c4c(cccc24)CC3)c([N+](=O)[O-])c1 ; CC(C)(C)c1ccc2c(c1)[nH]c1cc3c4c(cccc4c12)CC3 ; Fc1cccc(F)c1Br]

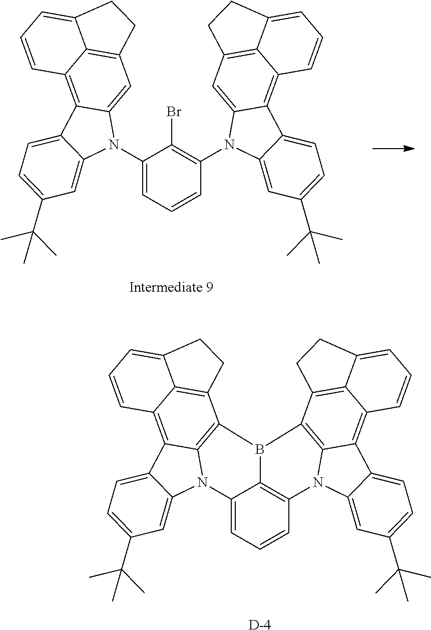

The compound D-4 was purified by sublimation at 360° C. under a pressure of 1×10⁻³ Pa using an oil diffusion pump, and then used as a light emitting element material. The evaluation results of the emission characteristics of compound D-4 are shown in Table 1.

### Examples 4 to 11

By appropriately changing the raw materials and synthesis conditions, compounds D-5 to D-12 having the following structures were synthesized and evaluated in the same manner as in Example 1. The results are shown in Table 1.

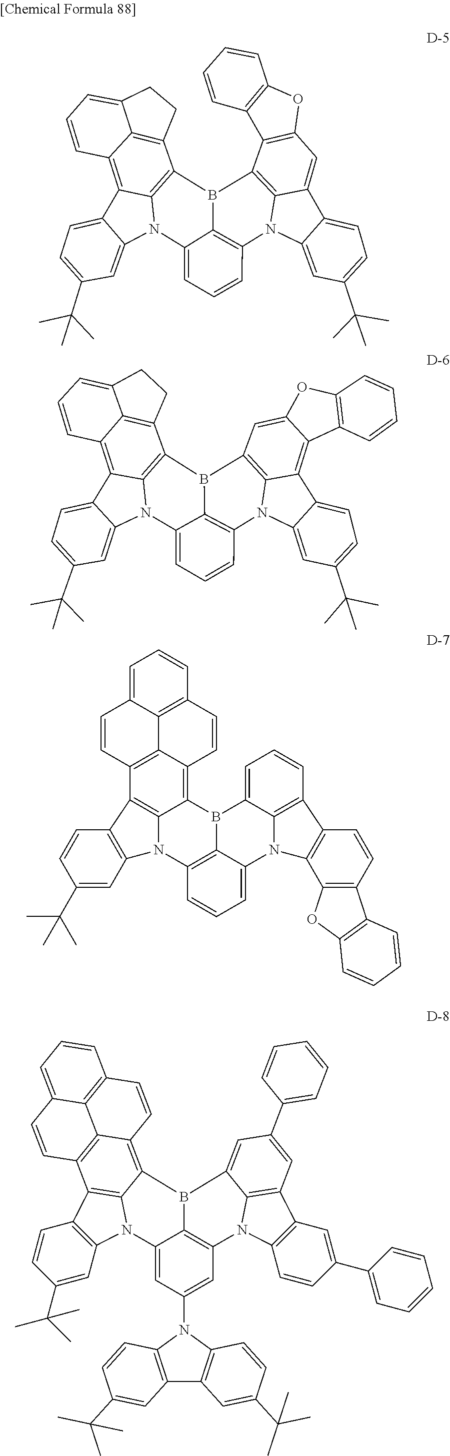

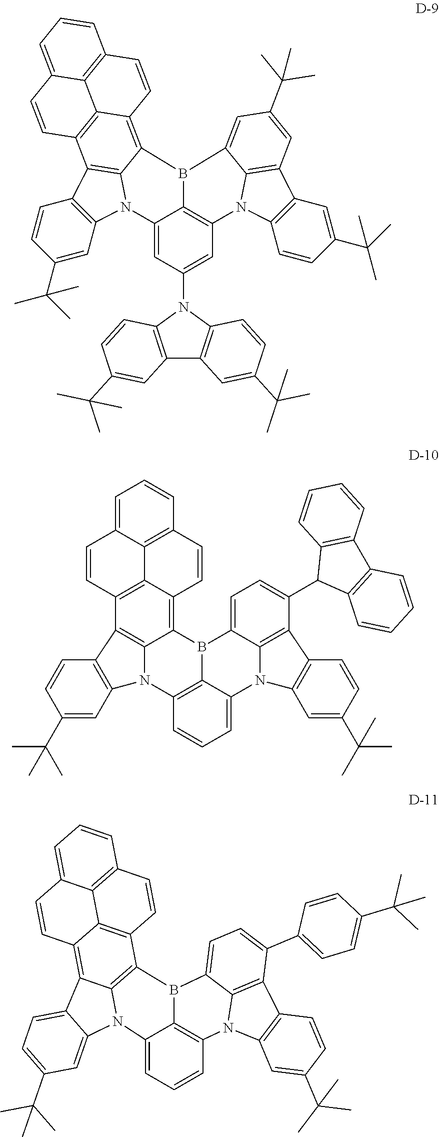

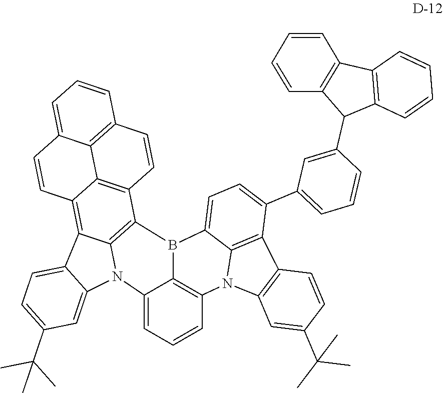 [SMILES: CC(C)(C)c1ccc2c3c(-c4cccc(C5c6ccccc6-c6ccccc65)c4)ccc4c3n(c2c1)-c1cccc2c1B4c1c3ccc4cccc5ccc(c3c45)c3c4ccc(C(C)(C)C)cc4n-2c13]

### Comparative Examples 1, 2

Compounds EX-1 and EX-2 having the following structures were evaluated in the same manner as in Example 1. The results are shown in Table 1.

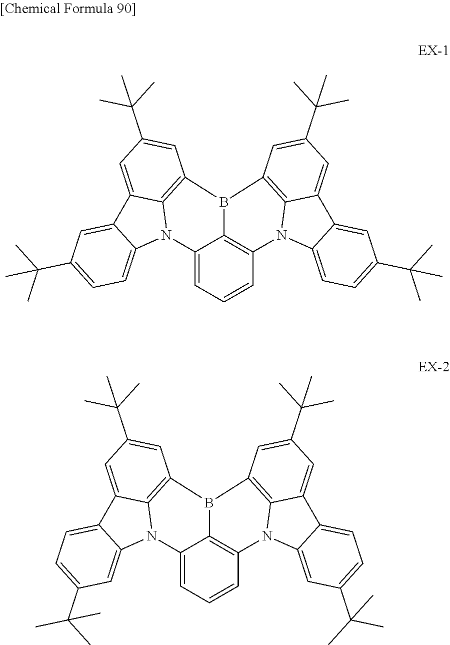

TABLE 1

| | | Emission characteristics | |
|---|---|---|---|
| | | Peak | Half |
| | | wavelength | width |
| | Compound | (nm) | (nm) |
| Example 1 | D-1 | 525 | 25 |
| Example 3 | D-4 | 516 | 26 |
| Example 4 | D-5 | 521 | 31 |
| Example 5 | D-6 | 522 | 32 |
| Example 6 | D-7 | 525 | 25 |
| Example 7 | D-8 | 518 | 23 |
| Example 8 | D-9 | 516 | 21 |
| Example 9 | D-10 | 523 | 24 |
| Example 10 | D-11 | 523 | 25 |
| Example 11 | D-12 | 524 | 25 |
| Comparative Example 1 | EX-1 | 481 | 22 |
| Comparative Example 2 | EX-2 | 479 | 22 |

### Example 12

A glass substrate (manufactured by GEOMATEC Co., Ltd., 11Ω/□, sputtered product) on which an ITO transparent conductive film was vapor-deposited with a thickness of 100 nm was cut into a size of 38×46 mm and etched. The substrate thus obtained was ultrasonically cleaned with “SEMICOCLEAN (trade name) 56” (manufactured by Furuuchi Chemical Corporation) for 15 minutes, and then washed with ultrapure water. Immediately before the element was produced, this substrate was subjected to a UV-ozone treatment for 1 hour, installed in a vacuum vapor deposition device, and the air was exhausted until the vacuum degree in the device became 5×10⁻⁴ Pa or less. By the resistance heating method, HAT-CN6 was first vapor-deposited with a thickness of 10 nm as a hole injection layer on the ITO transparent conductive film. Next, a compound HT-1 was vapor-deposited with a thickness of 40 nm as a first hole transporting layer. Next, a compound HT-2 was vapor-deposited with a thickness of 10 nm as a second hole transporting layer. Next, a compound H-1 as a matrix material and a compound D-1 as a dopant material were, with the doping concentration of 1% by mass of the dopant material, vapor-deposited with a thickness of 20 nm to form a light emitting layer. Next, a compound ET-1 as an electron transporting material and a compound 2E-1 as a donor material were vapor-deposited with a thickness of 30 nm in such a way that the vapor deposition rate ratio of ET-1 and 2E-1 was 1:1 to form an electron transporting layer. Thereafter, magnesium and silver were co-deposited with a thickness of 100 nm to form a cathode. Thus, a 5×5 mm square element was fabricated. HAT-CN6, HT-1, HT-2, H-1, ET-1 and 2E-1 are compounds shown below.

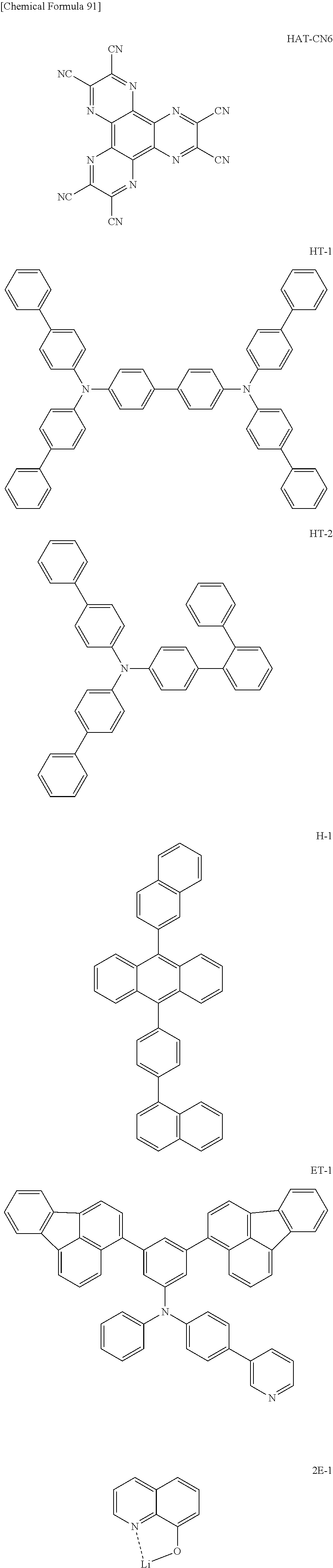

The light emitting element thus obtained was evaluated by the above-mentioned method. The results are shown in Table 2.

### Examples 13 to 20, Comparative Examples 3 to 4

In the same manner as in Example 12, except that the compounds shown in Table 2 were used as the dopant materials, light emitting elements were fabricated and evaluated. The results are shown in Table 2.

TABLE 2

| | | Light | Emission | | |
|---|---|---|---|---|---|
| | | emitting | characteristics | | |
| | | device | Peak | Half | Durability |
| | Dopant | efficiency | wavelength | width | LT90 |
| | material | (%) | (nm) | (nm) | (hours) |
| Example 12 | D-1 | 8.8 | 534 | 33 | 105 |
| Example 13 | D-4 | 7.7 | 516 | 36 | 71 |
| Example 14 | D-5 | 7.9 | 521 | 38 | 75 |
| Example 15 | D-6 | 7.5 | 522 | 40 | 74 |
| Example 16 | D-7 | 9.5 | 525 | 33 | 102 |
| Example 17 | D-8 | 8.7 | 518 | 30 | 108 |
| Example 18 | D-9 | 8.7 | 516 | 29 | 107 |
| Example 19 | D-11 | 9.3 | 523 | 33 | 110 |
| Example 20 | D-12 | 9.5 | 524 | 33 | 115 |
| Comparative | EX-1 | 5.1 | 481 | 32 | 52 |
| Example 3 | | | | | |
| Comparative | EX-2 | 5.4 | 479 | 32 | 56 |
| Example 4 | | | | | |

### Example 21

A glass substrate (manufactured by GEOMATEC Co., Ltd., 11Ω/□, sputtered product) on which an ITO transparent conductive film was vapor-deposited with a thickness of 100 nm was cut into a size of 38×46 mm and etched. The substrate thus obtained was ultrasonically cleaned with “SEMICOCLEAN 56” (trade name, manufactured by Furuuchi Chemical Corporation) for 15 minutes, and then washed with ultrapure water. Immediately before the element was fabricated, this substrate was subjected to a UV-ozone treatment for 1 hour, installed in a vacuum vapor deposition device, and the air was exhausted until the vacuum degree in the device became 5×10⁻⁴ Pa or less. By the resistance heating method, HAT-CN6 was first vapor-deposited with a thickness of 10 nm as a hole injection layer, and then HT-3 was vapor-deposited with a thickness of 30 nm as a hole transporting layer on the ITO transparent conductive film. Next, H-2 as a matrix material, a compound D-1 as a dopant material and a compound H-3 exhibiting delayed fluorescence were, at the weight ratio of 79.0:1.0:20, vapor-deposited with a thickness of 30 nm to form a light emitting layer. Subsequently, ET-2 was laminated with a thickness of 10 nm as a hole blocking layer, and ET-3 was laminated with a thickness of 40 nm as an electron transporting layer. After 2E-1 was vapor-deposited with a thickness of 0.5 nm as an electron injection layer, magnesium and silver were co-deposited with a thickness of 100 nm to form a cathode, thus fabricating a 5×5 mm square light emitting element. HT-3, H-2, H-3, ET-2 and ET-3 are the compounds shown below.

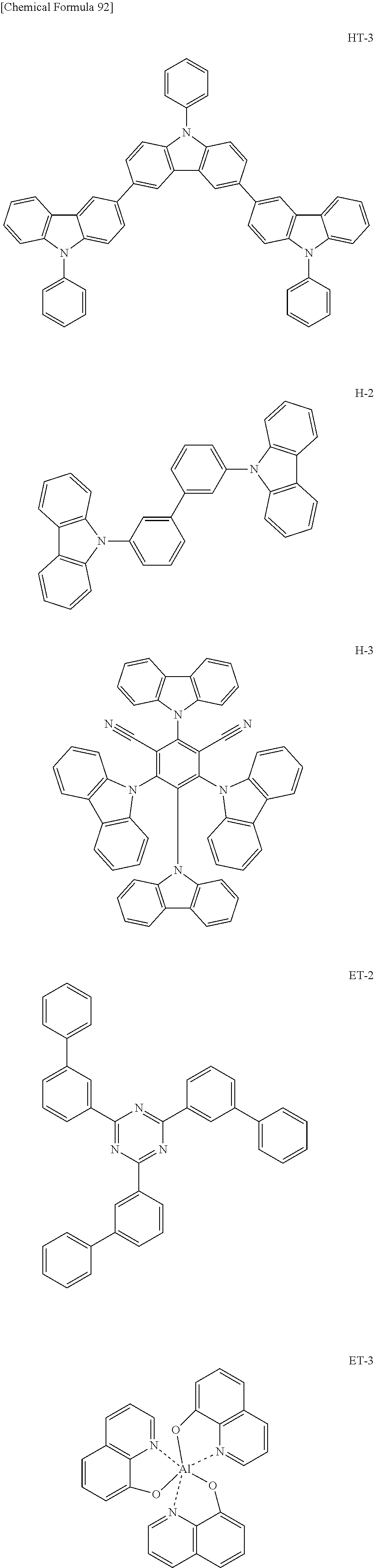

The light emitting element thus obtained was evaluated by the above-mentioned method. The results are shown in Table 3.

### Examples 22 to 29, Comparative Examples 5 to 6

In the same manner as in Example 21, except that the compounds shown in Table 3 were used as the dopant materials, light emitting elements were fabricated and evaluated. The results are shown in Table 3.

TABLE 3

| | | | Emission | | |
|---|---|---|---|---|---|
| | | Light emitting | characteristics | | |
| | | device | Peak | Half | Durability |
| | Dopant | efficiency | wavelength | width | LT90 |
| | material | (%) | (nm) | (nm) | (hours) |
| Example 21 | D-1 | 19.5 | 534 | 34 | 105 |
| Example 22 | D-4 | 16.1 | 516 | 38 | 71 |
| Example 23 | D-5 | 16.5 | 521 | 40 | 75 |
| Example 24 | D-6 | 16.8 | 522 | 42 | 74 |
| Example 25 | D-7 | 20.7 | 525 | 34 | 102 |
| Example 26 | D-8 | 19.2 | 518 | 31 | 108 |
| Example 27 | D-9 | 19.3 | 516 | 30 | 107 |
| Example 28 | D-11 | 20.5 | 523 | 34 | 110 |
| Example 29 | D-12 | 21.0 | 524 | 34 | 115 |
| Comparative | EX-1 | 9.5 | 481 | 45 | 52 |
| Example 5 | | | | | |
| Comparative | EX-2 | 9.6 | 479 | 43 | 56 |
| Example 6 | | | | | |

### Example 30

### (Evaluation of Tandem-Type Light Emitting Element)

A glass substrate (manufactured by GEOMATEC Co., Ltd., 11Ω/□, sputtered product) on which an ITO transparent conductive film was vapor-deposited with a thickness of 100 nm was cut into a size of 38×46 mm and etched. The substrate thus obtained was ultrasonically cleaned with “SEMICOCLEAN 56” (trade name, manufactured by Furuuchi Chemical Corporation) for 15 minutes, and then washed with ultrapure water. Immediately before the element was fabricated, this substrate was subjected to a UV-ozone treatment for 1 hour, installed in a vacuum vapor deposition device, and the air was exhausted until the vacuum degree in the device became 5×10⁻⁴ Pa or less. By the resistance heating method, HAT-CN6 was first vapor-deposited with a thickness of 10 nm as a hole injection layer, and then HT-3 was vapor-deposited with a thickness of 30 nm as a hole transporting layer on the ITO transparent conductive film. Next, a host material (third compound) H-2, a dopant material (first compound) compound G-1 and a compound H-3 which is a TADF material (second compound) were, at the weight ratio of 79.0:1.0:20, vapor-deposited with a thickness of 30 nm to form a light emitting layer. Subsequently, ET-2 was laminated with a thickness of 10 nm as a hole blocking layer, and ET-3 was laminated with a thickness of 40 nm as an electron transporting layer. Subsequently, a compound ET-4 as an n-type host and metallic lithium as an n-type dopant were, at the weight ratio of 99:1, laminated with a thickness of 10 nm to form an n-type charge generating layer. Furthermore, HAT-CN6 was laminated with a thickness of 10 nm as a p-type charge generation layer. A hole transporting layer with a thickness of 30 nm and a light emitting layer with a thickness of 30 nm were formed thereon in the same manner as above. Further, ET-2 was vapor-deposited with a thickness of 10 nm as a hole blocking layer, and ET-3 was vapor-deposited with a thickness of 40 nm as an electron transporting layer in this order. After 2E-1 was vapor-deposited with a thickness of 0.5 nm as an electron injection layer, magnesium and silver were co-deposited with a thickness of 1,000 nm to form a cathode, thus fabricating a 5×5 mm square tandem-type light emitting element.

The light emitting element thus obtained was evaluated by the above-mentioned method, and the light emitting element efficiency was found to be 31.5% and the LT90 was found to be 210 hours.

### Example 31

In the same manner as in Example 70, except that the compound shown in Table 4 was used in place of D-1 as the dopant material, a light emitting element was fabricated. The evaluation results are shown in Table 4.

### Examples 32 to 33

In the same manner as in Example 30, except that the compound ET-5 was used in place of the compound ET-4 which is the n-type host, as the n-type charge generating layer, and the compounds shown in Table 4 were used as the dopant materials, light emitting devices were fabricated. The evaluation results are shown in Table 4.

### Examples 34 to 35

In the same manner as in Example 30, except that Bphen was used in place of the n-type host compound ET-4 as the n-type charge generation layer, and the compounds shown in Table 4 were used as the dopant material, light emitting devices were fabricated. The evaluation results are shown in Table 4.

ET-4, ET-5 and Bphen are the compounds shown below.

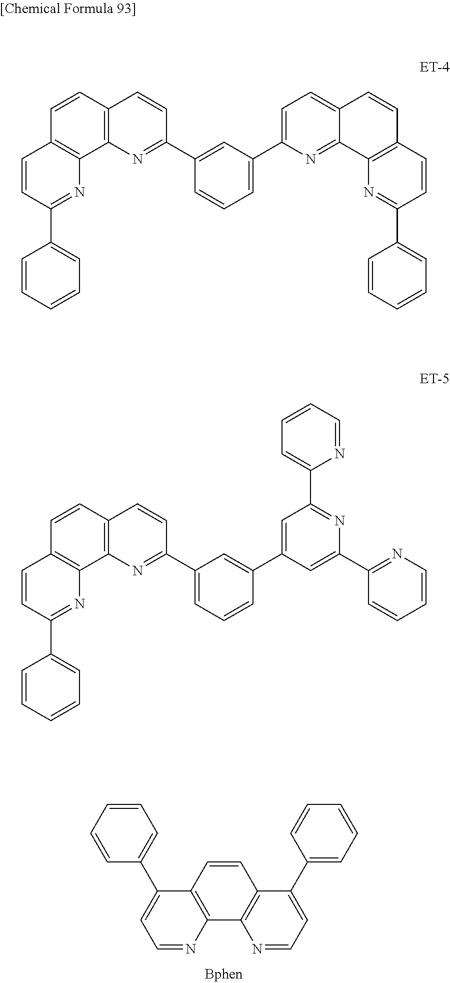 [SMILES: c1ccc(-c2ccc3ccc4ccc(-c5cccc(-c6ccc7ccc8ccc(-c9ccccc9)nc8c7n6)c5)nc4c3n2)cc1 ; c1ccc(-c2ccc3ccc4ccc(-c5cccc(-c6cc(-c7ccccn7)nc(-c7ccccn7)c6)c5)nc4c3n2)cc1 ; c1ccc(-c2ccnc3c2ccc2c(-c4ccccc4)ccnc23)cc1]

TABLE 4

| | | | Light emitting | |
|---|---|---|---|---|
| | | | device | |
| | | n-type | efficiency | LT90 |
| | Compound | host | (%) | (hours) |
| Example 30 | D-1 | ET-4 | 31.5 | 210 |
| Example 31 | D-12 | ET-4 | 32.7 | 223 |
| Example 32 | D-1 | ET-5 | 34.9 | 237 |
| Example 33 | D-12 | ET-5 | 36.5 | 249 |
| Example 34 | D-1 | Bphen | 26.5 | 120 |
| Example 35 | D-12 | Bphen | 27.0 | 125 |

1. A compound having a structure represented by the general formula (1) or (2): 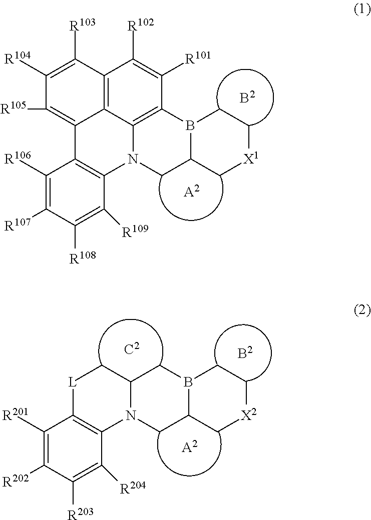
wherein, in the general formula (1), R¹⁰¹ to R¹⁰⁹ are each independently selected from the group consisting of a hydrogen atom, a halogen atom, a cyano group, an alkyl group, a cycloalkyl group, an alkenyl group, a cycloalkenyl group, an alkynyl group, an alkoxy group, an alkylthio group, an aryl ether group, an arylthio ether group, an aryl group, a heteroaryl group, a carboxyl group, an oxycarbonyl group, a carbamoyl group, an amino group, a nitro group and a silyl group; and these groups may further have a substituent; in which R¹⁰⁸ is selected from substituents other than a hydrogen atom;
ring A¹ and ring B¹ are each independently a substituted or unsubstituted aryl ring having 6 to 30 ring-forming carbon atoms, or a substituted or unsubstituted heteroaryl ring having 5 to 30 ring-forming atoms;
X¹ is O, N—R¹¹⁰ or S, R¹¹⁰ is an alkyl group, a cycloalkyl group, an alkenyl group, an imino group, an aryl group or a heteroaryl group; these groups may further have a substituent; and R¹¹⁰ may further form a ring structure between ring A¹ or ring B¹ via a linking group; in this case, the linking group is a single bond, —O—, —S—, >CR¹¹¹R¹¹² or >SiR¹¹³R¹¹⁴; R¹¹¹ to R¹¹⁴ are each independently selected from the group consisting of a hydrogen atom, a halogen atom, an alkyl group, a cycloalkyl group, an aryl group and a heteroaryl group, these groups may further have a substituent; and R¹¹¹ and R¹¹², and R¹¹³ and R¹¹⁴ may be further bonded via a linking group; and
wherein, in the general formula (2), R²⁰¹ to R²⁰⁴ are each independently selected from the group consisting of a hydrogen atom, a halogen atom, a cyano group, an alkyl group, a cycloalkyl group, an alkenyl group, a cycloalkenyl group, an alkynyl group, an alkoxy group, an alkylthio group, an aryl ether group, an arylthio ether group, an aryl group, a heteroaryl group, a carboxyl group, an oxycarbonyl group, a carbamoyl group, an amino group, a nitro group and a silyl group; and these groups may further have a substituent; in which R²⁰³ is selected from substituents other than a hydrogen atom;
ring A² and ring B² are each independently a substituted or unsubstituted aryl ring having 6 to 30 ring-forming carbon atoms, or a substituted or unsubstituted heteroaryl ring having 5 to 30 ring-forming atoms;
ring C² is a substituted or unsubstituted polycyclic aromatic hydrocarbon having 11 or more and 20 or less ring-forming atoms;
L is a single bond, O, S, >CR²⁰⁵R²⁰⁶ or >SiR²⁰⁷R²⁰⁸; R²⁰⁵ to R²⁰⁸ are each independently selected from the group consisting of a hydrogen atom, a halogen atom, an alkyl group, a cycloalkyl group, an aryl group and a heteroaryl group, these groups may further have a substituent; and R²⁰⁵ and R²⁰⁶, and R²⁰⁷ and R²⁰⁸ may be further bonded via a linking group;
X² is O, N—R²⁰⁹ or S, R²⁰⁹ is an alkyl group, a cycloalkyl group, an alkenyl group, an imino group, an aryl group or a heteroaryl group; these groups may further have a substituent; and R²⁰⁹ may further form a ring structure between ring A² or ring B² via a linking group; in this case, the linking group is a single bond, —O—, —S—, >CR²¹⁰R²¹¹ or >SiR²¹²R²¹³; R²¹⁰ to R²¹³ are each independently selected from the group consisting of a hydrogen atom, a halogen atom, an alkyl group, a cycloalkyl group, an aryl group and a heteroaryl group, these groups may further have a substituent; and R²¹⁰ and R²¹¹, and R²¹² and R²¹³ may be further bonded via a linking group.

2. The compound according to claim 1, wherein R¹⁰⁸ and R²⁰³ are selected from an alkyl group, an aryl group and a heteroaryl group.

3. The compound according to claim 1, wherein, in the general formula (2), L is a single bond.

4. The compound according to claim 1, wherein, in the general formula (2), X² is N—R²⁰⁹, and R²⁰⁹ is a substituted or unsubstituted aryl group, a substituted or unsubstituted heteroaryl group, a substituted or unsubstituted alkenyl group, or a substituted or unsubstituted imino group.

5. A light emitting element material comprising the compound according to claim 1.

6. A light emitting element material comprising a cathode, an anode, and one or more organic layers disposed between the cathode and the anode, wherein at least one layer of the organic layers contains the compound according to claim 1.

7. The light emitting element according to claim 6, wherein at least one layer of the one or more organic layers is a light emitting layer.

8. The light emitting element according to claim 7, wherein the light emitting layer further contains a matrix material.

9. The light emitting element according to claim 7, wherein the light emitting layer further contains a compound which exhibits delayed fluorescence.

10. The light emitting element according to claim 7, wherein the light emitting layer further contains a matrix material and a compound which exhibits delayed fluorescence, and when excited singlet energy of the matrix material is S₁ (1), excited singlet energy of a compound which exhibits delayed fluorescence is S₁ (2), and excited singlet energy of a compound having one or more structures represented by the general formula (1) or (2) is S₁ (3), they satisfy the relationship of the formula 1:
$${S}_{1} ( 1 ) > {S}_{1} ( 2 ) > {S}_{1} ( 3 ) . \qquad ( Formula 1 )$$

11. The light emitting element according to claim 7, further comprising a charge generation layer.

12. The light emitting element according to claim 7, which is a top-emission type organic electroluminescence element.

13. A photoelectric conversion material comprising the compound according to claim 1.

14. A color conversion composition which converts incident light into light having a wavelength different from that of the incident light, comprising the compound according to claim 1 and a binder resin.

15. A color conversion sheet comprising the color conversion composition according to claim 14, or a cured product thereof.

16. A light source unit comprising a light source and the color conversion sheet according to claim 15.

17. A display device comprising the light emitting element according to claim 6.

18. A display device comprising the light source unit according to claim 16.

19. An illumination device comprising the light emitting element according to claim 6.

20. An illumination device comprising the light source unit according to claim 16.
